(19) United States
(12) Patent Application Publication
(10) Pub. No.: US 2024/0130235 A1
(43) Pub. Date: Apr. 18, 2024

(54) LIGHT EMITTING ELEMENT AND FUSED POLYCYCLIC COMPOUND FOR THE SAME

(71) Applicant: Samsung Display Co., Ltd., Yongin-si (KR)

(72) Inventors: CHANSEOK OH, Yongin-si (KR); TAEIL KIM, Yongin-si (KR); JANG YEOL BAEK, Yongin-si (KR); MINJAE SUNG, Yongin-si (KR); MINJUNG JUNG, Yongin-si (KR); SEONHYOUNG HUR, Yongin-si (KR)

(21) Appl. No.: 18/369,053

(22) Filed: Sep. 15, 2023

(30) Foreign Application Priority Data
Sep. 19, 2022 (KR) 10-2022-0117712

(51) Int. Cl. H10K 85/60; C07F 5/02; C09K 11/06

(52) U.S. Cl. CPC H10K 85/658; C07F 5/027; C09K 11/06; H10K 50/12

(57) ABSTRACT

A light emitting element includes a first electrode, a second electrode disposed on the first electrode, and an emission layer disposed between the first electrode and the second electrode. The emission layer may include a first compound and at least one of a second compound or a third compound. The first compound may be represented by Formula 1, the second compound may be represented by Formula HT-1, and the third compound may be represented by Formula ET-1. Accordingly, a light emitting element of an embodiment may exhibit excellent or suitable light efficiency.

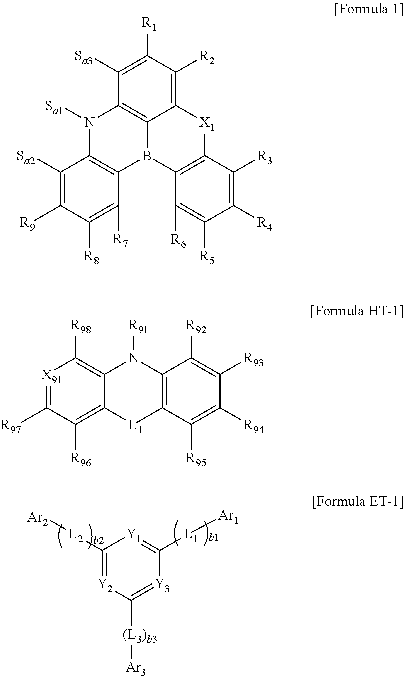

### CROSS-REFERENCE TO RELATED APPLICATIONS

This application claims priority to and the benefit of Korean Patent Application No. 10-2022-0117712, filed in the Korean Intellectual Property Office on Sep. 19, 2022, the entire content of which is hereby incorporated by reference in its entirety.

### BACKGROUND

### 1. Field

Embodiments of the present disclosure herein relate to a light emitting element and a fused polycyclic compound utilized therein.

### 2. Description of the Related Art

Image display devices, organic electroluminescence display devices and/or the like have been actively developed lately. The organic electroluminescence display devices and/or the like are display devices including so-called self-luminescent light emitting elements in which holes and electrons injected from a first electrode and a second electrode recombine in an emission layer, and thus a luminescent material in the emission layer emits light to accomplish display.

For application of light emitting elements to display devices, there is a demand for greater light efficiency, and development of materials, for light emitting elements, capable of stably attaining such characteristics is being continuously required.

### SUMMARY

Aspects of embodiments are directed toward a light emitting element having increased light efficiency.

Aspects of embodiments are directed toward a fused polycyclic compound as a material for a light emitting element, which increases light efficiency.

Additional aspects will be set forth in part in the description which follows and, in part, will be apparent from the description, or may be learned by practice of the presented embodiments of the disclosure.

According to one or more embodiments of the present disclosure, a light emitting element includes a first electrode, a second electrode disposed on the first electrode, and an emission layer disposed between the first electrode and the second electrode, wherein the emission layer includes a first compound represented by Formula 1, and at least one of a second compound represented by Formula HT-1 or a third compound represented by Formula ET-1.

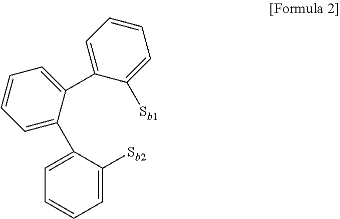

In Formula 1, X₁ may be NR₁₀ or O, R₁ to R₁₀ may each independently be a hydrogen atom, a deuterium atom, a halogen atom, a cyano group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heterocyclic group having 2 to 60 ring-forming carbon atoms, and a first substituent represented by Formula 2 may be bonded to Sₐ₁ and Sₐ₂, and Sₐ₃ may be a hydrogen atom, or the first substituent represented by Formula 2 may be bonded to Sₐ₁ and Sₐ₃, and Sₐ₂ may be a hydrogen atom.

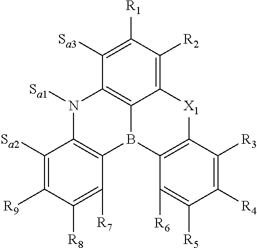

In Formula 2, Sₐ₁ and Sₐ₂ may be positions bonded to Formula 1 above.

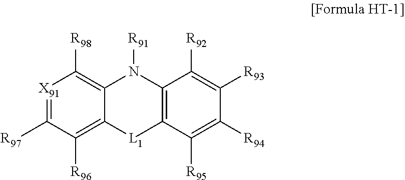

In Formula HT-1, L₁ may be a direct linkage, CR₉₉R₁₀₀, or SiR₁₀₁R₁₀₂, X₉₁ may be N or CR₁₀₃, and R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

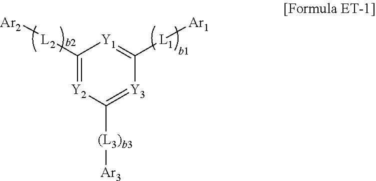

In Formula ET-1, at least one of Y₁ to Y₃ may be N and the others may be CRₐ, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms, and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, Formula 1 may be represented by Formula 1-1 or Formula 1-2.

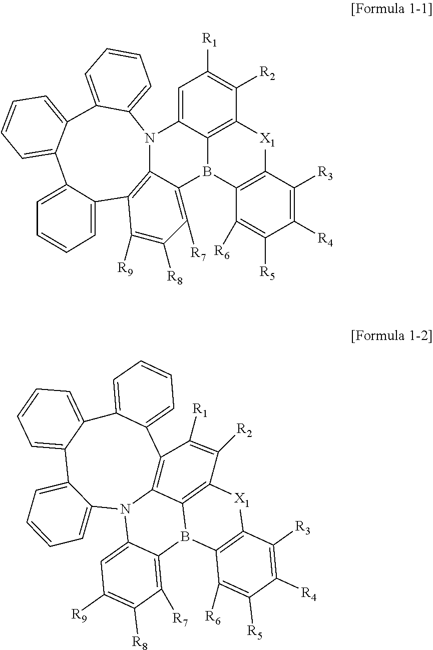

In Formulas 1-1 and 1-2, R₁ to R₉, and X₁ may be the same as defined in Formula 1.

In an embodiment, Formula 1-1 may be represented by Formula 1-1A.

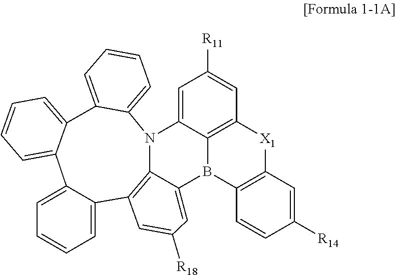

In Formula 1-1A, R₁₁, R₁₄, and R₁₈ may each independently be a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and X₁ may be the same as defined in Formula 1-1.

In an embodiment, Formula 1-2 may be represented by any one among Formulas 1-2A to 1-2C.

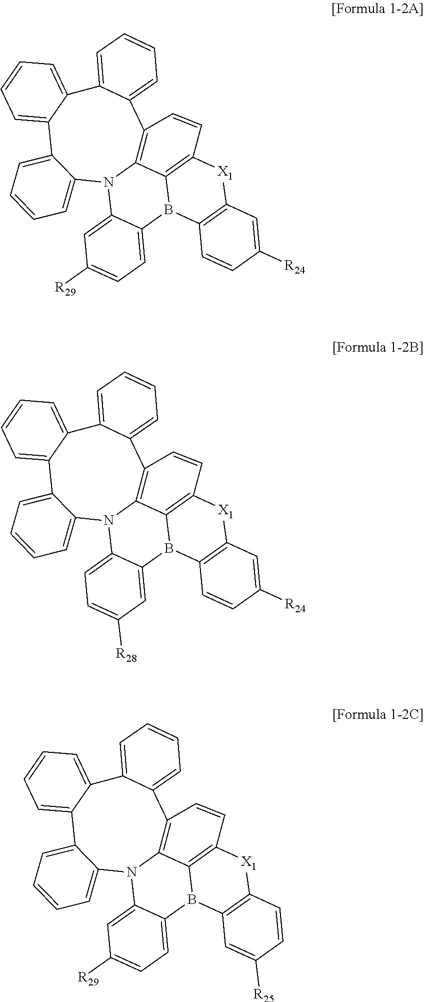

In Formulas 1-2A to 1-2C, R₂₄, R₂₅, R₂₈, and R₂₉ may each independently be a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and X₁ may be the same as defined in Formula 1-2.

In an embodiment, in Formula 1, X₁ may be NR₁₀, and R₁₀ may be represented by any one among R10-1 to R10-4.

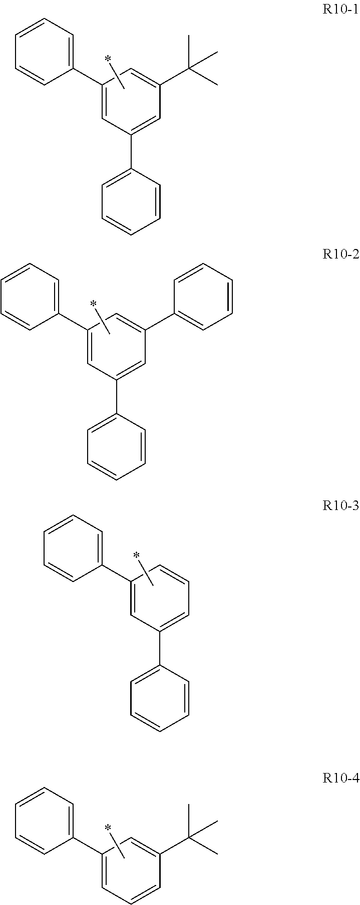

In an embodiment, in Formula 1, R₁ to R₉ may each independently be a hydrogen atom or represented by any one among R-1 to R-19.

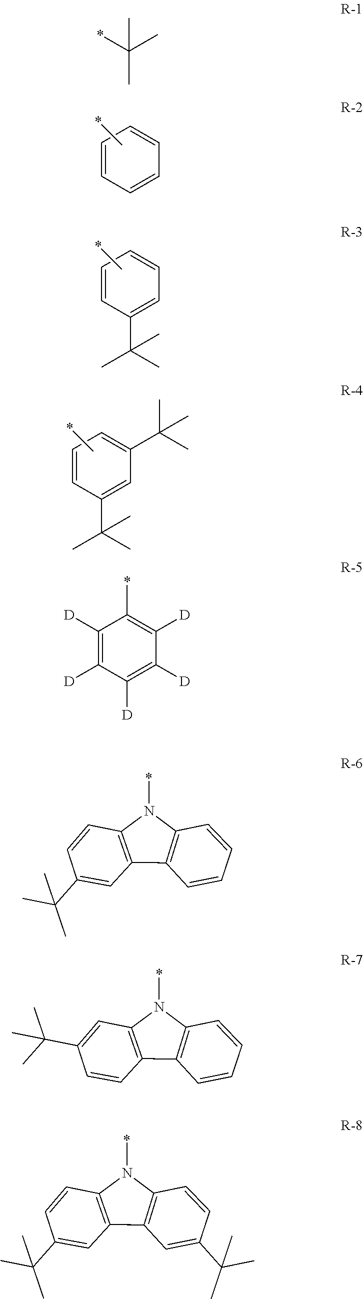

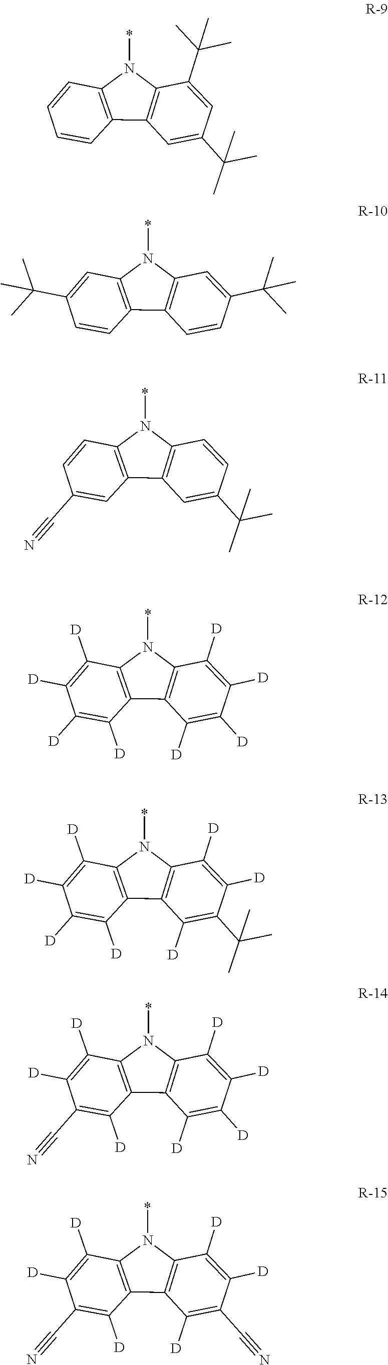

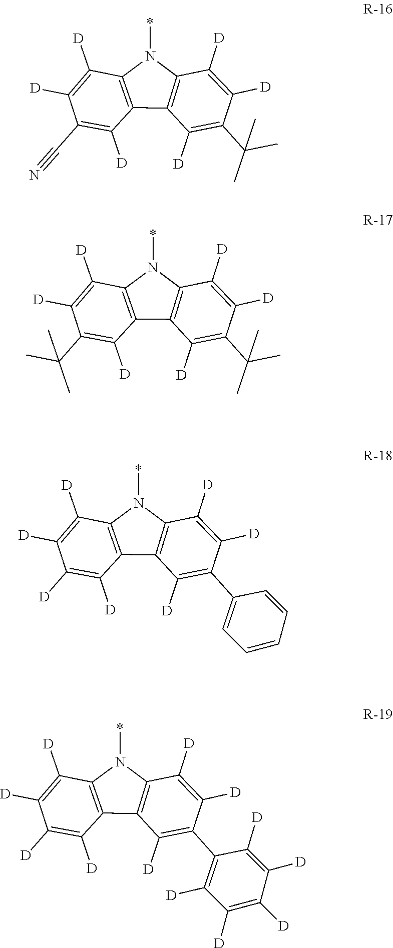

In R-12 and R-19, D is a deuterium atom.

In an embodiment, in Formula 1, at least one of R₁ to R₉ may be represented by any one among R-6 to R-19.

In an embodiment, in Formula 1, at least one of R₁ to R₉ may be a carbazole group substituted with at least one of a deuterium atom, a cyano group, an unsubstituted t-butyl group, an unsubstituted phenyl group, or a substituted phenyl group, or an unsubstituted carbazole group.

In an embodiment, in Formula 1, at least one of R₁ to R₉ may be a deuterium atom or may include a substituent containing a deuterium atom.

In an embodiment, the emission layer may further include a fourth compound represented by Formula M-b.

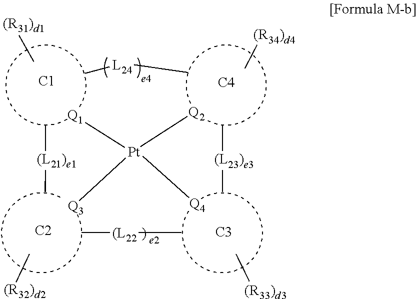

In Formula M-b, Q₁ to Q₄ may each independently be C or N, C1 to 04 may each independently be a substituted or unsubstituted hydrocarbon ring having 5 to 30 ring-forming carbon atoms, or a substituted or unsubstituted heterocycle having 2 to 30 ring-forming carbon atoms, e1 to e4 may each independently be 0 or 1, L₂₁ to L₂₄ may each independently be a direct linkage,

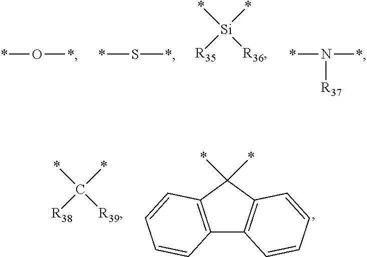

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, d1 to d4 may each independently be an integer of 0 to 4, and R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In an embodiment, the emission layer may include a host and a dopant, and the dopant may contain the first compound.

In an embodiment of the present disclosure, provided is a fused polycyclic compound represented by Formula 1.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a portion corresponding to line I-I′ of FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7A shows a three-dimensional structure of a compound;

FIG. 7B shows a three-dimensional structure of a compound;

FIG. 8 is a cross-sectional view showing a display device according to an embodiment;

FIG. 9 is a cross-sectional view showing a display device according to an embodiment;

FIG. 10 is a cross-sectional view showing a display device according to an embodiment;

FIG. 11 is a cross-sectional view showing a display device according to an embodiment; and

FIG. 12 is a view showing a vehicle in which a display device according to an embodiment is disposed.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

As utilized herein, when an element (or a region, a layer, a portion, and/or the like) is referred to as being “on,” “connected to,” or “coupled to” another element, it refers to that the element may be directly disposed on/connected to/coupled to the other element, or that a third element may be disposed therebetween.

Like reference numerals refer to like elements. In some embodiments, in the drawings, the thickness, the ratio, and the dimensions of elements are exaggerated for an effective description of technical contents. The term “and/or,” includes all combinations of one or more of which associated configurations may define.

It will be understood that, although the terms “first”, “second”, and/or the like may be utilized herein to describe one or more suitable elements, these elements should not be limited by these terms. These terms are only utilized to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In some embodiments, terms such as “below,” “lower,” “above,” “upper,” and/or the like are utilized to describe the relationship of the configurations shown in the drawings. The terms are utilized as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “About” or “substantially”, as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “substantially” may mean within one or more standard deviations, or within ±30%, 20%, 10%, 5% of the stated value.

Depending on context, a divalent group may refer or be a polyvalent group (e.g., trivalent, tetravalent, etc., and not just divalent) per, e.g., the structure of a formula in connection with which of the terms are utilized.

The light emitting element and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the [device] may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Unless otherwise defined, all terms (including technical and scientific terms) utilized herein have the same meaning as commonly understood by one of ordinary skill in the art to which the present disclosure belongs. In some embodiments, terms, such as those defined in commonly utilized dictionaries, should be interpreted as having a meaning that is consistent with their meaning in the context of the relevant art and should not be interpreted in an idealized or overly formal sense unless expressly so defined herein.

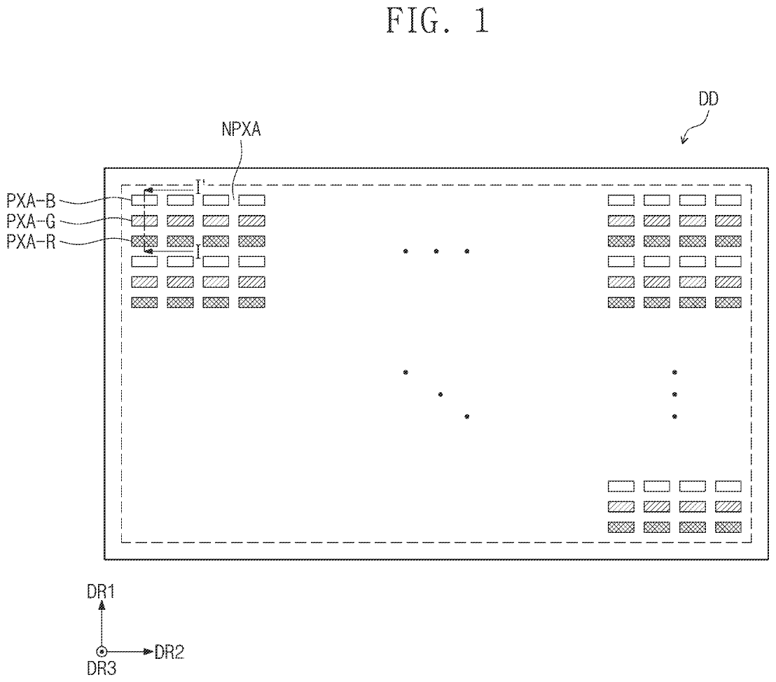

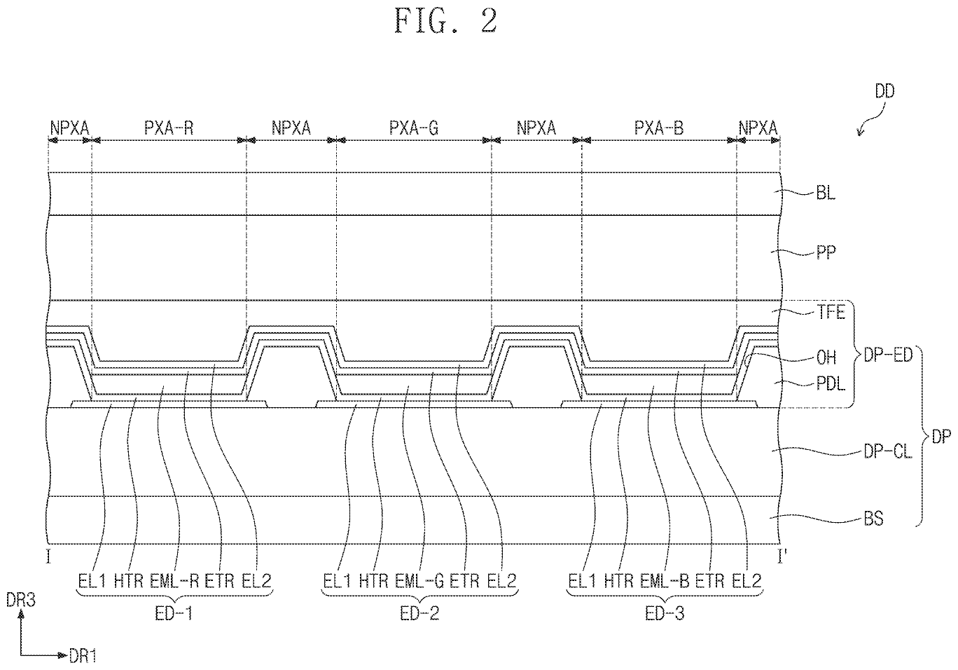

Hereinafter, embodiments of the present disclosure will be described with reference to the accompanying drawings. FIG. 1 is a plan view showing an embodiment of a display device DD. FIG. 2 is a cross-sectional view of a display device DD of an embodiment. FIG. 2 is a cross-sectional view showing a portion corresponding to line I-I′ of FIG. 1.

A display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarizing layer or a color filter layer. In some embodiments, unlike what is shown in the drawings, the optical layer PP may not be provided in the display device DD of an embodiment.

A base substrate BL may be disposed on the optical layer PP. The base substrate BL may be a member providing a base surface on which the optical layer PP is disposed. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike what is shown, the base substrate BL may not be provided in an embodiment.

The display device DD according to an embodiment may further include a filling layer. The filling layer may be disposed between a display element layer DP-ED and the base substrate BL. The filling layer may be an organic material layer. The filling layer may include at least one among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE disposed on the plurality of light emitting elements ED-1, ED-2, and ED-3.

The base layer BS may be a member providing a base surface in which the display element layer DP-ED is disposed. The base layer BS may be a glass substrate, a metal substrate, a plastic substrate, and/or the like. However, the embodiment of the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

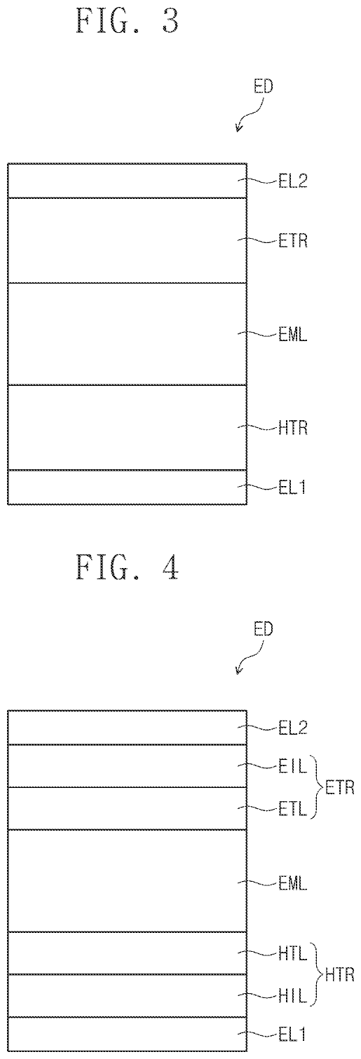

The light emitting elements ED-1, ED-2, and ED-3 may each have a structure of a light emitting element ED according to an embodiment of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided as a common layer throughout the light emitting elements ED-1, ED-2, and ED-3. However, the embodiment of the present disclosure is not limited thereto, and unlike what is shown in FIG. 2, in an embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, and the electron transport region ETR, and/or the like of the light emitting elements ED-1, ED-2, and ED-3 may be patterned and provided through an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be a single layer or a laminated layer of a plurality of layers. The encapsulation layer may include at least one insulating layer. The encapsulation layer TFE according to an embodiment may include at least one inorganic film (hereinafter, an encapsulation inorganic film). In some embodiments, the encapsulation layer TFE according to an embodiment may include at least one organic film (hereinafter, an encapsulation organic film) and at least one encapsulation inorganic film.

The encapsulation inorganic film may protect the display element layer DP-ED from moisture/oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, and/or the like, but is not particularly limited thereto. The encapsulation organic film may include an acrylic compound, an epoxy-based compound, and/or the like. The encapsulation organic film may include a photopolymerizable organic material, and is not particularly limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other when viewed in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In some embodiments, as utilized herein, the light emitting regions PXA-R, PXA-G, and PXA-B may each correspond to a pixel. The pixel defining films PDL may separate the light emitting elements ED-1, ED-2 and ED-3. The emission layers EML-R, EML-G, and EML-B of the light emitting elements ED-1, ED-2 and ED-3 may be disposed and separated in openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B, which may emit red light, green light, and blue light, are shown as an example. For example, the display device DD of an embodiment may include a red light emitting region PXA-R, a green light emitting region PXA-G, and a blue light emitting region PXA-B, which are distinct from one another.

In the display device DD according to an embodiment, the plurality of light emitting elements ED-1, ED-2, and ED-3 may be configured to emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2 and ED-3 may be configured to emit light in substantially the same wavelength range or emit light in at least one different wavelength range. For example, the first to third light emitting elements ED-1, ED-2, and ED-3 may all emit blue light.

The light emitting regions PXA-R, PXA-G, and PXA-B in the display device DD according to an embodiment may be arranged in the form of a stripe. Referring to FIG. 1, a plurality of red light emitting regions PXA-R, a plurality of green light emitting regions PXA-G, and a plurality of blue light emitting regions PXA-B may each be arranged along a second directional axis DR2. In some embodiments, the red light emitting region PXA-R, the green light emitting region PXA-G, and the blue light emitting region PXA-B may be alternately arranged in turn along a first directional axis DR1.

FIGS. 1 and 2 show that the light emitting regions PXA-R, PXA-G, and PXA-B are all similar in size, but the embodiment of the present disclosure is not limited thereto, and the light emitting regions PXA-R, PXA-G and PXA-B may be different in size from each other according to wavelength range of emitted light. In some embodiments, the areas of the light emitting regions PXA-R, PXA-G, and PXA-B may refer to areas when viewed on a plane defined by the first directional axis DR1 and the second directional axis DR2.

In some embodiments, the arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged comes with varied combination according to display quality characteristics required for the display device DD. For example, the light emitting regions PXA-R, PXA-G, and PXA-B may be arranged in the form of a pentile (e.g., PENTILE®) or a diamond (e.g., Diamond Pixel™).

In some embodiments, areas of each of the light emitting regions PXA-R, PXA-G, and PXA-B may be different in size from one another. For example, in an embodiment, the green light emitting region PXA-G may be smaller than the blue light emitting region PXA-B in size, but the embodiment of the present disclosure is not limited thereto.

Hereinafter, FIGS. 3 to 6 are cross-sectional views schematically showing a light emitting element according to an embodiment. The light emitting element ED according to an embodiment may include a first electrode EL1, a hole transport region HTR, an emission layer EML, an electron transport region ETR, and a second electrode EL2.

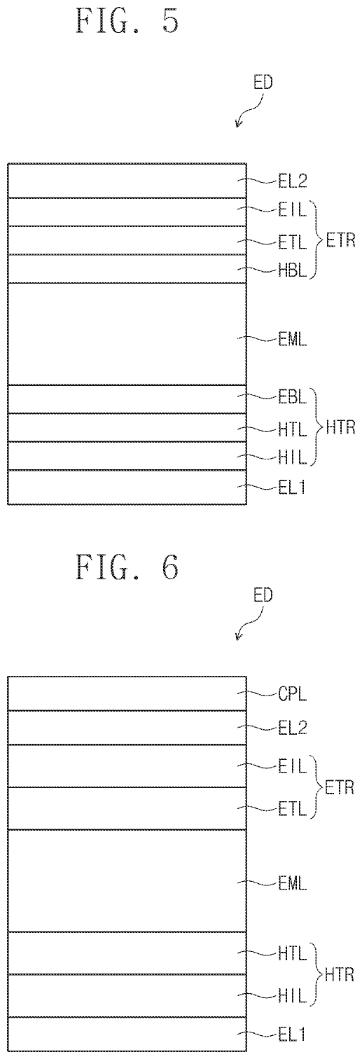

FIG. 4 shows, compared with FIG. 3, a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In some embodiments, FIG. 5 shows, compared with FIG. 3, a cross-sectional view of a light emitting element ED according to an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 4, a cross-sectional view of a light emitting element ED according to an embodiment, in which a capping layer CPL disposed on the second electrode EL2 is provided.

The light emitting element ED of an embodiment may include a first compound and at least one of a second compound or a third compound. The second compound may include a fused ring of three rings, which contains a nitrogen atom as a ring-forming atom. The third compound may include a hexagonal heterocyclic group with a nitrogen atom as a ring-forming atom.

In an embodiment, the first compound may be referred to as a fused polycyclic compound. The first compound and the fused polycyclic compound herein may each independently be the same. In an embodiment, the emission layer EML may include the fused polycyclic compound of an embodiment, and include at least one of the second compound or the third compound.

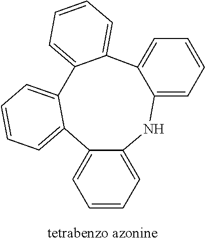 [SMILES: c1ccc2c(c1)[nH]c1ccccc1c1ccccc1c1ccccc21]

In an embodiment, the fused polycyclic compound may include a tetrabenzo azonine derivative. Tetrabenzo azonine constitutes a central structure of the fused polycyclic compound, and the central structure may include a nitrogen atom and a boron atom as ring-forming atoms. In the fused polycyclic compound of an embodiment, the nitrogen atom and the boron atom may be positioned para. A light emitting element ED including the fused polycyclic compound of an embodiment may exhibit excellent or suitable light efficiency.

As utilized herein, the term “substituted or unsubstituted” may indicate that one is substituted or unsubstituted with at least one substituent selected from the group consisting of a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or as a phenyl group substituted with a phenyl group.

As utilized herein, the term “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

As utilized herein, the term “an adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In some embodiments, two methyl groups in 4,5-dimethylphenanthrene may be interpreted as mutually “adjacent groups”.

As utilized herein, examples of a halogen atom may include a fluorine atom, a chlorine atom, a bromine atom, and an iodine atom.

As utilized herein, an alkyl group may be a linear, branched or cyclic type or kind. The number of carbon atoms in the alkyl group is 1 to 60, 1 to 50, 1 to 30, 1 to 20, 1 to 10 or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but are not limited thereto.

As utilized herein, an alkenyl group refers to a hydrocarbon group including at least one carbon double bond in the middle or end of an alkyl group having 2 or more carbon atoms. The alkenyl group may be linear or branched. The number of carbon atoms is not particularly limited, but may be 2 to 60, 2 to 30, 2 to 20 or 2 to 10. Examples of the alkenyl group include a vinyl group, a 1-butenyl group, a 1-pentenyl group, a 1,3-butadienyl aryl group, a styrenyl group, a styryl vinyl group, and/or the like, but are not limited thereto.

As utilized herein, an alkynyl group refers to a hydrocarbon group including at least one carbon triple bond in the middle or end of an alkyl group having 2 or more carbon atoms. The alkynyl group may be linear or branched. The number of carbon atoms is not particularly limited, but may be 2 to 60, 2 to 30, 2 to 20 or 2 to 10. Specific examples of the alkynyl group may include an ethynyl group, a propynyl group, and/or the like, but are not limited thereto.

As utilized herein, a hydrocarbon ring group refers to any functional group or substituent derived from an aliphatic hydrocarbon ring. The hydrocarbon ring group may be a saturated hydrocarbon ring group having 5 to 60, 5 to 30, or 5 to 20 ring-forming carbon atoms.

As utilized herein, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but are not limited thereto.

As utilized herein, a heterocyclic group refers to any functional groups or substituents derived from a ring containing at least one of B, O, N, P, Si, or S as a hetero atom. The heterocyclic group includes an aliphatic heterocyclic group and an aromatic heterocyclic group. The aromatic heterocyclic group may be a heteroaryl group. The aliphatic heterocyclic group and the aromatic heterocyclic group may be monocyclic or polycyclic.

As utilized herein, the heterocyclic group may contain at least one of B, O, N, P, Si or S as a hetero atom. When the heterocyclic group contains two or more hetero atoms, the two or more hetero atoms may be the same as or different from each other. The heterocyclic group may be a monocyclic heterocyclic group or a polycyclic heterocyclic group, and include a heteroaryl group. The number of ring-forming carbon atoms in the heterocyclic group may be 2 to 60, 2 to 30, 2 to 20, or 2 to 10.

As utilized herein, the aliphatic heterocyclic group may contain at least one of B, O, N, P, Si or S as a hetero atom. The number of ring-forming carbon atoms in the aliphatic heterocyclic group may be 2 to 60, 2 to 30, 2 to 20, or 2 to 10. Examples of the aliphatic heterocyclic group include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but are not limited to thereto

As utilized herein, a heteroaryl group may include at least one of B, O, N, P, Si, or S as a hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but are not limited thereto.

As utilized herein, the above description of the aryl group may be applied to an arylene group, except that the arylene group is a divalent group. The above description of the heteroaryl group may be applied to a heteroarylene group, except that the heteroarylene group is a divalent group.

As utilized herein, a silyl group may refer to one that a silicon atom is bonded to an alkyl group or aryl group as defined above. The silyl group includes an alkyl silyl group and an aryl silyl group. The number of carbon atoms in the silyl group is not particularly limited, but may be 1 to 30, 1 to 20, or 1 to 10. Examples of the silyl group include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, and/or the like, but are not limited thereto.

As utilized herein, the number of carbon atoms in a sulfinyl group and a sulfonyl group is not particularly limited, but may be 1 to 30, 1 to 20, or 1 to 10. The sulfinyl group may include an alkyl sulfinyl group and an aryl sulfinyl group. The sulfonyl group may include an alkyl sulfonyl group and an aryl sulfonyl group.

As utilized herein, a thio group may include an alkyl thio group and an aryl thio group. The thio group may indicate the one that a sulfur atom is bonded to an alkyl group or an aryl group as defined above. The number of carbon atoms in the thio group is not particularly limited, but may be 1 to 30, 1 to 20, or 1 to 10. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but are not limited to thereto.

As utilized herein, an oxy group may indicate the one that an oxygen atom is bonded to an alkyl group or aryl group as defined above. The oxy group may include an alkoxy group and an aryl oxy group. The alkoxy group may be linear, branched or cyclic. The number of carbon atoms in the oxy group is not particularly limited, but may be 1 to 30, 1 to 20, or 1 to 10. Examples of the oxy group include methoxy, ethoxy, n-propoxy, isopropoxy, butoxy, pentyloxy, hexyloxy, octyloxy, nonyloxy, decyloxy, benzyloxy, and/or the like, but are not limited thereto.

As utilized herein, a boron group may refer to one that a boron atom is bonded to an alkyl group or aryl group as defined above. The boron group includes an alkyl boron group and an aryl boron group. The number of carbon atoms in the boron group is not particularly limited, but may be 1 to 30, 1 to 20, or 1 to 10. Examples of the boron group include a dimethylboron group, a diethylboron group, a t-butylmethylboron group, a diphenylboron group, a phenylboron group, and/or the like, but are not limited thereto.

As utilized herein, the number of carbon atoms in an amine group is not particularly limited, but may be 1 to 30, 1 to 20, or 1 to 10. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, and/or the like, but are not limited thereto.

As utilized herein, the above-described examples of the alkyl group also apply to the alkyl group in an alkylthio group, an alkyl sulfinyl group, an alkyl sulfonyl group, an alkoxy group, an alkyl boron group, an alkyl silyl group, and an alkyl amine group.

As utilized herein, examples of the aryl group include an aryloxy group, an arylthio group, an aryl sulfinyl group, an aryl sulfonyl group, an aryl boron group, an aryl silyl group, and an aryl amine group.

As utilized herein, a direct linkage may refer to a single bond. As utilized herein,

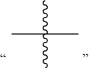

and “—*” refer to positions to be connected.

The fused polycyclic compound of an embodiment may be represented by Formula 1. In an embodiment, the emission layer EML may include the fused polycyclic compound represented by Formula 1.

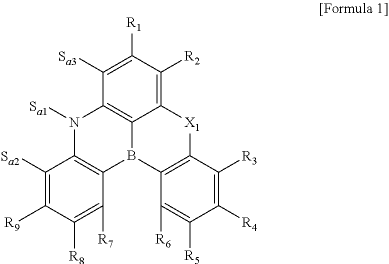

In Formula 1, X₁ may be NR₁₀ or O. When X₁ is NR₁₀, the fused polycyclic compound represented by Formula 1 may include a nitrogen atom as a ring-forming atom of a central structure. When X₁ is O, the fused polycyclic compound represented by Formula 1 may include an oxygen atom as a ring-forming atom of a central structure.

In Formula 1, Sₐ₁ to Sₐ₃ may each independently be a position bonded to Formula 2, which will be described later, or a hydrogen atom. Sₐ₁ to Sₐ₃ will be described in more detail later.

R₁ to R₁₀ may each independently be a hydrogen atom, a deuterium atom, a halogen atom, a cyano group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heterocyclic group having 2 to 60 ring-forming carbon atoms. In an embodiment, at least one of R₁ to R₉ may include a carbazole group, a deuterium atom, or a substituent containing a deuterium atom.

For example, at least one of R₁ to R₉ may be a substituted or unsubstituted carbazole group or a substituent containing a deuterium atom. When at least one of R₁ to R₉ is a substituted carbazole group, the substituted carbazole group may be substituted with at least one of a deuterium atom, a cyano group, an unsubstituted t-butyl group, an unsubstituted phenyl group, or a substituted phenyl group. In the substituted or unsubstituted carbazole group, there may be a position in which a nitrogen atom, which is a ring-forming atom of the carbazole group, is bonded to Formula 1. However, this is presented as an example, and the position bonded to Formula 1 in the carbazole group is not limited thereto.

In Formula 1, X₁ may be NR₁₀, and R₁₀ may be a substituted or unsubstituted phenyl group. In an embodiment, R₁₀ may be represented by any one among R10-1 to R10-4. R10-1 to R10-4 represent phenyl groups substituted with at least one of a phenyl group or a t-butyl group.

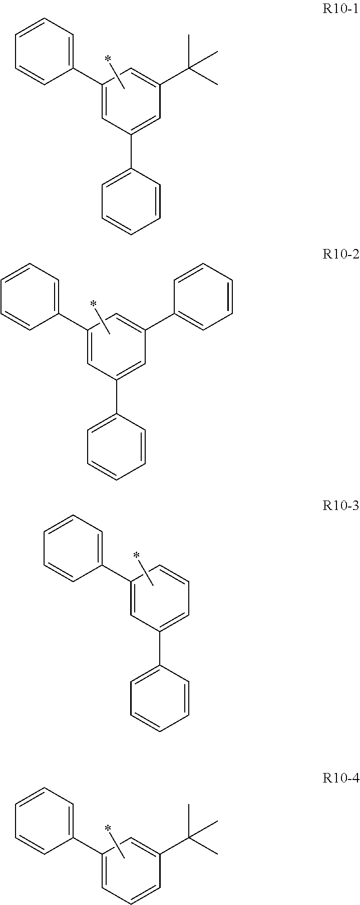

For example, R10-1 may be represented by R10-11, and R10-4 may be represented by R10-41. R10-3 may be represented by any one among R10-31 to R10-33.

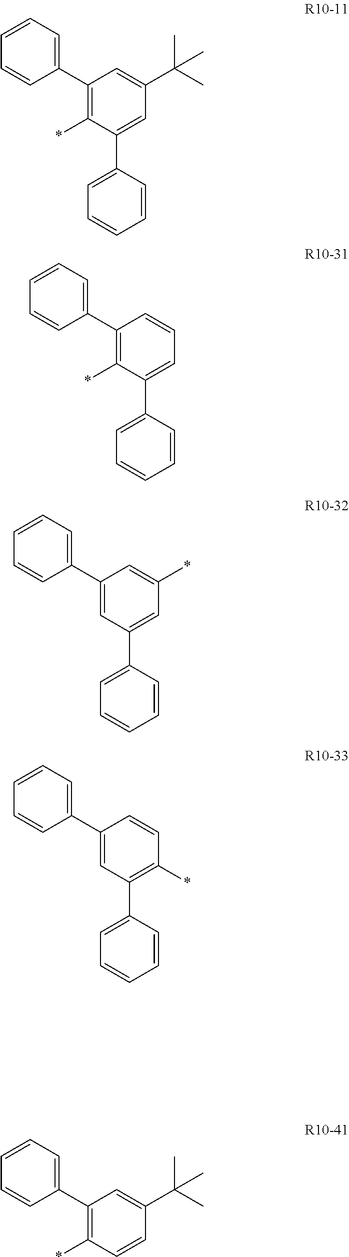 [SMILES: *c1c(-c2ccccc2)cc(C(C)(C)C)cc1-c1ccccc1 ; *c1c(-c2ccccc2)cccc1-c1ccccc1 ; *c1cc(-c2ccccc2)cc(-c2ccccc2)c1 ; *c1ccc(-c2ccccc2)cc1-c1ccccc1 ; *c1ccc(C(C)(C)C)cc1-c1ccccc1]

R10-11 represents a specific binding position in R10-1, and R10-41 represents a specific binding position in R10-4. R10-31 to R10-33 represent specific binding positions in R10-3.

In an embodiment, R₁ and R₉ may each independently be a hydrogen atom or represented by any one among R-1 to R-19. R-1 represents an unsubstituted t-butyl group, and R-2 represents an unsubstituted phenyl group. R-3 and R-4 represent a phenyl group substituted with a t-butyl group, and R-5 represents a phenyl group substituted with a deuterium atom. R-6 to R-19 represent a carbazole group substituted with at least one of a deuterium atom, a cyano group, an unsubstituted t-butyl group, an unsubstituted phenyl group, or a substituted phenyl group.

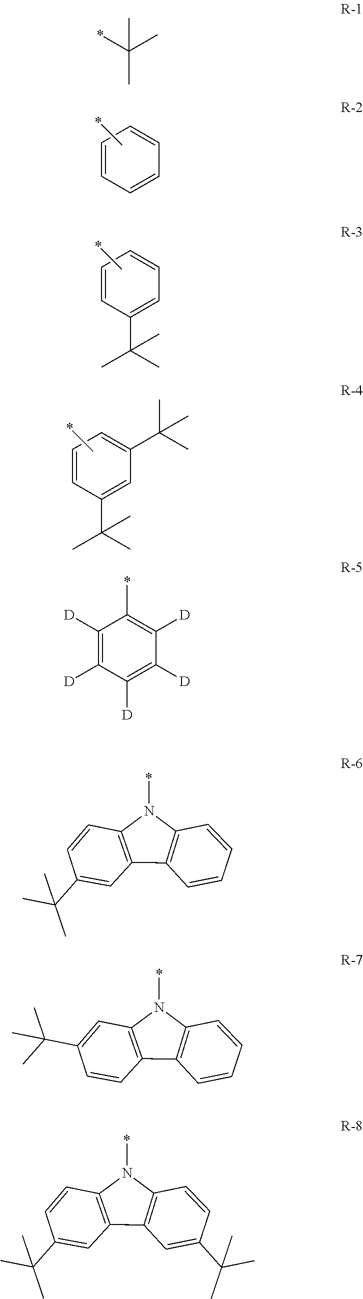

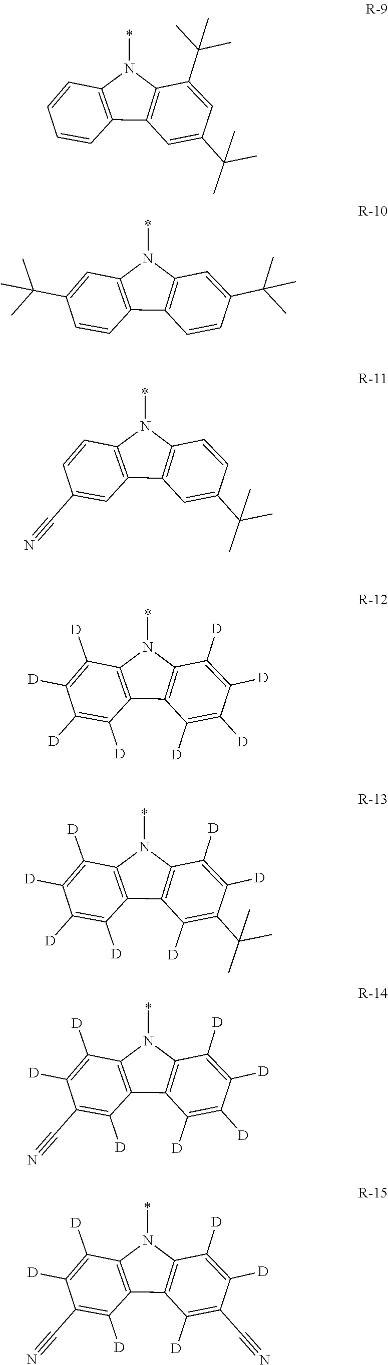

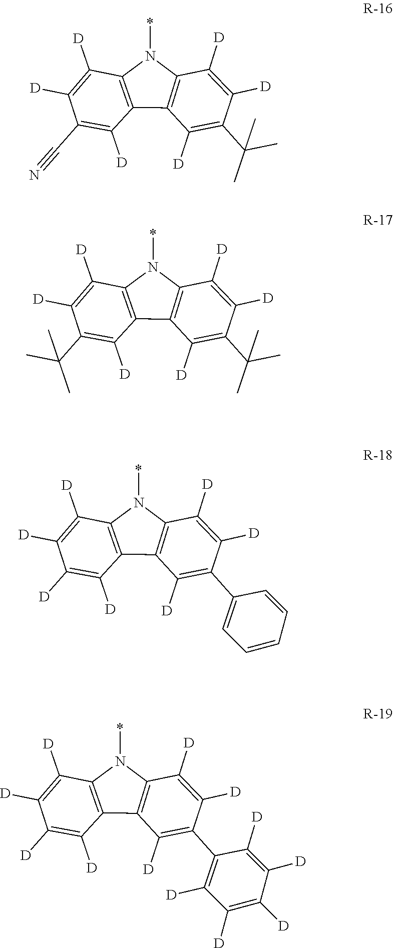

In R-12 to R-19, D is a deuterium atom. At least one of R₁ to R₉ in Formula 1 may be represented by any one among R-6 to R-19.

For example, R-3 may be represented by R-3a or R-3b. R-4 may be represented by R-4a. R-3a and R-3b represent specific binding positions in R-3. R-4a represents a specific binding position in R-4. However, this is presented as an example, and the embodiment of the present disclosure is not limited thereto.

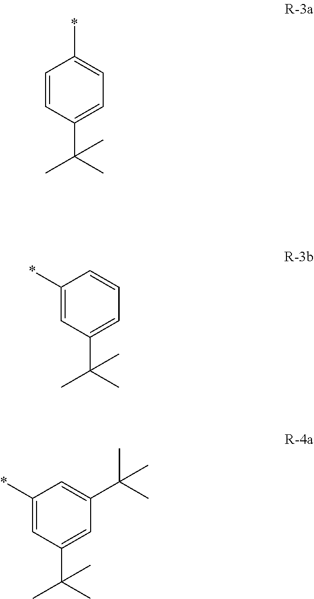 [SMILES: *c1ccc(C(C)(C)C)cc1 ; *c1cccc(C(C)(C)C)c1 ; *c1cc(C(C)(C)C)cc(C(C)(C)C)c1]

In Formula 1, a first substituent represented by Formula 2 may be bonded to Sₐ₁ and Sₐ₂, and Sₐ₃ may be a hydrogen atom. In some embodiments, the first substituent represented by Formula 2 may be bonded to Sₐ₁ and Sₐ₃, and Sₐ₂ may be a hydrogen atom. The first substituent represented by Formula 2 may constitute a tetrabenzo azonine derivative. In Formula 1, N with the bonding site Sₐ₁ indicated may be a ring-forming atom of the tetrabenzo azonine derivative.

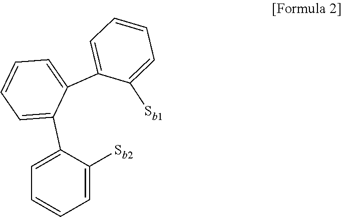

In Formula 2, S_{b1} and S_{b2} may be positions bonded to Formula 1. Any one of S_{b1} and S_{b2} may be bonded to Sₐ₁, and the other one may be bonded to Sₐ₂ or Sₐ₃. Formula 1 and Formula 2 may be bonded to form a tetrabenzo azonine derivative included in the fused polycyclic compound of an embodiment.

In an embodiment, Formula 1 may be represented by Formula 1-1 or Formula 1-2. Formula 1-1 and Formula 1-2 represent structural formulas in which Formula 2 is bonded to Formula 1.

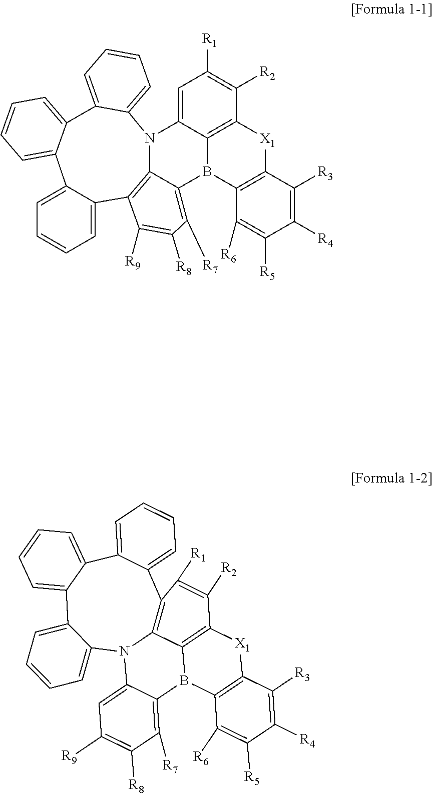

Formula 1-1 shows a case where S_{b1} of Formula 2 is bonded to Sₐ₁ of Formula 1, and S_{b2} of Formula 2 is bonded to Sₐ₂ of Formula 1. Formula 1-2 shows a case where S_{b2} of Formula 2 is bonded to Sₐ₁ of Formula 1, and S_{b1} of Formula 2 is bonded to Sₐ₃ of Formula 1. In Formulas 1-1 to 1-2, the same descriptions as in Formula 1 may be applied to R₁ to R₉, and X₁.

In an embodiment, Formula 1-1 may be represented by Formula 1-1A. Formula 1-1A shows a case where R₂, R₃, R₅ to R₇, and R₉ in Formula 1-1 are hydrogen atoms.

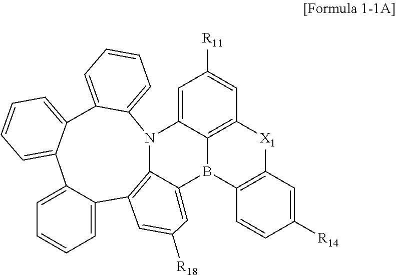

In Formula 1-1A, the same descriptions as in Formula 1-1 may be applied to X₁. R₁₁, R₁₄, and R₁₈ may each independently be a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms. For example, R₁₁, R₁₄, and R₁₈ may each independently be represented by any one among R-1 to R-19 described above.

In an embodiment, Formula 1-2 may be represented by any one among Formulas 1-2A to 1-2C. Formulas 1-2A to 1-2C show cases in which at least one of R₁ to R₉ in Formula 1-2 is a hydrogen atom.

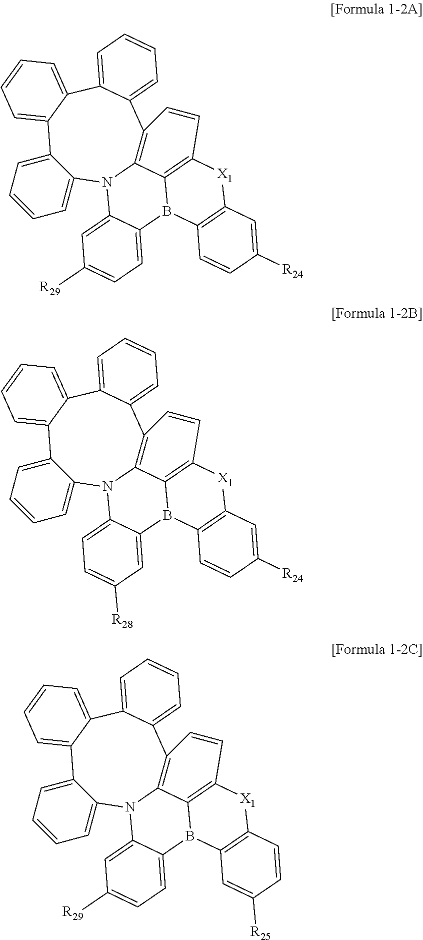

Formula 1-2A shows a case where R₁ to R₃ and R₅ to R₈ in Formula 1-2 are hydrogen atoms. Formula 1-2B shows a case where R₁ to R₃, R₅ to R₇, and R₉ in Formula 1-2 are hydrogen atoms. Formula 1-2C shows a case in which R₁ to R₄ and R₆ to R₈ in Formula 1-2 are hydrogen atoms.

In Formulas 1-2A to 1-2C, the same descriptions as in Formula 1-2 may be applied to X₁. In Formulas 1-2A to 1-2C, R₂₄, R₂₅, R₂₈, and R₂₉ may each independently be a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms. For example, R₂₄, R₂₅, R₂₈, and R₂₉ may each independently be represented by any one among R-1 to R-19 described above.

The fused polycyclic compound of an embodiment may be represented by any one among compounds of Compound Group 1. A light emitting element ED of an embodiment may include at least one of the compounds from Compound Group 1. In Compound Group 1, D is a deuterium atom, and Ph is a phenyl group.

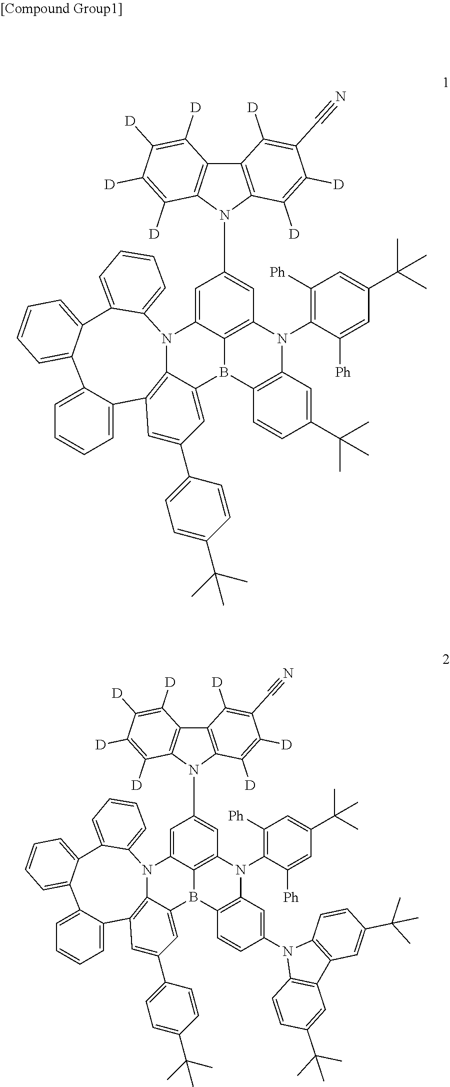 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(C(C)(C)C)cc1N2c1c(-c2ccccc2)cc(C(C)(C)C)cc1-c1ccccc1 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-n3c4ccc(C(C)(C)C)cc4c4cc(C(C)(C)C)ccc43)cc1N2c1c(-c2ccccc2)cc(C(C)(C)C)cc1-c1ccccc1]

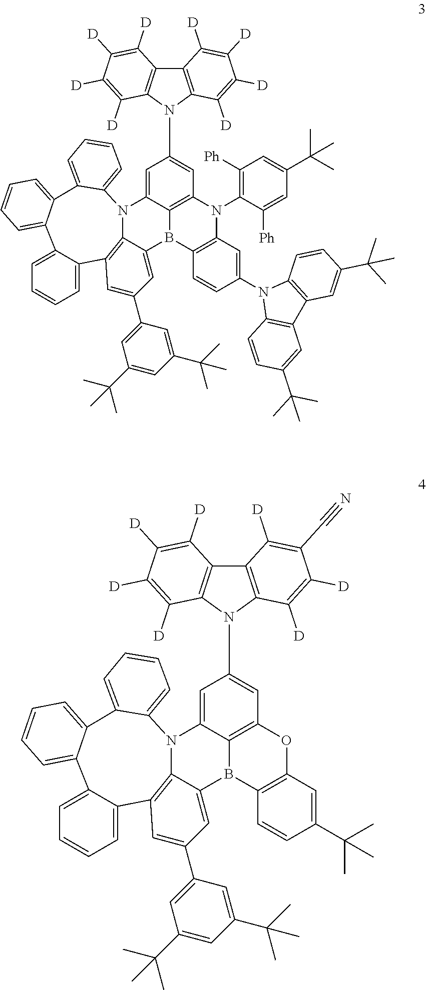 [SMILES: [2H]c1c([2H])c([2H])c2c(c1[2H])c1c([2H])c([2H])c([2H])c([2H])c1n2-c1cc2c3c(c1)-n1c4ccccc4c4ccccc4c4ccccc4c4cc(-c5cc(C(C)(C)C)cc(C(C)(C)C)c5)cc(c41)B3c1ccc(-n3c4ccc(C(C)(C)C)cc4c4cc(C(C)(C)C)ccc43)cc1N2c1c(-c2ccccc2)cc(C(C)(C)C)cc1-c1ccccc1 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cc(C(C)(C)C)cc(C(C)(C)C)c5)cc(c41)B3c1ccc(C(C)(C)C)cc1O2]

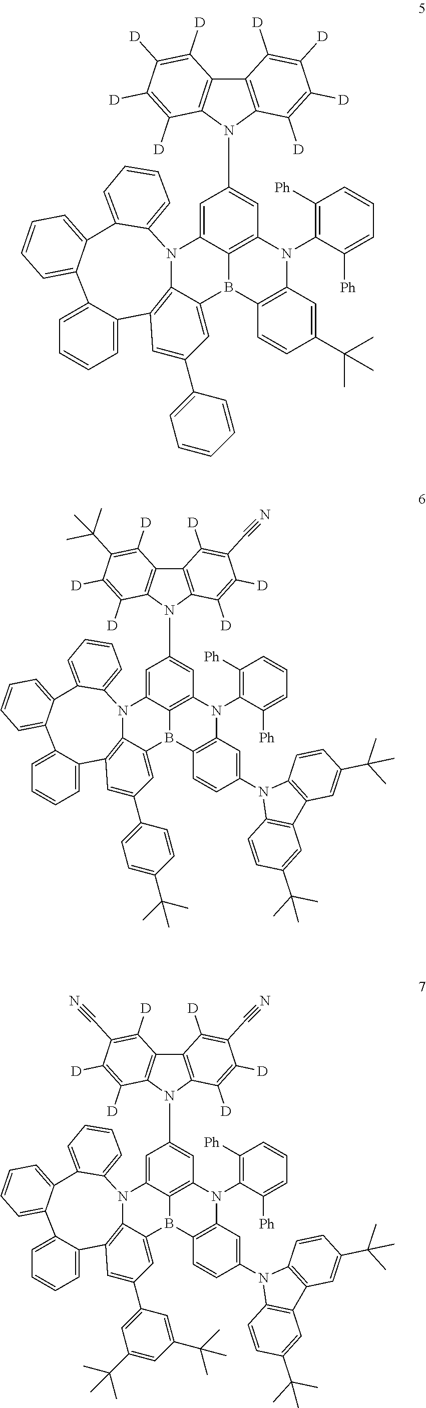

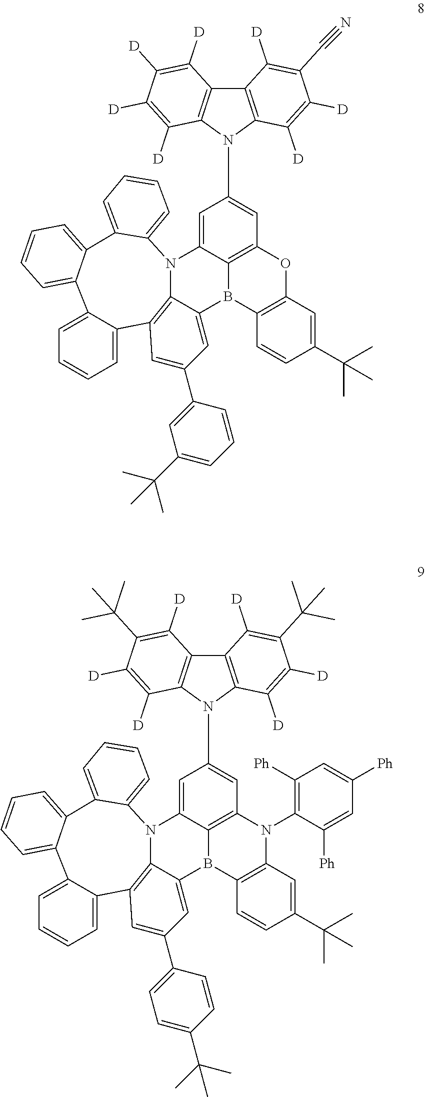 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(C(C)(C)C)cc1O2 ; [2H]c1c(C(C)(C)C)c([2H])c2c3c([2H])c(C(C)(C)C)c([2H])c([2H])c3n(-c3cc4c5c(c3)-n3c6ccccc6c6ccccc6c6ccccc6c6cc(-c7ccc(C(C)(C)C)cc7)cc(c63)B5c3ccc(C(C)(C)C)cc3N4c3c(-c4ccccc4)cc(-c4ccccc4)cc3-c3ccccc3)c2c1[2H]]

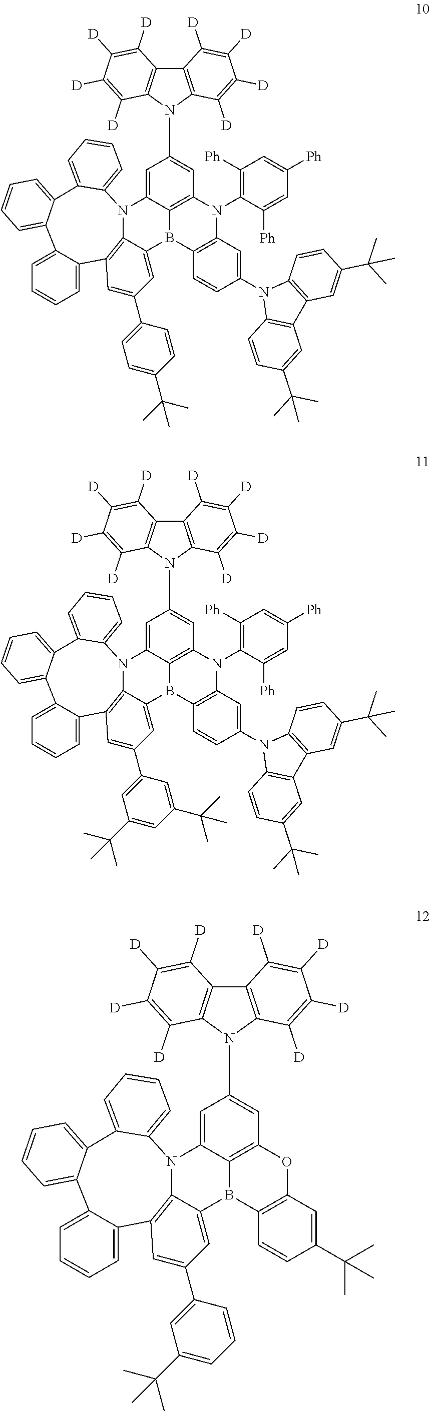

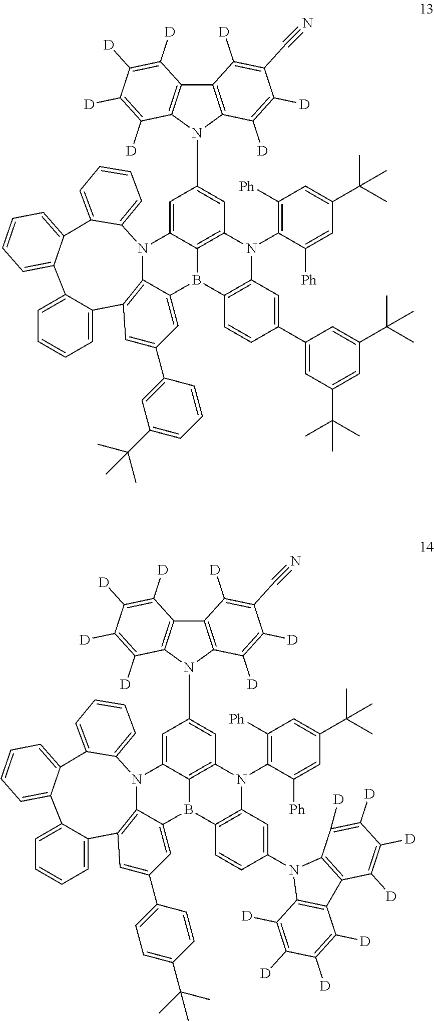 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cc(C(C)(C)C)cc(C(C)(C)C)c3)cc1N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2ccc(C(C)(C)C)cc2)cc2c4ccccc4c4ccccc4c4ccccc4n-3c12]

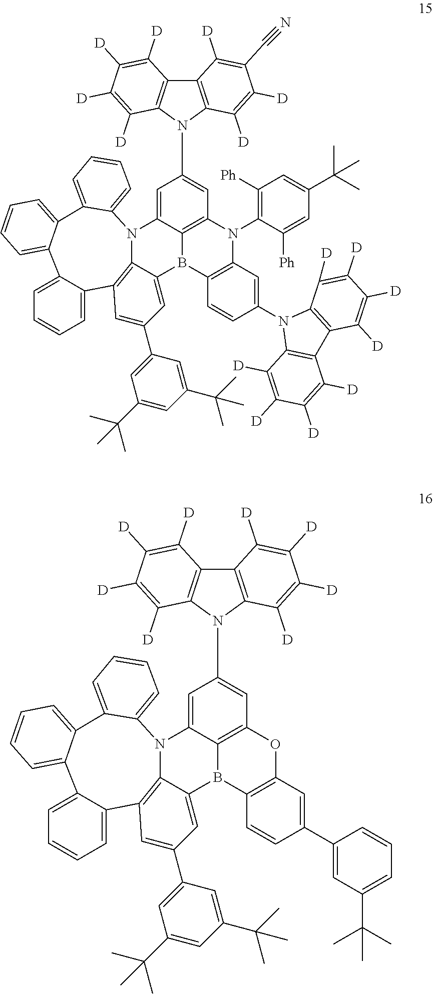 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c([2H])c([2H])c([2H])c1n2-c1cc2c3c(c1)-n1c4ccccc4c4ccccc4c4ccccc4c4cc(-c5cc(C(C)(C)C)cc(C(C)(C)C)c5)cc(c41)B3c1ccc(-c3cccc(C(C)(C)C)c3)cc1O2]

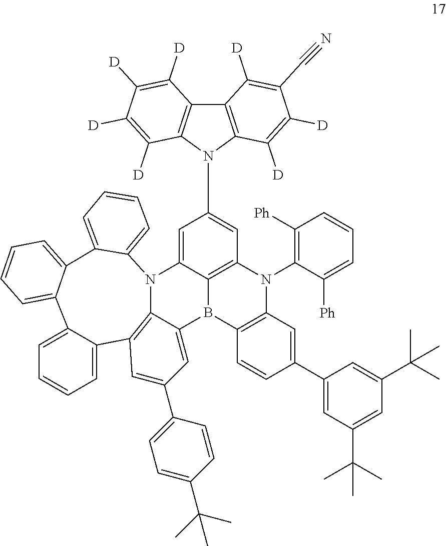 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cc(C(C)(C)C)cc(C(C)(C)C)c3)cc1N2c1c(-c2ccccc2)cccc1-c1ccccc1]

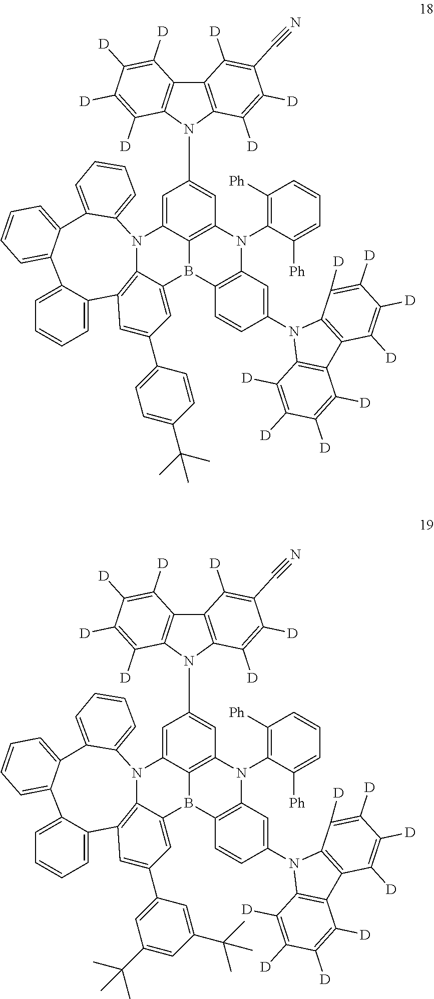

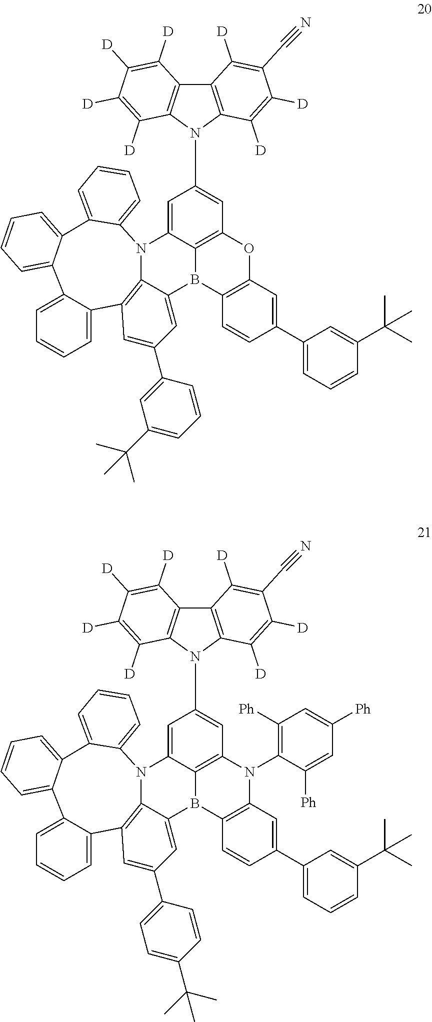 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cccc(C(C)(C)C)c3)cc1N2c1c(-c2ccccc2)cc(-c2ccccc2)cc1-c1ccccc1]

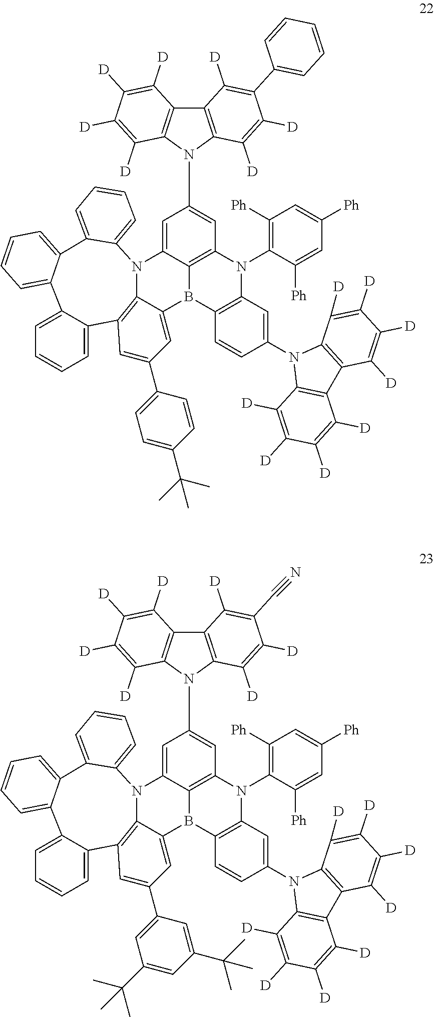

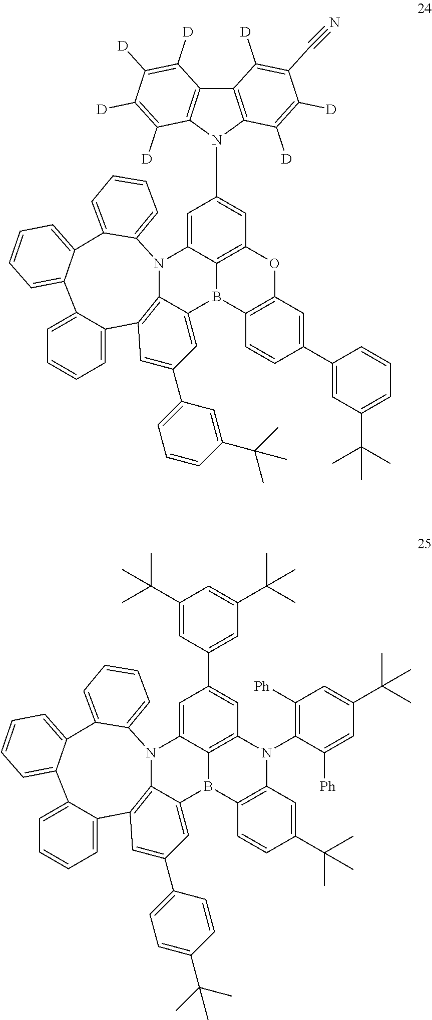 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cc(C(C)(C)C)cc2-c2ccccc2)cc1]

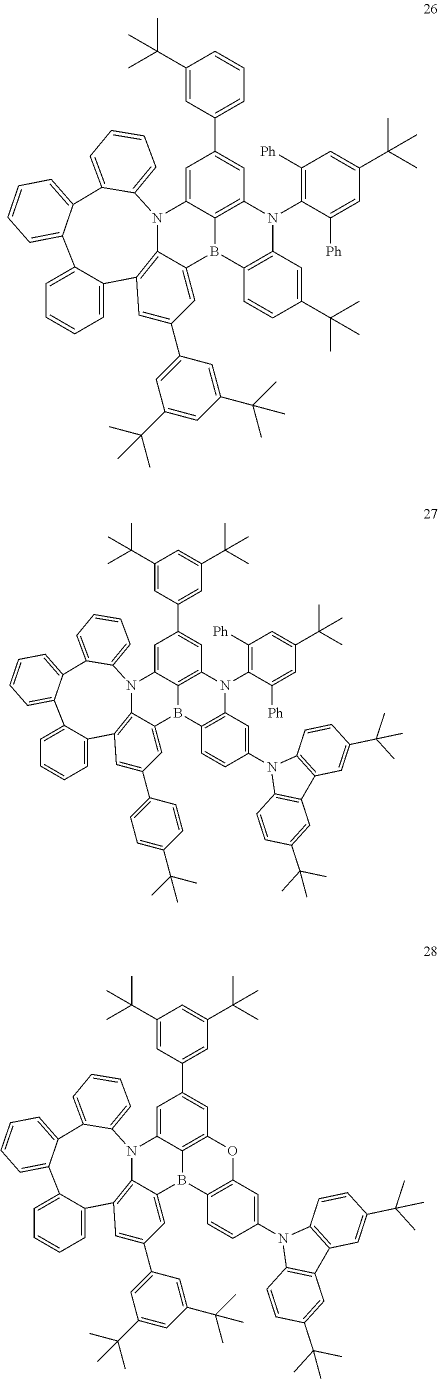

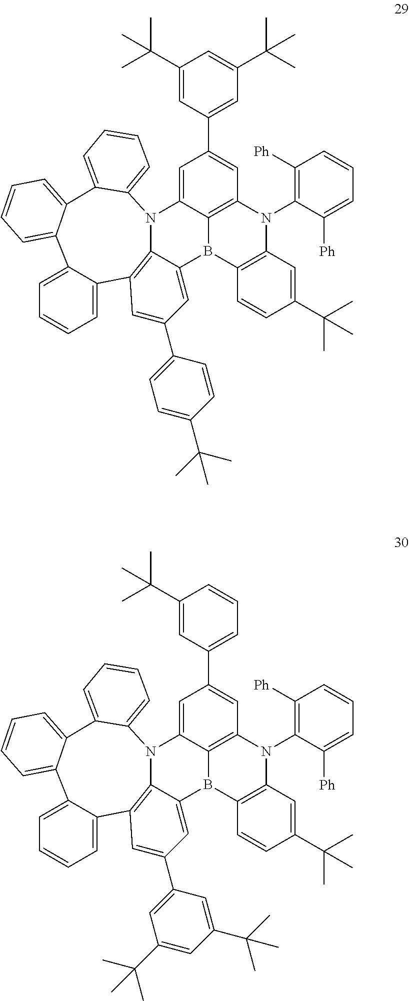 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cccc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(C(C)(C)C)cc2N3c2c(-c3ccccc3)cccc2-c2ccccc2)c1]

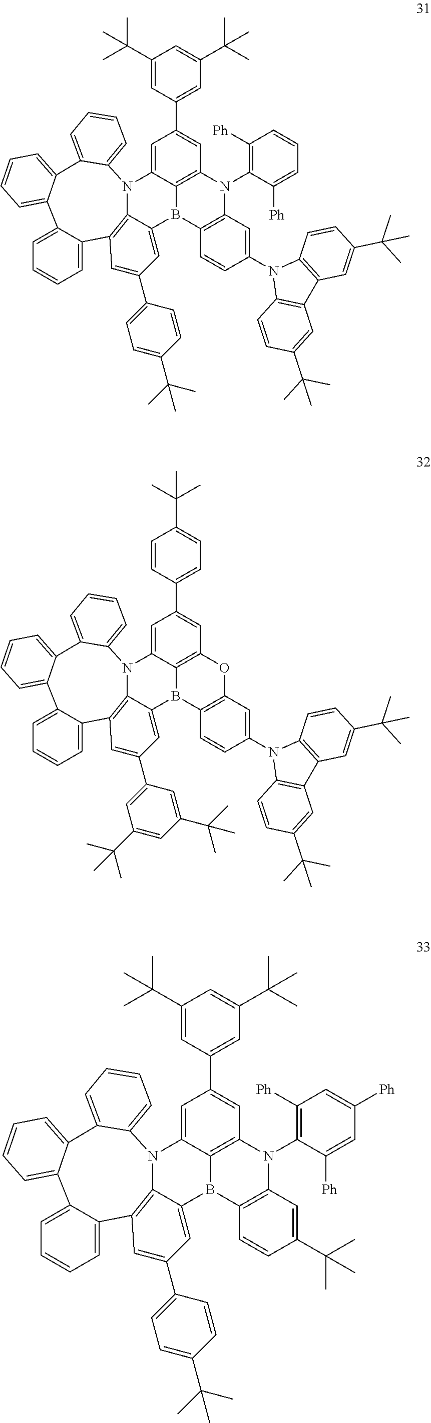 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1ccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cc(-c3ccccc3)cc2-c2ccccc2)cc1]

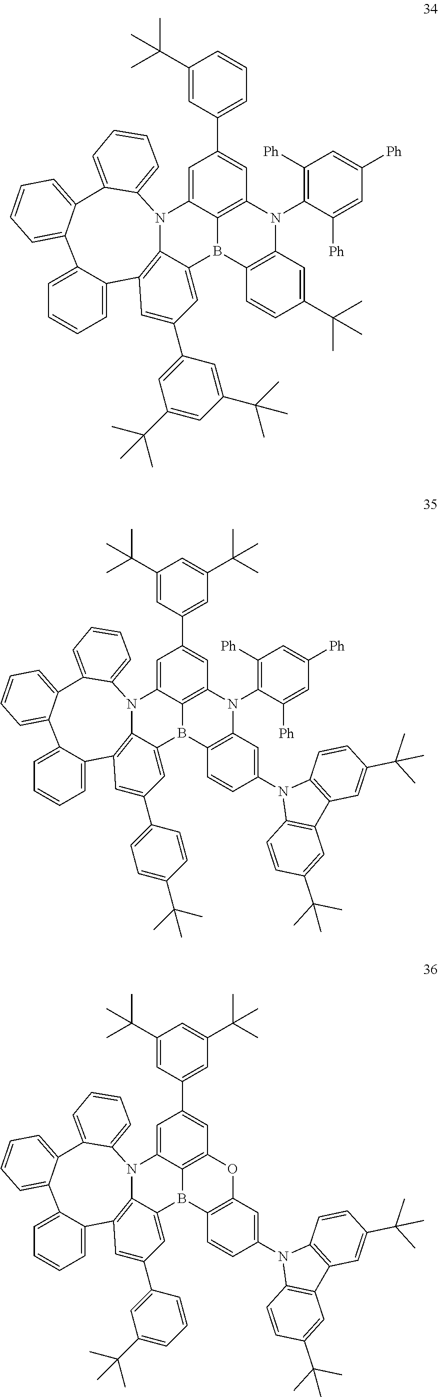

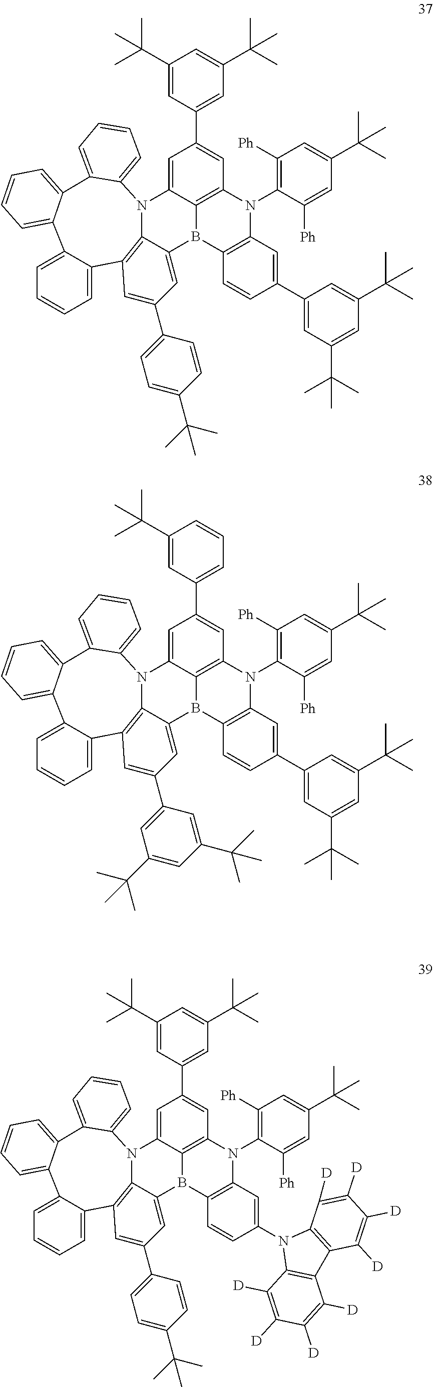

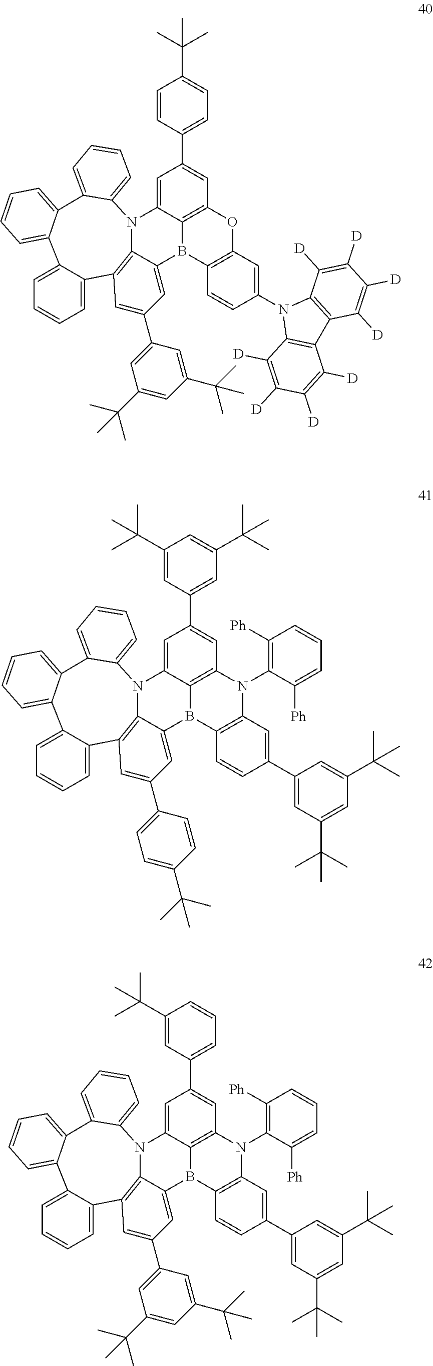

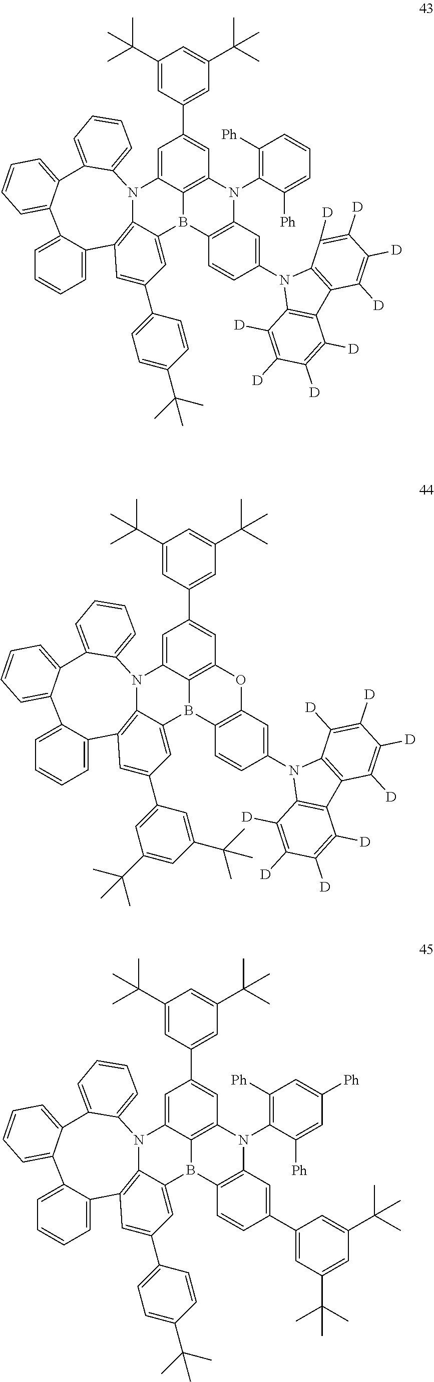

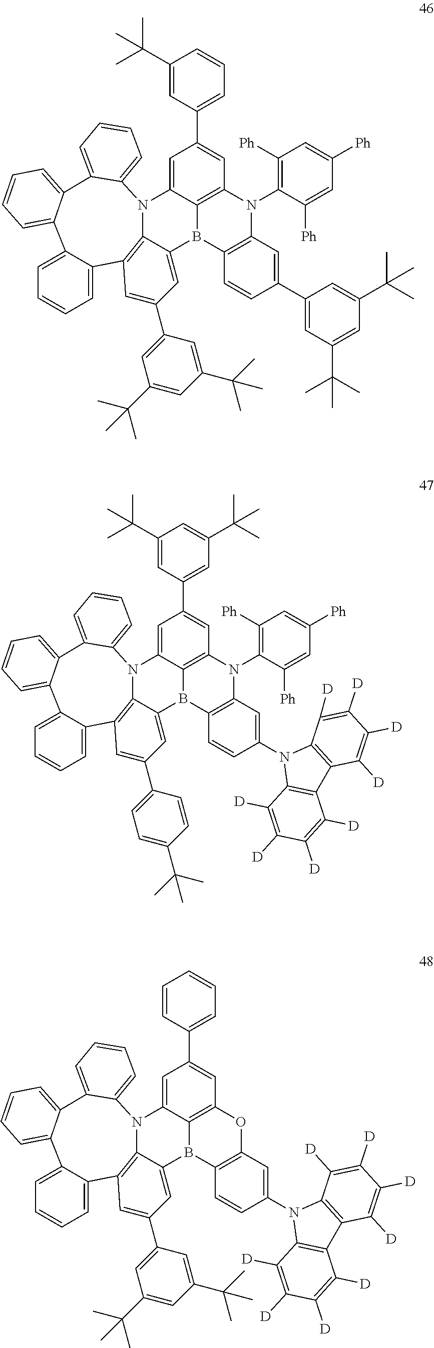

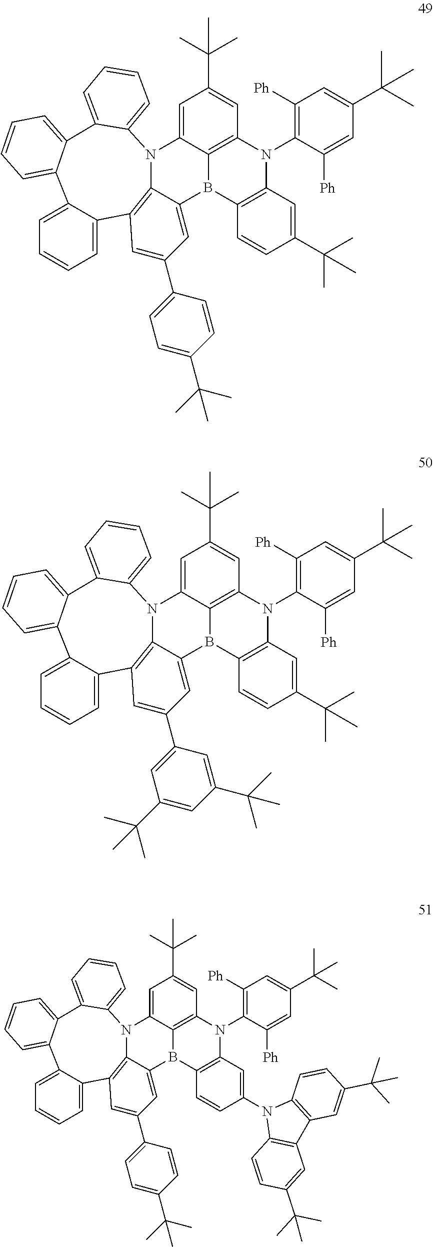 [SMILES: CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc1]

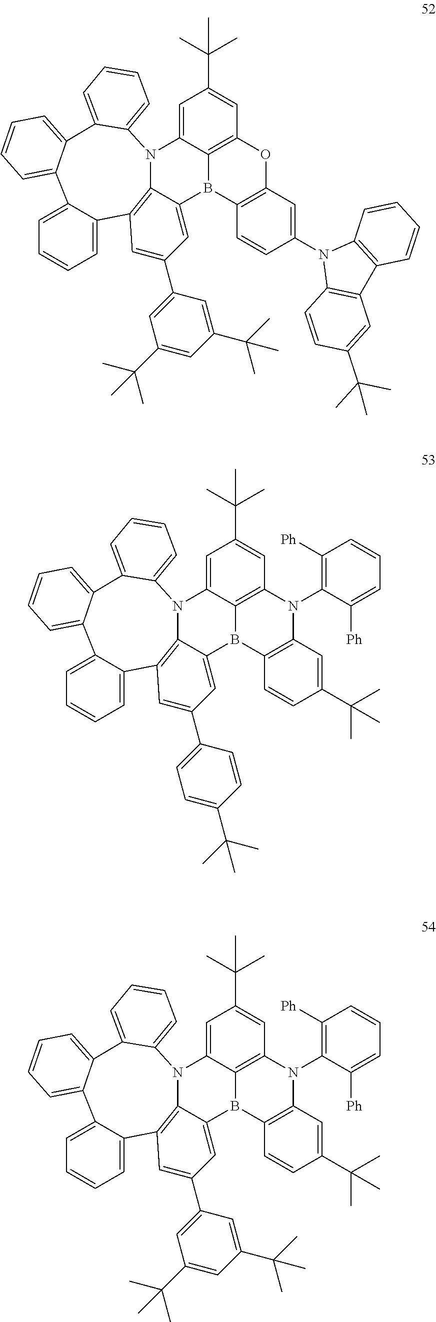 [SMILES: CC(C)(C)c1cc(-c2cc3c4c(c2)c2ccccc2c2ccccc2c2ccccc2n4-c2cc(C(C)(C)C)cc4c2B3c2ccc(-n3c5ccccc5c5cc(C(C)(C)C)ccc53)cc2O4)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc(C(C)(C)C)c1]

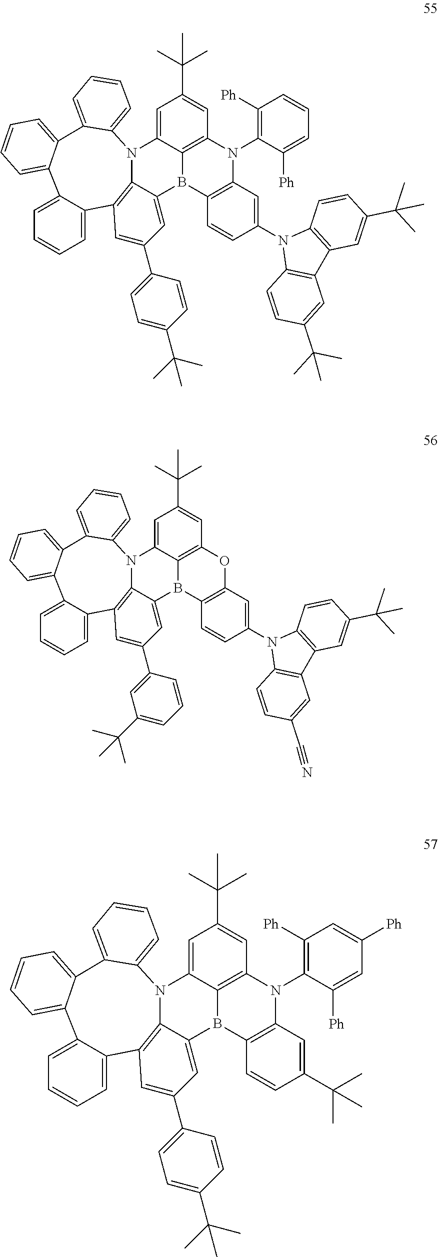 [SMILES: CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1cccc(-c2cc3c4c(c2)c2ccccc2c2ccccc2c2ccccc2n4-c2cc(C(C)(C)C)cc4c2B3c2ccc(-n3c5ccc(C#N)cc5c5cc(C(C)(C)C)ccc53)cc2O4)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc1]

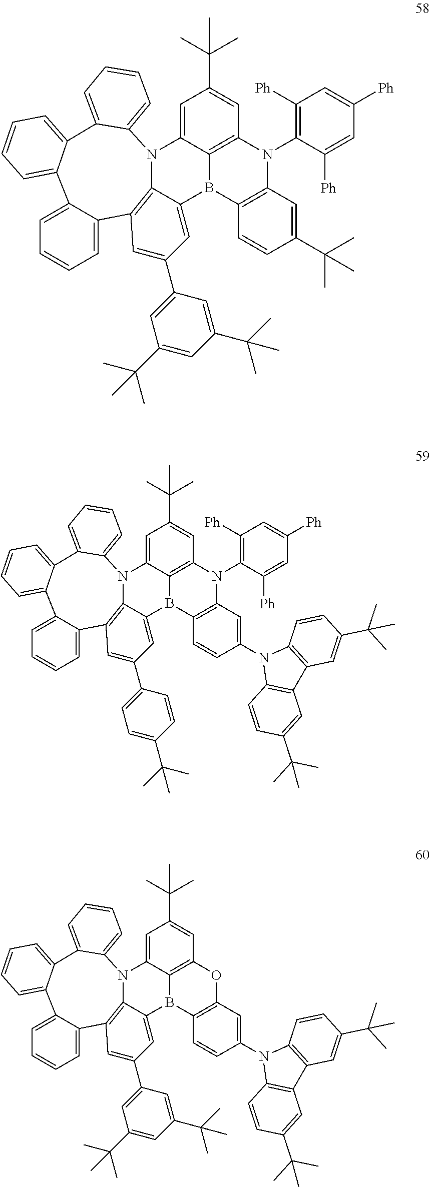 [SMILES: CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2O4)cc(C(C)(C)C)c1]

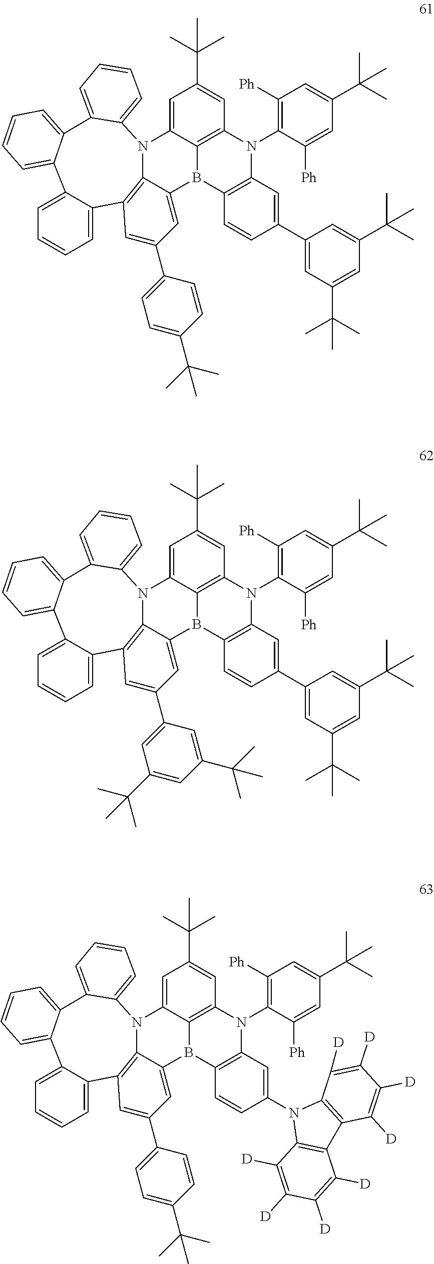

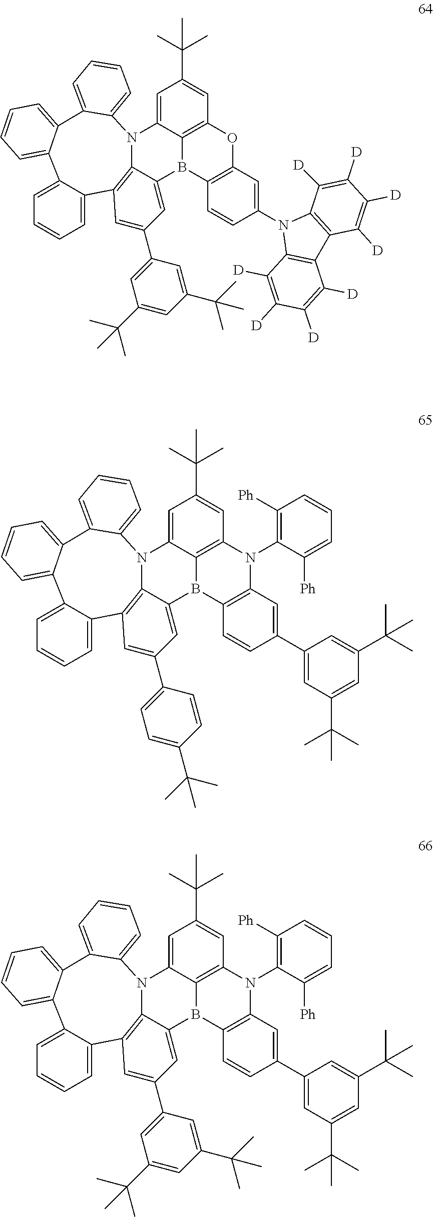 [SMILES: [2H]c1c([2H])c([2H])c2c(c1[2H])c1c([2H])c([2H])c([2H])c([2H])c1n2-c1ccc2c(c1)Oc1cc(C(C)(C)C)cc3c1B2c1cc(-c2cc(C(C)(C)C)cc(C(C)(C)C)c2)cc2c4ccccc4c4ccccc4c4ccccc4n-3c12 ; CC(C)(C)c1ccc(-c2cc3c4c(c2)c2ccccc2c2ccccc2c2ccccc2n4-c2cc(C(C)(C)C)cc4c2B3c2ccc(-c3cc(C(C)(C)C)cc(C(C)(C)C)c3)cc2N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(C(C)(C)C)cc4c2B3c2cc(-c3cc(C(C)(C)C)cc(C(C)(C)C)c3)cc3c5ccccc5c5ccccc5c5ccccc5n-4c23)cc(C(C)(C)C)c1]

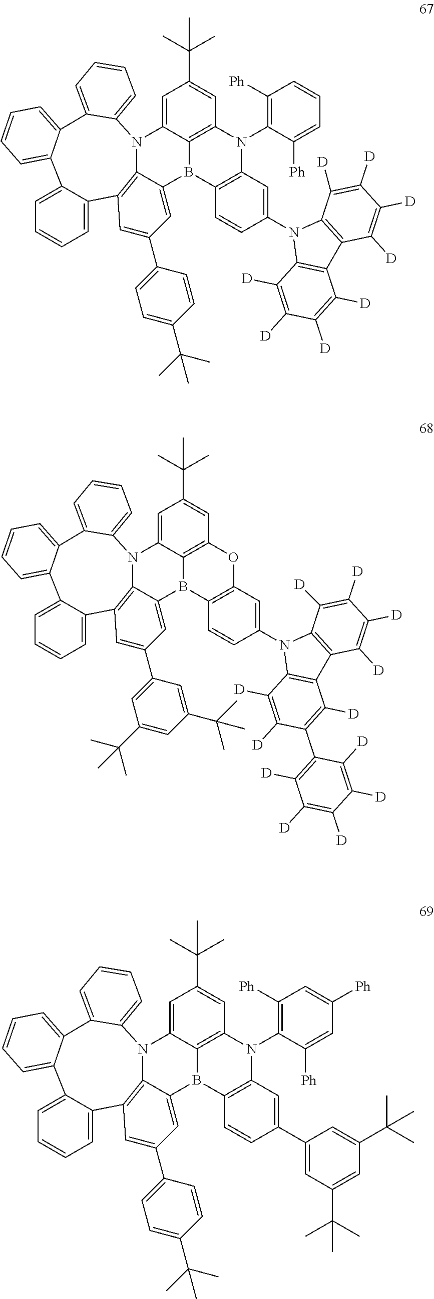

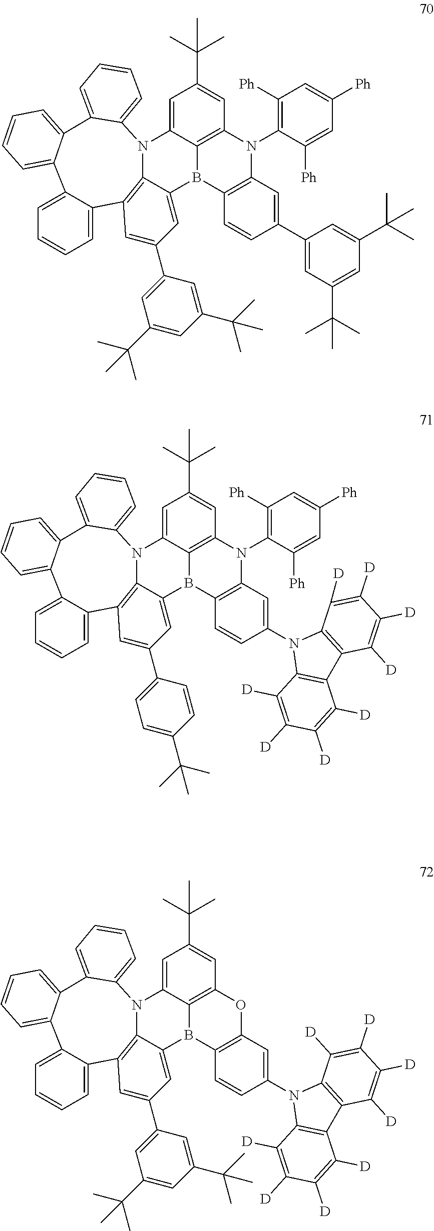

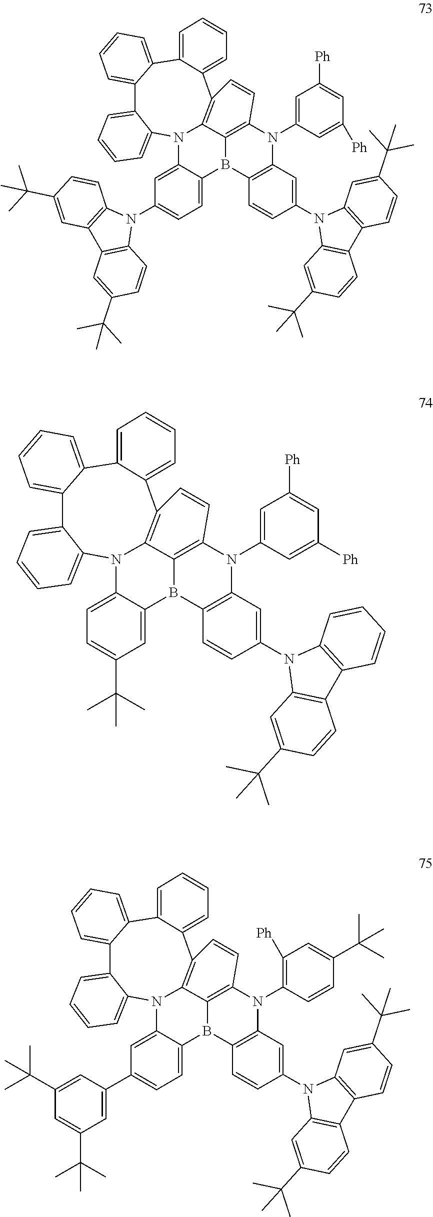

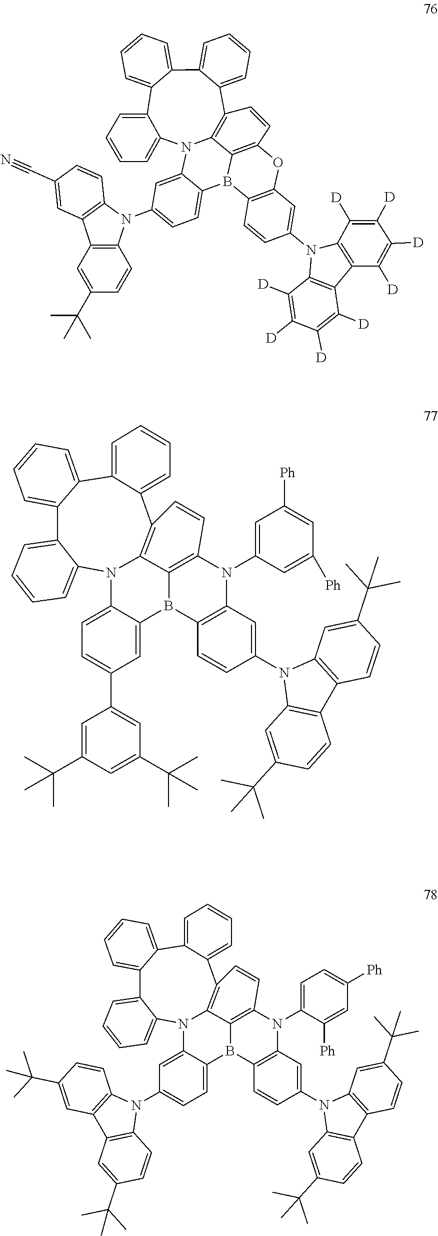

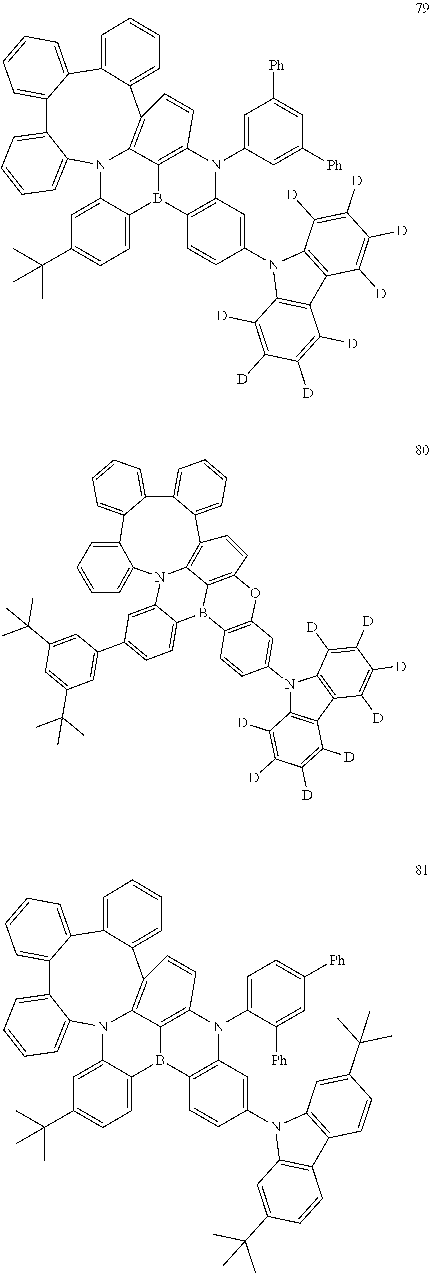 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1ccc(-c2ccccc2)cc1-c1ccccc1]

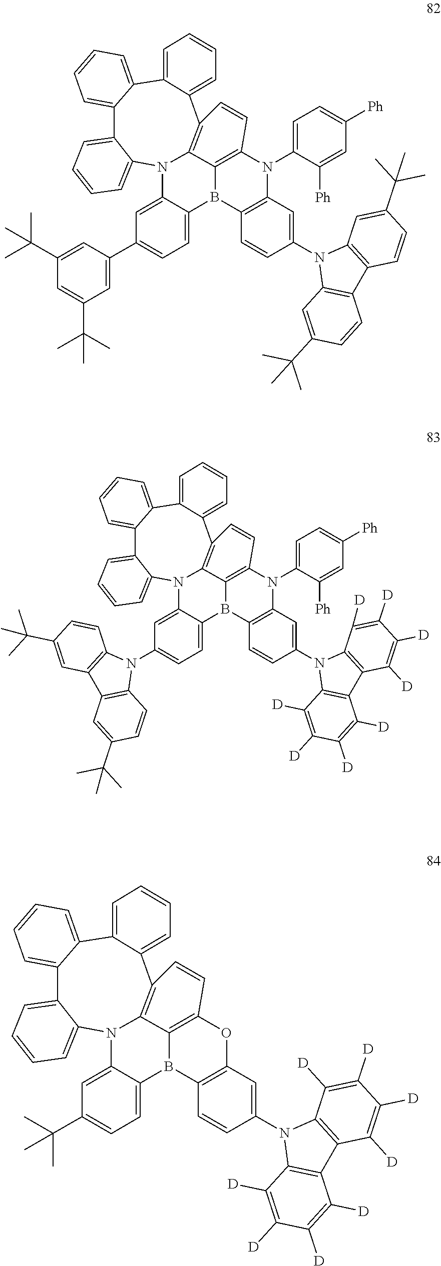

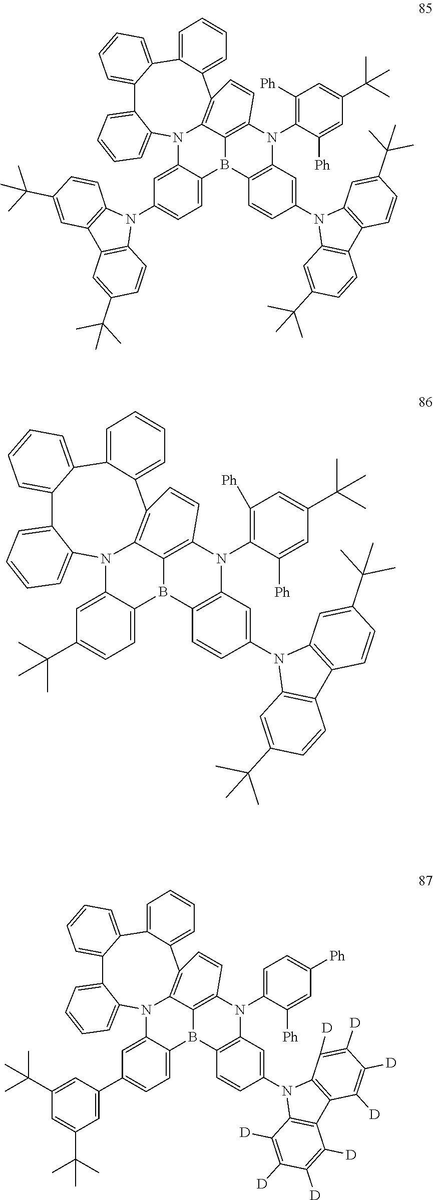

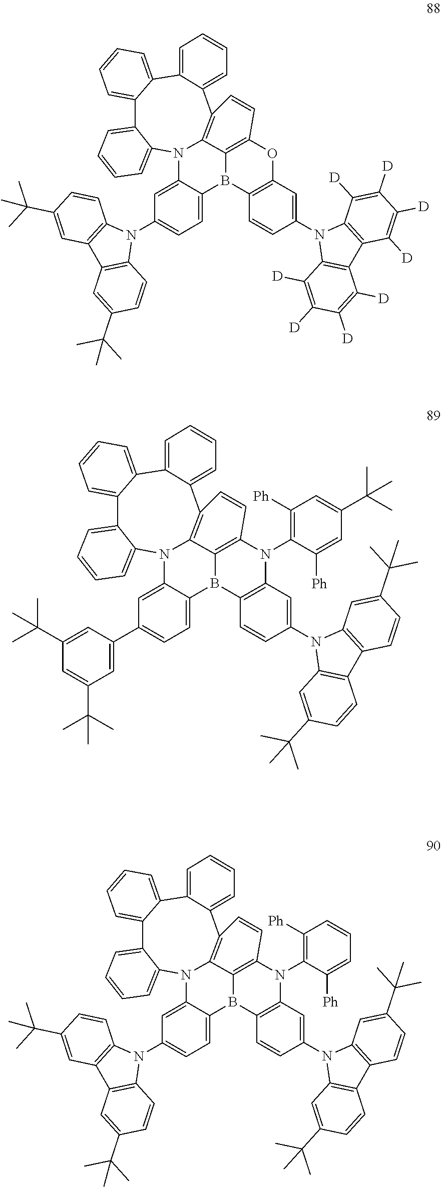

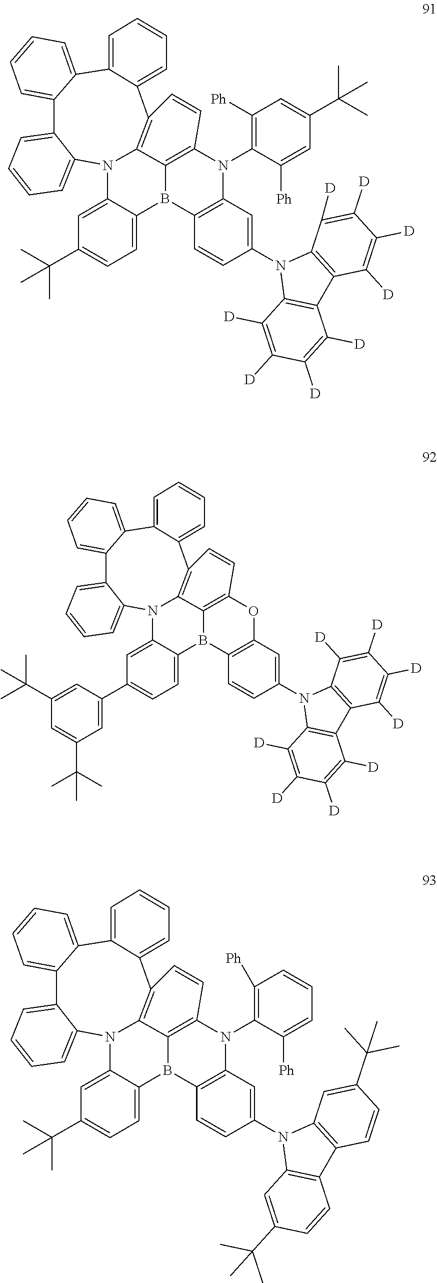 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1c(-c2ccccc2)cccc1-c1ccccc1]

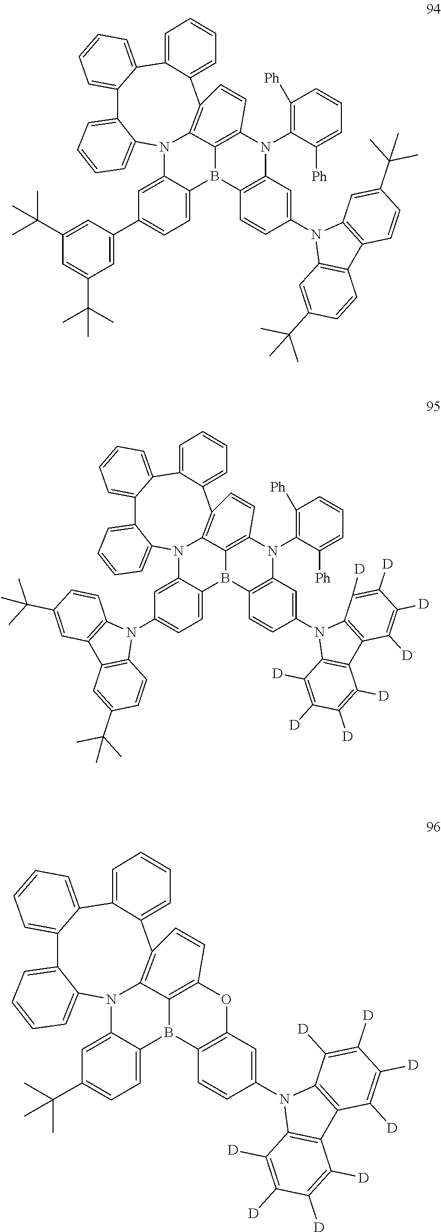

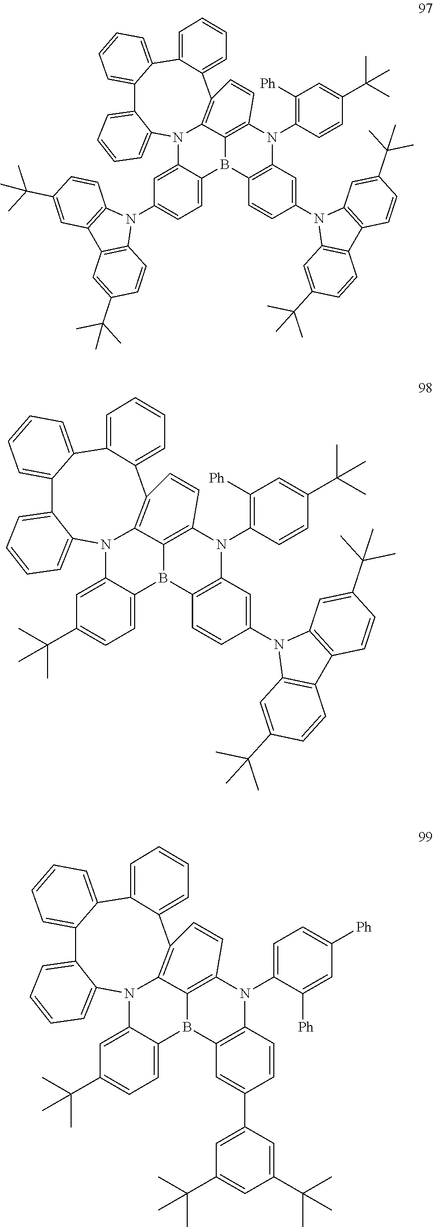 [SMILES: CC(C)(C)c1ccc(N2c3cc(-n4c5cc(C(C)(C)C)ccc5c5ccc(C(C)(C)C)cc54)ccc3B3c4ccc(-n5c6ccc(C(C)(C)C)cc6c6cc(C(C)(C)C)ccc65)cc4-n4c5ccccc5c5ccccc5c5ccccc5c5ccc2c3c54)c(-c2ccccc2)c1 ; CC(C)(C)c1ccc(N2c3cc(-n4c5cc(C(C)(C)C)ccc5c5ccc(C(C)(C)C)cc54)ccc3B3c4ccc(C(C)(C)C)cc4-n4c5ccccc5c5ccccc5c5ccccc5c5ccc2c3c54)c(-c2ccccc2)c1 ; CC(C)(C)c1cc(-c2ccc3c(c2)B2c4ccc(C(C)(C)C)cc4-n4c5ccccc5c5ccccc5c5ccccc5c5ccc(c2c54)N3c2ccc(-c3ccccc3)cc2-c2ccccc2)cc(C(C)(C)C)c1]

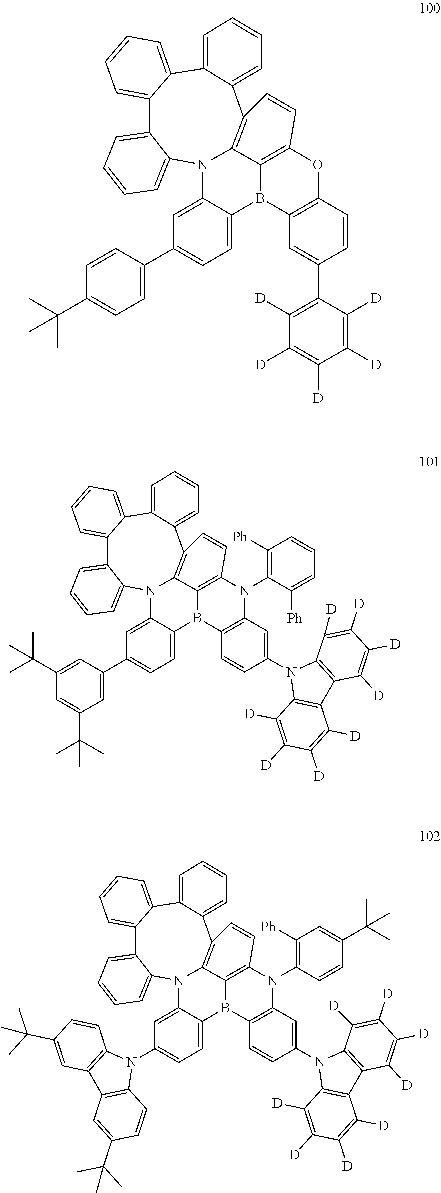

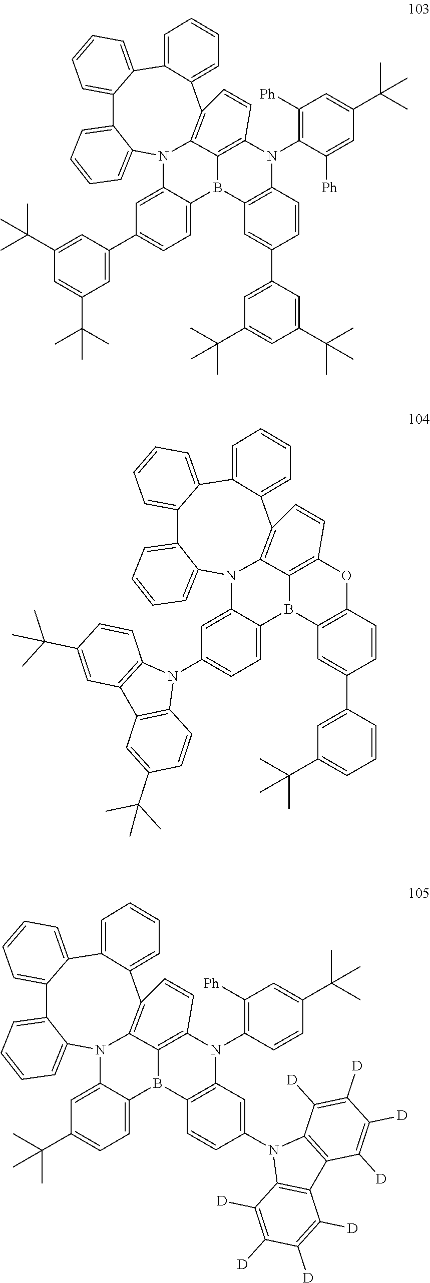

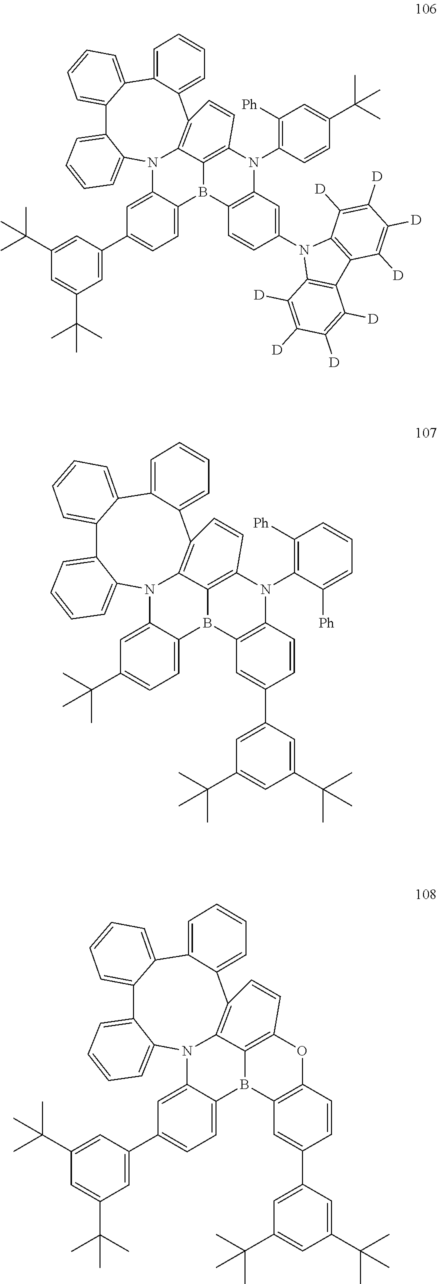

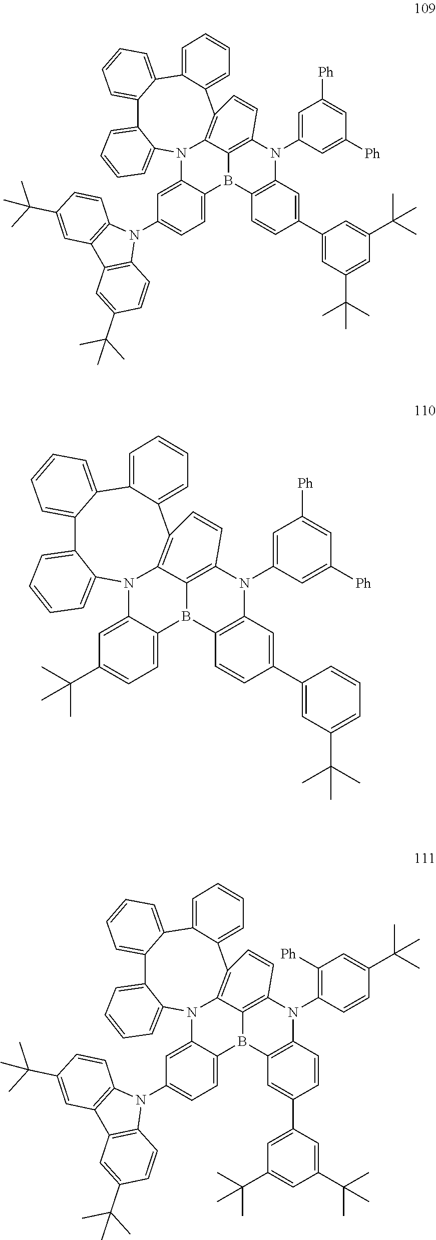

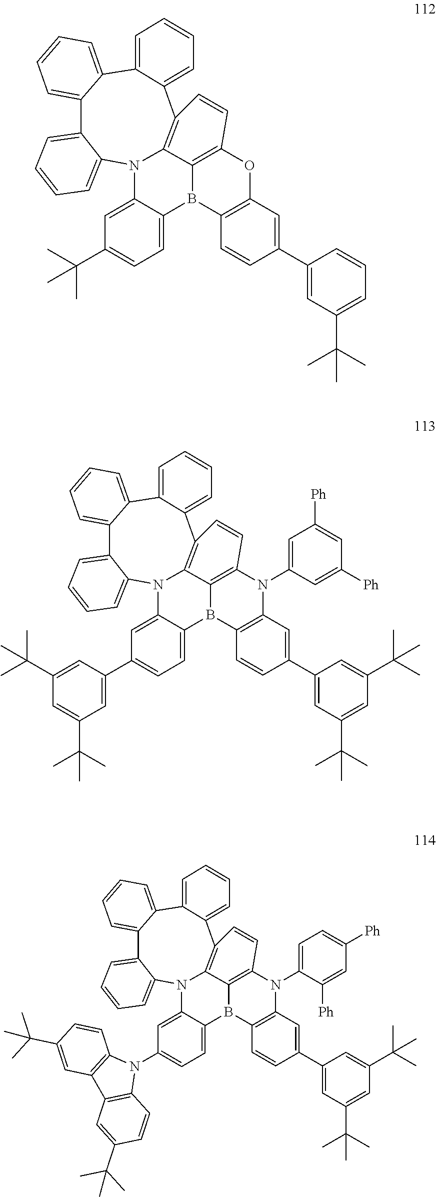

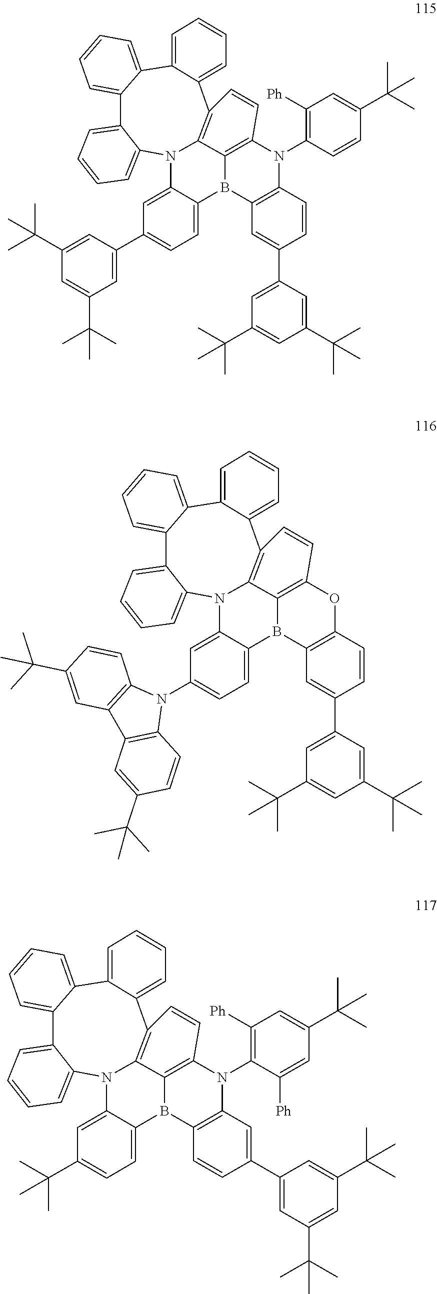

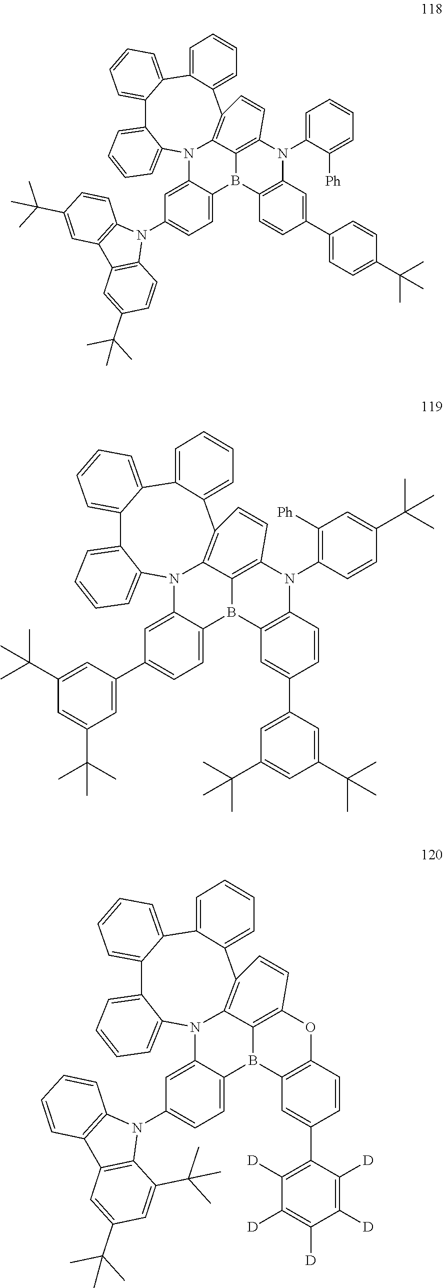

The fused polycyclic compound of an embodiment may include a tetrabenzo azonine derivative. The tetrabenzo azonine derivative is shown to be in a form in which peripheral ring groups are vertically bent with respect to a central ring group in terms of a three-dimensional structure, and interaction between molecules may be prevented or reduced by such a three-dimensional structure.

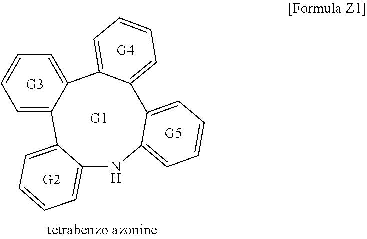 [SMILES: c1ccc2c(c1)[nH]c1ccccc1c1ccccc1c1ccccc21]

Formula Z1 represents tetrabenzo azonine, and G1 to G5 are indicated to refer to each ring group. The ring group of G1 may be a central ring group, and the ring groups of G2 to G5 may be peripheral ring groups. The ring groups of G1 to G5 may be present on different planes. With respect to the ring group of G1, the ring groups of G3 and G5 may be present as being vertically bent.

In the fused polycyclic compound of an embodiment in which intermolecular interactions are prevented or reduced, dexter energy transfer may not take place. A light emitting element including a compound in which dexter energy transition takes place has reduced light efficiency. The fused polycyclic compound of an embodiment includes a tetrabenzo azonine derivative, and may thus contribute to increasing efficiency of the light emitting element ED. The light emitting element ED including the fused polycyclic compound of an embodiment may exhibit excellent or suitable light efficiency.

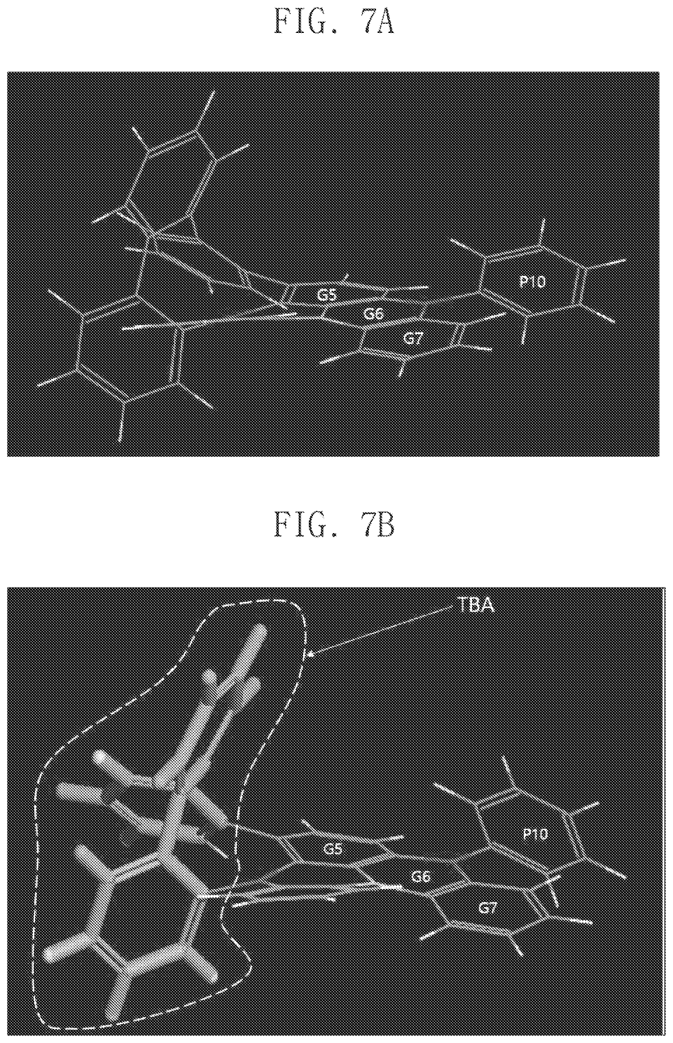

FIGS. 7A and 7B are three-dimensional images showing a structure of a compound represented by Formula Z2. Formula Z2 may represent a structural formula in which R₁ to R₉ are all hydrogen atoms, X₁ is NR₁₀, and R₁₀ is an unsubstituted phenyl group in Formula 1-2 described above.

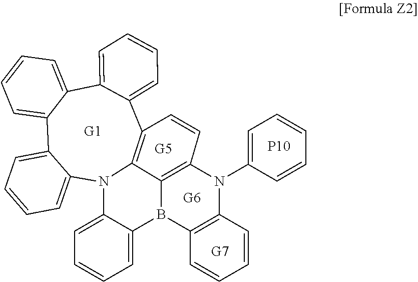

G1, G5, G6, G7, and P10 in Formula Z2 are indicated to refer to ring groups, and G5, G6, G7, and P10 correspond to the ring groups of G5, G6, G7, and P10 in FIGS. 7A and 7B. In some embodiments, G5, G6, G7, and P10 correspond to G1 and G5 of Formula Z2 and G1 and G5 of Formula Z1. TBA in FIG. 7B is indicated to refer to a tetrabenzo azonine moiety.

Referring to Formula Z2 and FIGS. 7A and 7B, it is seen that the G5 ring group and the G1 ring group are present on different planes. It is seen that the tetrabenzo azonine moiety indicated as TBA is present on a different plane from the ring groups of G5, G6, G7 and P10. Due to the three-dimensional structural characteristics of the compound, intermolecular interaction may be prevented or reduced in the fused polycyclic compound of an embodiment, which includes a tetrabenzo azonine derivative.

In an embodiment, the emission layer EML may include a host and a dopant. The fused polycyclic compound of an embodiment may be included as a dopant material of the emission layer EML. The fused polycyclic compound of an embodiment may be utilized as a blue dopant material. The fused polycyclic compound of an embodiment may be configured to emit light of thermally activated delayed fluorescence (TADF).

In an embodiment, the emission layer EML may include at least one of a second compound or a third compound. The second compound and the third compound may be host materials. For example, the emission layer EML may include two or more hosts, sensitizers, and dopants. The emission layer EML may include a hole transporting host and an electron transporting host. The emission layer EML may include a phosphorescent sensitizer as a sensitizer.

In the emission layer EML, the hole transporting host and the electron transporting host may form an exciplex. In this case, triplet energy of the exciplex formed by the hole transporting host and the electron transporting host corresponds to a difference between Lowest Unoccupied Molecular Orbital (LUMO) energy level of the electron transporting host and Highest Occupied Molecular Orbital (HOMO) energy level of the hole transporting host. For example, the exciplex formed by the hole transporting host and the electron transporting host may have an absolute value in the triplet energy level (T1) of about 2.4 eV to about 3.0 eV. In some embodiments, the triplet energy of the exciplex may have a value smaller than the energy gap of each host material. The exciplex may have a triplet energy of 3.0 eV or less, which is an energy gap between the hole transporting host and the electron transporting host. However, this is presented as an example, and the embodiment of the present disclosure is not limited thereto.

When the emission layer EML includes the hole transporting host, the electron transporting host, a sensitizer, and a dopant, the hole transporting host and the electron transporting host may form an exciplex, and energy may be transferred from the exciplex to the sensitizer and from the sensitizer to the dopant, thereby emitting light. However, this is presented as an example, and materials included in the emission layer EML are not limited thereto. In some embodiments, the hole transporting host and the electron transporting host may not form an exciplex.

In an embodiment, the second compound may be represented by Formula HT-1. For example, the emission layer EML may include the second compound as a hole transporting host material.

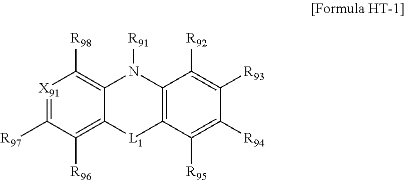

In Formula HT-1, L₁ may be a direct linkage, CR₉₉R₁₀₀, or SiR₁₀₁R₁₀₂. In Formula HT-1, X₉₁ may be N or CR₁₀₃. When L₁ is a direct linkage and X₉₁ is CR₁₀₃, the second compound represented by Formula HT-1 may include a carbazole group.

R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and

For example, R₉₁ may be a substituted phenyl group, an unsubstituted dibenzofuran group, or a substituted fluorenyl group. Any one among R₉₂ to R₉₈ may be a substituted or unsubstituted carbazole group. R₉₄ and R₉₅ may be bonded to each other to form a ring. However, this is presented as an example, and the embodiment of the present disclosure is not limited thereto.

The second compound may be represented by any one among compounds of Compound Group 2. In Compound Group 2, D is a deuterium atom, and Ph is a phenyl group.

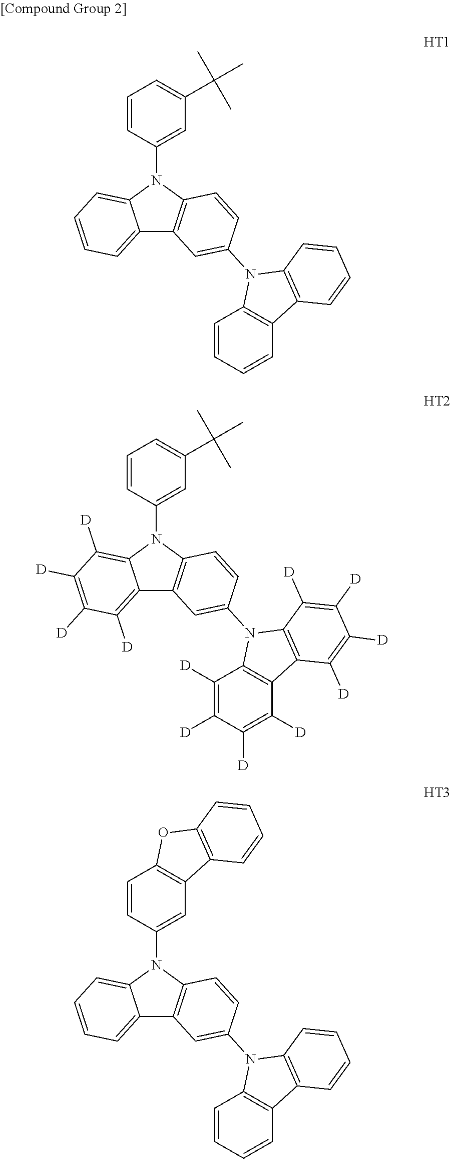

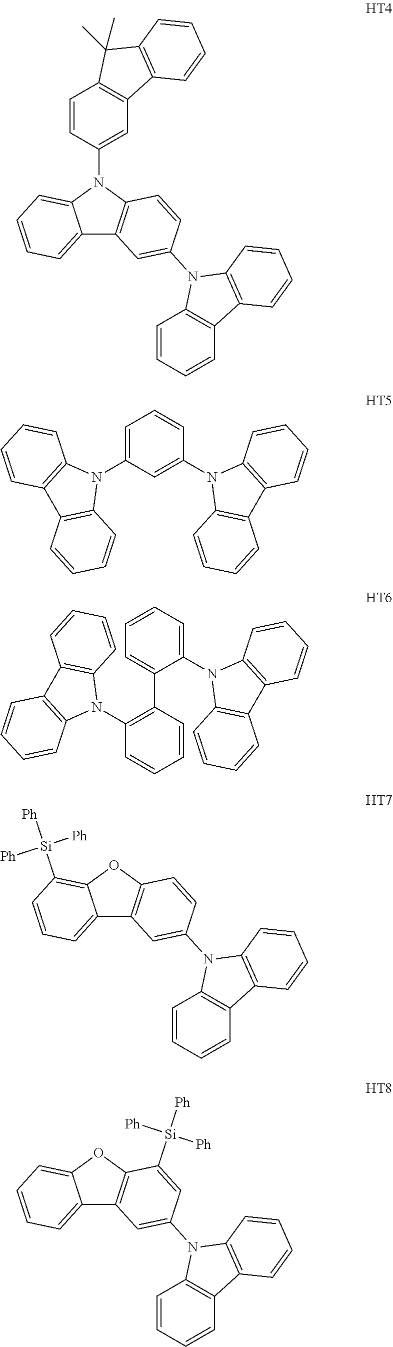

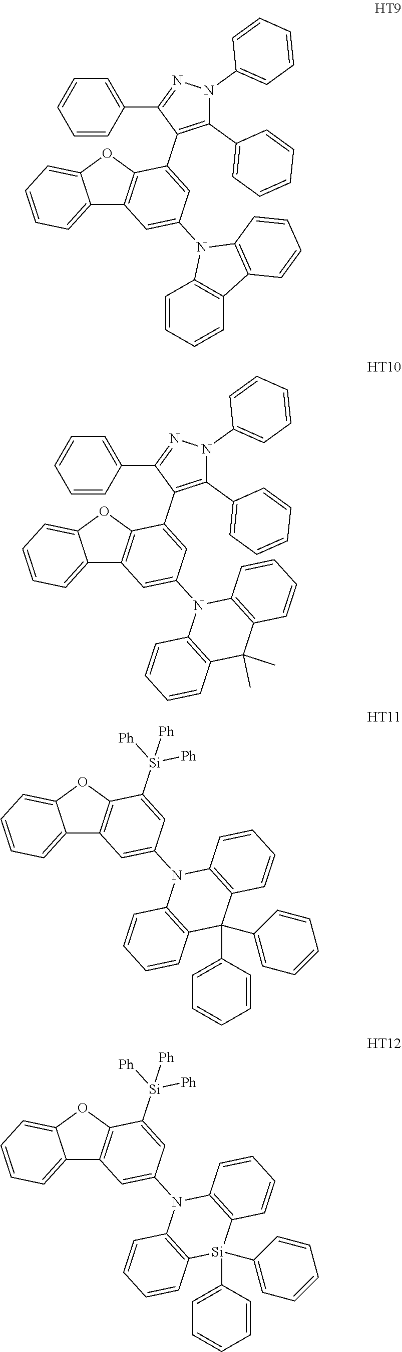

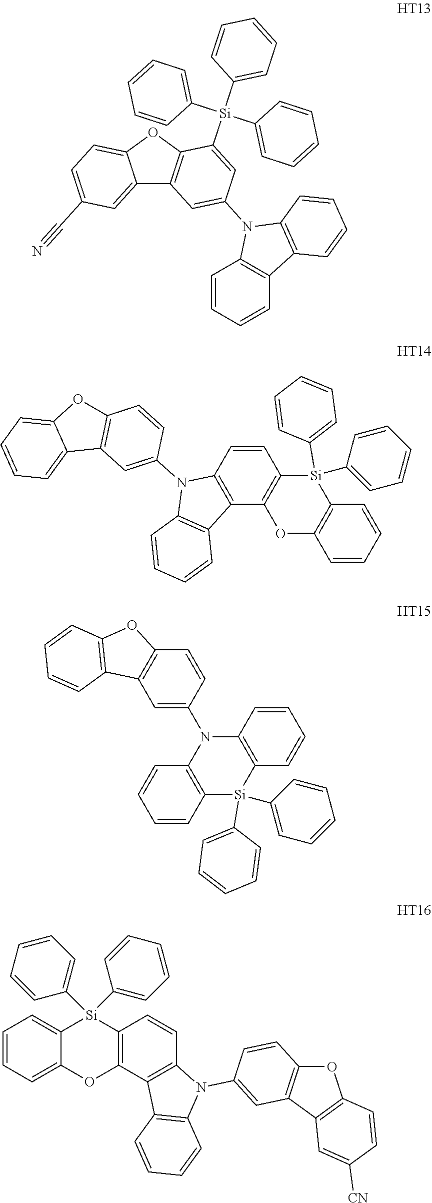 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

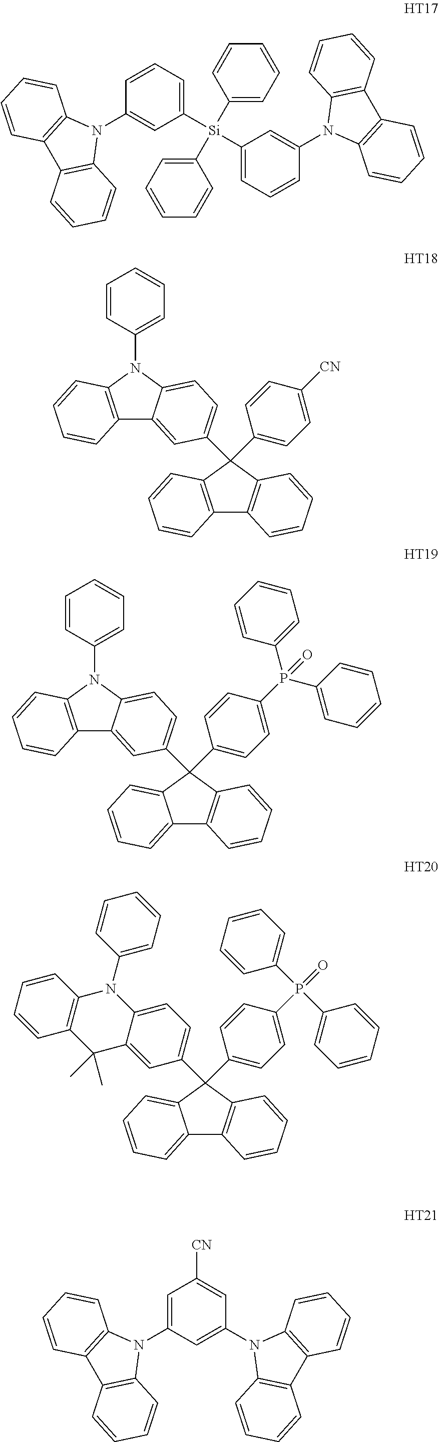

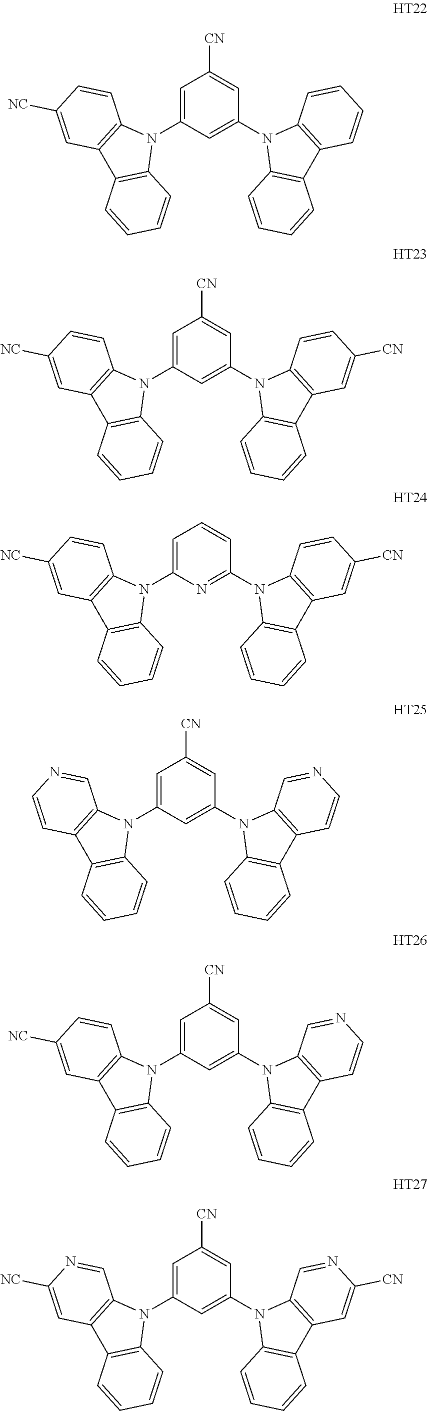 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

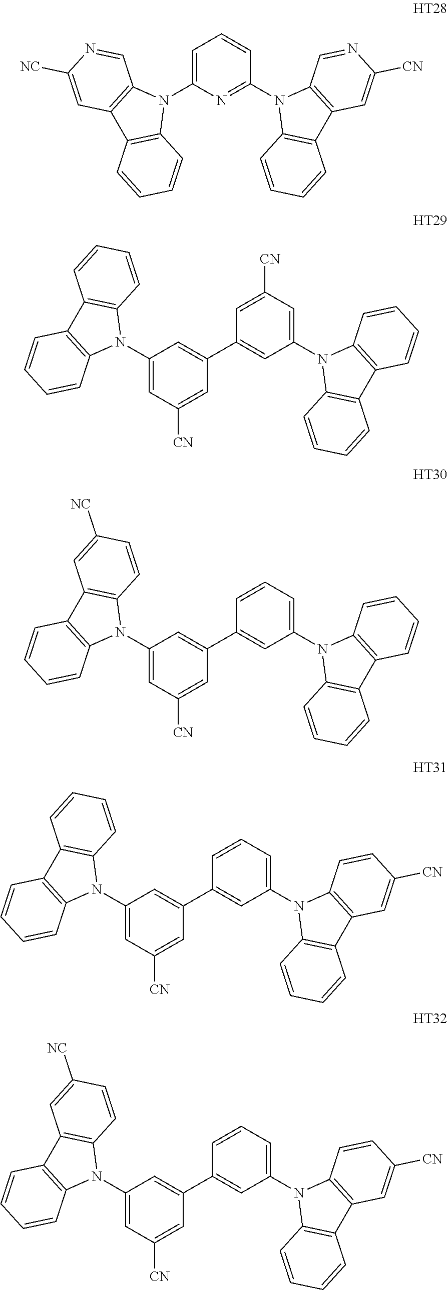 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

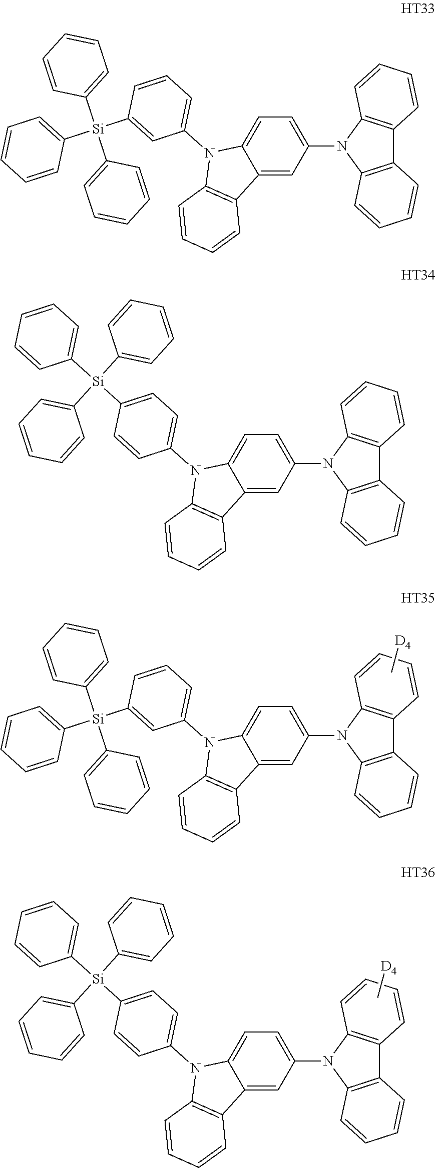

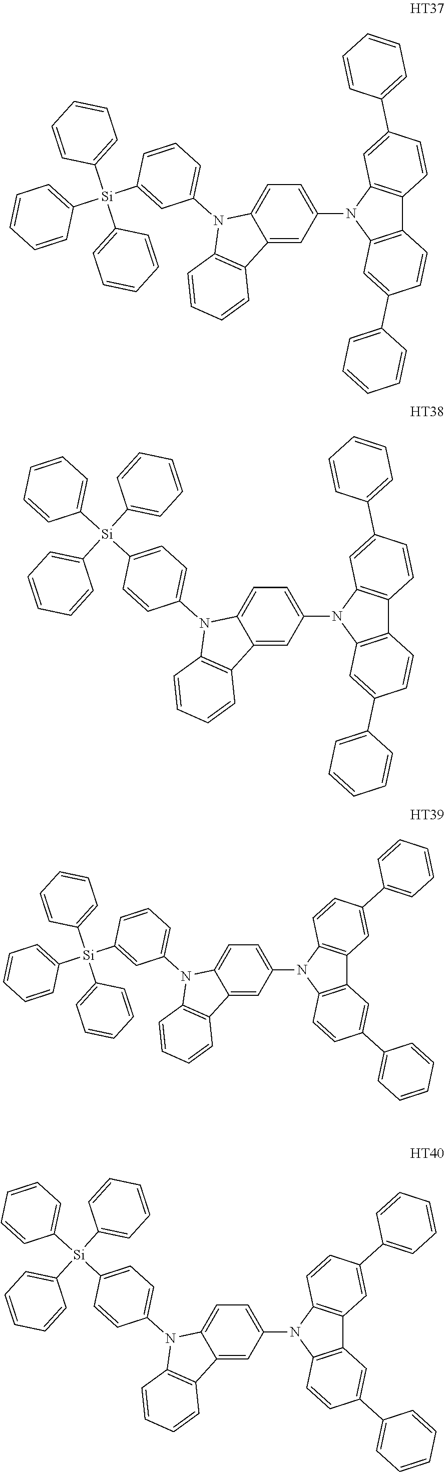 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

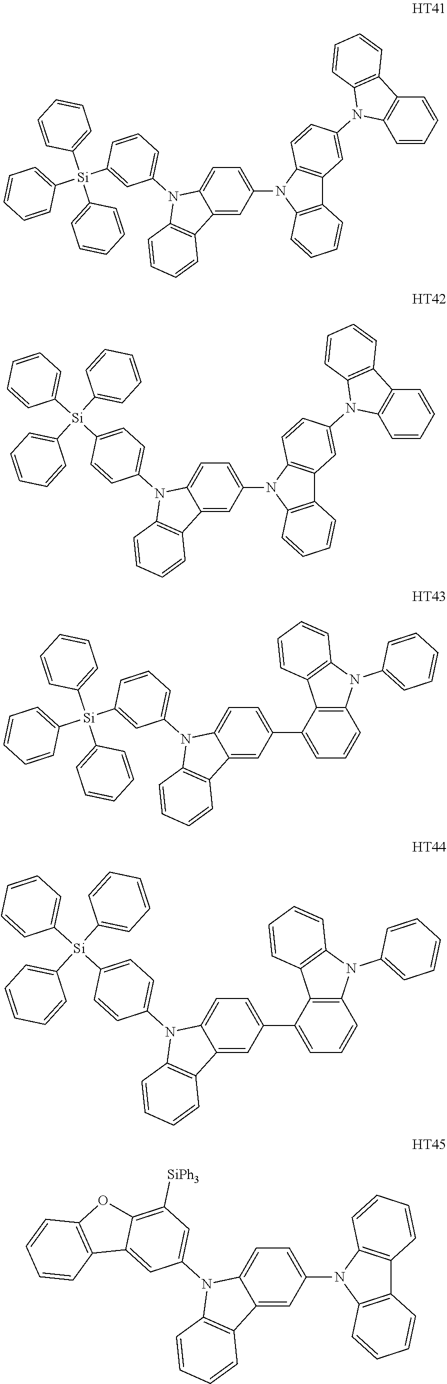

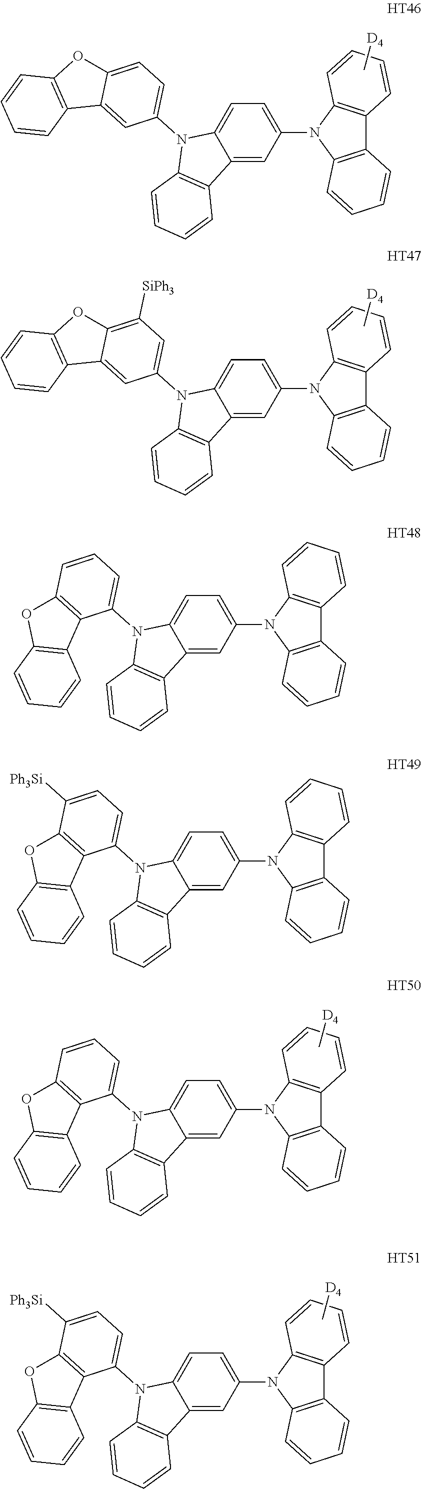

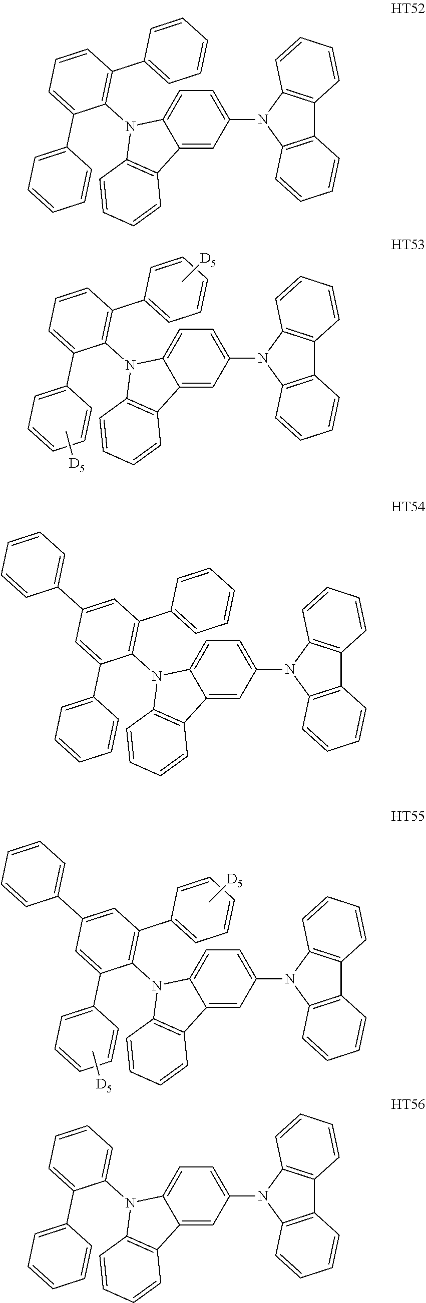

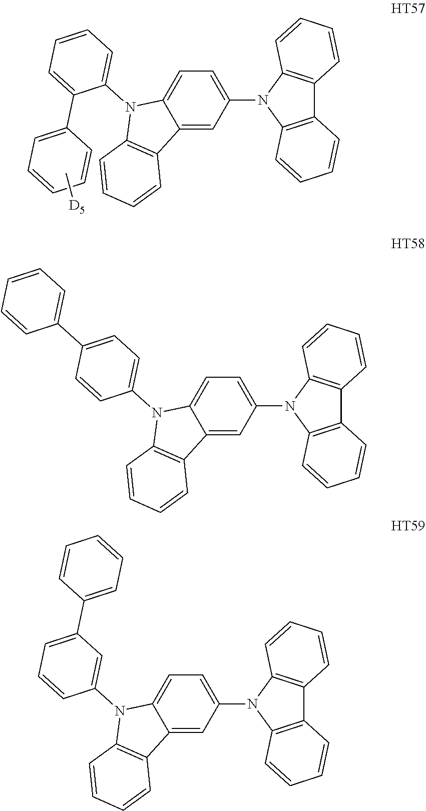

In an embodiment, the third compound may be represented by Formula ET-1. For example, the emission layer EML may include the third compound as an electron transporting host material.

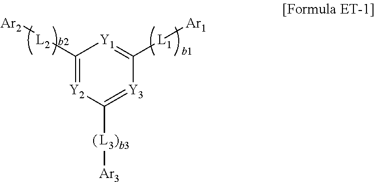

In Formula ET-1, at least one of Y₁ to Y₃ may be N and the others are CRₐ. Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

When any one of Y₁ to Y₃ is N, the third compound represented by Formula ET-1 may include a pyridine group. When any two of Y₁ to Y₃ are N, the third compound represented by Formula ET-1 may include a pyrimidine group. When all of Y₁ to Y₃ are N, the third compound represented by Formula ET-1 may include a triazine group.

In some embodiments, b1 to b3 may each independently be an integer of 0 to 10. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may a substituted or unsubstituted phenyl group or a substituted or unsubstituted carbazole group. However, this is presented as an example, and the embodiment of the present disclosure is not limited thereto.

The third compound may be represented by any one among compounds of Compound Group 3. The light emitting element ED according to an embodiment may include any one among compounds of Compound Group 3. In Compound Group 3, D is a deuterium atom.

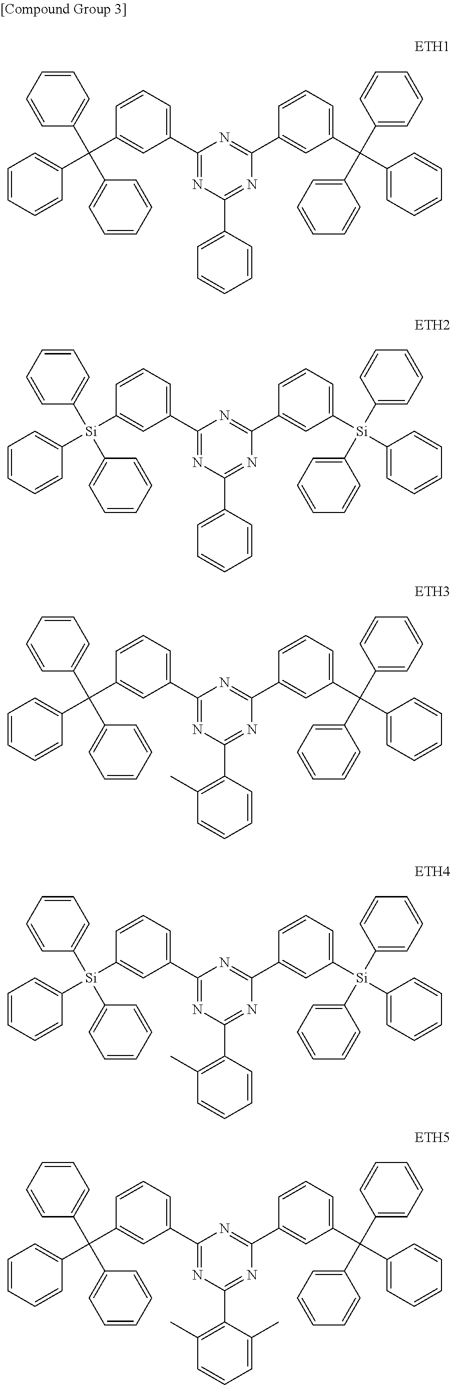

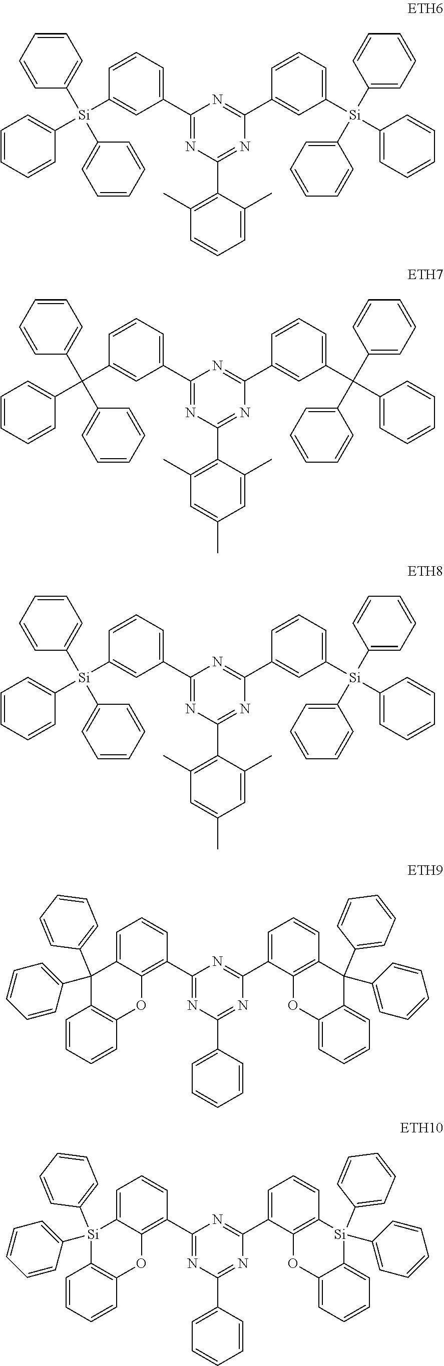

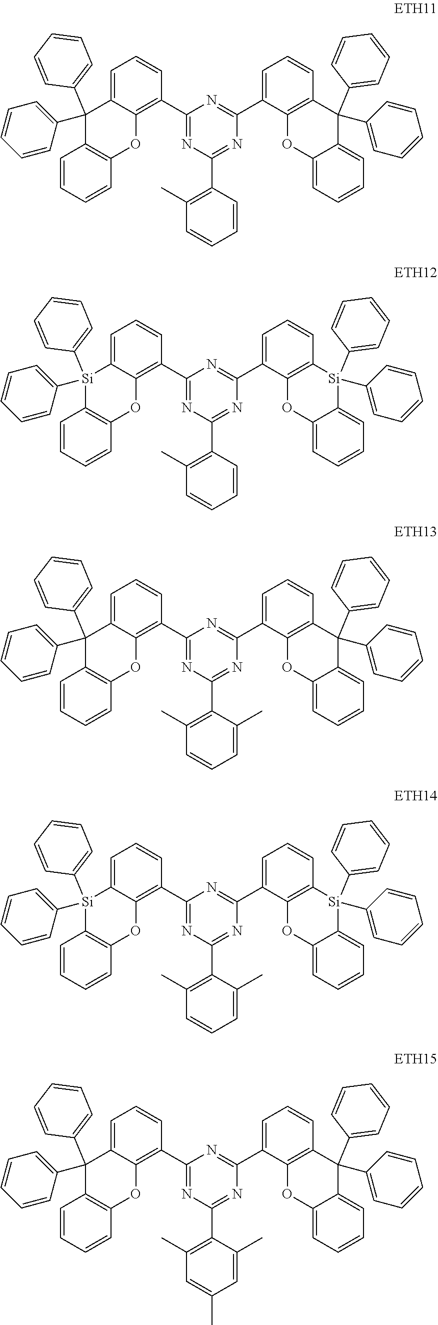

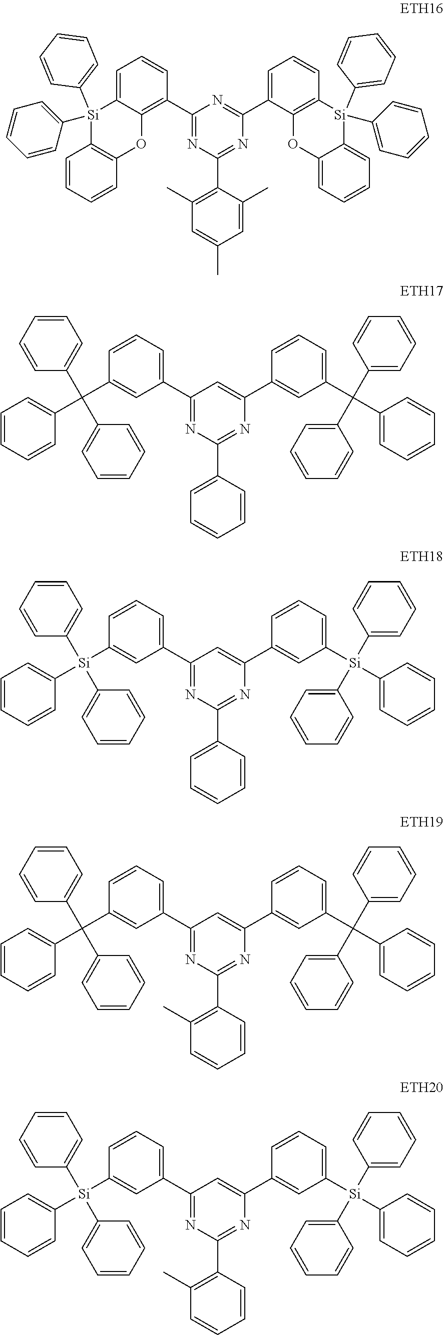

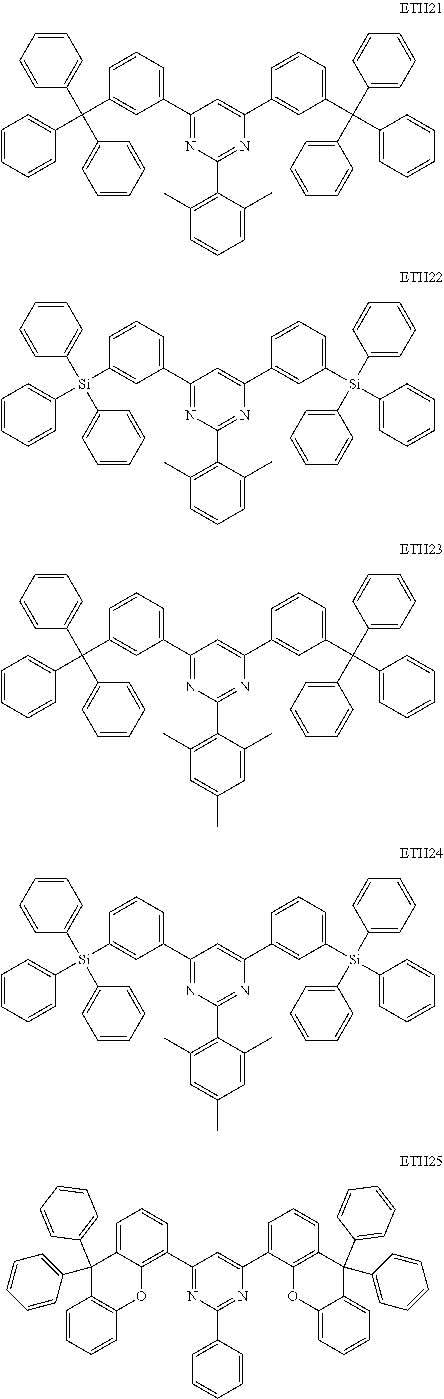

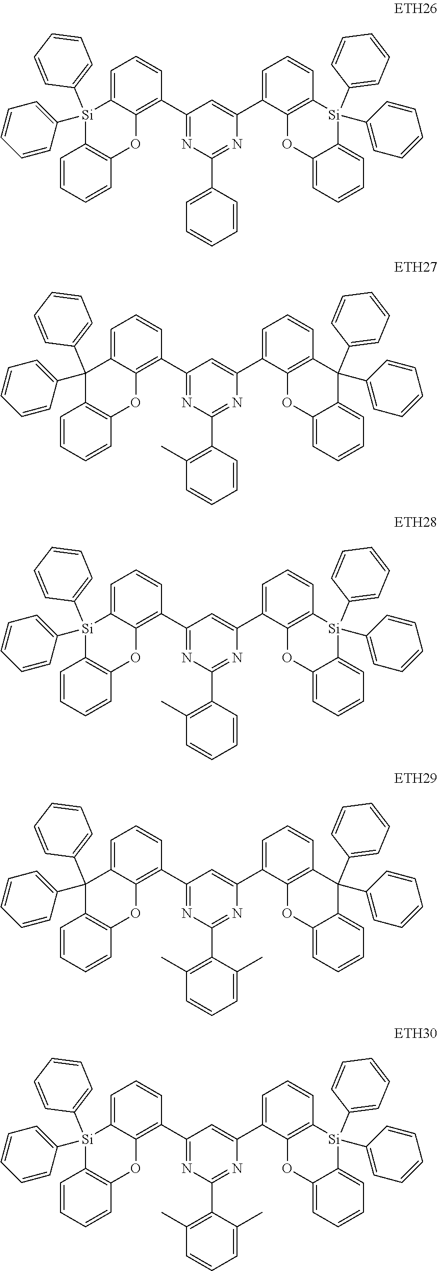

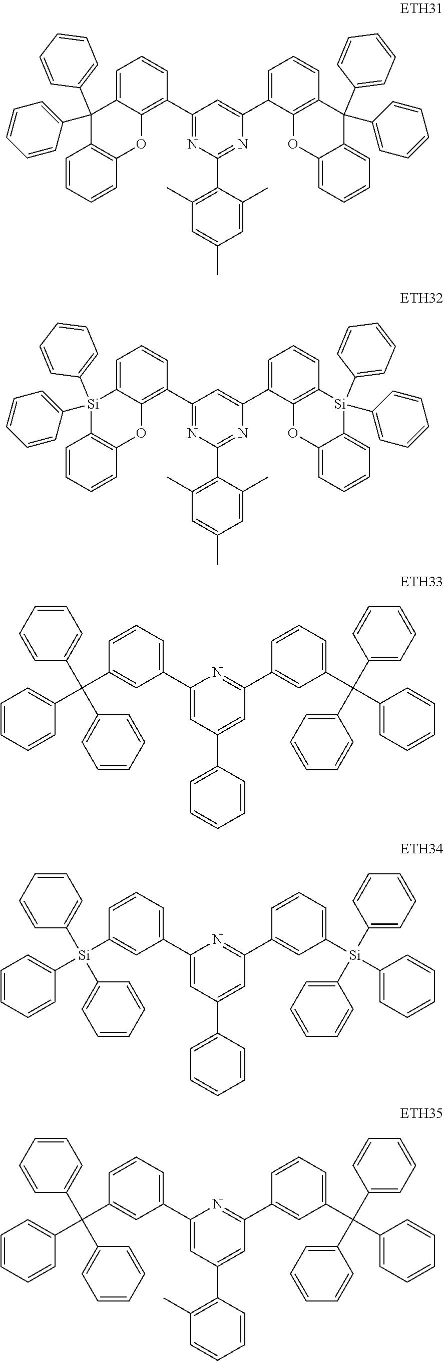

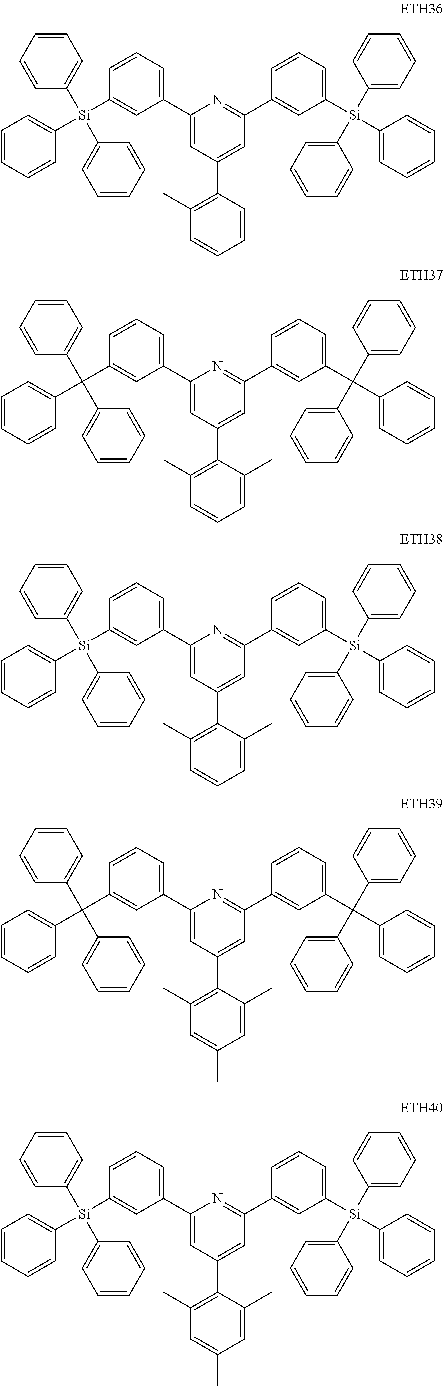

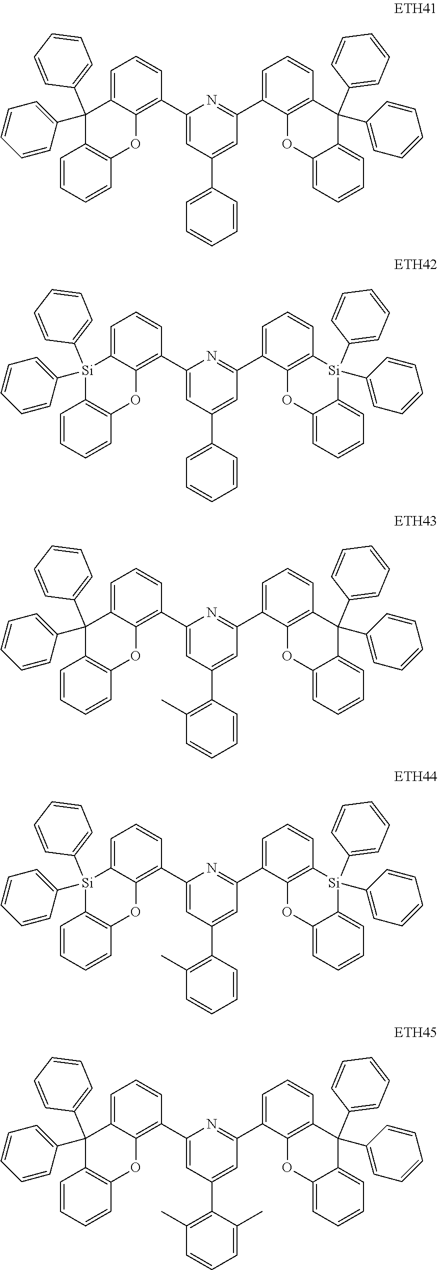

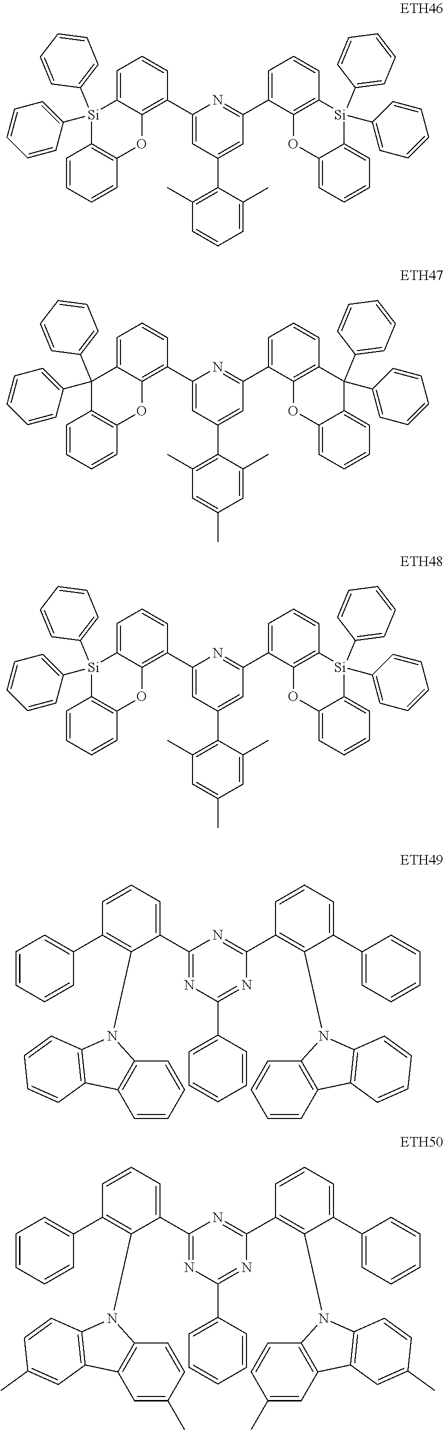

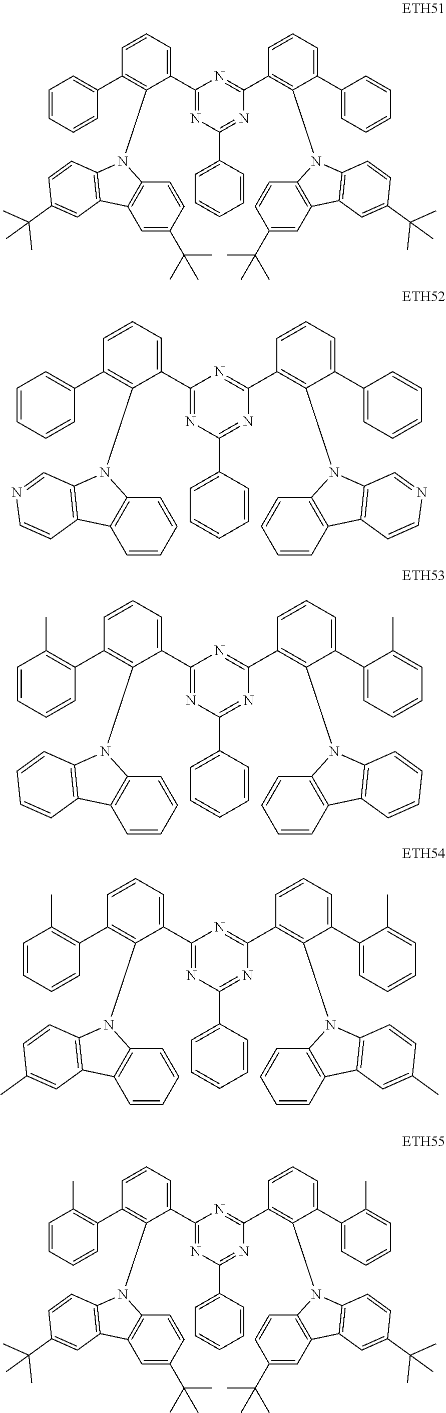

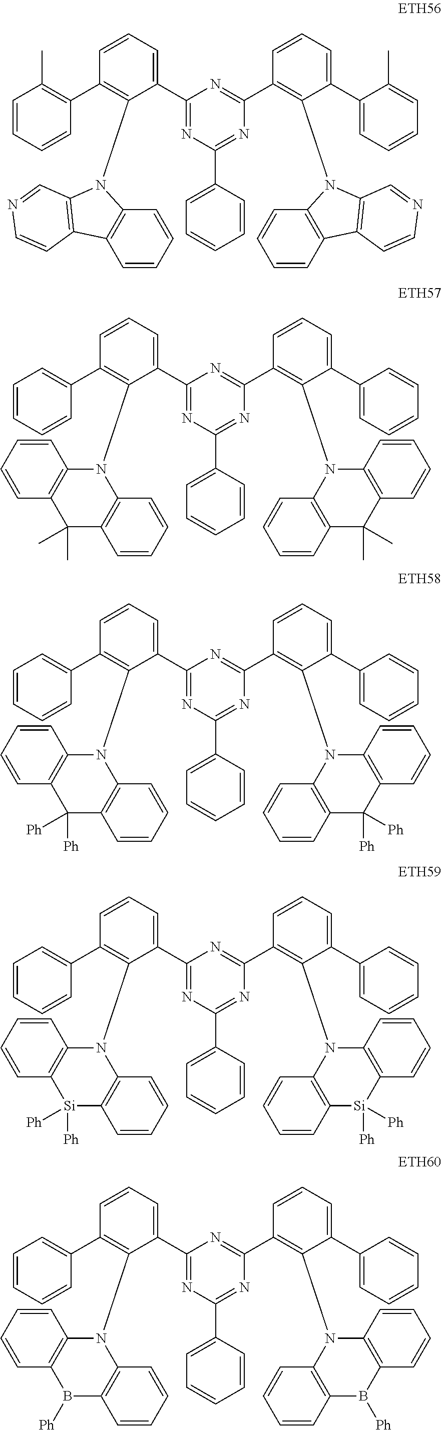

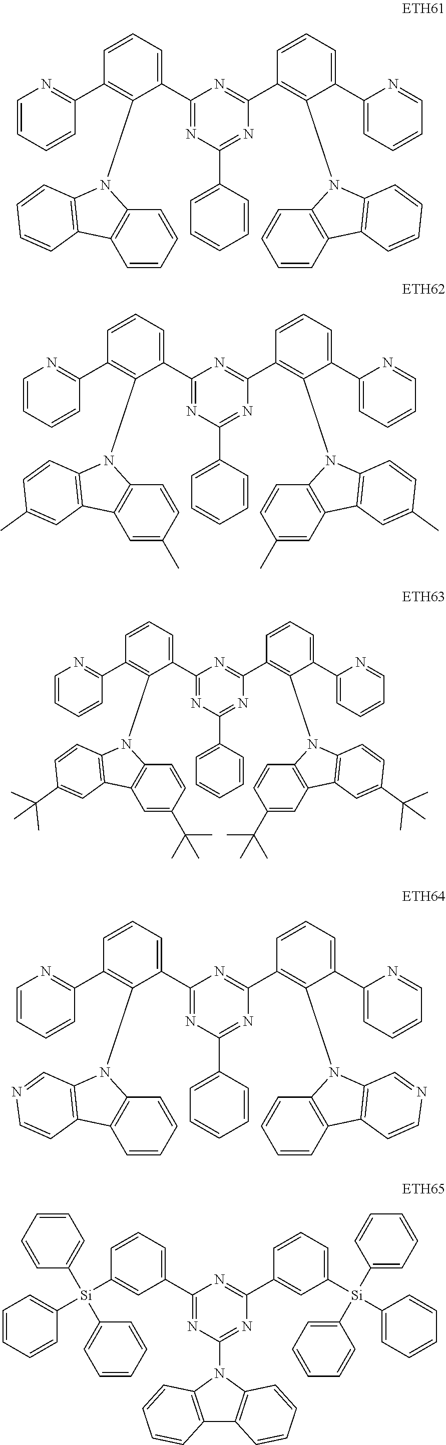

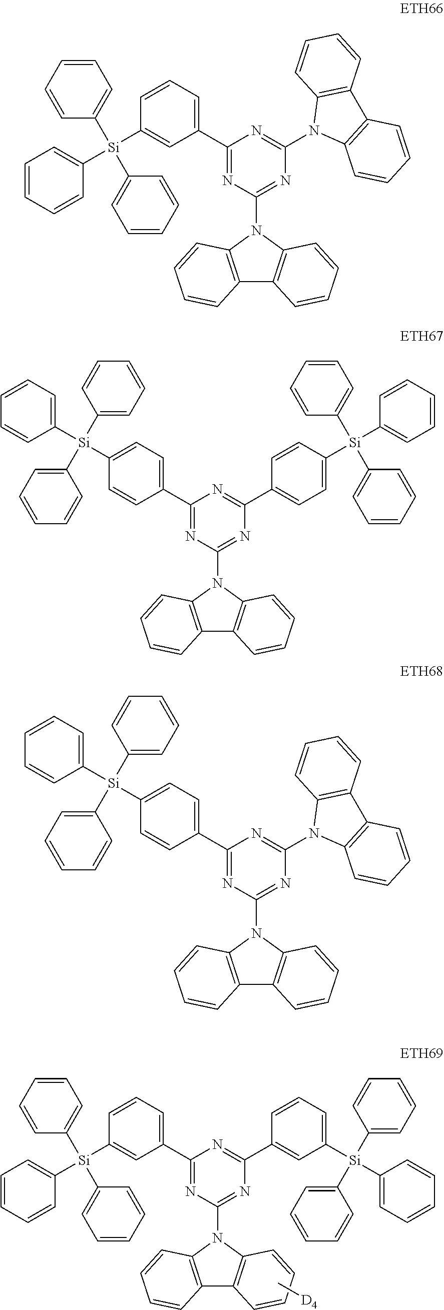

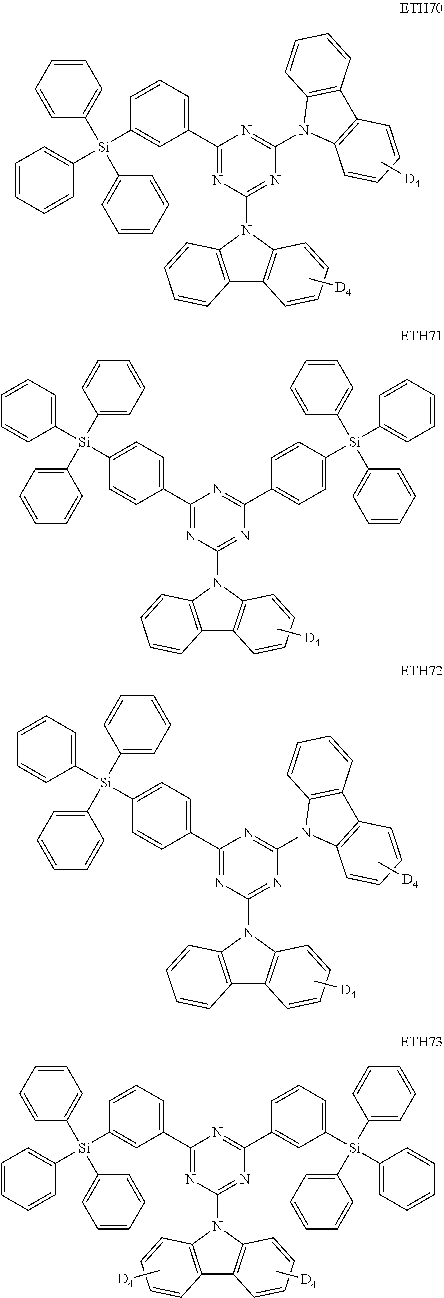

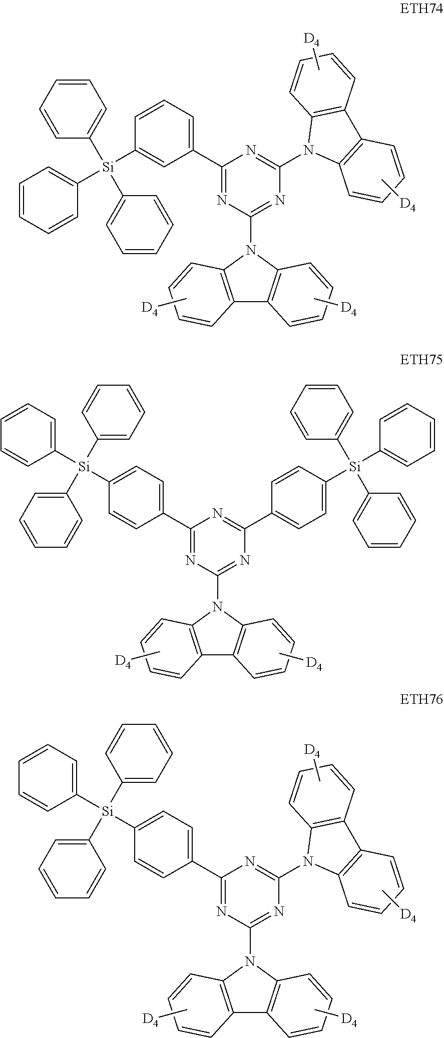

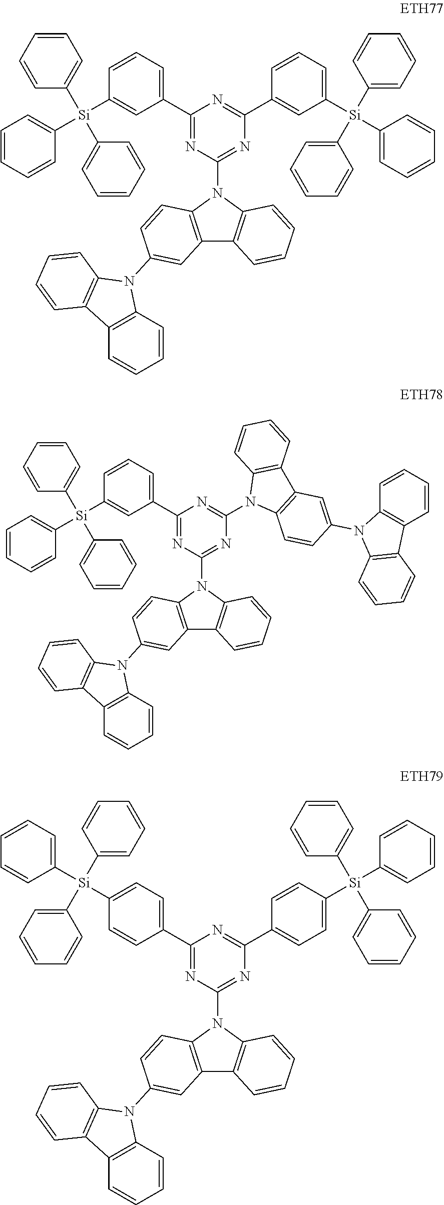 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

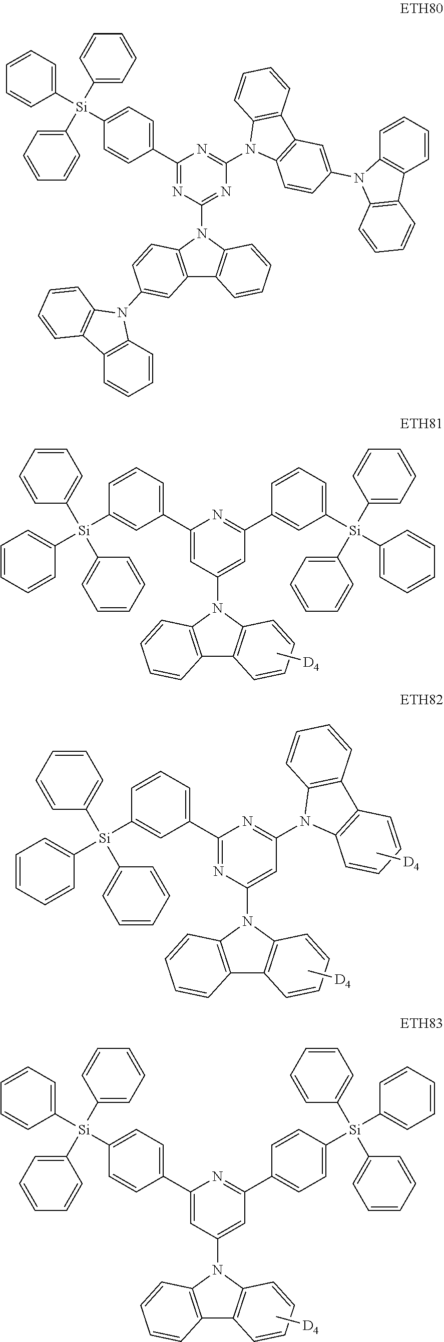

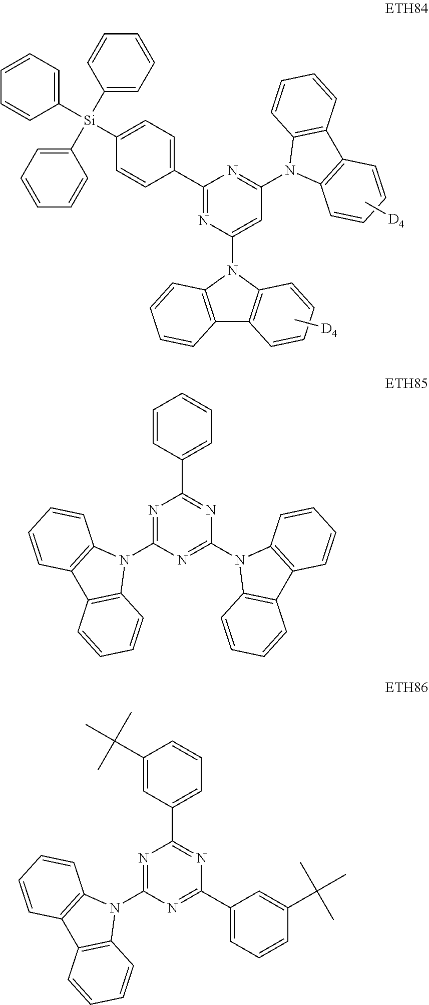

In an embodiment, the emission layer EML may further include the fourth compound represented by Formula M-b. The fourth compound may be utilized as a phosphorescent dopant material or a phosphorescent sensitizer. For example, the emission layer EML may include the fourth compound as a phosphorescent sensitizer.

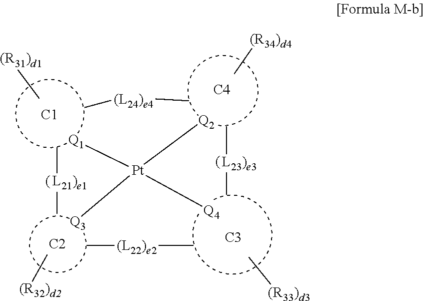

In Formula M-b, Q₁ to Q₄ may each independently be C or N. C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

e1 to e4 may each independently be 0 or 1. L₂₁ to L₂₄ may each independently be a direct linkage,

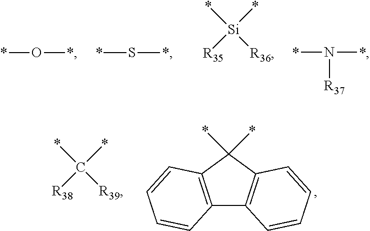

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In some embodiments, d1 to d4 may each independently be an integer of 0 to 4. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

In some embodiments, the compound represented by Formula M-b may be utilized as a blue phosphorescent dopant or a green phosphorescent dopant. The compound represented by Formula M-b may be represented by any one among compounds from Compound Group 4. The light emitting element ED according to an embodiment may include any one among compounds of Compound Group 4. However, the compounds are presented as an example, and the compound represented by Formula M-b is not limited to those represented by the compounds.

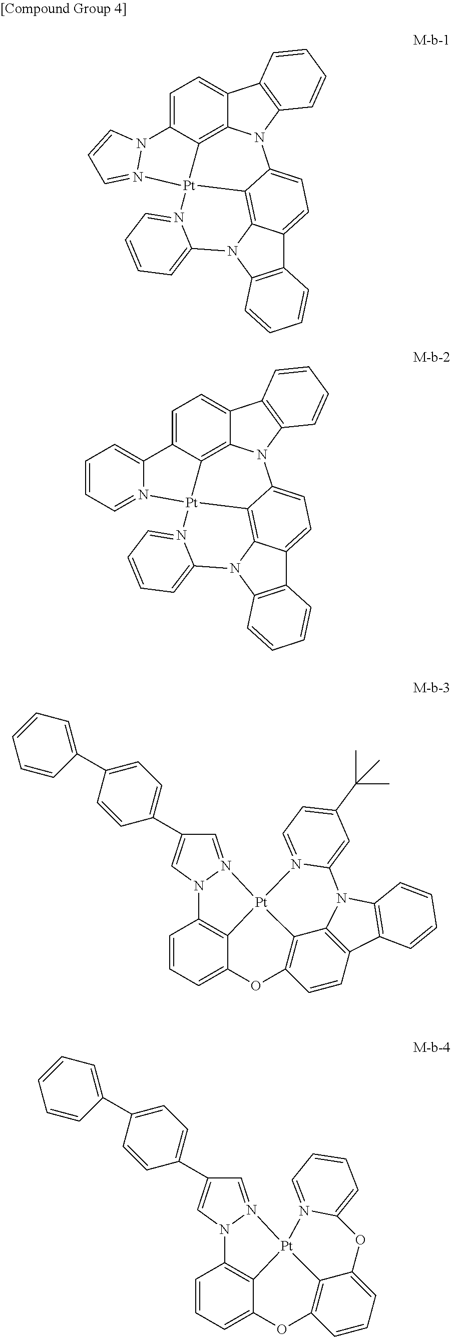

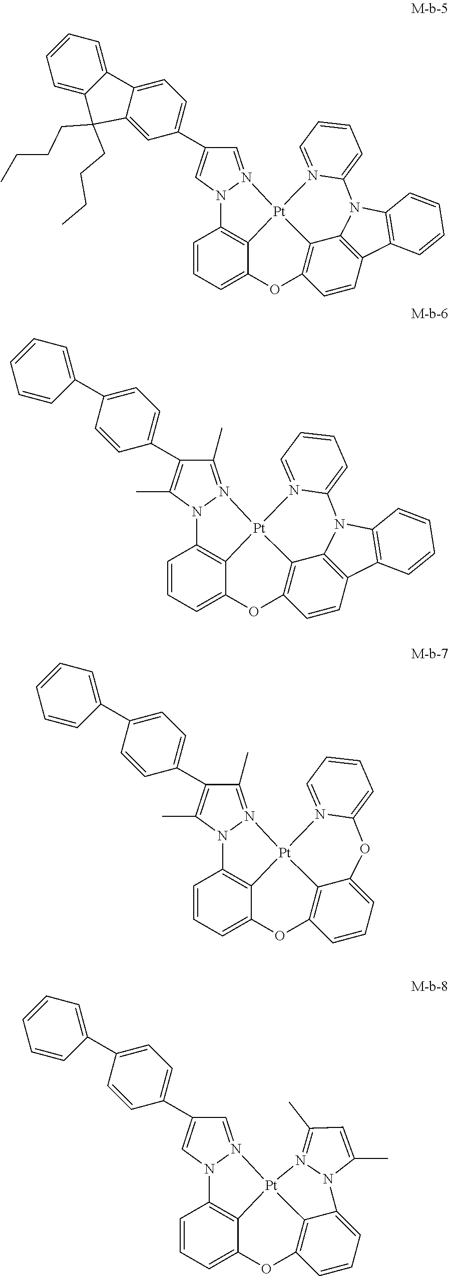

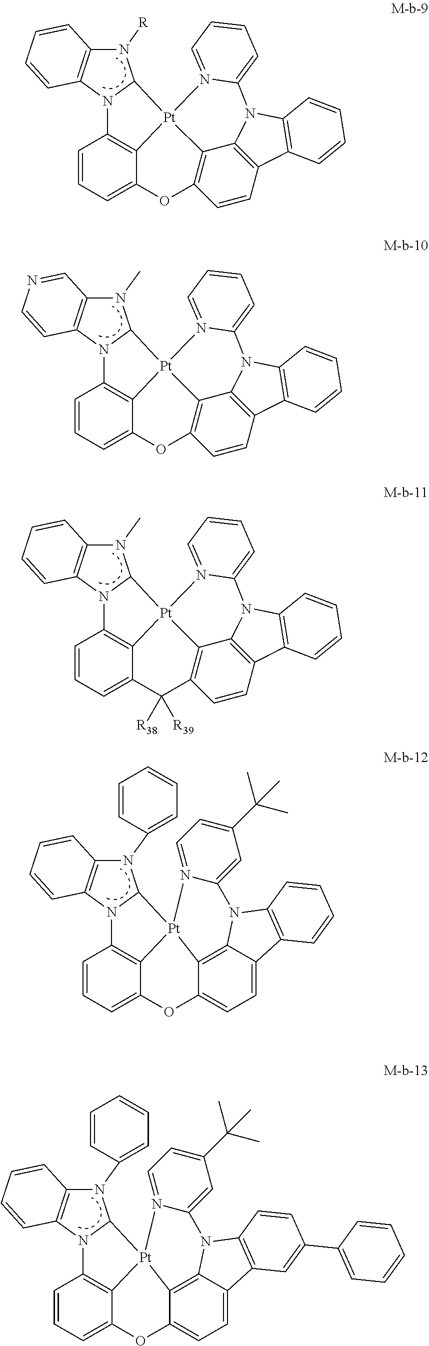

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the light emitting element ED of an embodiment, the emission layer EML may include at least one of the second compound represented by Formula HT-1 or the third compound represented by Formula ET-1, and the fused polycyclic compound of an embodiment. In some embodiments, the emission layer EML may include the fourth compound represented by Formula M-b. In an embodiment, a light emitting element ED including the second to fourth compounds and a fused polycyclic compound may exhibit excellent or suitable light efficiency. In some embodiments, in an embodiment, the light emitting element ED including the second to fourth compounds and a fused polycyclic compound may have reduced driving voltage and increased lifespan.

The emission layer EML may be provided on the hole transport region HTR. The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML may further include compounds which will be described later, in addition to the second to fourth compounds and the fused polycyclic compound described above. For example, the emission layer EML may include an anthracene derivative, a pyrene derivative, a fluoranthene derivative, a chrysene derivative, a dihydrobenzanthracene derivative, or a triphenylene derivative. To be specific, the emission layer EML may include an anthracene derivative or a pyrene derivative.

The emission layer EML may include a compound represented by Formula E-1. The compound represented by Formula E-1 may be utilized as a fluorescent host material.

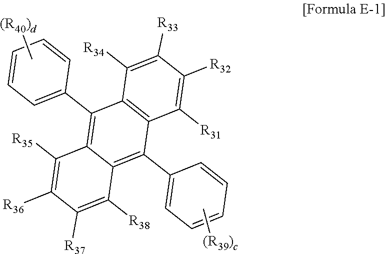

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In some embodiments, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5. When c is an integer of 2 or greater, a plurality of R₃₉'s may all be the same or at least one may be different from the others. When d is an integer of 2 or greater, a plurality of R₄₀'s may all be the same or at least one may be different from the others. Formula E-1 may be represented by any one among compounds E1 to E19.

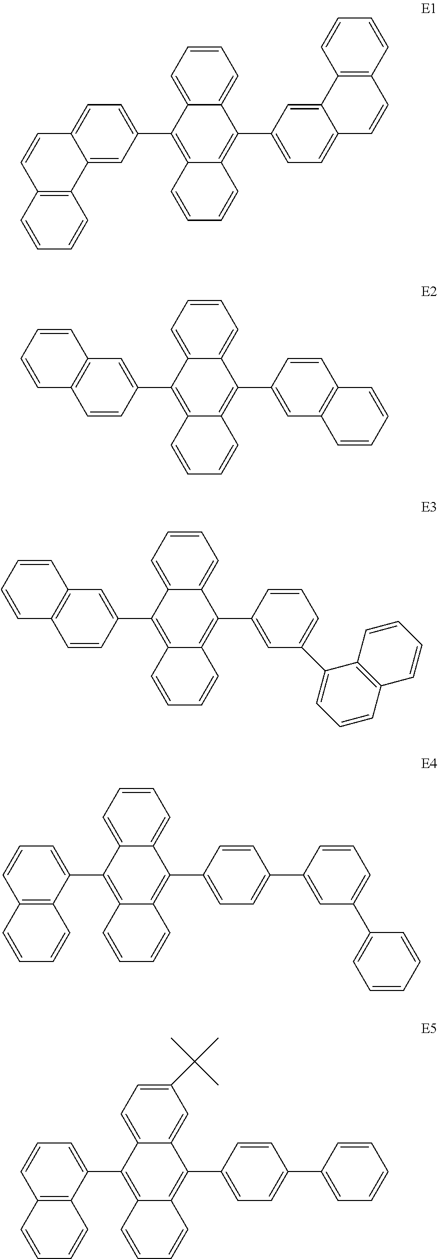

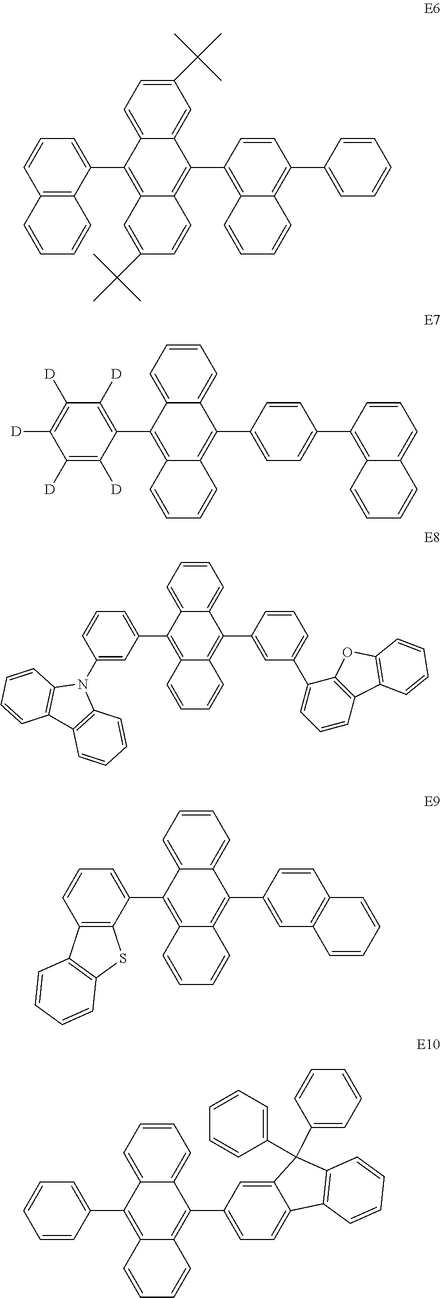

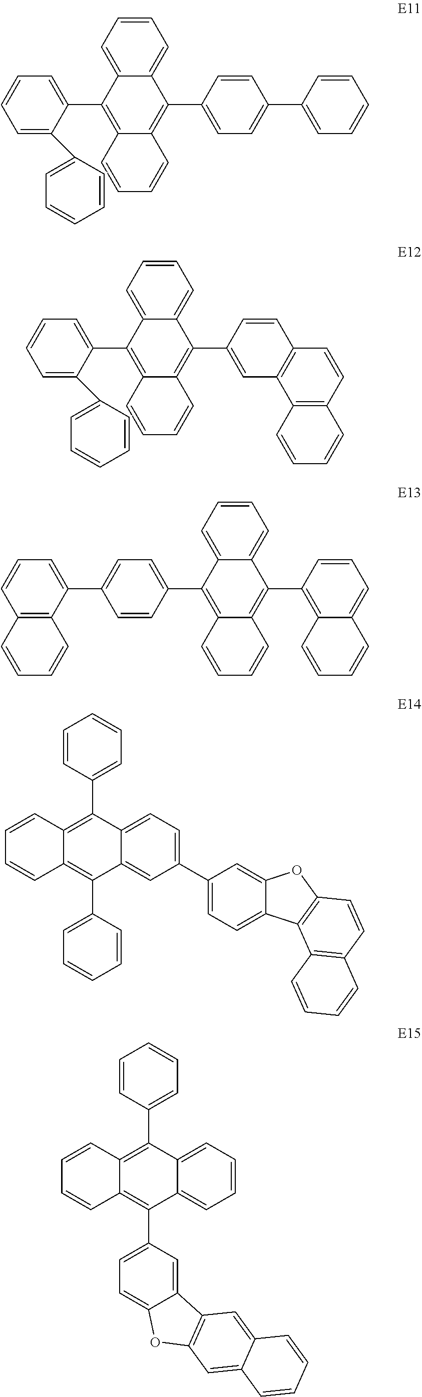

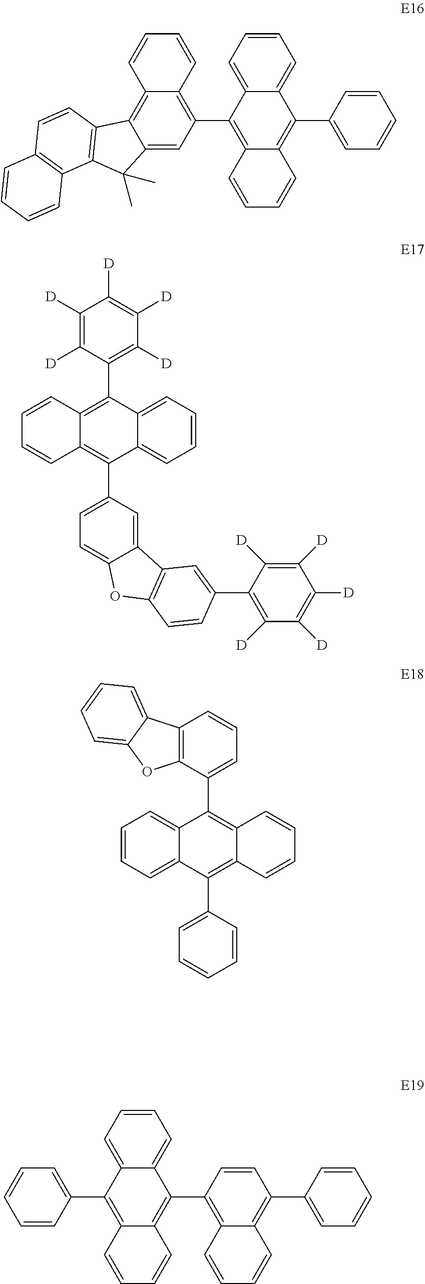

In an embodiment, the emission layer EML may include a compound represented by Formula E-2a or Formula E-2b. The compound represented by Formula E-2a or Formula E-2b may be utilized as a phosphorescent host material.

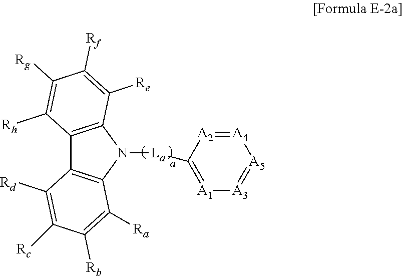

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. Rₐ to Rᵢ may be bonded to an adjacent group to form a hydrocarbon ring or a heterocycle containing N, O, S, and/or the like as a ring-forming atom.

In some embodiments, in Formula E-2a, two or three selected from A₁ to A₅ may be N, and the others may be CRᵢ.

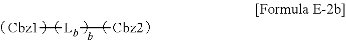

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and when b is an integer of 2 or greater, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among compounds from Compound Group E-2. However, the compounds listed in Compound Group E-2 are presented as an example, and the compound represented by Formula E-2a or Formula E-2b is not limited to those listed in Compound Group E-2.

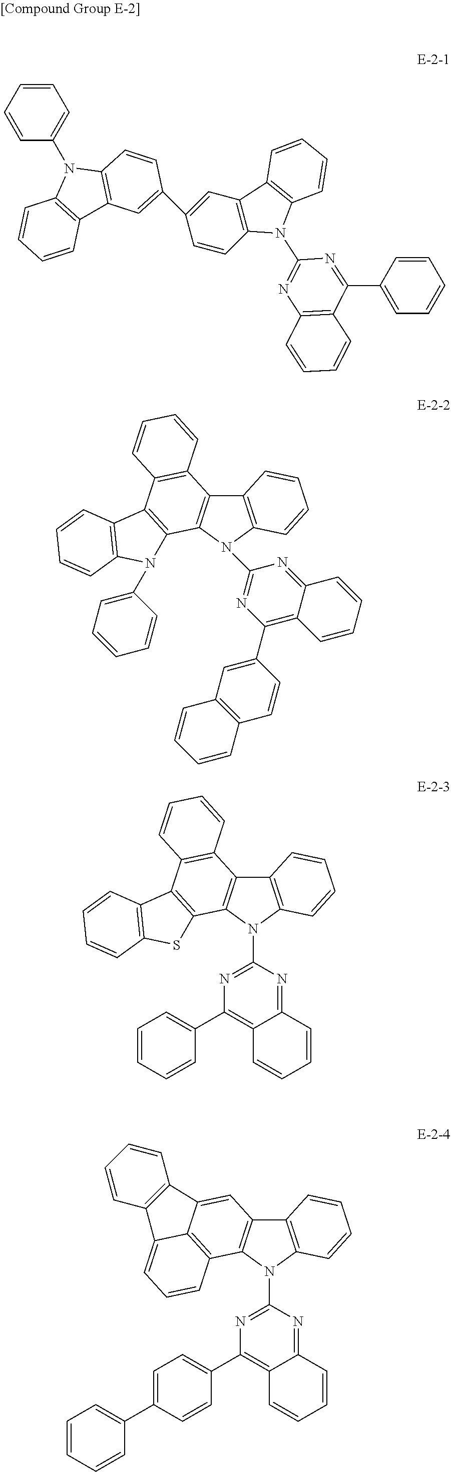

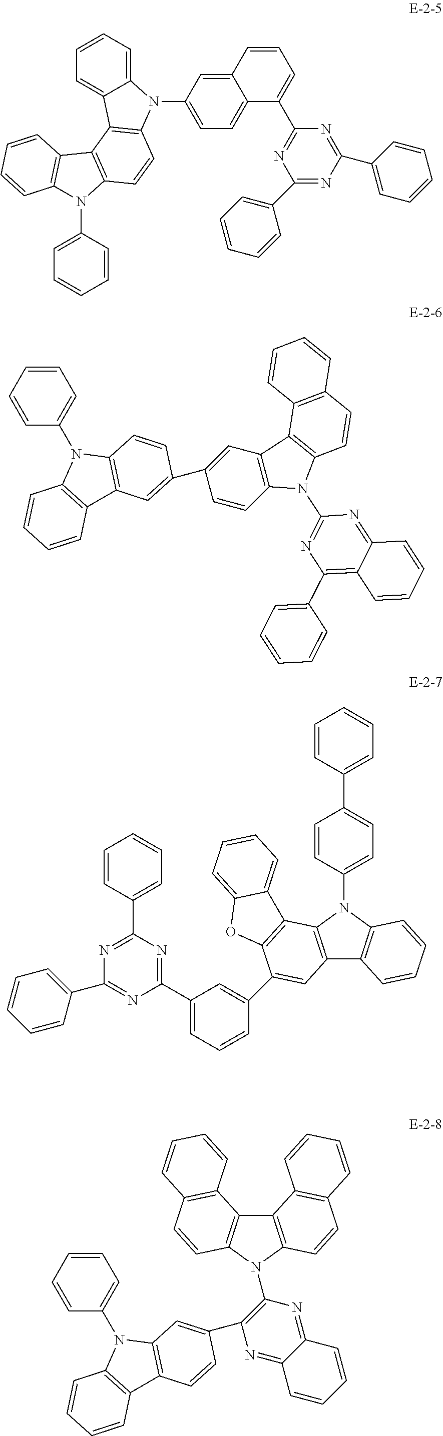 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

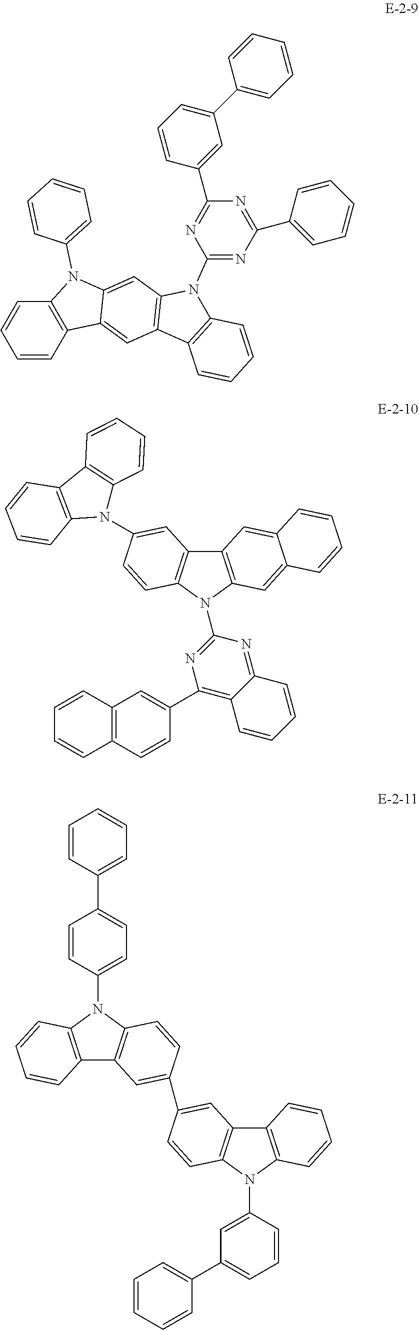 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

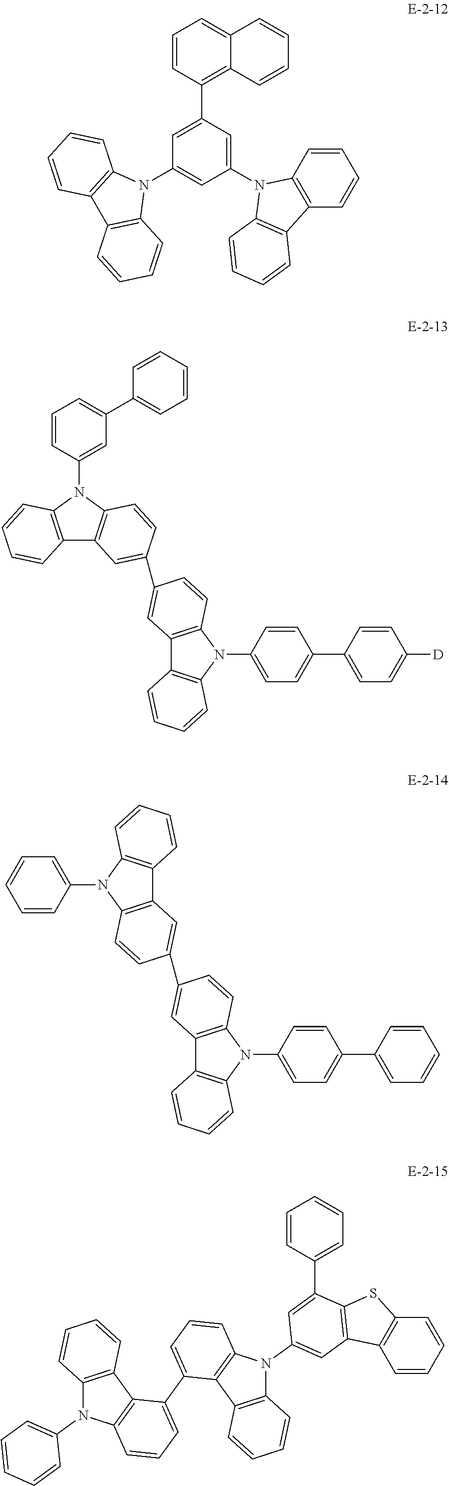 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

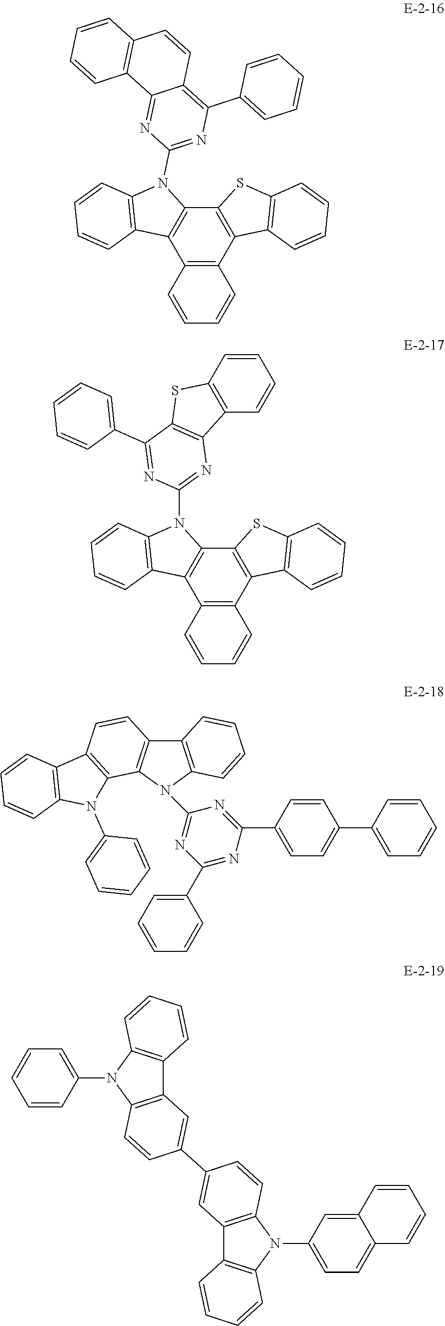

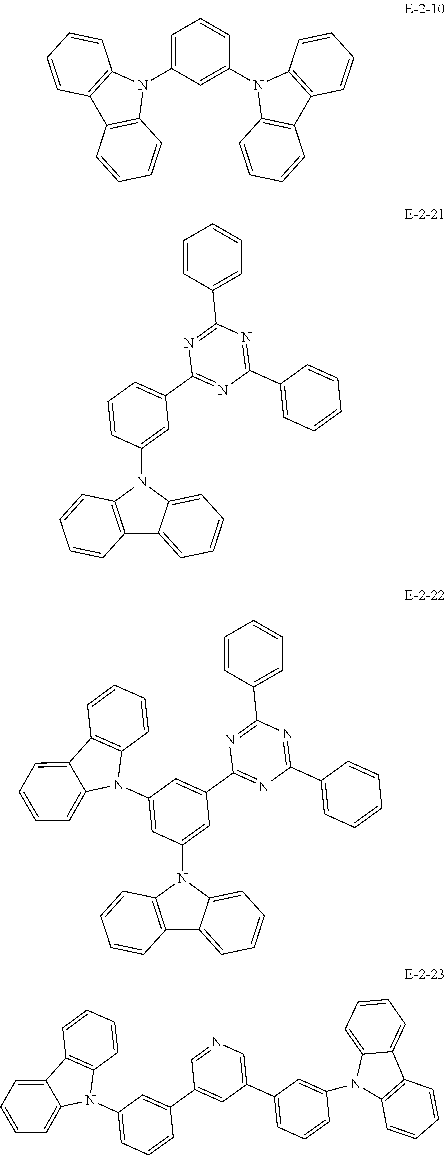 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

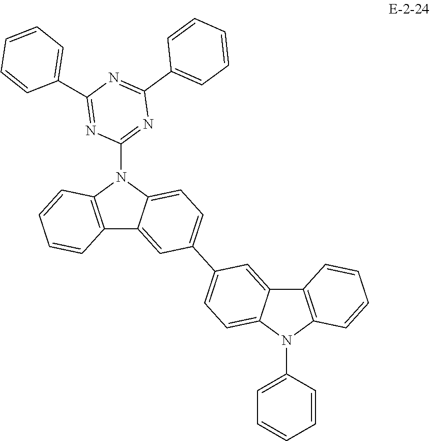 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the embodiment of the present disclosure is not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be utilized as a host material.

The emission layer EML may include a compound represented by Formula M-a. The compound represented by Formula M-a may be utilized as a phosphorescent dopant material or a phosphorescent sensitizer.

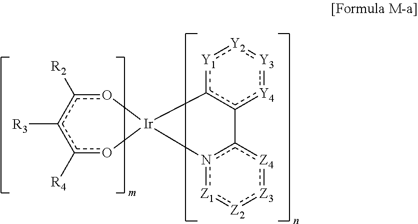

In Formula M-a above, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In Formula M-a, m is 0 or 1, and n is 2 or 3. In Formula M-a, when m is 0, n is 3, and when m is 1, n is 2.

The compound represented by Formula M-a may be represented by any one among compounds M-a1 to M-a25. However, the compounds M-a1 to M-a25 are presented as an example, and the compound represented by Formula M-a is not limited to those represented by the compounds M-a1 to M-a25.

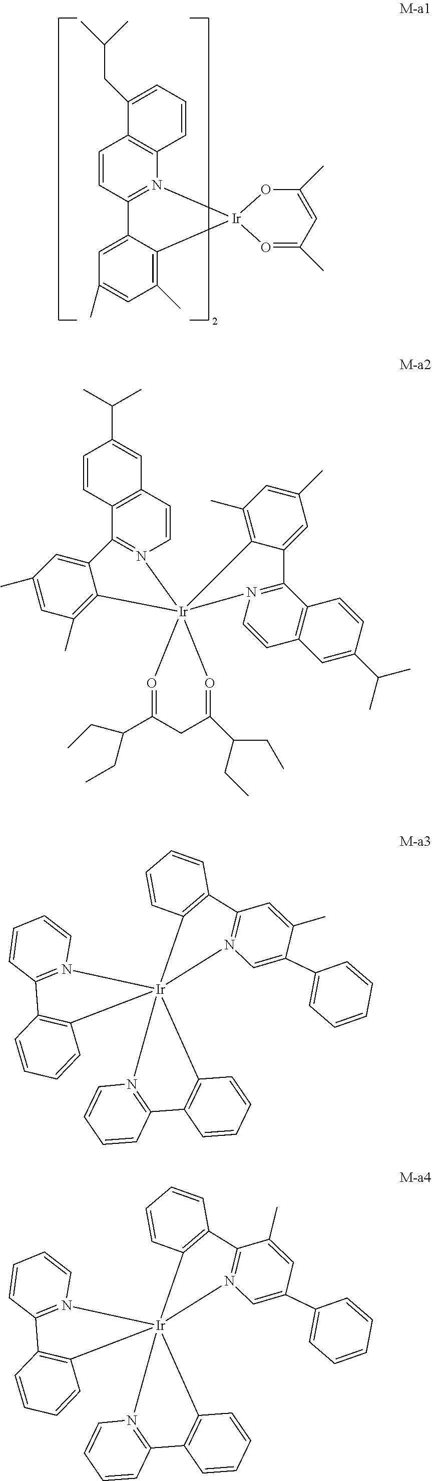

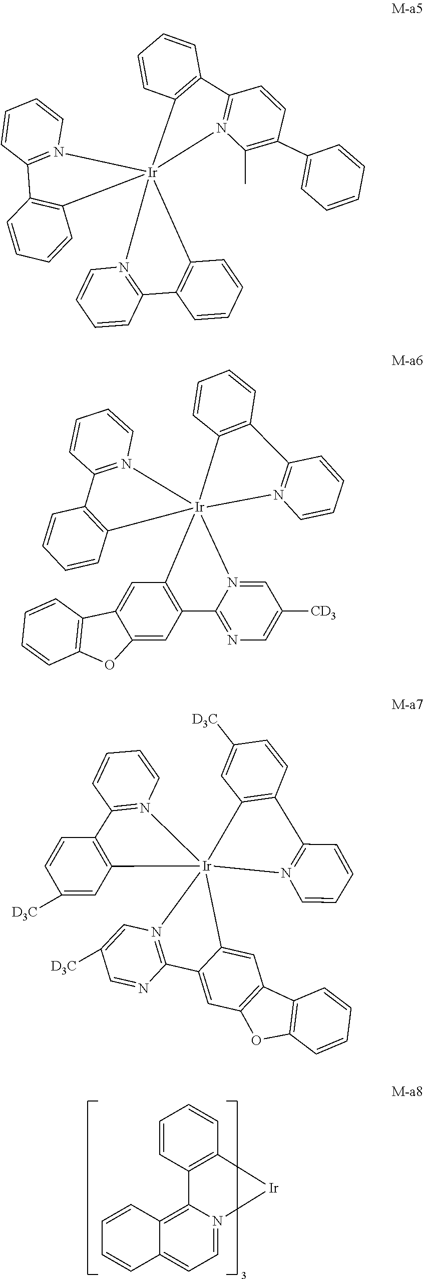

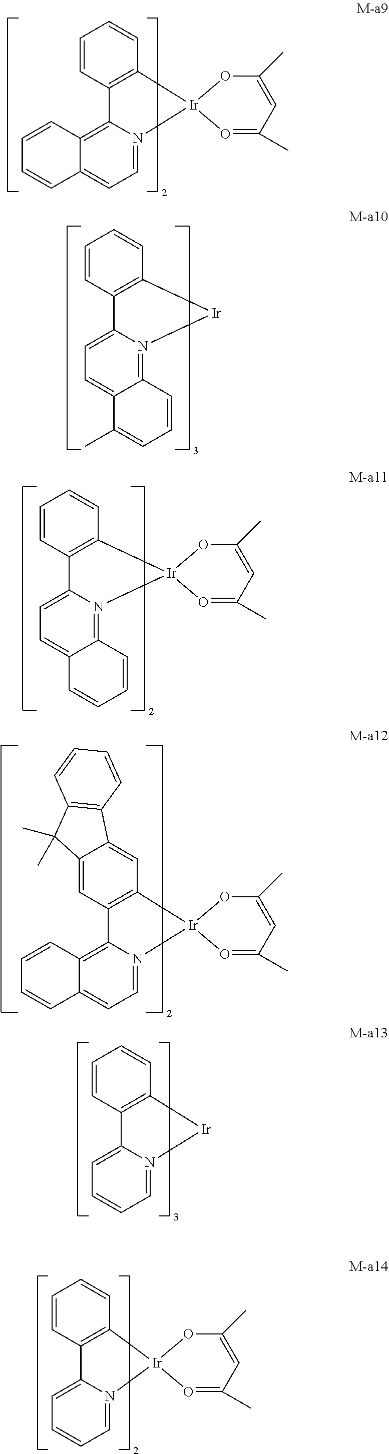

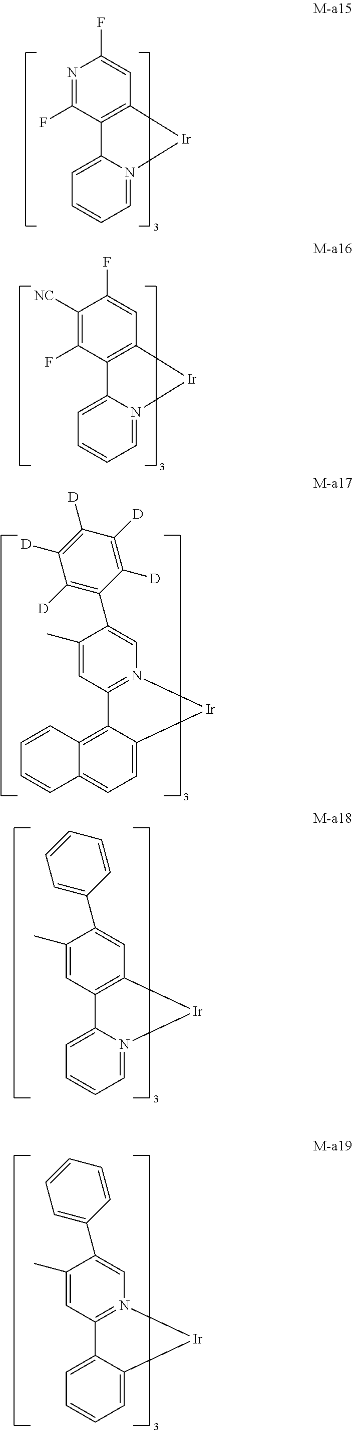

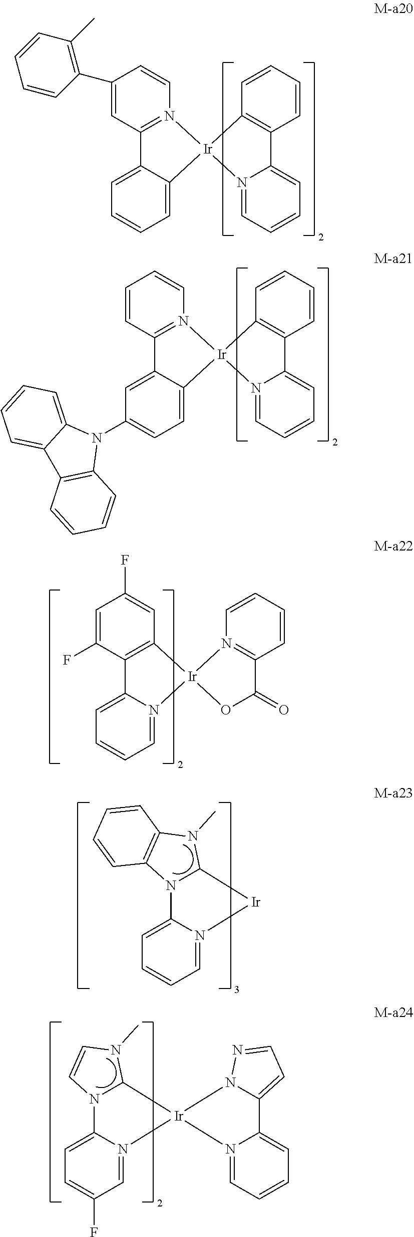

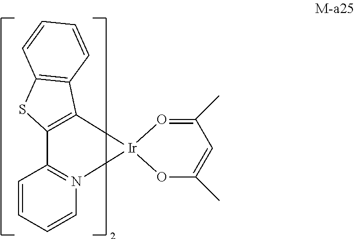

The compounds M-a1 and M-a2 may be utilized as a red dopant material, and the compounds M-a3 to M-a7 may be utilized as a green dopant material.

The emission layer EML may include a compound represented by any one among Formulas F-a to F-c. The compounds represented by Formulas F-a to F-c may be utilized as a fluorescent dopant material.

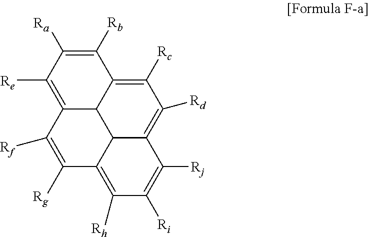

In Formula F-a above, two selected from Rₐ to Rⱼ may each independently be substituted with *—NAr₁Ar₂ The others among Rₐ to Rⱼ which are not substituted with *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

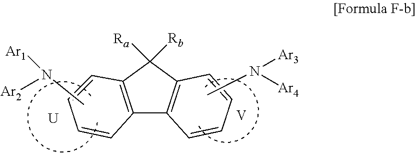

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring group having 5 to 30 ring-forming carbon atoms, or a substituted or unsubstituted heterocyclic group having 2 to 30 ring-forming carbon atoms. In Formula F-b, the number of rings represented by U and V may each independently be 0 or 1.

For example, in Formula F-b, when the number of U or V is 1, one ring forms a fused ring in a portion indicated by U or V, and when the number of U or V is 0, it refers to that no ring indicated by U or V is present. To be specific, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are 0, the fused ring having a fluorene core of Formula F-b may be a cyclic compound having three rings. In some embodiments, when both (e.g., simultaneously) U and V are 1, the fused ring having a fluorene core of Formula F-b may be a cyclic compound having five rings.

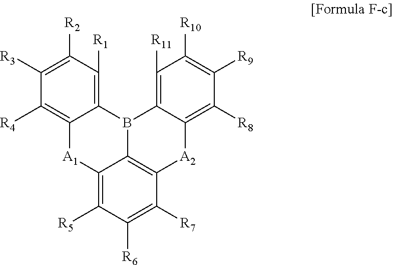

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to substituents of neighboring rings to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

The emission layer EML may include, as a suitable dopant material, styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1′-dipyrene, 1,4-dipyrenylbenzene, 1,4-bis(N,N-diphenylamino)pyrene), and/or the like.

The emission layer EML may include a suitable phosphorescent dopant material. For example, the phosphorescent dopant may include a metal complex including iridium (Ir), platinum (Pt), osmium (Os), gold (Au), titanium (Ti), zirconium (Zr), hafnium (Hf), europium (Eu), and terbium (Tb), or thulium (Tm). To be specific, iridium(III) bis(4,6-difluorophenylpyridinato-N,C2′)picolinato (Flrpic), bis(2,4-difluorophenylpyridinato)-tetrakis(1-pyrazolyl)borate iridium(III) (Fir6), platinum octaethyl porphyrin (PtOEP), and/or the like may be utilized as a phosphorescent dopant. However, the embodiment of the present disclosure is not limited thereto.

The emission layer EML may include a quantum dot material. The core of quantum dots may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ and/or In₂Se₃, a ternary compound such as InGaS₃ and/or InGaSe₃, or a combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, or any mixture thereof, or a quaternary compound such as AgInGaS₂ and CulnGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may be present in particles having a substantially uniform concentration distribution, or may be present in substantially the same particles having a partially different concentration distribution. In some embodiments, a core/shell structure in which one quantum dot surrounds another quantum dot may be present. The core/shell structure may have a concentration gradient in which the concentration of an element present in the shell becomes lower towards the core.

In some embodiments, quantum dots may have the core/shell structure including a core having nano-crystals, and a shell around (e.g., surrounding) the core, which are described above. The shell of the quantum dots may serve as a protection layer to prevent or reduce the chemical deformation of the core so as to keep semiconductor properties, and/or a charging layer to impart electrophoresis properties to the quantum dots. The shell may be a single layer or multiple layers. Examples of the shell of the quantum dots may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, or a ternary compound such as MgAl₂O₄, CoFe₂O₄, NiFe₂O₄, and CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

The quantum dots may have, in an emission wavelength spectrum, a full width of half maximum (FWHM) of about 45 nm or less, about 40 nm or less, and about 30 nm or less, and in this range, the color purity or the color reproducibility may be improved. In some embodiments, light emitted through the quantum dots is emitted in all directions, and thus a wide viewing angle may be improved.

In some embodiments, the form of quantum dots is not particularly limited as long as it is a form commonly utilized in the art, but more specifically, a quantum dot in the form of spherical, pyramidal, multi-arm, or cubic nanoparticles, nanotubes, nanowires, nanofibers, nanoplatelets, and/or the like may be utilized.

The quantum dots may control the color of emitted light according to particle size. Accordingly, the quantum dots may have one or more suitable light emitting colors such as blue, red, and green.

Referring back to FIGS. 3 to 6, the first electrode EL1 may have conductivity. The first electrode EL1 may be formed of a metal material, a metal alloy or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layer structure of ITO/Ag/ITO, but is not limited thereto.

In some embodiments, the first electrode EL1 may include the above-described metal materials, a combination of two or more metal materials selected from the previously described metal materials, or oxides of the previously described metal materials, and the embodiment of the present disclosure is not limited thereto. The first electrode EL1 may have a thickness of about 700 Å to about 10000 Å. For example, the first electrode EL1 may have a thickness of 1000 Å to about 3000 Å.

A hole transport region HTR may be provided on the first electrode EL1. The hole transport region HTR may include at least one among a hole injection layer HIL, a hole transport layer HTL, a buffer layer, an auxiliary emission layer, and/or an electron blocking layer EBL.

The hole transport region HTR may have a single layer formed of a single material, a single layer formed of a plurality of different materials, or a multilayer structure having a plurality of layers formed of a plurality of different materials. For example, the hole transport region HTR may have a single-layer structure formed of the hole injection layer HIL or the hole transport layer HTL, or a single-layer structure formed of a hole injection material or a hole transport material.

For example, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1. However, this is presented as an example, and the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

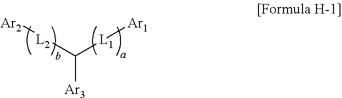

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

A compound represented by Formula H-1 above may be a monoamine compound. In some embodiments, the compound represented by Formula H-1 may be a diamine compound in which at least one of Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂ or a substituted or unsubstituted fluorene-based group in at least one of Ar₁ or Ar₂.

The compound represented by Formula H-1 may be represented by any one among compounds from Compound Group H. However, the compounds listed in Compound Group H are presented as an example, and the compound represented by Formula H-1 is not limited to the those listed in Compound Group H.

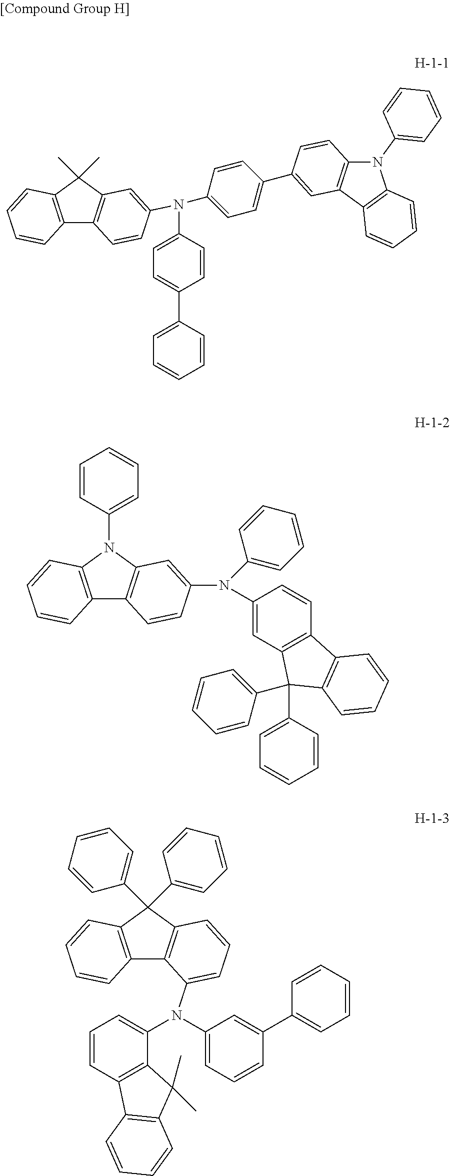 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

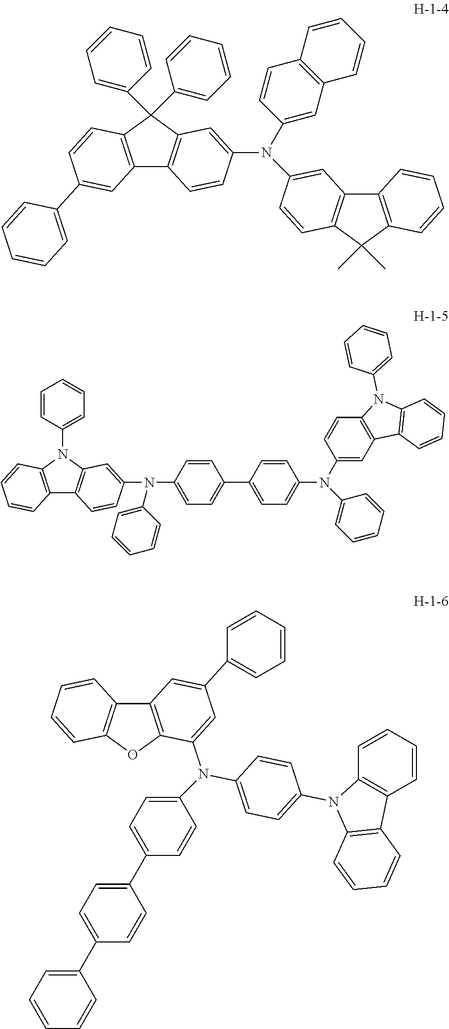 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

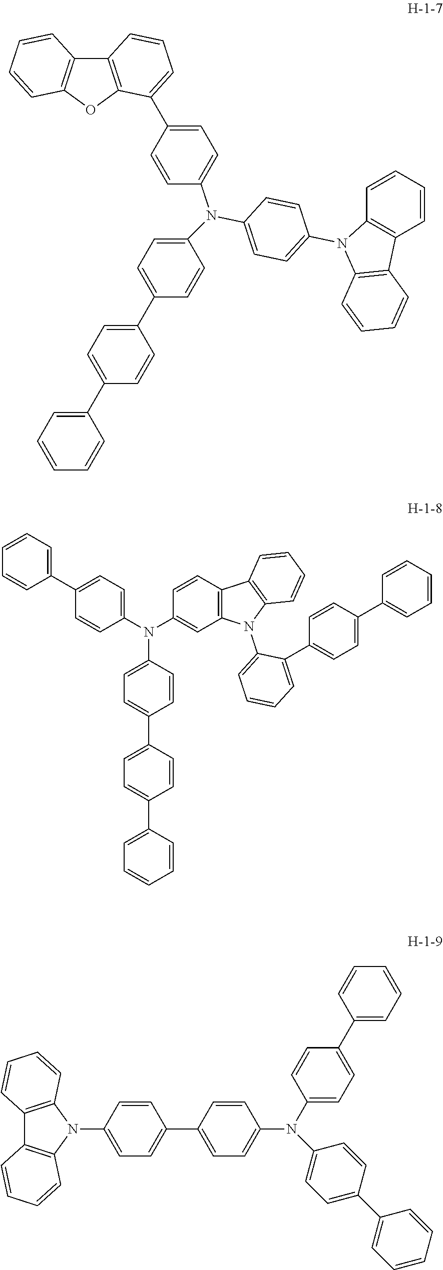 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

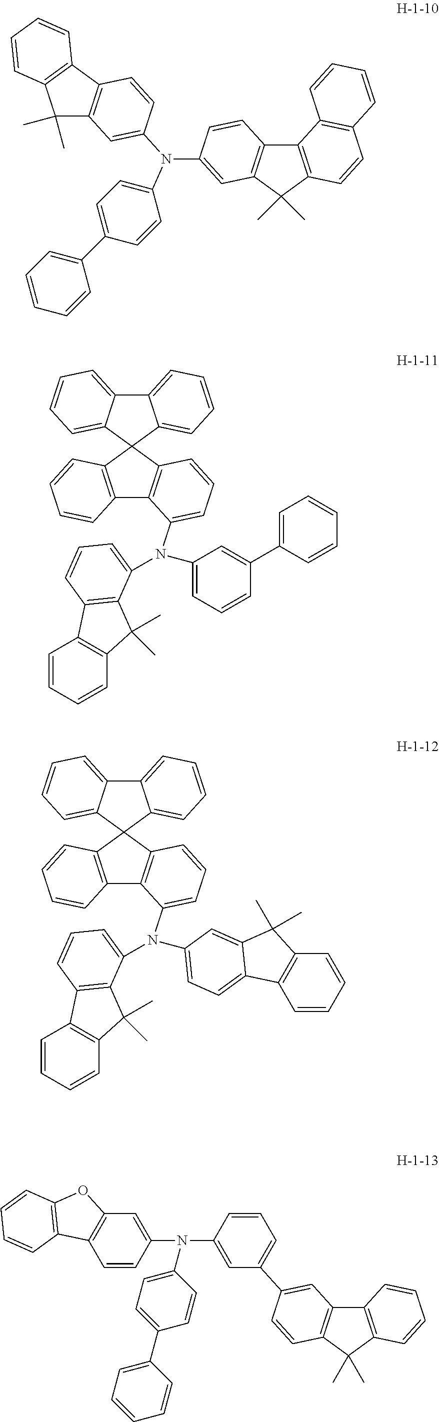 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

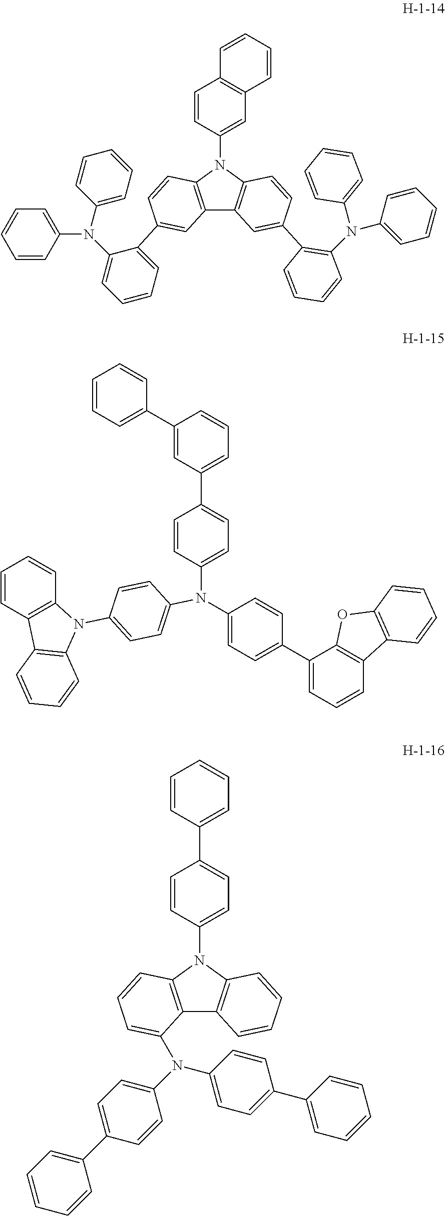 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

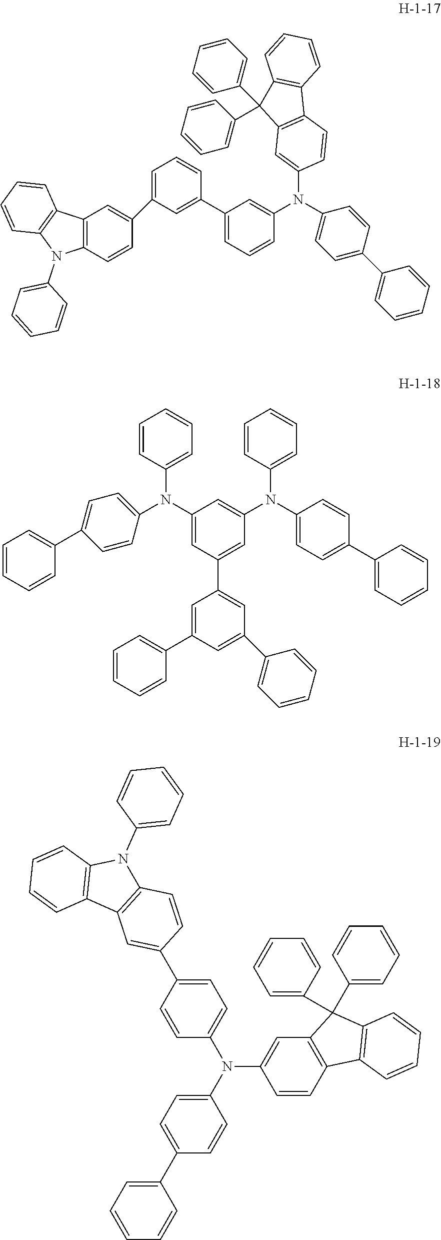 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹, N^{1′}-([1,1′-biphenyl]-4,4′-diyl)bis(N¹-phenyl-N⁴, N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f:2′,3′-h] quinoxaline-2,3,6,7,10,11-hexacarbonitrile (HATCN), and/or the like.

In some embodiments, the hole transport region HTR may include carbazole-based derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazol-9-yl)benzene (mCP), 1,3-bis(1,8-dimethyl-9H-carbazol-9-yl)benzene (mDCP), and/or the like.

The hole transport region HTR may include the compounds of the hole transport region described above in at least one among the hole injection layer HIL, the hole transport layer HTL, or the electron blocking layer EBL.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but is not limited thereto. For example, the p-dopant may include halogenated metal compounds such as Cul and Rbl, quinone derivatives such as tetracyanoquinodimethane (TCNQ) and 2,3,5,6-tetrafluoro-7,7′,8,8′-tetracyanoquinodimethane (F4-TCNQ), metal oxides such as tungsten oxides and molybdenum oxides, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but is not limited thereto.

The hole transport region HTR may have, for example, a thickness of about 50 Å to about 15000 Å. The hole transport region HTR may have a thickness of about 100 Å to about 10000 Å, for example, about 100 Å to about 5000 Å. When the hole transport region HTR includes the hole injection layer HIL, the hole injection layer HIL may have a thickness of, for example, about 30 Å to about 1000 Å. When the hole transport region HTR includes the hole transport layer HTL, the hole transport layer HTL may have a thickness of about 30 Å to about 1000 Å. When the hole transport region HTR includes the electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

As described above, the hole transport region HTR may further include at least one of a buffer layer, an auxiliary emission layer, or an electron blocking layer EBL in addition to the hole injection layer HIL and the hole transport layer HTL. The buffer layer may compensate a resonance distance according to wavelengths of light emitted from an emission layer EML, and may thus increase light emitting efficiency. Materials which may be included in the hole transport region HTR may be utilized as materials included in the buffer layer. The electron blocking layer EBL may serve to prevent or reduce electrons from being injected from the electron transport region ETR to the hole transport region HTR. The auxiliary emission layer may improve charge balance between holes and electrons. When the hole transport region HTR includes the electron blocking layer EBL, the electron blocking layer EBL may function as an auxiliary emission layer.

In the light emitting element ED according to an embodiment shown in FIGS. 3 to 6, an electron transport region ETR may be provided on the emission layer EML. The electron transport region ETR may include at least one among a hole blocking layer HBL, an electron transport layer ETL, and an electron injection layer EIL, but the embodiment of the present disclosure is not limited thereto.

The electron transport region ETR may have a single layer formed of a single material, a single layer formed of a plurality of different materials, or a multilayer structure having a plurality of layers formed of a plurality of different materials. For example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order from the emission layer EML, but is not limited thereto. The electron transport region ETR may have a thickness of, for example, about 1000 Å to about 1500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a third compound represented by Formula ET-1 described above. The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1, 10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

In some embodiments, the electron transport region ETR may include halogenated metals such as LiF, NaCl, CsF, RbCl, Rbl, Cul, and KI, lanthanide metals such as Yb, or co-deposition materials of a halogenated metal and a lanthanide metal. For example, the electron transport region ETR may include KI:Yb, Rbl:Yb, LiF:Yb, and/or the like as a co-deposition material. In some embodiments, for the electron transport region ETR, a metal oxide such as Li₂O and BaO, or 8-hydroxyl-lithium quinolate (Liq), and/or the like may be utilized, but the embodiment of the present disclosure is limited thereto. The electron transport region ETR may also be formed of a mixture material of an electron transport material and an insulating organo-metal salt. The organo metal salt may be a material having an energy band gap of about 4 eV or greater. For example, the organo-metal salt may include, for example, metal acetates, metal benzoates, metal acetoacetates, metal acetylacetonates, or metal stearates.

The electron transport region ETR may further include, for example, at least one of 2,9-dimethyl-4,7-diphenyl-1, 10-phenanthroline (BCP), diphenyl(4-(triphenylsilyl)phenyl)phosphine oxide (TSPO1), and 4,7-diphenyl-1, 10-phenanthroline (Bphen) in addition to the materials described above, but the embodiment of the present disclosure is not limited thereto. The electron transport region ETR may include the compounds of the electron transport region described above in at least one among the electron injection layer EIL, the electron transport layer ETL, and/or the hole blocking layer HBL.

When the electron transport region ETR includes the electron transport layer ETL, the electron transport layer ETL may have a thickness of about 100 Å to about 1000 Å, for example, about 150 Å to about 500 Å. When the thickness of the electron transport layer ETL satisfies the above-described range, satisfactory electron transport properties may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the second electrode EL2 may include the above-described metal materials, a combination of two or more metal materials selected from the above-described metal materials, or oxides of the above-described metal materials.

the second electrode EL2 may be connected with an auxiliary electrode. When the second electrode EL2 is connected with the auxiliary electrode, the resistance of the second electrode EL2 may decrease.

In some embodiments, a capping layer CPL may be further disposed on the second electrode EL2 of the light emitting element ED according to an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, and/or the like.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), and/or the like or may include epoxy resins or acrylates such as methacrylates. However, the embodiment of the present disclosure is not limited thereto, and the capping layer CPL may include compounds P1 to P5.

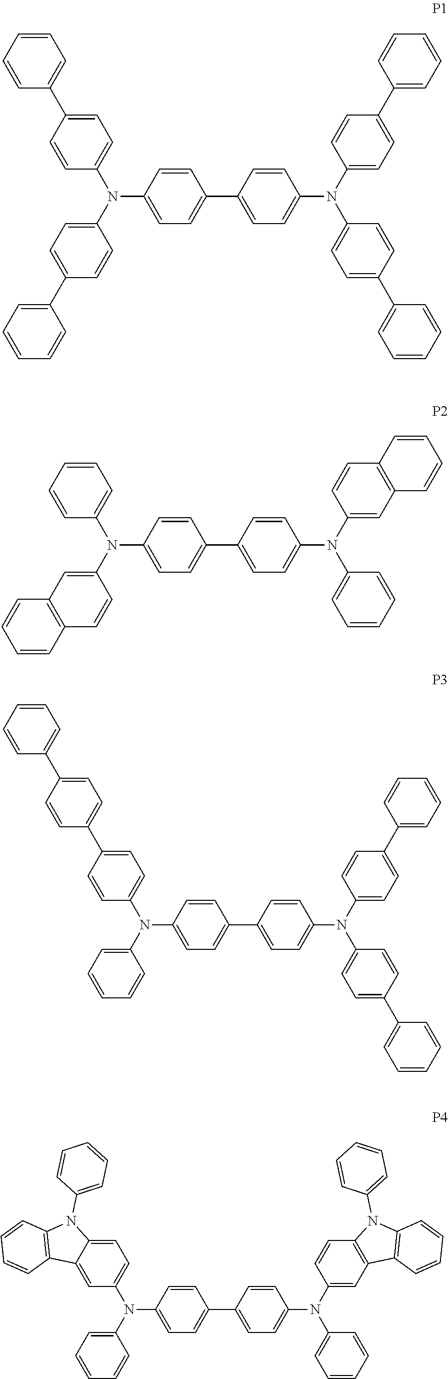 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

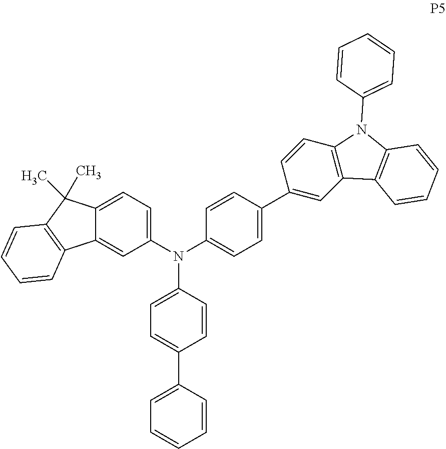 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or greater. To be specific, the capping layer CPL may have a refractive index of about 1.6 or greater in a wavelength range of about 550 nm to about 660 nm.

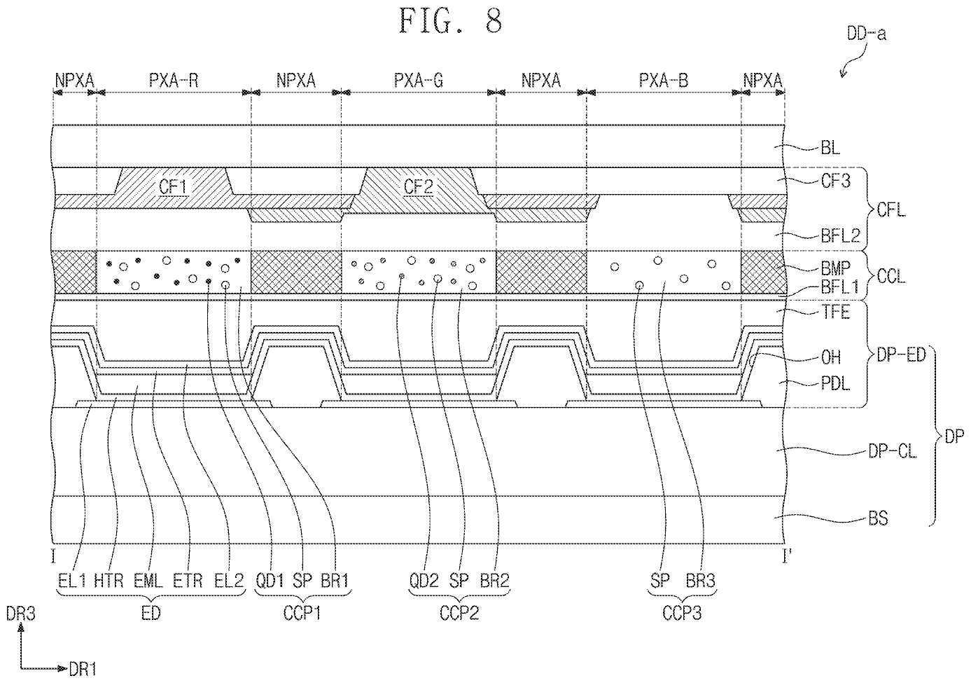

FIGS. 8 to 11 are each a cross-sectional view of a display device according to an embodiment. Hereinafter, in the description of the display device according to an embodiment with reference to FIGS. 8 to 11, content overlapping the one described above with reference to FIGS. 1 to 6 may not be described again, and the differences may be mainly described.

Referring to FIG. 8, a display device DD-a according to an embodiment may include a display panel DP having a display element layer DP-ED, a light control layer CCL disposed on the display panel DP, and a color filter layer CFL. In an embodiment shown in FIG. 8, the display panel DP may include a base layer BS, a circuit layer DP-CL provided on the base layer BS, and a display element layer DP-ED, and the element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The light emitting element ED may include a fused polycyclic compound according to an embodiment. A structure of the light emitting element ED shown in FIG. 8 may be substantially the same as the structure of the light emitting element ED of FIGS. 3 to 6 described previously.

Referring to FIG. 8, the emission layer EML may be disposed in the openings OH defined in the pixel defining films PDL. For example, the emission layer EML separated by the pixel defining films PDL and provided corresponding to each of light emitting regions PXA-R, PXA-G, and PXA-B may be configured to emit light in substantially the same wavelength ranges. In the display device DD-a of an embodiment, the emission layer EML may be configured to emit blue light. In some embodiments, unlike what is shown, in an embodiment, the emission layer EML may be provided as a common layer throughout the light emitting regions PXA-R, PXA-G, and PXA-B.

The light control layer CCL may be disposed on the display panel DP. The light control layer CCL may include a light converter. The light converter may be quantum dots or phosphors. The light converter may convert the wavelength of the provided light (e.g., wavelength-convert) and may emit the wavelength-converted light. For example, the light control layer CCL may be a layer containing quantum dots or phosphors.

The light control layer CCL may include a plurality of light control units CCP1, CCP2, and CCP3. The light control units CCP1, CCP2, and CCP3 may be spaced apart from each other.

Referring to FIG. 8, a division pattern BMP may be disposed between the light control units CCP1, CCP2, and CCP3 spaced apart from each other, but the embodiment of the present disclosure is not limited thereto. In FIG. 8, the division pattern BMP is shown to non-overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting first color light provided from the light emitting element ED into second color light, a second light control unit CCP2 including a second quantum dot QD2 for converting the first color light into third color light, and a third light control unit CCP3 transmitting the first color light.

In an embodiment, the first light control unit CCP1 may provide red light, which is the second color light, and the second light control unit CCP2 may provide green light, which is the third color light. The third light control unit CCP3 may be configured to transmit and provide blue light, which is the first color light provided from the light emitting element ED. For example, the first quantum dot QD1 may be a red quantum dot and the second quantum dot QD2 may be a green quantum dot. The same descriptions previously described may be applied to the quantum dots QD1 and QD2.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) a quantum dot but may include the scatterers SP.

The scatterers SP may be inorganic particles. For example, the scatterers SP may include at least one among TiO₂, ZnO, Al₂O₃, SiO₂, or hollow silica. The scatterers SP may include any one among TiO₂, ZnO, Al₂O₃, SiO₂, and hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 are a medium in which at least one of the quantum dots QD1 and QD2 or the scatterers SP are dispersed, and may be formed of one or more suitable resin compositions, which may be generally referred to as a binder. For example, the first to third base resins BR1, BR2, and BR3 may be an acrylic resin, a urethane-based resin, a silicone-based resin, an epoxy-based resin, and/or the like. The first to third base resins BR1, BR2, and BR3 may be a transparent resin. The first base resin BR1, the second base resin BR2, and the third base resin BR3 may be substantially the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may prevent or reduce the light control units CCP1, CCP2, and CCP3 from being exposed to moisture/oxygen. In some embodiments, the barrier layer BFL1 may cover the light control units CCP1, CCP2, and CCP3. In some embodiments, a barrier layer BFL2 may be provided between the light control units CCP1, CCP2, and CCP3 and the color filter layer CFL.

The barrier layers BFL1 and BFL2 may include at least one inorganic layer. For example, the barrier layers BFL1 and BFL2 may be formed of an inorganic material. For example, the barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, and/or the like. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include filters CF1, CF2, and CF3. For example, the color filter layer CFL may include a first filter CF1 transmitting second color light, a second filter CF2 transmitting third color light, and a third filter CF3 transmitting first color light. The first to third filters CF1, CF2, and CF3 may be disposed corresponding to the red light emitting region PXA-R, the green light emitting region PXA-G, and the blue light emitting region PXA-B, respectively.

For example, the first filter CF1 may be a red filter, the second filter CF2 may be a green filter, and the third filter CF3 may be a blue filter. The filters CF1, CF2, and CF3 may each include a polymer photosensitive resin, a pigment or a dye. The first filter CF1 may include a red pigment or a red dye, the second filter CF2 may include a green pigment or a green dye, and the third filter CF3 may include a blue pigment or a blue dye. In some embodiments, the embodiment of the present disclosure is not limited thereto, and the third filter CF3 may not include (e.g., may exclude) a pigment or a dye. The third filter CF3 may include a polymer photosensitive resin, but not include a pigment or a dye. The third filter CF3 may be transparent. The third filter CF3 may be formed of a transparent photosensitive resin.

In some embodiments, in an embodiment, the first filter CF1 and the second filter CF2 may be yellow filters. The first filter CF1 and the second filter CF2 may not be separated and may be provided as a single body.

the color filter layer CFL may further include a light blocking unit. The light blocking unit may be a black matrix. The light blocking unit may be formed including an organic light blocking material or an inorganic light blocking material, both (e.g., simultaneously) including a black pigment or a black dye. The light blocking unit may prevent or reduce light leakage, and separate boundaries between the adjacent filters CF1, CF2, and CF3.

The base substrate BL may be disposed on the color filter layer CFL. The base substrate BL may be a member providing a base surface on which the color filter layer CFL and the light control layer CCL are disposed. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike what is shown, the base substrate BL may not be provided in an embodiment.

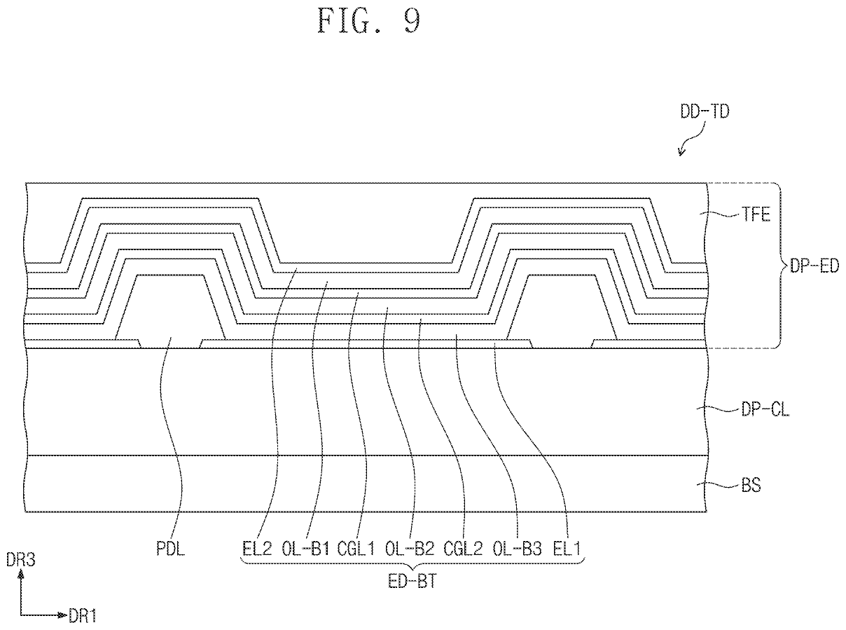

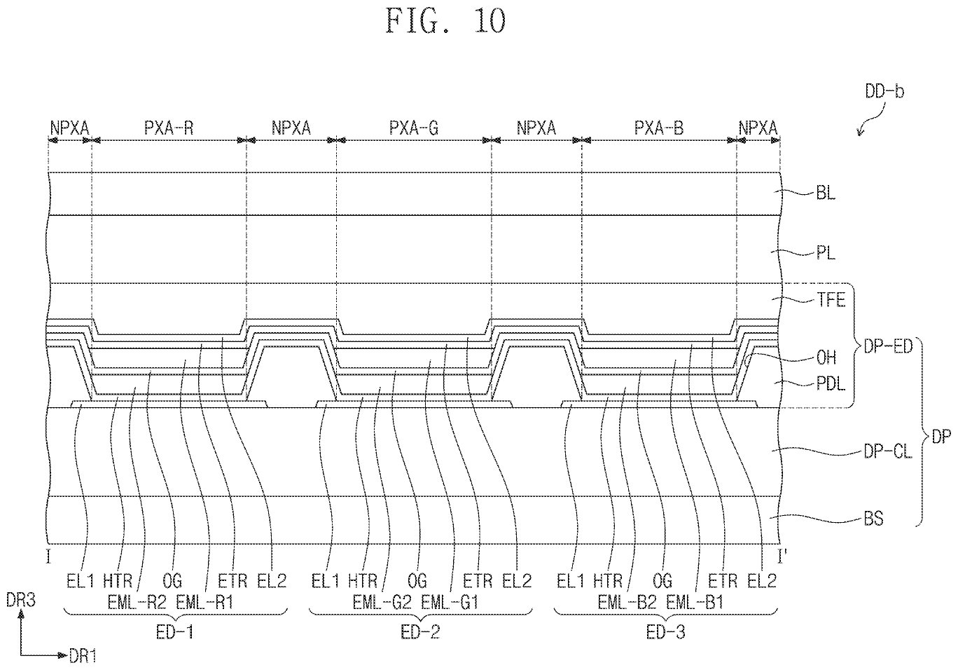

FIG. 9 is a cross-sectional view showing a portion of a display device according to an embodiment. FIG. 9 shows a cross-sectional view of a portion corresponding to the display panel DP of FIG. 8. In a display device DD-TD of an embodiment, a light emitting element ED-BT may include a plurality of light emitting structures OL-B1, OL-B2, and OL-B3. The light emitting element ED-BT may include the first electrode EL1 and the second electrode EL2 facing each other, and the plurality of light emitting structures OL-B1, OL-B2, and OL-B3 provided by being sequentially stacked in a thickness direction between the first electrode EL1 and the second electrode EL2. The light emitting structures OL-B1, OL-B2, and OL-B3 each may include the emission layer EML (FIG. 8), a hole transport region HTR and an electron transport region ETR disposed with the emission layer EML (FIG. 8) therebetween. For example, the light emitting element ED-BT included in the display device DD-TD of an embodiment may be a light emitting element having a tandem structure including a plurality of emission layers. At least one of the plurality of light emitting structures OL-B1, OL-B2, and OL-B3 may include the fused polycyclic compound of an embodiment.

In an embodiment shown in FIG. 9, light emitted from each of the light emitting structures OL-B1, OL-B2, and OL-B3 may all be blue light. However, the embodiment of the present disclosure is not limited thereto, and wavelength ranges of light emitted from each of the light emitting structures OL-B1, OL-B2, and OL-B3 may be different from each other. For example, the light emitting element ED-BT including the plurality of light emitting structures OL-B1, OL-B2, and OL-B3 emitting light in different wavelength ranges may be configured to emit white light.

Charge generation layers CGL1 and CGL2 may be disposed between neighboring light emitting structures OL-B1, OL-B2, and OL-B3. The charge generation layers CGL1 and CGL2 may include a p-type charge generation layer and/or an n-type charge generation layer.

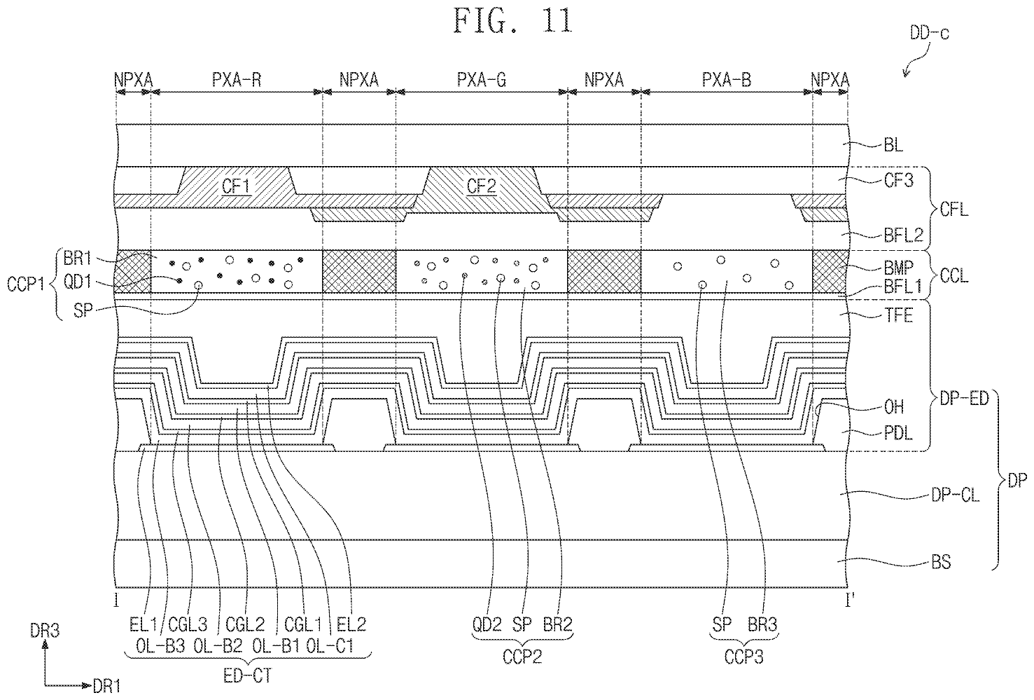

Referring to FIG. 10, a display device DD-b according to an embodiment may include light emitting elements ED-1, ED-2, and ED-3 in which two emission layers are stacked. Compared to the display device DD according to an embodiment shown in FIG. 2, the difference is that in an embodiment shown in FIG. 10, the first to third light emitting elements ED-1, ED-2, and ED-3 each include two emission layers stacked in a thickness direction. In each of the first to third light emitting elements ED-1, ED-2, and ED-3, the two emission layers may be configured to emit light in substantially the same wavelength range. At least one of the first to third light emitting elements ED-1, ED-2, and ED-3 may include the fused polycyclic compound of an embodiment.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. A light emitting auxiliary portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. More specifically, the light emitting auxiliary portion OG may include an electron transport region, a charge generation layer, and a hole transport region, which are sequentially stacked between the hole transport region HTR and the electron transport region ETR of the first to third light emitting elements ED-1, ED-2, and ED-3. The light emitting auxiliary portion OG may be provided as a common layer throughout the first to third light emitting elements ED-1, ED-2, and ED-3. However, the embodiment of the present disclosure is not limited thereto, and the light emitting auxiliary portion OG may be provided to be patterned inside the openings OH defined in the pixel defining films PDL.

The first red emission layer EML-R1, the first green emission layer EML-G1, and the first blue emission layer EML-B1 may be disposed between the light emitting auxiliary portion OG and the electron transport region ETR. The second red emission layer EML-R2, the second green emission layer EML-G2, and the second blue emission layer EML-B2 may be disposed between the hole transport region HTR and the light emitting auxiliary portion OG.

For example, the light emitting element ED-1 may include the first electrode EL1, the hole transport region HTR, the second red emission layer EML-R2, the light emitting auxiliary portion OG, the first red emission layer EML-R1, the electron transport region ETR, and the second electrode EL2, which are sequentially stacked. The second light emitting element ED-2 may include the first electrode EL1, the hole transport region HTR, the second green emission layer EML-G2, the light emitting auxiliary portion OG, the first green emission layer EML-G1, the electron transport region ETR, and the second electrode EL2, which are sequentially stacked. The third light emitting element ED-3 may include the first electrode EL1, the hole transport region HTR, the second blue emission layer EML-B2, the light emitting auxiliary portion OG, the first blue emission layer EML-B1, the electron transport region ETR, and the second electrode EL2, which are sequentially stacked.

In some embodiments, an optical auxiliary layer PL may be disposed on the display element layer DP-ED. The optical auxiliary layer PL may include a polarizing layer. The optical auxiliary layer PL may be disposed on the display panel DP to control reflected light in the display panel DP due to external light. Unlike what is shown, the optical auxiliary layer PL may not be provided in the display device according to an embodiment.

Unlike FIGS. 9 and 10, the display device DD-c of FIG. 11 is illustrated to include four light emitting structures OL-B1, OL-B2, OL-B3, and OL-C1. The light emitting element ED-CT may include the first electrode EL1 and the second electrode EL2 facing each other, and a third light emitting structure OL-B3, a second light emitting structure OL-B2, a first light emitting structure OL-B1, and a fourth light emitting structure OL-C1, which are sequentially stacked in a thickness direction between the first electrode EL1 and the second electrode EL2. At least one of the first to fourth light emitting structures OL-B1, OL-B2, OL-B3, and OL-C1 may include a fused polycyclic compound of an embodiment.

Among the four light emitting structures, the first to third light emitting structures OL-B1, OL-B2, and OL-B3 may be configured to emit blue light, and the fourth light emitting structure OL-C1 may be configured to emit green light. However, the embodiment of the present disclosure is not limited thereto, and the first to fourth light emitting structures OL-B1, OL-B2, OL-B3, and OL-C1 may be configured to emit light having different wavelength ranges.

Between the third light emitting structure OL-B3, the second light emitting structure OL-B2, the first light emitting structure OL-B1, and the fourth light emitting structure OL-C1, charge generation layers CGL3, CGL2, and CGL1 may be disposed. The charge generation layers CGL3, CGL2 and CGL1 disposed between the neighboring light emitting structures OL-B3, OL-B2, OL-B1, and OL-C1 may include a p-type charge generation layer and/or an n-type charge generation layer.

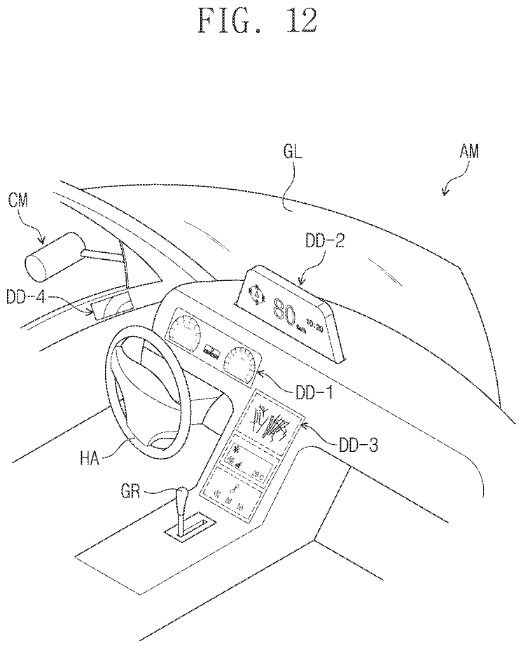

FIG. 12 is a view showing a vehicle AM in which first to fourth display devices DD-1, DD-2, DD-3, and DD-4 are disposed. At least one of the first to fourth display devices DD-1, DD-2, DD-3, and DD-4 may have the same configuration as the display devices DD, DD-TD, DD-a, DD-b, and DD-c of an embodiment described with reference to FIGS. 1, 2, and 8 to 10.

FIG. 12 shows a car as the vehicle AM, but this is presented as an example, and the first to fourth display devices DD-1, DD-2, DD-3, and DD-4 may be disposed on other means of transportation, such as bicycles, motorcycles, trains, ships, airplanes, and/or the like. In some embodiments, at least one of the first to fourth display devices DD-1, DD-2, DD-3, and DD-4 having the same configuration as the display devices DD, DD-TD, DD-a, DD-b, and DD-c of an embodiment may also be adopted for personal computers, laptop computers, personal digital terminals, game consoles, portable electronic devices, televisions, monitors, outdoor billboards, and/or the like. In some embodiments, these are merely presented as an embodiment, and thus the display device may be adopted for other electronic devices without departing from the present disclosure.

At least one of the first to fourth display devices DD-1, DD-2, DD-3, and DD-4 may include the light emitting element ED of an embodiment described with reference to FIGS. 3 to 6. In the light emitting element ED of an embodiment, the emission layer EML may include the fused polycyclic compound of an embodiment. In some embodiments, the emission layer EML may include at least one of a second compound or a third compound. At least one of the first to fourth display devices DD-1, DD-2, DD-3, and DD-4 includes a light emitting element ED containing the fused polycyclic compound of an embodiment, thereby increasing display efficiency and display lifespan.

Referring to FIG. 12, the vehicle AM may include a wheel HA and a gear GR for operating the vehicle AM. In some embodiments, the vehicle AM may include a front window GL disposed to face a driver.

The first display device DD-1 may be disposed in a first region overlapping the wheel HA. For example, the first display device DD-1 may be a digital cluster displaying first information of the vehicle AM. The first information may include a first scale indicating driving speed of the vehicle AM, a second scale indicating engine revolutions (i.e., revolutions per minute (RPM)), and an image indicating fuel gauge, and/or the like. The first scale and the second scale may be displayed as digital images.

The second display device DD-2 may be disposed in a second region facing a driver seat and overlapping the front window GL. The driver seat may be a seat in which the wheel HA is disposed. For example, the second display device DD-2 may be a head up display HUD displaying second information of the vehicle AM. The second display device DD-2 may be optically transparent. The second information includes digital numbers indicating driving speed of the vehicle AM and may further include information such as current time. Unlike what is shown, the second information of the second display device DD-2 may be projected on the front window GL and displayed.

The third display device DD-3 may be disposed in a third region adjacent to the gear GR. For example, the third display device DD-3 may be a center information display CID for a vehicle, which is disposed between a driver seat and a front passenger seat and displays third information. The passenger seat may be a seat spaced apart from the driver seat with the gear GR therebetween. The third information may include information about road conditions (e.g., navigation information), music or radio play, dynamic video (or image) play, temperature inside the vehicle AM, and/or the like.

The fourth display device DD-4 may be disposed in a fourth region spaced apart from the wheel HA and the gear GR and adjacent to a side of the vehicle AM. For example, the fourth display device DD-4 may be a digital side mirror displaying fourth information. The fourth display device DD-4 may display images of conditions outside the vehicle AM, which are taken by a camera module CM disposed outside the vehicle AM. The fourth information may include images of conditions outside the vehicle AM.

The first to fourth information described above are presented as an example, and the first to fourth display devices DD-1, DD-2, DD-3, and DD-4 may further display information about inside or outside the vehicle AM. The first to fourth information may include different information. However, the embodiment of the present disclosure is not limited thereto, and some of the first to fourth information may include the same information.

Hereinafter, with reference to Examples and Comparative Examples, a fused polycyclic compound and a light emitting element of an embodiment of the present disclosure will be specifically described. In some embodiments, Examples shown are shown only for the understanding of the present disclosure, and the scope of the present disclosure is not limited thereto.

### Examples

### 1. Synthesis of Fused Polycyclic Compounds of an Embodiment

A process of synthesizing fused polycyclic compounds according to an embodiment of the present disclosure will be described in more detail by presenting a process of synthesizing Compounds 13, 19, 28, 83, 87, and 115 as an example. In some embodiments, a process of synthesizing fused polycyclic compounds, which will be described hereinafter, is provided as an example, and thus a process of synthesizing compounds according to an embodiment of the present disclosure is not limited to Examples.

### (1) Synthesis of Fused Polycyclic Compound 13

Fused polycyclic Compound 13 according to an embodiment may be synthesized by, for example, a process of Reaction Formula 1.

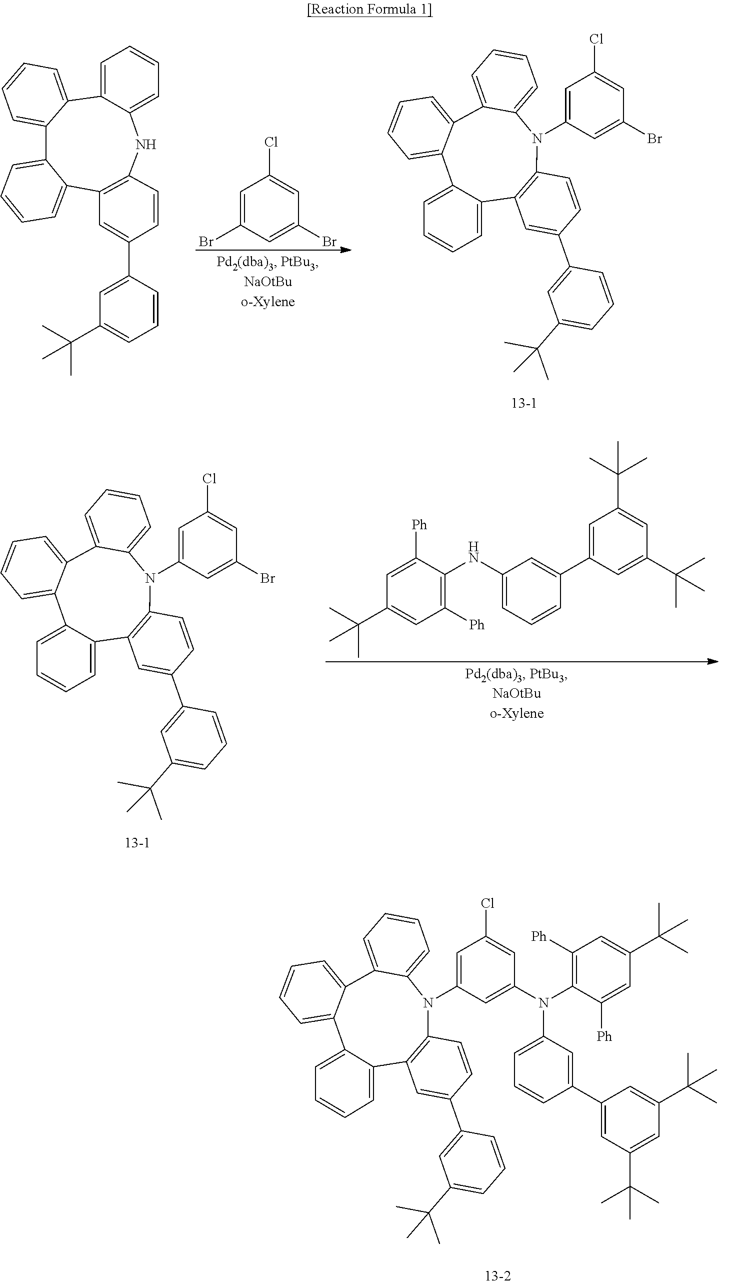 [SMILES: CC(C)(C)c1cccc(-c2ccc3[nH]c4ccccc4c4ccccc4c4ccccc4c3c2)c1 ; Clc1cc(Br)cc(Br)c1 ; CC(C)(C)c1cccc(-c2ccc3c(c2)c2ccccc2c2ccccc2c2ccccc2n3-c2cc(Cl)cc(Br)c2)c1 ; CC(C)(C)c1cccc(-c2ccc3c(c2)c2ccccc2c2ccccc2c2ccccc2n3-c2cc(Cl)cc(Br)c2)c1 ; CC(C)(C)c1cc(-c2cccc(Nc3c(-c4ccccc4)cc(C(C)(C)C)cc3-c3ccccc3)c2)cc(C(C)(C)C)c1 ; CC(C)(C)c1cccc(-c2ccc3c(c2)c2ccccc2c2ccccc2c2ccccc2n3-c2cc(Cl)cc(N(c3cccc(-c4cc(C(C)(C)C)cc(C(C)(C)C)c4)c3)c3c(-c4ccccc4)cc(C(C)(C)C)cc3-c3ccccc3)c2)c1]

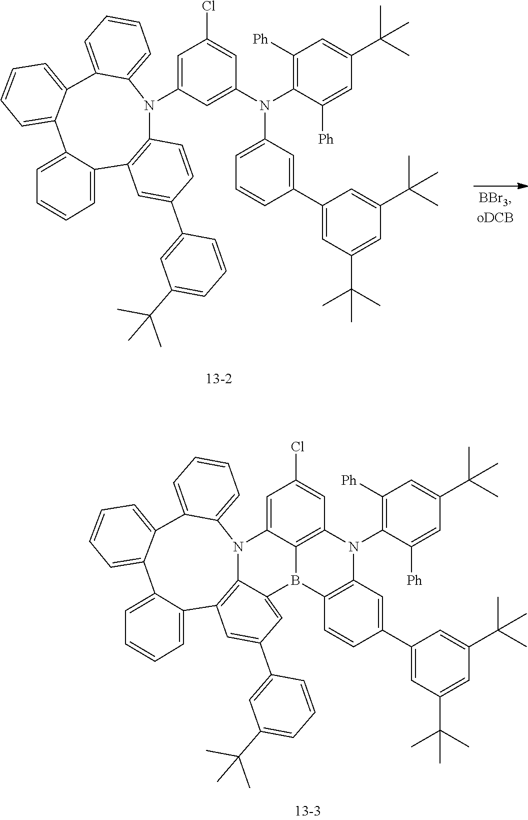 [SMILES: CC(C)(C)c1cccc(-c2ccc3c(c2)c2ccccc2c2ccccc2c2ccccc2n3-c2cc(Cl)cc(N(c3cccc(-c4cc(C(C)(C)C)cc(C(C)(C)C)c4)c3)c3c(-c4ccccc4)cc(C(C)(C)C)cc3-c3ccccc3)c2)c1 ; CC(C)(C)c1cccc(-c2cc3c4c(c2)c2ccccc2c2ccccc2c2ccccc2n4-c2cc(Cl)cc4c2B3c2ccc(-c3cc(C(C)(C)C)cc(C(C)(C)C)c3)cc2N4c2c(-c3ccccc3)cc(C(C)(C)C)cc2-c2ccccc2)c1]

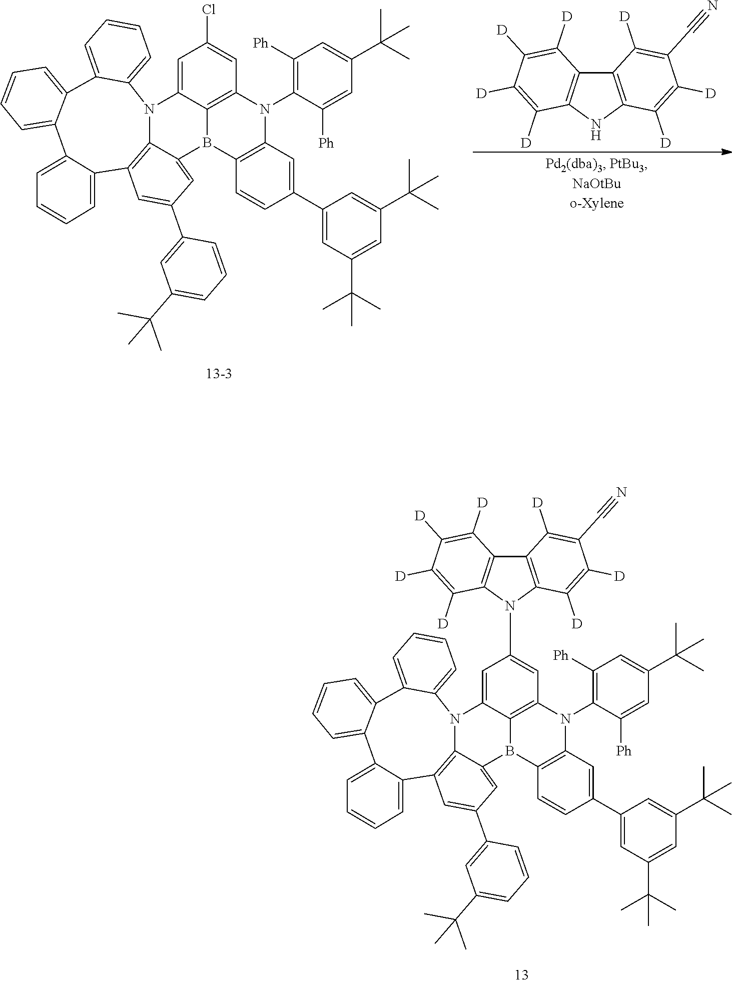 [SMILES: CC(C)(C)c1cccc(-c2cc3c4c(c2)c2ccccc2c2ccccc2c2ccccc2n4-c2cc(Cl)cc4c2B3c2ccc(-c3cc(C(C)(C)C)cc(C(C)(C)C)c3)cc2N4c2c(-c3ccccc3)cc(C(C)(C)C)cc2-c2ccccc2)c1 ; [2H]c1c([2H])c([2H])c2c([nH]c3c([2H])c([2H])c(C#N)c([2H])c32)c1[2H] ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cc(C(C)(C)C)cc(C(C)(C)C)c3)cc1N2c1c(-c2ccccc2)cc(C(C)(C)C)cc1-c1ccccc1]

### Synthesis of Intermediate 13-1

2-(3-(tert-butyl)phenyl)-5H-tetrabenzo[b,d,f,h]azonine (1 eq), 1,3-dibromo-5-chlorobenzene (2 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 100° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 13-1. (Yield: 59%)

### Synthesis of Intermediate 13-2

Intermediate 13-1 (1 eq), 5′-(tert-butyl)-N-(3′,5′-di-tert-butyl-[1,1′-biphenyl]-3-yl)-[1,1′:3′,1″-terphenyl]-2′-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 130° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 13-2. (Yield: 63%)

### Synthesis of Intermediate 13-3

Intermediate 13-3 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified through MC/Hex (methylenechloride/hexane) recrystallization, thereby obtaining Intermediate 13-3. Then, Intermediate 13-3 was subjected to final purification through a column (dichloromethane: n-hexane). (Yield: 13%)

### Synthesis of Compound 13

Intermediate 13-3 (1 eq), 9H-carbazole-3-carbonitrile-1,2,4,5,6,7,8-d₇ (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Compound 13. (Yield: 66%) The resulting product was further purified through sublimation purification, and the obtained compound was confirmed to be Compound 13 through ESI-LCMS. ESI-LCMS: [M]+: C₉₅H₇₄D₇BN₄, 1297.0

### (2) Synthesis of Fused Polycyclic Compound 19

Fused polycyclic Compound 19 according to an embodiment may be synthesized by, for example, a process of Reaction Formula 2.

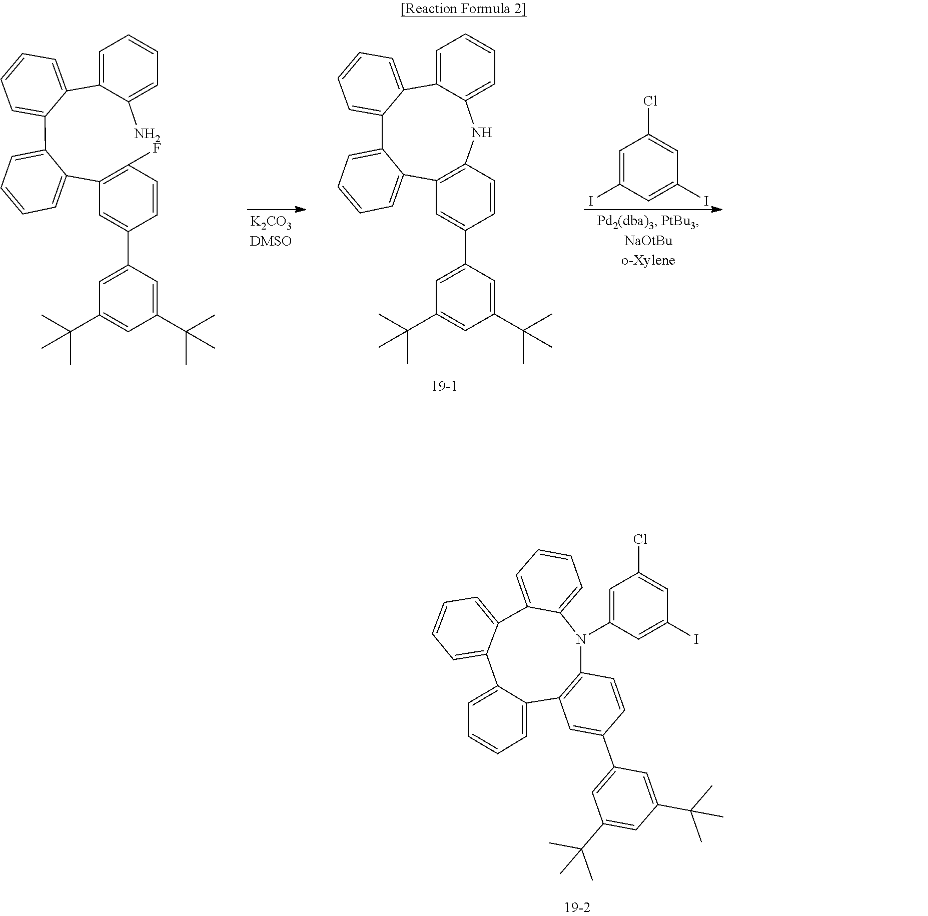 [SMILES: CC(C)(C)c1cc(-c2ccc(F)c(-c3ccccc3-c3ccccc3-c3ccccc3N)c2)cc(C(C)(C)C)c1 ; CC(C)(C)c1cc(-c2ccc3[nH]c4ccccc4c4ccccc4c4ccccc4c3c2)cc(C(C)(C)C)c1 ; Clc1cc(I)cc(I)c1 ; CC(C)(C)c1cc(-c2ccc3c(c2)c2ccccc2c2ccccc2c2ccccc2n3-c2cc(Cl)cc(I)c2)cc(C(C)(C)C)c1]

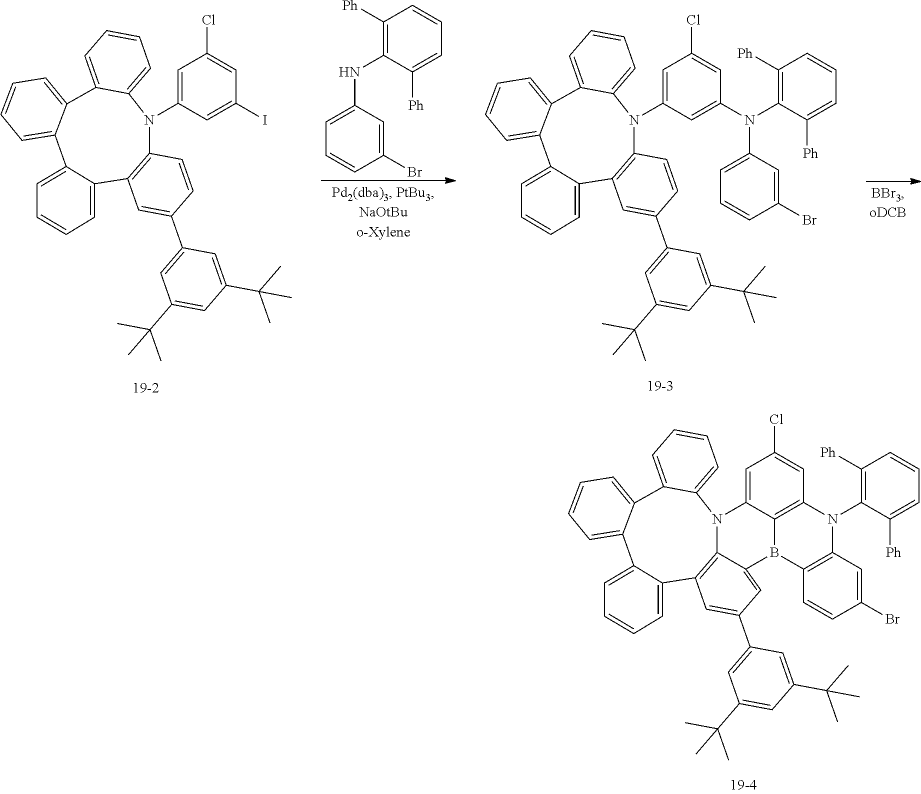 [SMILES: CC(C)(C)c1cc(-c2ccc3c(c2)c2ccccc2c2ccccc2c2ccccc2n3-c2cc(Cl)cc(I)c2)cc(C(C)(C)C)c1 ; Brc1cccc(Nc2c(-c3ccccc3)cccc2-c2ccccc2)c1 ; CC(C)(C)c1cc(-c2ccc3c(c2)c2ccccc2c2ccccc2c2ccccc2n3-c2cc(Cl)cc(N(c3cccc(Br)c3)c3c(-c4ccccc4)cccc3-c3ccccc3)c2)cc(C(C)(C)C)c1 ; CC(C)(C)c1cc(-c2cc3c4c(c2)c2ccccc2c2ccccc2c2ccccc2n4-c2cc(Cl)cc4c2B3c2ccc(Br)cc2N4c2c(-c3ccccc3)cccc2-c2ccccc2)cc(C(C)(C)C)c1]

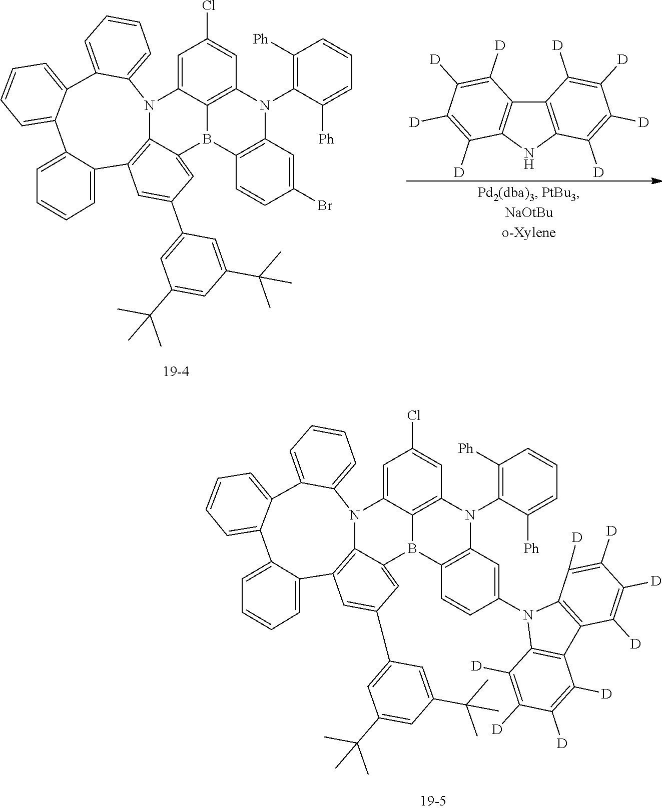 [SMILES: CC(C)(C)c1cc(-c2cc3c4c(c2)c2ccccc2c2ccccc2c2ccccc2n4-c2cc(Cl)cc4c2B3c2ccc(Br)cc2N4c2c(-c3ccccc3)cccc2-c2ccccc2)cc(C(C)(C)C)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(Cl)cc3c1B2c1cc(-c2cc(C(C)(C)C)cc(C(C)(C)C)c2)cc2c4ccccc4c4ccccc4c4ccccc4n-3c12]

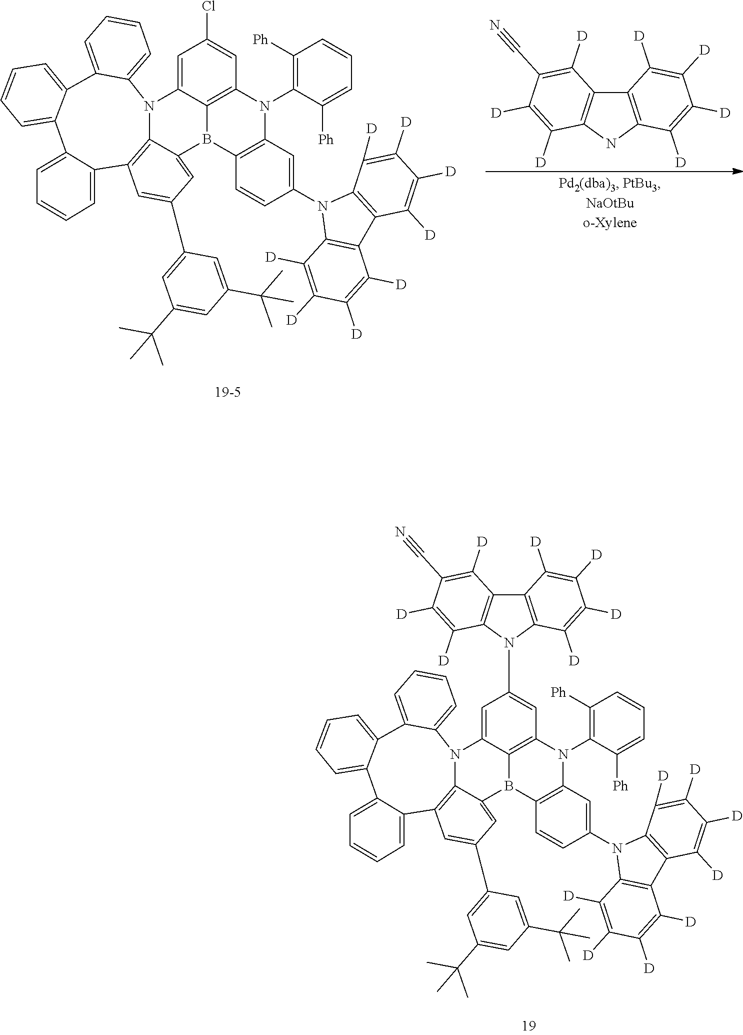

### Synthesis of Intermediate 19-1

3″″,5″″-di-tert-butyl-6″′-fluoro-[1, 1′:2′,1″:2″,1″′:3″′,1″″-quinquephenyl]-2-amine (1 eq) and potassium carbonate (K₂CO₃, 3 eq) were dissolved in dimethyl sulfoxide (DMSO) and stirred at 160° C. for 24 hours in a nitrogen atmosphere. After cooling, the resulting product was dried under reduced pressure to remove dimethyl sulfoxide. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 19-1. (Yield: 61%)

### Synthesis of Intermediate 19-2

Intermediate 19-1 (1 eq), 1-chloro-3,5-diiodobenzene (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 80° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 19-2. (Yield: 59%)

### Synthesis of Intermediate 19-3

Intermediate 19-2 (1 eq), N-(3-bromophenyl)-[1,1′:3′,1″-terphenyl]-2′-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over MgSO₄ and dried under reduced pressure. The resulting product was purified through column chromatography and recrystallized (dichloromethane: n-Hexane), thereby obtaining Intermediate 19-3. (Yield: 55%)

### Synthesis of Intermediate 19-4

Intermediate 19-3 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified through MC/Hex (methylenechloride/hexane) recrystallization, thereby obtaining Intermediate 19-4. Then, Intermediate 19-4 was subjected to final purification through a column (dichloromethane: n-hexane). (Yield: 10%)

### Synthesis of Intermediate 19-5

Intermediate 19-4 (1 eq), 9H-carbazole-1,2,3,4,5,6,7,8-d₈ (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 110° C. for 14 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 19-5. (Yield: 67%)

### Synthesis of Compound 19

Intermediate 19-5 (1 eq), 9H-carbazole-3-carbonitrile-1,2,4,5,6,7,8-d₇ (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Compound 19. (Yield: 45%) The resulting product was further purified through sublimation purification, and the obtained compound was confirmed to be Compound 19 through ESI-LCMS. ESI-LCMS: [M]+: C₉₃H₅₃D₁₅BN₅, 1281.9

### (3) Synthesis of Fused Polycyclic Compound 28

Fused polycyclic Compound 28 according to an embodiment may be synthesized by, for example, a process of Reaction Formula 3.

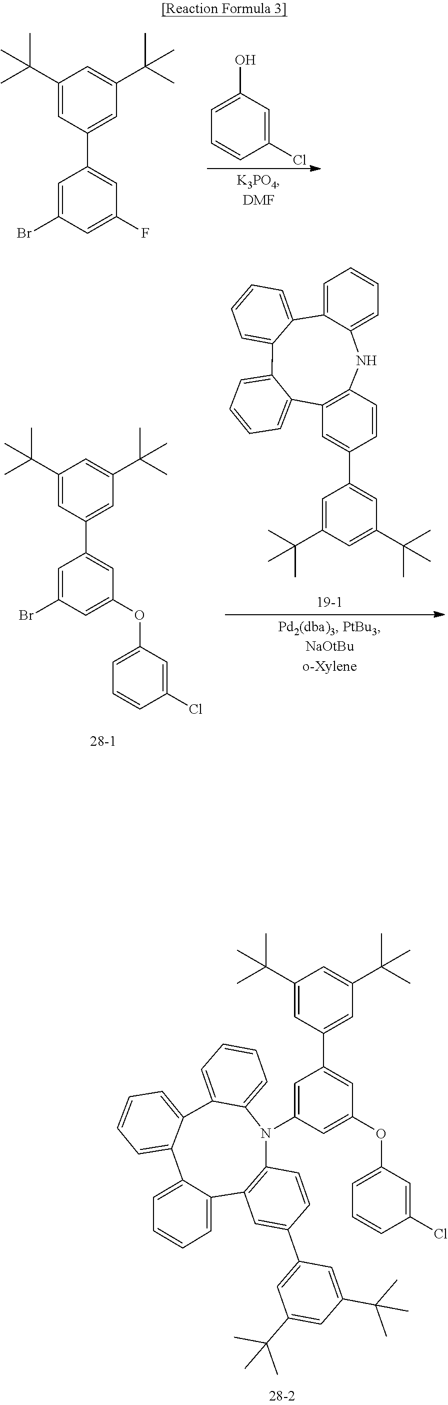

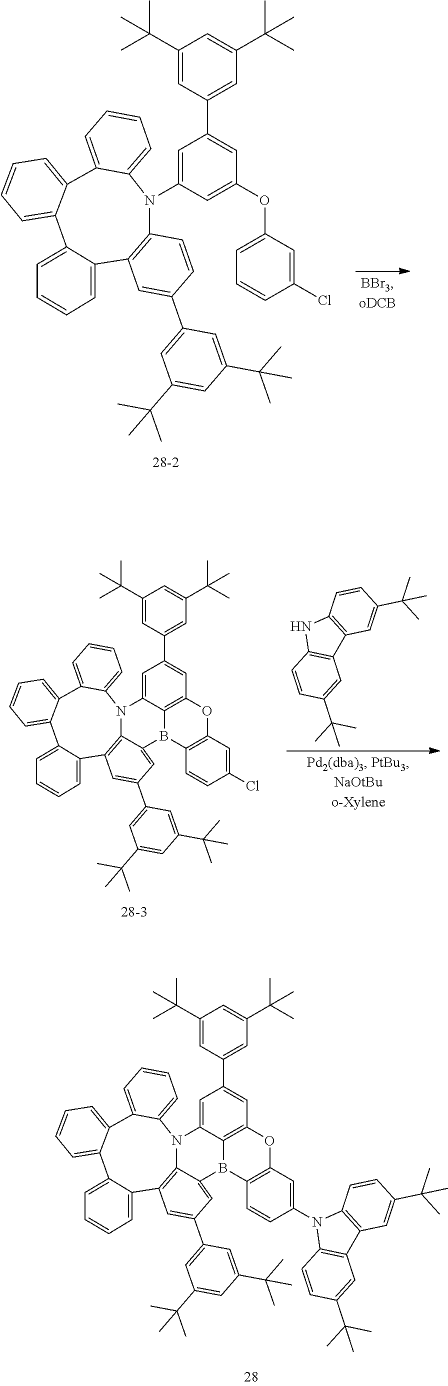 [SMILES: CC(C)(C)c1cc(-c2cc(Oc3cccc(Cl)c3)cc(-n3c4ccccc4c4ccccc4c4ccccc4c4cc(-c5cc(C(C)(C)C)cc(C(C)(C)C)c5)ccc43)c2)cc(C(C)(C)C)c1 ; CC(C)(C)c1cc(-c2cc3c4c(c2)-n2c5ccccc5c5ccccc5c5ccccc5c5cc(-c6cc(C(C)(C)C)cc(C(C)(C)C)c6)cc(c52)B4c2ccc(Cl)cc2O3)cc(C(C)(C)C)c1 ; CC(C)(C)c1ccc2[nH]c3ccc(C(C)(C)C)cc3c2c1 ; CC(C)(C)c1cc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc(C(C)(C)C)c1]

### Synthesis of Intermediate 28-1

3-bromo-3′,5′-di-tert-butyl-5-fluoro-1,1′-biphenyl (1 eq), 3-chlorophenol (1.5 eq), and potassium phosphate (K₃PO₄, 3 eq) were dissolved in dimethyl sulfoxide (DMSO) and stirred at 160° C. for 24 hours in a nitrogen atmosphere. After cooling, the resulting product was dried under reduced pressure to remove dimethylformamide. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 28-1. (Yield: 66%)

### Synthesis of Intermediate 28-2

Intermediate 28-1 (1 eq), Intermediate 19-1 (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 28-2. (Yield: 64%)

### Synthesis of Intermediate 28-3

Intermediate 28-2 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified through MC/Hex (methylenechloride/hexane) recrystallization, thereby obtaining Intermediate 28-3. Then, Intermediate 28-3 was subjected to final purification through a column (dichloromethane: n-hexane). (Yield: 9%)

### Synthesis of Compound 28

Intermediate 28-3 (1 eq), 3,6-di-tert-butyl-9H-carbazole (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 150° C. for 24 hours in a nitrogen atmosphere. After cooling, the resulting product was dried under reduced pressure to remove o-Xylene. Thereafter, the resulting product was washed with ethyl acetate and water each three times to obtain an organic layer, which was then dried over magnesium sulfate (MgSO₄) and dried under reduced pressure. The resulting product was purified through column chromatography and recrystallized (dichloromethane: n-Hexane), thereby obtaining Compound 28. (Yield: 53%) The resulting product was further purified through sublimation purification, and the obtained compound was confirmed to be Compound 28 through ESI-LCMS. ESI-LCMS: [M]+: C₈₄H₈₅BN₂O, 1149.8

### (4) Synthesis of Fused Polycyclic Compound 83

Fused polycyclic Compound 83 according to an embodiment may be synthesized by, for example, a process of Reaction Formula 4.

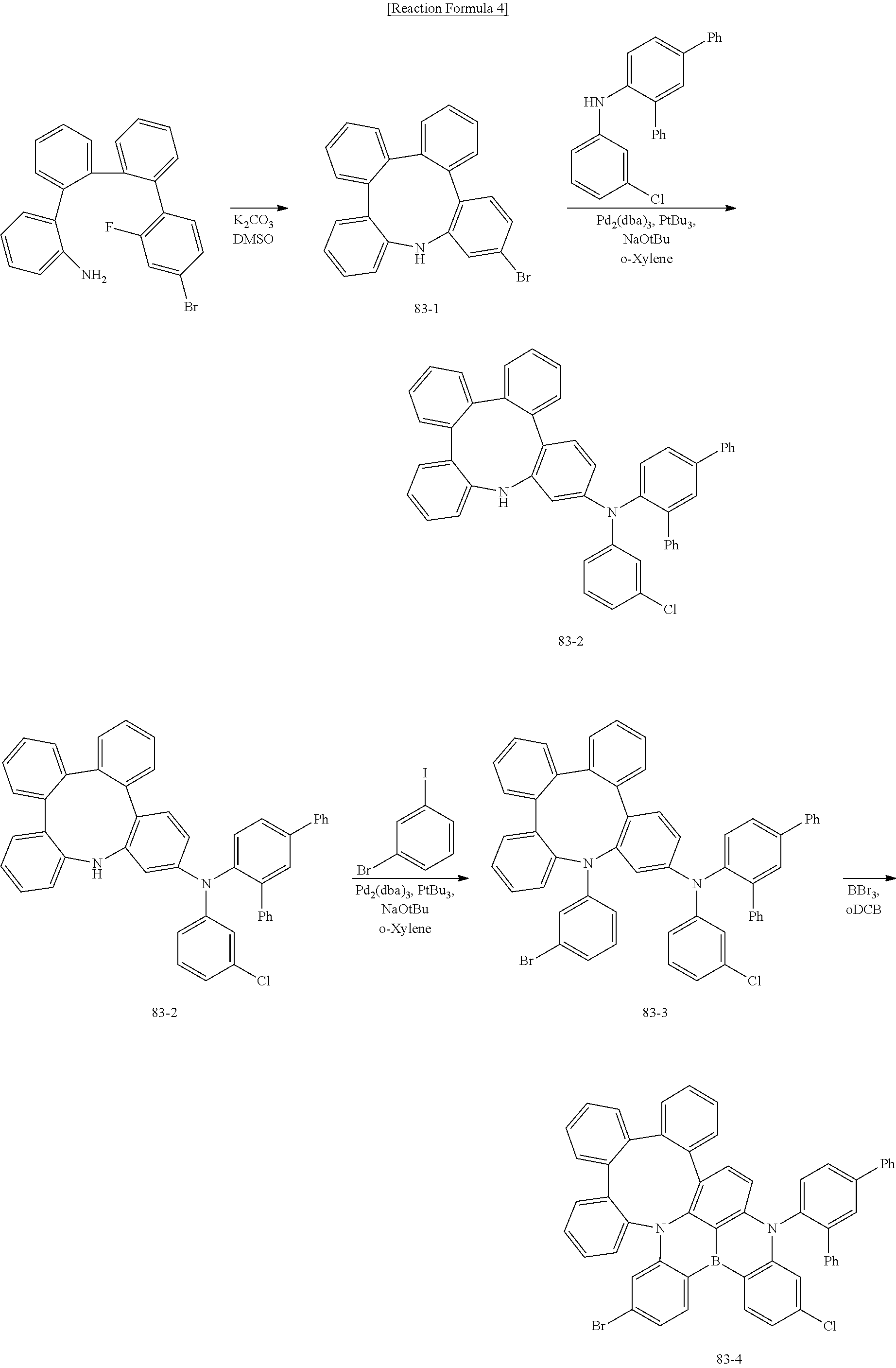

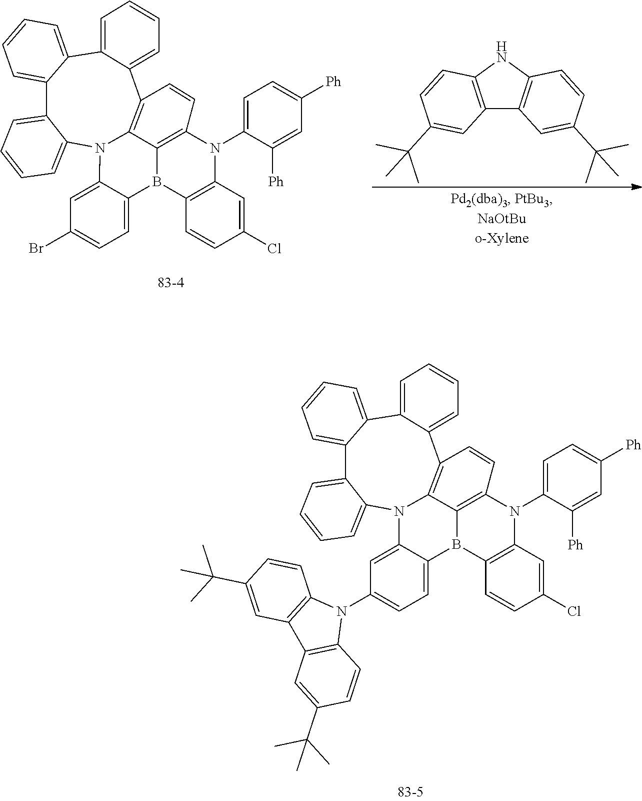 [SMILES: Clc1ccc2c(c1)N(c1ccc(-c3ccccc3)cc1-c1ccccc1)c1ccc3c4ccccc4c4ccccc4c4ccccc4n4c3c1B2c1ccc(Br)cc1-4 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccc2c(c1)-n1c3ccccc3c3ccccc3c3ccccc3c3ccc4c(c31)B2c1ccc(Cl)cc1N4c1ccc(-c2ccccc2)cc1-c1ccccc1]

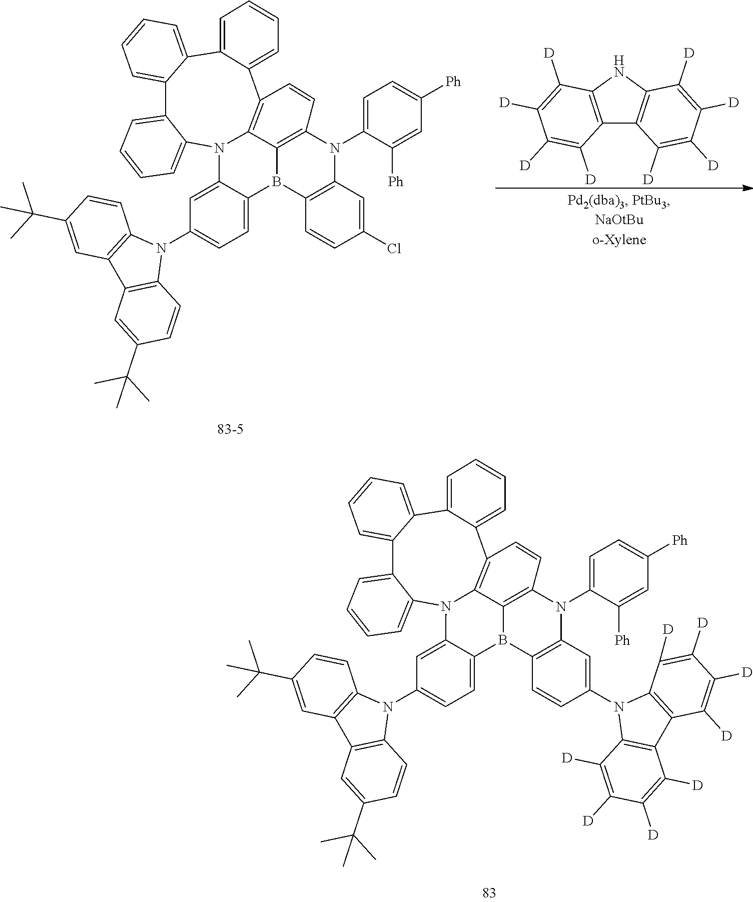 [SMILES: CC(C)(C)c1ccc2c(c1)c1cc(C(C)(C)C)ccc1n2-c1ccc2c(c1)-n1c3ccccc3c3ccccc3c3ccccc3c3ccc4c(c31)B2c1ccc(Cl)cc1N4c1ccc(-c2ccccc2)cc1-c1ccccc1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1ccc3c4ccccc4c4ccccc4c4ccccc4n4c3c1B2c1ccc(-n2c3ccc(C(C)(C)C)cc3c3cc(C(C)(C)C)ccc32)cc1-4]

### Synthesis of Intermediate 83-1

4″′-bromo-2″′-fluoro-[1,1′:2′,1″:2″,1″′-quaterphenyl]-2-amine (1 eq) and potassium carbonate (K₂CO₃, 3 eq) were dissolved in dimethyl sulfoxide (DMSO) and stirred at 160° C. for 24 hours in a nitrogen atmosphere. After cooling, the resulting product was dried under reduced pressure to remove dimethyl sulfoxide. Thereafter, the resulting product was washed with ethyl acetate and water three each for times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 83-1. (Yield: 59%)

### Synthesis of Intermediate 83-2

Intermediate 83-1 (1 eq), N-(3-chlorophenyl)-[1,1′:3′,1″-terphenyl]-4′-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 83-2. (Yield: 59%)

### Synthesis of Intermediate 83-3

Intermediate 83-2 (1 eq), 1-bromo-3-iodobenzene (1.2 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 140° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 83-3. (Yield: 67%)

### Synthesis of Intermediate 83-4

Intermediate 83-3 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified through MC/Hex (methylenechloride/hexane) recrystallization, thereby obtaining Intermediate 83-4. Then, Intermediate 83-4 was subjected to final purification through a column (dichloromethane: n-hexane). (Yield: 12%)

### Synthesis of Intermediate 83-5

Intermediate 83-4 (1 eq), 3,6-di-tert-butyl-9H-carbazole (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 110° C. for 24 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 83-5. (Yield: 64%)

### Synthesis of Compound 83

Intermediate 83-5 (1 eq), 9H-carbazole-1,2,3,4,5,6,7,8-d₈ (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 2.0 eq) were dissolved in o-Xylene and stirred at 140° C. for 24 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Compound 83. (Yield: 56%) The resulting product was further purified through sublimation purification, and the obtained compound was confirmed to be Compound 83 through ESI-LCMS. ESI-LCMS: [M]+: C₈₆H₅₇D₈BN₄, 1173.8

### (5) Synthesis of Fused Polycyclic Compound 87

Fused polycyclic Compound 87 according to an embodiment may be synthesized by, for example, a process of Reaction Formula 5.

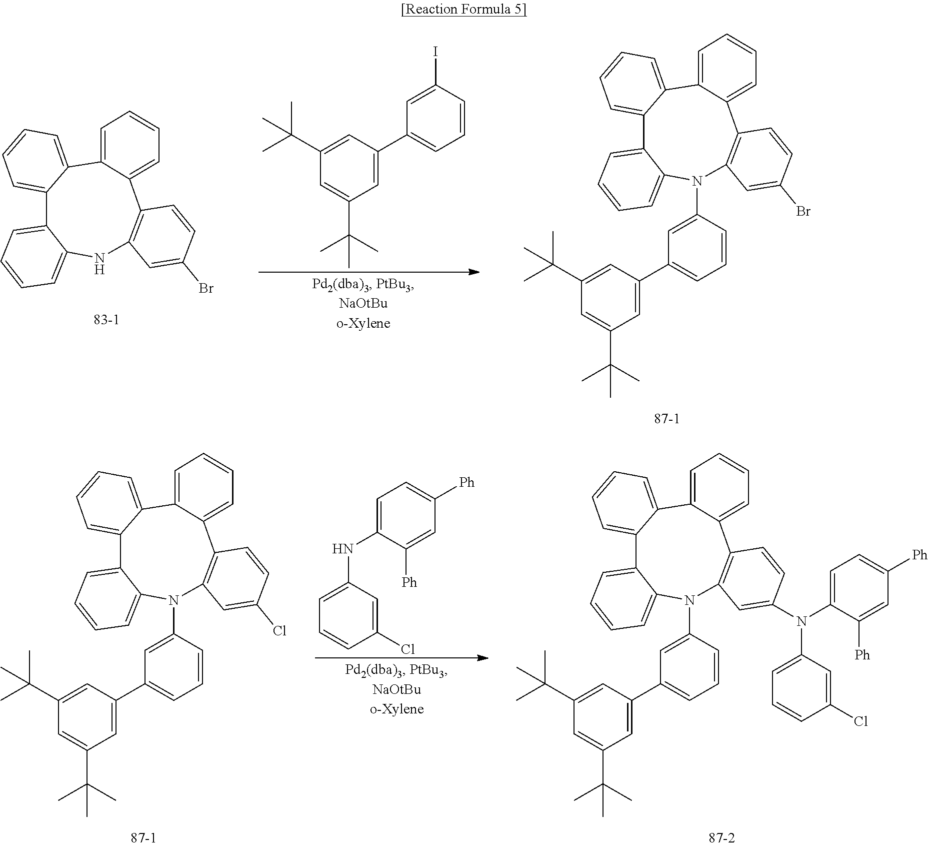

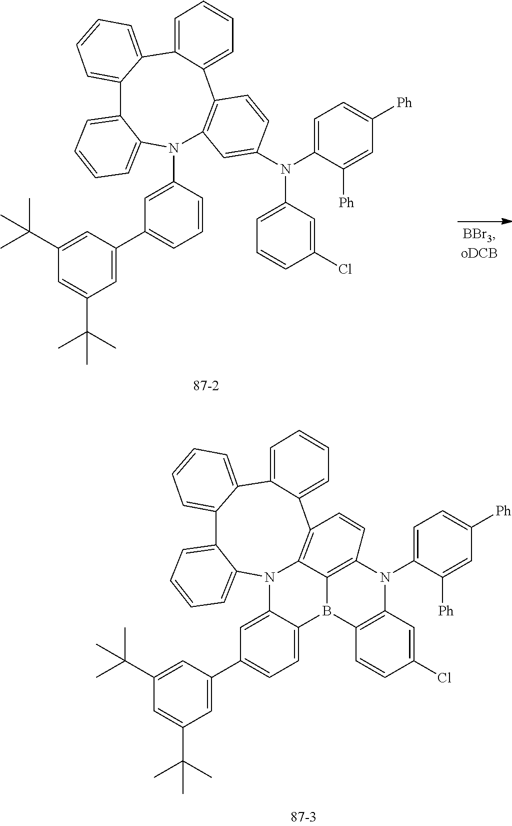 [SMILES: CC(C)(C)c1cc(-c2cccc(-n3c4ccccc4c4ccccc4c4ccccc4c4ccc(N(c5cccc(Cl)c5)c5ccc(-c6ccccc6)cc5-c5ccccc5)cc43)c2)cc(C(C)(C)C)c1 ; CC(C)(C)c1cc(-c2ccc3c(c2)-n2c4ccccc4c4ccccc4c4ccccc4c4ccc5c(c42)B3c2ccc(Cl)cc2N5c2ccc(-c3ccccc3)cc2-c2ccccc2)cc(C(C)(C)C)c1]

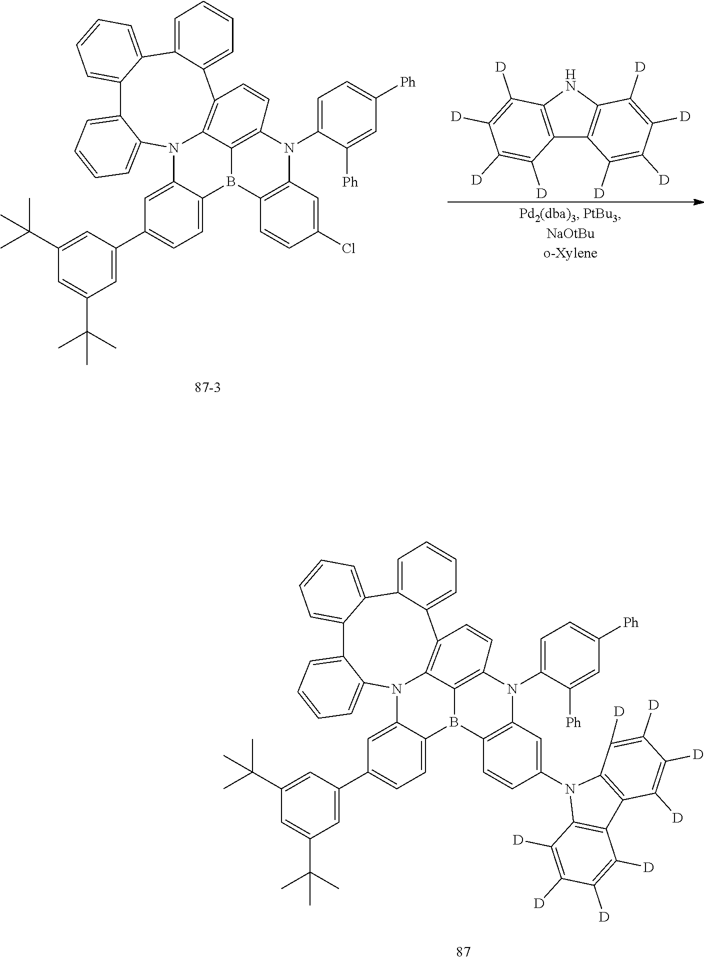 [SMILES: CC(C)(C)c1cc(-c2ccc3c(c2)-n2c4ccccc4c4ccccc4c4ccccc4c4ccc5c(c42)B3c2ccc(Cl)cc2N5c2ccc(-c3ccccc3)cc2-c2ccccc2)cc(C(C)(C)C)c1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1ccc3c4ccccc4c4ccccc4c4ccccc4n4c3c1B2c1ccc(-c2cc(C(C)(C)C)cc(C(C)(C)C)c2)cc1-4]

### Synthesis of Intermediate 87-1

Intermediate 83-1 (1 eq), 3,5-di-tert-butyl-3′-iodo-1,1′-biphenyl (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 87-1. (Yield: 62%)

### Synthesis of Intermediate 87-2

Intermediate 87-1 (1 eq), N-(3-chlorophenyl)-[1,1′:3′,1″-terphenyl]-4′-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 100° C. for 10 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 87-2. (Yield: 58%)

### Synthesis of Intermediate 87-3

Intermediate 87-2 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified through MC/Hex (methylenechloride/hexane) recrystallization, thereby obtaining Intermediate 87-3. Then, Intermediate 87-3 was subjected to final purification through a column (dichloromethane: n-hexane). (Yield: 8%)

### Synthesis of Compound 87

Intermediate 87-3 (1 eq), 9H-carbazole-1,2,3,4,5,6,7,8-d₈ (1.1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 2.0 eq) were dissolved in o-Xylene and stirred at 150° C. for 24 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Compound 87. (Yield: 72%) The resulting product was further purified through sublimation purification, and the obtained compound was confirmed to be Compound 87 through ESI-LCMS. ESI-LCMS: [M]+: C₈₀H₅₄D₈BN₃, 1084.7

### (6) Synthesis of Fused Polycyclic Compound 115

Fused polycyclic Compound 115 according to an embodiment may be synthesized by, for example, a process of Reaction Formula 6.

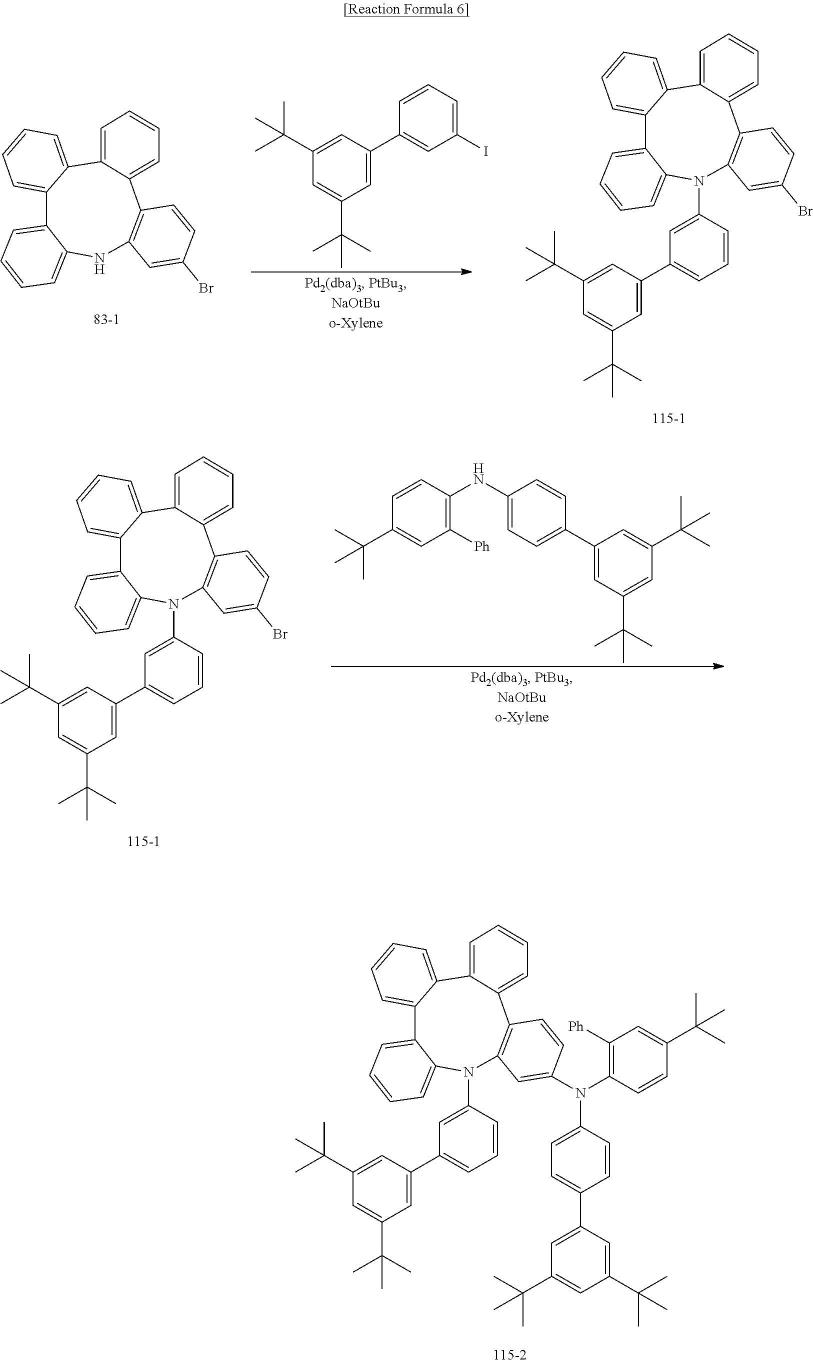 [SMILES: Brc1ccc2c(c1)[nH]c1ccccc1c1ccccc1c1ccccc21 ; CC(C)(C)c1cc(-c2cccc(I)c2)cc(C(C)(C)C)c1 ; CC(C)(C)c1cc(-c2cccc(-n3c4ccccc4c4ccccc4c4ccccc4c4ccc(Br)cc43)c2)cc(C(C)(C)C)c1 ; CC(C)(C)c1cc(-c2cccc(-n3c4ccccc4c4ccccc4c4ccccc4c4ccc(Br)cc43)c2)cc(C(C)(C)C)c1 ; CC(C)(C)c1cc(-c2ccc(Nc3ccc(C(C)(C)C)cc3-c3ccccc3)cc2)cc(C(C)(C)C)c1 ; CC(C)(C)c1cc(-c2ccc(N(c3ccc4c5ccccc5c5ccccc5c5ccccc5n(-c5cccc(-c6cc(C(C)(C)C)cc(C(C)(C)C)c6)c5)c4c3)c3ccc(C(C)(C)C)cc3-c3ccccc3)cc2)cc(C(C)(C)C)c1]

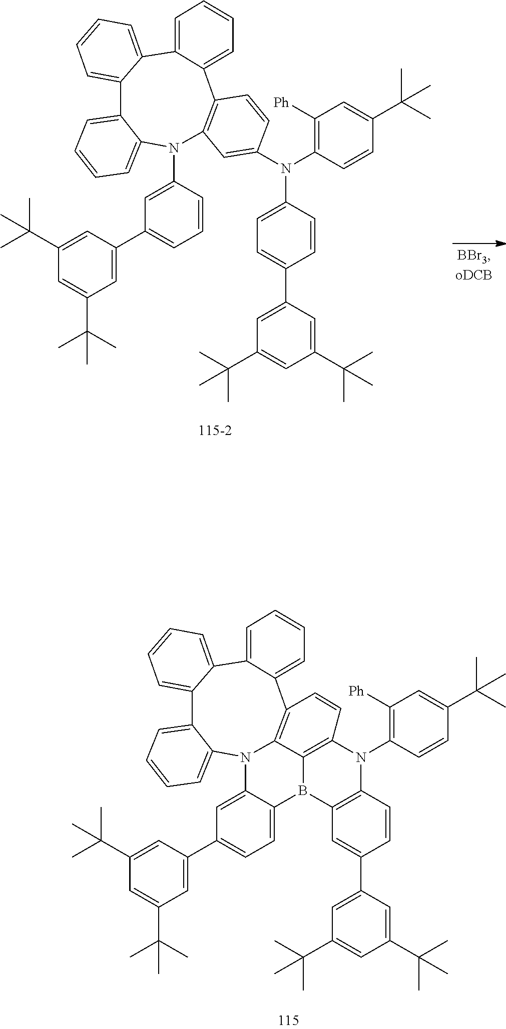

### Synthesis of Intermediate 115-1

Intermediate 83-1 (1 eq), 3,5-di-tert-butyl-3′-iodo-1,1′-biphenyl (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 90° C. for 12 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 115-1. (Yield: 71%)

### Synthesis of Intermediate 115-2

Intermediate 115-1 (1 eq), 5-(tert-butyl)-N-(3′,5′-di-tert-butyl-[1,1′-biphenyl]-4-yl)-[1,1′-biphenyl]-2-amine (1 eq), tris(dibenzylideneacetone)dipalladium(0) (Pd₂(dba)₃, 0.05 eq), tri-tert-butylphosphine (PtBu₃, 0.10 eq), and sodium tert-butoxide (NaOtBu, 1.5 eq) were dissolved in o-Xylene and stirred at 130° C. for 12 hours in a nitrogen atmosphere. After cooling, the resulting product was dried under reduced pressure to remove o-Xylene. Thereafter, the resulting product was washed with ethyl acetate and water each for three times to obtain an organic layer, which was then dried over magnesium sulfate (MgSO₄) and dried under reduced pressure. The resulting product was purified through column chromatography and recrystallized (dichloromethane: n-Hexane), thereby obtaining Intermediate 115-2. (Yield: 68%)

### Synthesis of Compound 115

Intermediate 115-2 (1 eq) was dissolved in ortho dichlorobenzene (oDCB), and a flask was cooled to 0° C. in a nitrogen atmosphere, and then BBr₃ (2.5 eq) dissolved in ortho dichlorobenzene was slowly injected thereto. After the dropping was completed, the temperature was raised to 190° C. to stir the resulting product for 24 hours. After cooling the resulting product to 0° C., triethylamine was slowly dropped into the flask until exotherm stopped to complete the reaction. Thereafter, n-hexane and methanol were added to precipitate and filtrate the mixture to obtain a solid content (e.g., amount). The obtained solid was purified through silica filtration and then purified again through a column (dichloromethane: n-hexane), thereby obtaining Compound 115. Then, Compound 115 was subjected to additional purification through a column (dichloromethane: n-hexane) (Yield: 15%). The resulting product was further purified through sublimation purification, and the obtained compound was confirmed to be Compound 115 through ESI-LCMS. ESI-LCMS: [M]+: C₈₀H₇₉BN₂, 1079.7

### 2. Preparation and Evaluation of Light Emitting Elements 1

### (1) Preparation of Light Emitting Elements 1

Light emitting elements including fused polycyclic compounds according to an embodiment or Comparative Example compounds were prepared through a method. Light emitting elements of Examples 1-1 to 1-6 were prepared utilizing Compounds 13, 19, 28, 83, 87, and 115, which are fused polycyclic compounds according to an embodiment, as dopant materials of emission layers. Light emitting elements of Comparative Examples 1-1 to 1-3 were prepared utilizing Comparative Example Compounds CX1 to CX3 as dopant materials of emission layers.

As an anode, a glass substrate having an ITO electrode (Corning, 15 Ω/cm² 1200 Å) formed thereon was cut to a size of about 50 mm×50 mm×0.7 mm, subjected to ultrasonic cleaning utilizing isopropyl alcohol and pure water for 5 minutes respectively and ultraviolet irradiation for 30 minutes, and then exposed to ozone for cleaning to be mounted on a vacuum deposition apparatus.

On the anode, a hole injection layer having a thickness of 300 Å was formed through deposition of NPD. On the hole injection layer, a hole transport layer having a thickness of 200 Å was formed through deposition of a hole transport layer material, and then on the hole transport layer, an auxiliary emission layer having a thickness of 100 Å was formed through deposition of CzSi.

On the auxiliary emission layer, a host mixture, a sensitizer, and a dopant were co-deposited in a weight ratio of 85:14.5:0.5 to form an emission layer having a thickness of 200 Å. The host mixture was provided by mixing a hole transporting host HT (Table 2) and an electron transporting host ET (Table 2) were in a weight ratio of 5:5. Any one among HT1 to HT3 was utilized as a hole transporting host material, and any one among ETH85, ETH66, and ETH86 was utilized as an electron transporting host material. Host materials, sensitizers, and dopants are listed in more detail in Table 2.

Thereafter, on the emission layer, a hole blocking layer having a thickness of 200 Å was formed through deposition of TSPO1. On the hole blocking layer, an electron transport layer having a thickness of 300 Å was formed through deposition of TPBI, and then on the electron transport layer, an electron injection layer having a thickness of 10 Å was formed through deposition of LiF. On the electron injection layer, a cathode having a thickness of 3000 Å was formed through deposition of Al and on the cathode, a capping layer having a thickness of 700 Å was formed to prepare a light emitting element.

(Materials utilized upon preparation of light emitting elements)

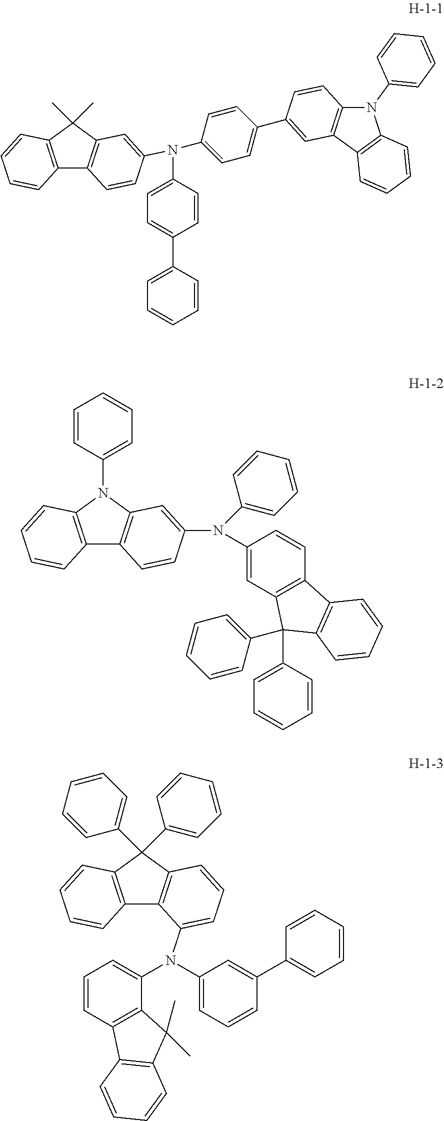 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

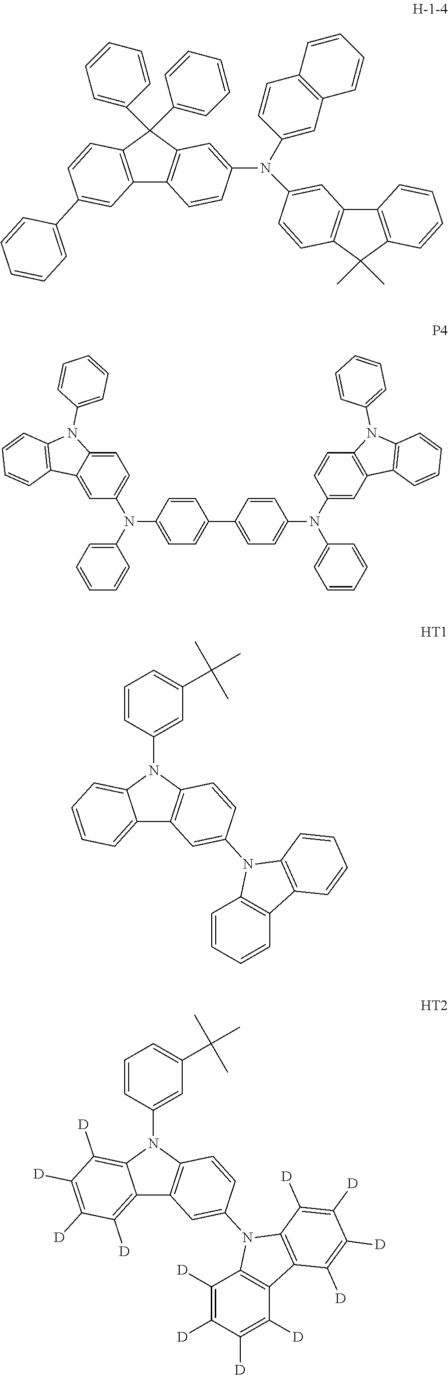 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1]

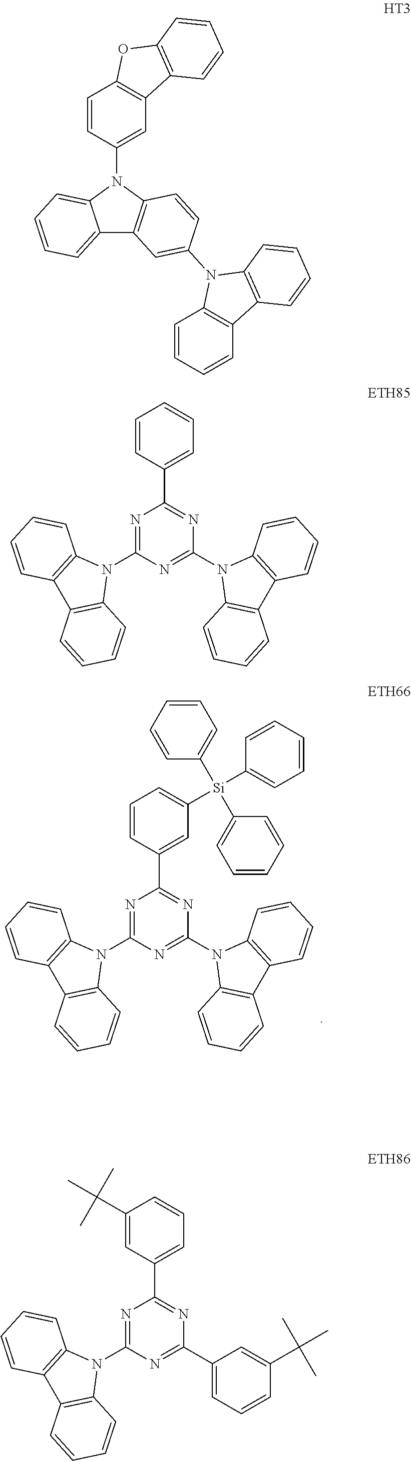

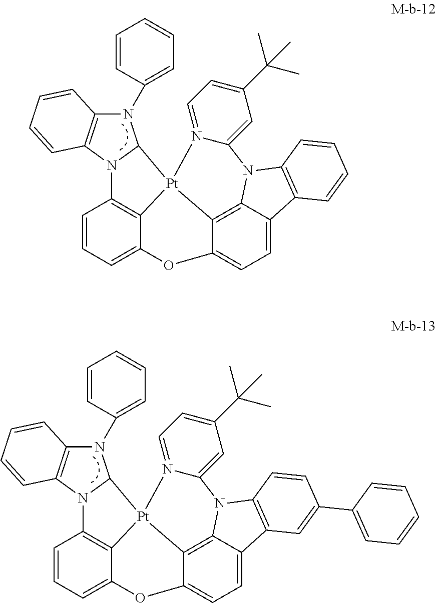

Dopant materials utilized in the preparation of light emitting elements of Examples 1-1 to 1-6 and Comparative Examples 1-1 to 1-3 are shown in Table 1.

TABLE 1

| Comparative Example Compound CX1 | 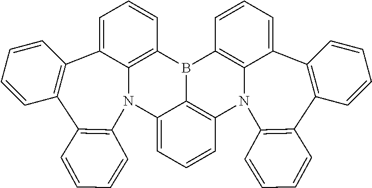 [SMILES: c1ccc2c(c1)-c1ccccc1N1c3cccc4c3B(c3cccc-2c31)c1cccc2c1N4c1ccccc1-c1ccccc1-2] |
|---|---|
| | CX1 |
| Comparative Example Compound CX2 | 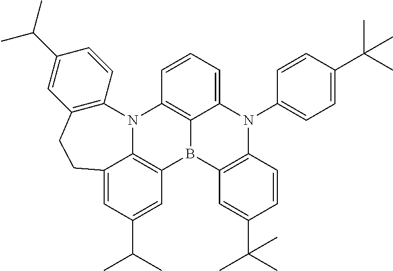 |
| | CX2 |
| Comparative Example Compound CX3 | 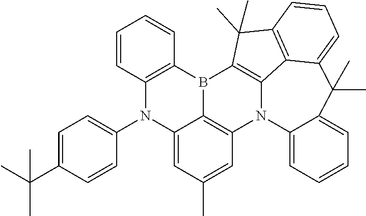 |
| | CX3 |
| — | — |
| Compound 13 | 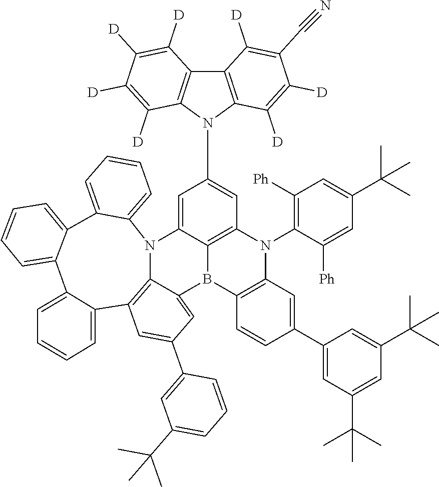 |
| | 13 |
| Compound 19 | 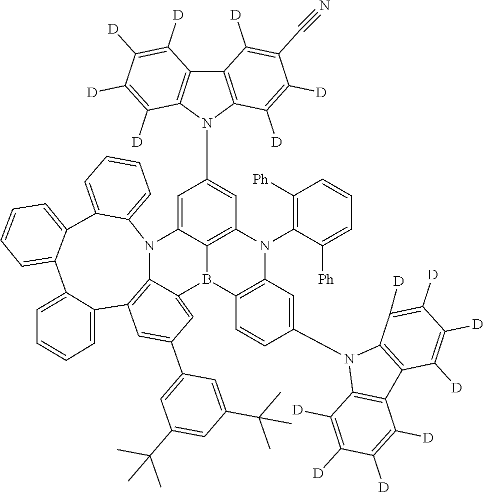 |
| | 19 |
| Compound 28 | 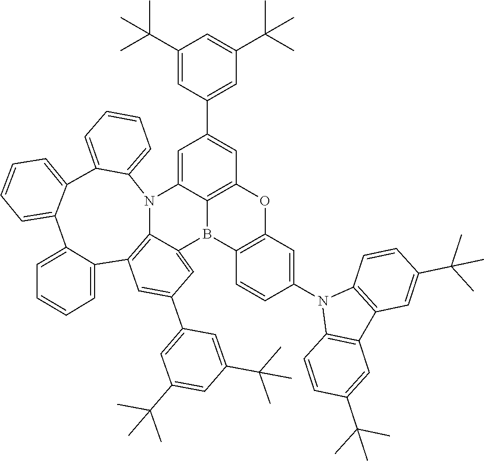 |
| | 28 |
| Compound 83 | 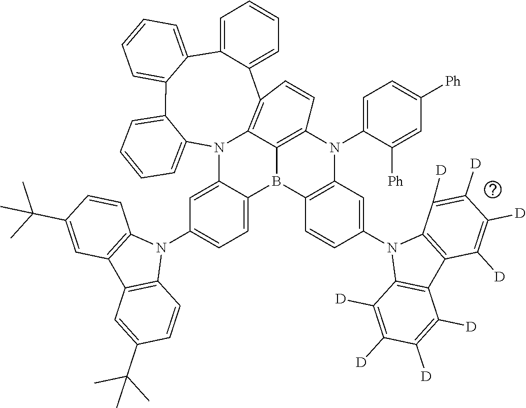 |
| | 83 |
| Compound 87 | 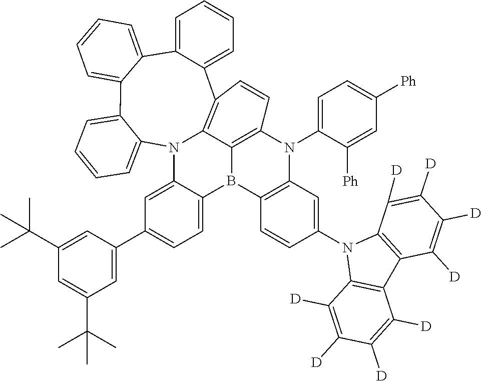 |
| | 87 |
| Compound 115 | 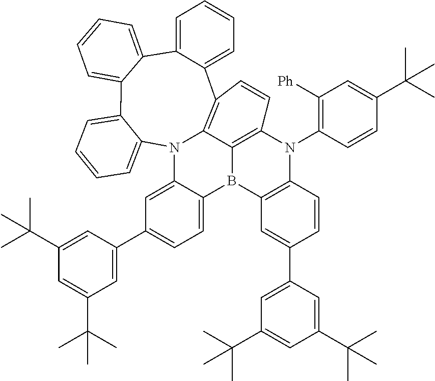 |
| | 115 |

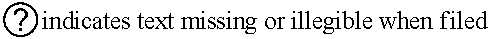

### (2) Evaluation of Light Emitting Elements 1

Driving voltage (V), luminous efficiency (Cd/A), maximum external quantum efficiency (%), lifespan, and light emitting color were measured and are shown in Table 2. The driving voltage (V), the luminous efficiency (Cd/A), the maximum external quantum efficiency (%), and the light emitting color were measured utilizing Keithley MU 236 and a luminance meter PR650. For the lifespan, the time taken to decrease to 95% from an initial luminance of 100% was measured, and a relative value was calculated by taking the time measured in the light emitting element of Comparative Example 1-1 as 100%.

TABLE 2

| Example | | | | | | | Maximum | | |
|---|---|---|---|---|---|---|---|---|---|
| of | Hole | Host | | | | | external | | |
| element | trans- | (HT: | | | Driving | | quantum | Element | |
| prepar- | port | ET = | | | voltage | Efficiency | efficiency | lifespan | Emitted |
| ation | layer | 5:5) | Sensitizer | Dopant | (V) | (cd/A) | (%) | (%) | color |
| Ex- | H-1- | HT2/ | M-b-12 | Com- | 4.4 | 24.8 | 24.1 | 310 | Blue |
| ample | 2 | ETH85 | | pound | | | | | |
| 1-1 | | | | 13 | | | | | |
| Ex- | H-1- | HT2/ | M-b-13 | Com- | 4.3 | 25.6 | 24.8 | 305 | Blue |
| ample | 1 | ETH66 | | pound | | | | | |
| 1-2 | | | | 19 | | | | | |
| Ex- | H-1- | HT1/ | M-b-12 | Com- | 4.4 | 24.3 | 23.6 | 270 | Blue |
| ample | 3 | ETH66 | | pound | | | | | |
| 1-3 | | | | 28 | | | | | |
| Ex- | H-1- | HT3/ | M-b-13 | Com- | 4.2 | 26.9 | 25.7 | 345 | Blue |
| ample | 2 | ETH85 | | pound | | | | | |
| 1-4 | | | | 83 | | | | | |
| Ex- | H-1- | HT2/ | M-b-12 | Com- | 4.4 | 25.2 | 24.5 | 320 | Blue |
| ample | 1 | ETH66 | | pound | | | | | |
| 1-5 | | | | 87 | | | | | |
| Ex- | H-1- | HT3/ | M-b-13 | Com- | 4.4 | 23.8 | 22.9 | 295 | Blue |
| ample | 1 | ETH86 | | pound | | | | | |
| 1-6 | | | | 115 | | | | | |
| Com- | H-1- | HT3/ | M-b-12 | Com- | 4.8 | 14.5 | 13.8 | 100 | Blue |
| parative | 4 | ETH66 | | parative | | | | | |
| Ex- | | | | Ex- | | | | | |
| ample | | | | ample | | | | | |
| 1-1 | | | | Com- | | | | | |
| | | | | pound | | | | | |
| | | | | CX1 | | | | | |
| Com- | H-1- | HT1/ | M-b-13 | Com- | 4.7 | 15.4 | 14.9 | 155 | Blue |
| parative | 2 | ETH86 | | parative | | | | | |
| Ex- | | | | Ex- | | | | | |
| ample | | | | ample | | | | | |
| 1-2 | | | | Com- | | | | | |
| | | | | pound | | | | | |
| | | | | CX2 | | | | | |
| Com- | H-1- | HT2/ | M-b-12 | Com- | 4.8 | 15.9 | 15.2 | 175 | Blue |
| parative | 3 | ETH85 | | parative | | | | | |
| Ex- | | | | Ex- | | | | | |
| ample | | | | ample | | | | | |
| 1-3 | | | | Com- | | | | | |
| | | | | pound | | | | | |
| | | | | CX3 | | | | | |

Referring to Table 2, it is seen that, compared to the light emitting elements of Comparative Examples 1-1 to 1-3, the light emitting elements of Examples 1-1 to 1-6 exhibited excellent or suitable light efficiency. In some embodiments, it is seen that, compared to the light emitting elements of Comparative Example 1-1 to 1-3, the light emitting elements of Examples 1-1 to 1-6 had reduced driving voltage and increased lifespan. The light emitting elements of Examples 1-1 to 1-6 include Compounds 13, 19, 28, 83, 87, and 115, and Compounds 13, 19, 28, 83, 87, and 115 are fused polycyclic compounds according to an embodiment.

Compounds 13, 19, 28, 83, 87, and 115, which are fused polycyclic compounds of an embodiment, include tetrabenzo azonine derivatives, and may thus prevent or reduce dexter energy transfer. In some embodiments, in Compounds 13, 19, 28, 83, 87 and 115, bulky substituents may be introduced to be positioned para or meta to a boron atom to protect a central structure and prevent or reduce dexter energy transition. The para or meta positions with respect to the boron atom are active sites. Accordingly, the light emitting elements of Examples 1-1 to 1-6 including Compounds 13, 19, 28, 83, 87 and 115 have increased efficiency and lifespan. In some embodiments, a light emitting element including the fused polycyclic compound of an embodiment, which contains a tetrabenzo azonine derivative, may exhibit high efficiency and long lifespan.

The light emitting elements of Comparative Examples 1-1 to 1-3 include Comparative Example Compounds CX1 to CX3, and Comparative Example Compounds CX1 to CX3 do not contain a tetrabenzo azonine derivative. Accordingly, the light emitting elements of Comparative Examples 1-1 to 1-3 including Comparative Example Compounds CX1 to CX3 exhibited relatively high driving voltage, low efficiency, and short lifespan.

### 3. Preparation and Evaluation of Light Emitting Elements 2

### (1) Preparation of Light Emitting Elements 2

The light emitting elements of Examples 2-1 to 2-6 including the fused polycyclic compound of an embodiment in emission layers and the light emitting elements of Comparative Examples 2-1 to 2-3 including Comparative Example compounds in emission layers were prepared.

The light emitting elements of Examples 2-1 to 2-6 were prepared through the same method as the method of preparing the light emitting elements of Examples 1-1 to 1-6 described above except for the method of forming an emission layer. The light emitting elements of Examples 2-1 to 2-6 were prepared without providing a sensitizer when forming an emission layer in the method of preparing the light emitting elements of Examples 1-1 to 1-6 described above. In the light emitting elements of Examples 2-1 to 2-6, the emission layer was formed through co-deposition of a host mixture and an Example compound in a weight ratio of 99:1. As described above, the host mixture is provided by mixing a hole transporting host and an electron transporting host in a weight ratio of 5:5.

The light emitting elements of Comparative Examples 2-1 to 2-3 were prepared through the same method as the method of preparing the light emitting elements of Comparative Examples 1-1 to 1-3 described above except for the method of forming an emission layer. The light emitting elements of Comparative Examples 2-1 to 2-3 were prepared without providing a sensitizer in the method of preparing the light emitting elements of Comparative Examples 1-1 to 1-3 described above. The light emitting elements of Comparative Examples 2-1 to 2-3 were prepared through co-deposition of a host mixture and a Comparative Example compound in a weight ratio of 99:1.

### (2) Evaluation of Light Emitting Elements 2

For the light emitting elements of Comparative Examples 2-1 to 2-3 and Examples 2-1 to 2-6, luminous efficiency (Cd/A), maximum external quantum efficiency (%), and light emitting color were evaluated and are shown in Table 3. The luminous efficiency (Cd/A), the maximum external quantum efficiency (%), and light emitting color in Table 3 were evaluated through the same evaluation method as described with reference to Table 2.

TABLE 3

| Example | Hole | | | | Maximum | |
|---|---|---|---|---|---|---|
| of | trans- | Host | | | external | |
| element | port | (HT: | | Luminous | quantum | |
| prepar- | layer | ET = | | efficiency | efficiency | Emitted |
| ation | Host | 5:5) | Dopant | (cd/A) | (%) | color |
| Example | H-1-2 | HT2/ | Compound | 8.1 | 7.8 | Blue |
| 2-1 | | ETH85 | 13 | | | |
| Example | H-1-1 | HT2/ | Compound | 8.3 | 8.1 | Blue |
| 2-2 | | ETH66 | 19 | | | |
| Example | H-1-3 | HT1/ | Compound | 7.9 | 7.7 | Blue |
| 2-3 | | ETH66 | 28 | | | |
| Example | H-1-2 | HT3/ | Compound | 8.8 | 8.4 | Blue |
| 2-4 | | ETH85 | 83 | | | |
| Example | H-1-1 | HT2/ | Compound | 8.2 | 8.0 | Blue |
| 2-5 | | ETH66 | 87 | | | |
| Example | H-1-1 | HT3/ | Compound | 7.7 | 7.4 | Blue |
| 2-6 | | ETH86 | 115 | | | |
| Com- | H-1-4 | HT3/ | Comparative | 4.6 | 4.4 | Blue |
| parative | | ETH66 | Example | | | |
| Example | | | Compound | | | |
| 2-1 | | | CX1 | | | |
| Com- | H-1-2 | HT1/ | Comparative | 4.9 | 4.8 | Blue |
| parative | | ETH86 | Example | | | |
| Example | | | Compound | | | |
| 2-2 | | | CX2 | | | |
| Com- | H-1-3 | HT2/ | Comparative | 5.1 | 4.9 | Blue |
| parative | | ETH85 | Example | | | |
| Example | | | Compound | | | |
| 2-3 | | | CX3 | | | |

Referring to Table 3, it is seen that, compared ta the light emitting elements at Comparative Examples 2-1 to 2-3, the light emitting elements at Examples 2-1 to 2-6 exhibited excellent or suitable luminous efficiency. The light emitting elements of Examples 2-1 ta 2-6 include Compounds 13, 19, 28, 83, 87, and 115, and Compounds 13, 19, 28, 83, 87, and 115 are fused polycyclic compounds of an embodiment. Compounds 13, 19, 28, 83, 87, and 115, which are fused polycyclic compounds of an embodiment, include tetrabenzo azonine derivatives to prevent or reduce dexter energy transfer, and thus light emitting elements of Examples 2-1 to 2-6 containing Compounds 13, 19, 28, 83, 87, and 115 have increased luminous efficiency. Accordingly, a light emitting element including the fused polycyclic compound of an embodiment, which contains a tetrabenzo azonine derivative, may exhibit high efficiency.

The light emitting elements of Comparative Examples 2-1 to 2-3 include Comparative Example Compounds CX1 to CX3, and Comparative Example Compounds CX1 to CX3 do not contain a tetrabenzo azonine derivative. Accordingly, the light emitting elements of Comparative Examples 2-1 to 2-3 including Comparative Example Compounds CX1 to CX3 exhibited relatively low efficiency.

A light emitting element may include a first electrode, a second electrode disposed on the first electrode, and an emission layer disposed between the first electrode and the second electrode. The emission layer may include a fused polycyclic compound of an embodiment. The fused polycyclic compound of an embodiment includes a central structure in which a tetrabenzo azonine derivative is fused, and may thus prevent or reduce intermolecular interaction. Accordingly, in the fused polycyclic compound of an embodiment, dexter energy transfer may not take place. Accordingly, the light emitting element of an embodiment may exhibit high efficiency.

A light emitting element of an embodiment includes a fused polycyclic compound of an embodiment, and may thus exhibit increased light efficiency.

A fused polycyclic compound of an embodiment may contribute to increasing light efficiency of a light emitting element.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1; and
at least one of a second compound represented by Formula HT-1 or a third compound represented by Formula ET-1: 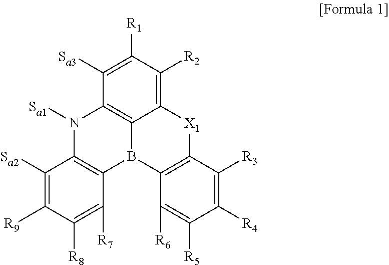
wherein in Formula 1,
X₁ is NR₁₀ or O,
R₁ to R₁₀ are each independently a hydrogen atom, a deuterium atom, a halogen atom, a cyano group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heterocyclic group having 2 to 60 ring-forming carbon atoms,
wherein,
a first substituent represented by Formula 2 is bonded to Sₐ₁ and Sₐ₂, and Sₐ₃ is a hydrogen atom, or
the first substituent represented by Formula 2 is bonded to Sₐ₁ and Sₐ₃, and Sₐ₂ is a hydrogen atom, 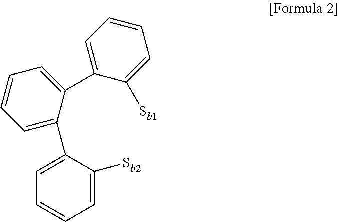
wherein in Formula 2,
S_{b1} and S_{b2} are positions bonded to Formula 1, 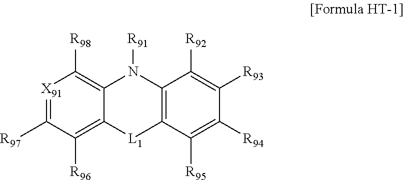
wherein in Formula HT-1,
L₁ is a direct linkage, CR₉₉R₁₀₀, or SiR₁₀₁R₁₀₂,
X₉₁ is N or CR₁₀₃, and
R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and 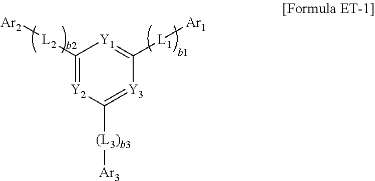
wherein in Formula ET-1,
at least one of Y₁ to Y₃ is N and the others are CRₐ,
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

2. The light emitting element of claim 1, wherein Formula 1 is represented by Formula 1-1 or Formula 1-2: 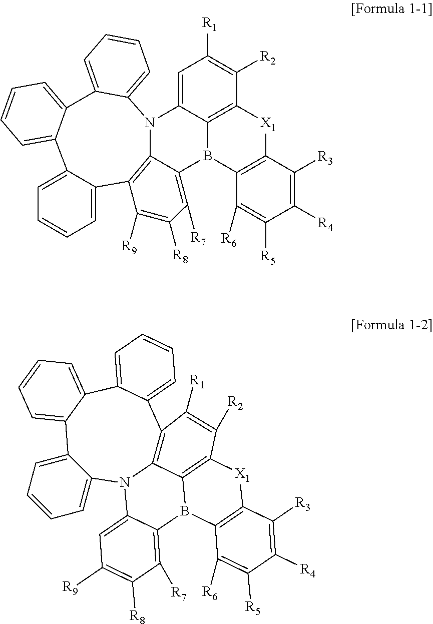
wherein in Formulas 1-1 and 1-2,
R₁ to R₉, and X₁ are the same as defined in Formula 1.

3. The light emitting element of claim 2, wherein Formula 1-1 is represented by Formula 1-1A: 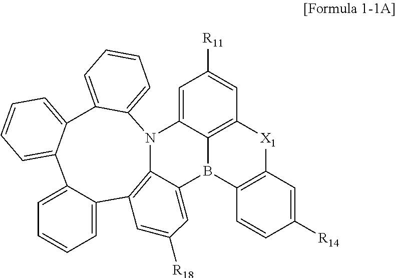
wherein in Formula 1-1A,
R₁₁, R₁₄, and R₁₈ are each independently a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and
X₁ is the same as defined in Formula 1-1.

4. The light emitting element of claim 2, wherein Formula 1-2 is represented by any one of among Formulas 1-2A to 1-2C: 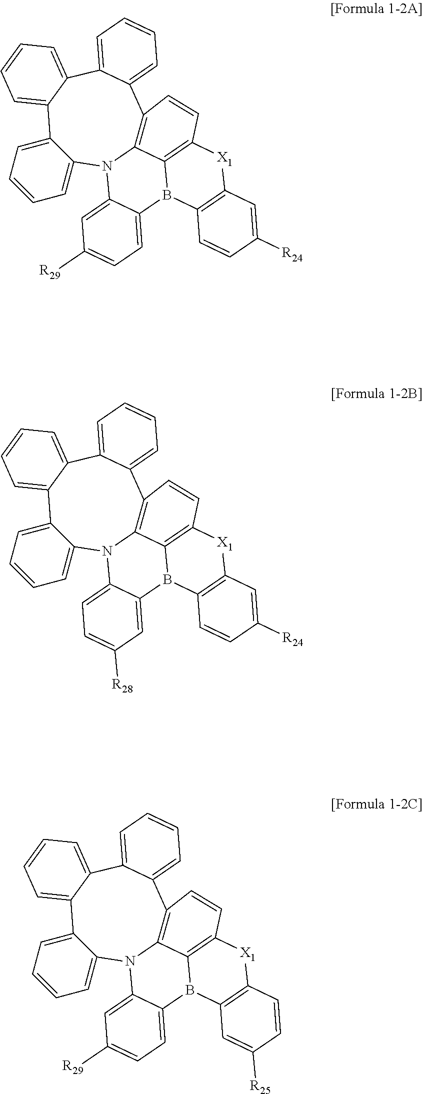
wherein in Formulas 1-2A to 1-2C,
R₂₄, R₂₅, R₂₈, and R₂₉ are each independently a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and
X₁ is the same as defined in Formula 1-2.

5. The light emitting element of claim 1, wherein in Formula 1, X₁ is NR₁₀, and R₁₀ is represented by any one of among R10-1 to R10-4:

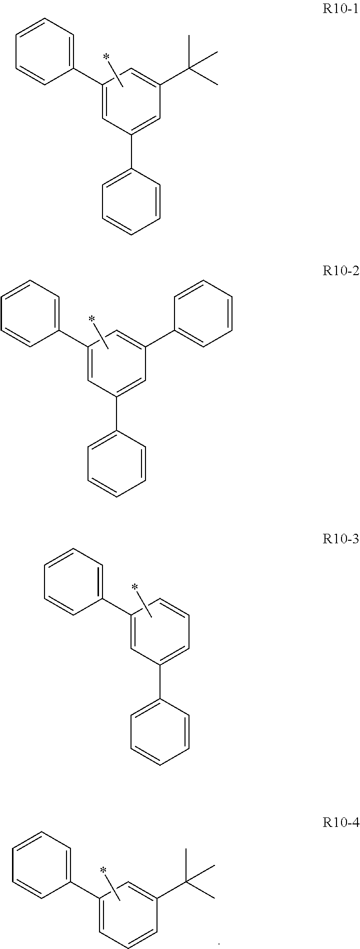

6. The light emitting element of claim 1, wherein in Formula 1, R₁ to R₉ are each independently a hydrogen atom or represented by any one of among R-1 to R-19: 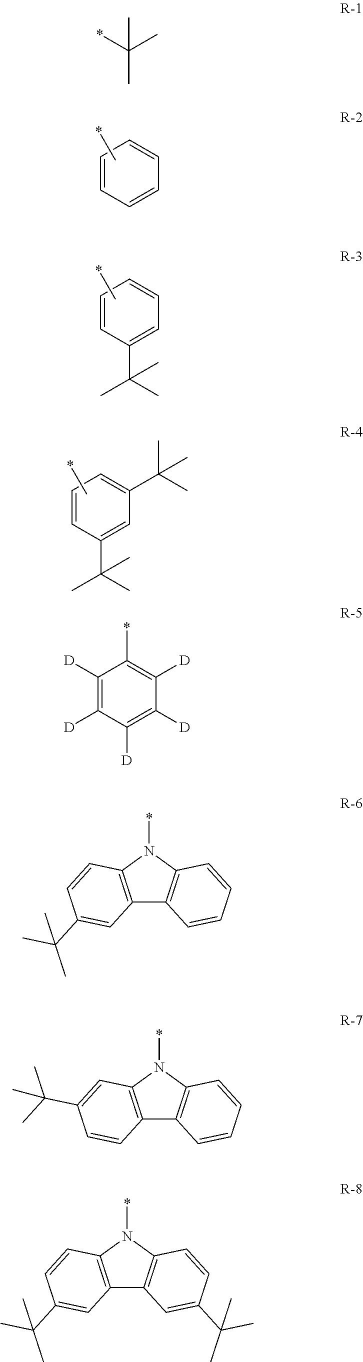 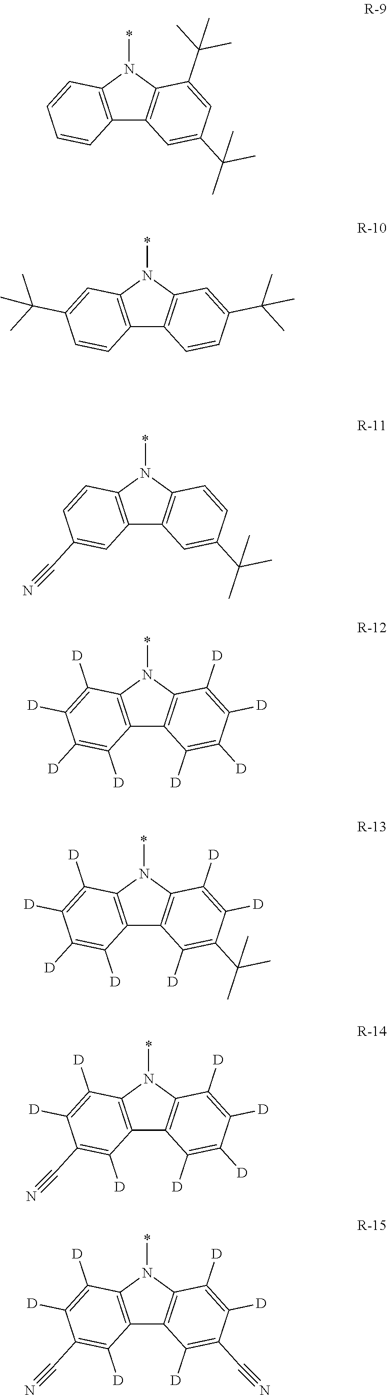 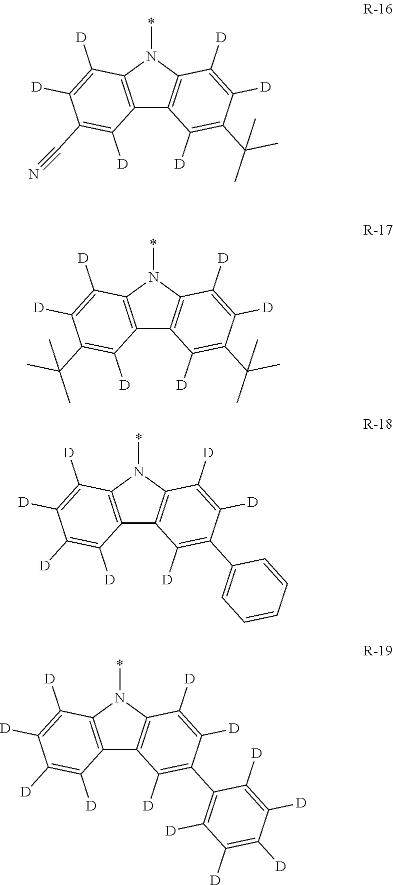
wherein in R-12 and R-19, D is a deuterium atom.

7. The light emitting element of claim 6, wherein in Formula 1, at least one of R₁ to R₉ is represented by any one of among R-6 to R-19.

8. The light emitting element of claim 1, wherein in Formula 1, at least one of R₁ to R₉ is a carbazole group substituted with at least one of a deuterium atom, a cyano group, an unsubstituted t-butyl group, an unsubstituted phenyl group, or a substituted phenyl group, or an unsubstituted carbazole group.

9. The light emitting element of claim 1, wherein in Formula 1, at least one of R₁ to R₉ is a deuterium atom or comprises a substituent containing a deuterium atom.

10. The light emitting element of claim 1, wherein the emission layer further comprises a fourth compound represented by Formula M-b: 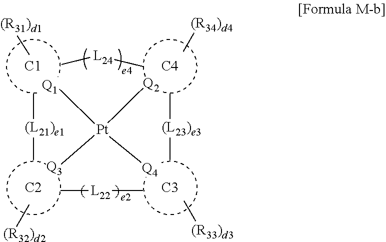
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 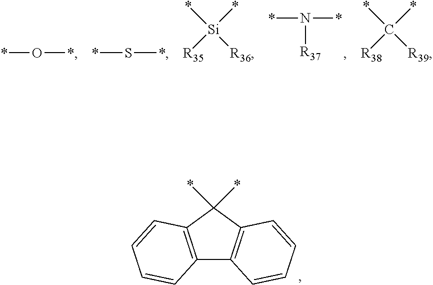
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer of 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring.

11. The light emitting element of claim 1, wherein the emission layer is a delayed fluorescent emission layer comprising a host and a dopant,
the dopant containing the first compound.

12. The light emitting element of claim 1, wherein the first compound is represented by any one of among compounds of Compound Group 1: 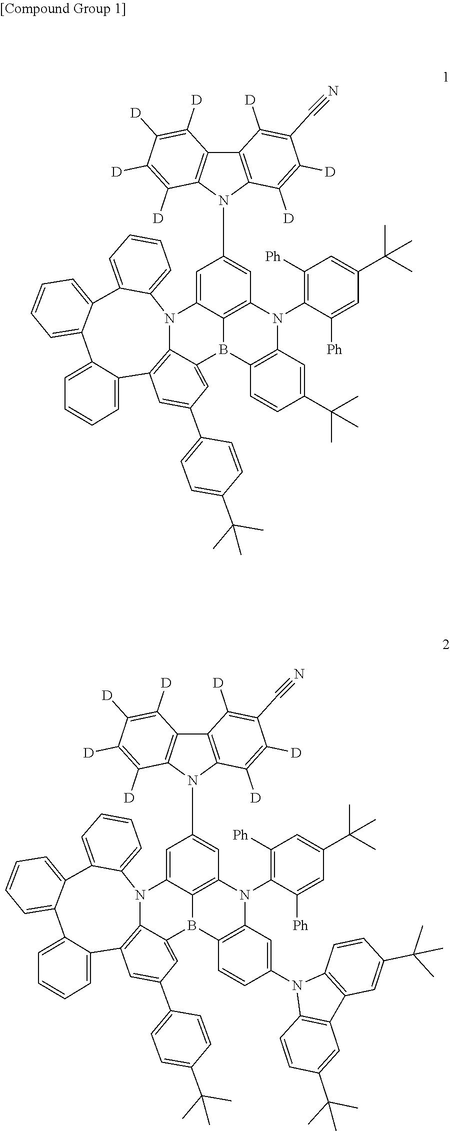 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(C(C)(C)C)cc1N2c1c(-c2ccccc2)cc(C(C)(C)C)cc1-c1ccccc1 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-n3c4ccc(C(C)(C)C)cc4c4cc(C(C)(C)C)ccc43)cc1N2c1c(-c2ccccc2)cc(C(C)(C)C)cc1-c1ccccc1] 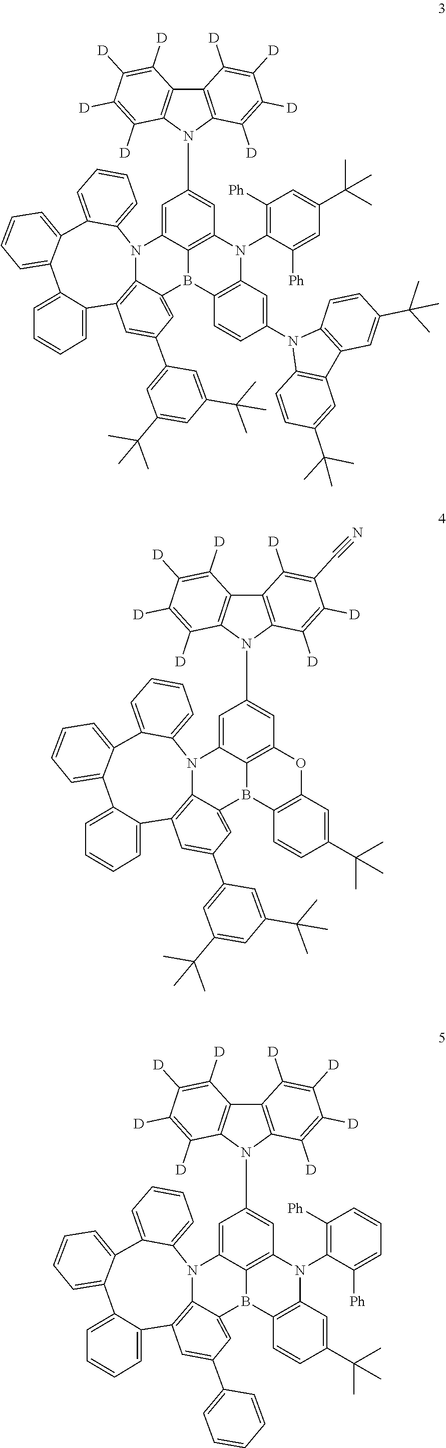 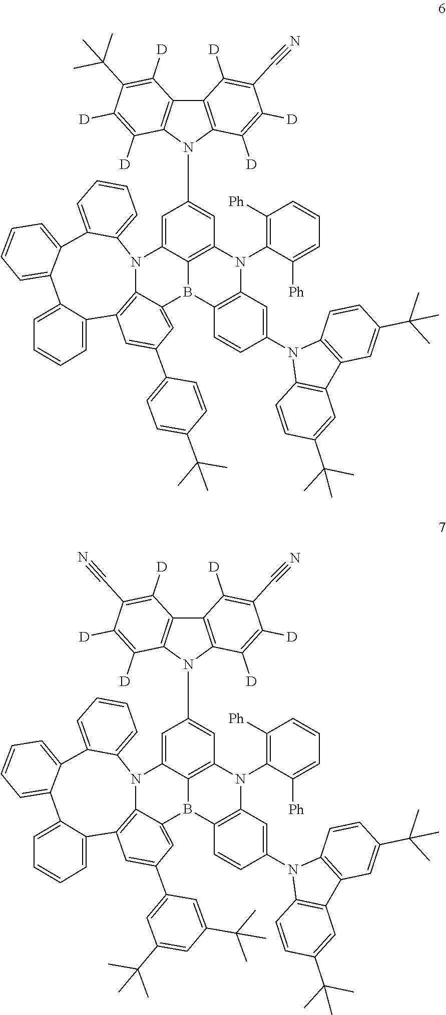 [SMILES: [2H]c1c(C#N)c([2H])c2c3c([2H])c(C(C)(C)C)c([2H])c([2H])c3n(-c3cc4c5c(c3)-n3c6ccccc6c6ccccc6c6ccccc6c6cc(-c7ccc(C(C)(C)C)cc7)cc(c63)B5c3ccc(-n5c6ccc(C(C)(C)C)cc6c6cc(C(C)(C)C)ccc65)cc3N4c3c(-c4ccccc4)cccc3-c3ccccc3)c2c1[2H] ; [2H]c1c(C#N)c([2H])c2c3c([2H])c(C#N)c([2H])c([2H])c3n(-c3cc4c5c(c3)-n3c6ccccc6c6ccccc6c6ccccc6c6cc(-c7cc(C(C)(C)C)cc(C(C)(C)C)c7)cc(c63)B5c3ccc(-n5c6ccc(C(C)(C)C)cc6c6cc(C(C)(C)C)ccc65)cc3N4c3c(-c4ccccc4)cccc3-c3ccccc3)c2c1[2H]] 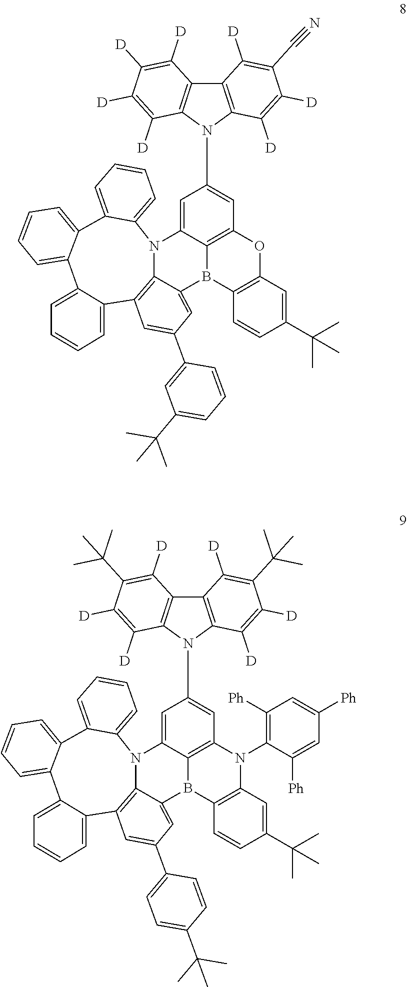 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(C(C)(C)C)cc1O2 ; [2H]c1c(C(C)(C)C)c([2H])c2c3c([2H])c(C(C)(C)C)c([2H])c([2H])c3n(-c3cc4c5c(c3)-n3c6ccccc6c6ccccc6c6ccccc6c6cc(-c7ccc(C(C)(C)C)cc7)cc(c63)B5c3ccc(C(C)(C)C)cc3N4c3c(-c4ccccc4)cc(-c4ccccc4)cc3-c3ccccc3)c2c1[2H]] 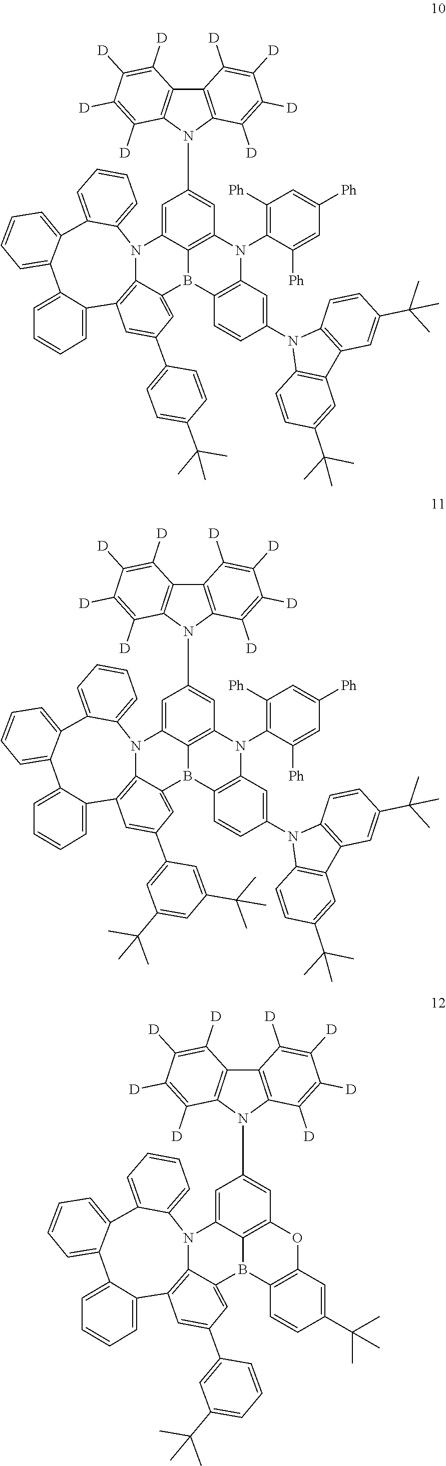 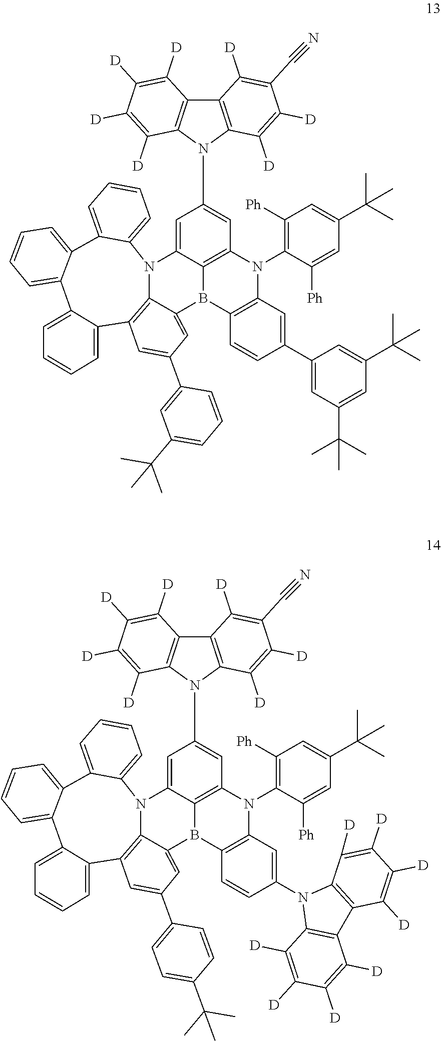 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cc(C(C)(C)C)cc(C(C)(C)C)c3)cc1N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2ccc(C(C)(C)C)cc2)cc2c4ccccc4c4ccccc4c4ccccc4n-3c12] 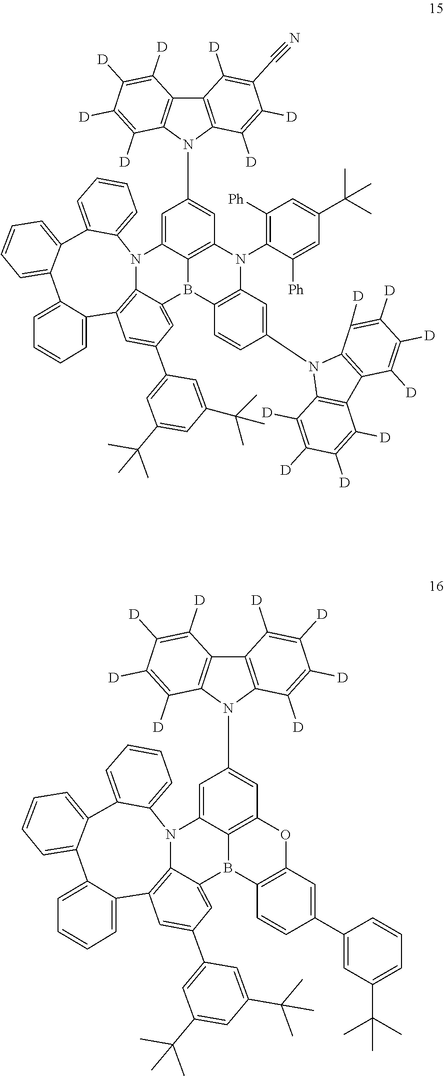 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c([2H])c([2H])c([2H])c1n2-c1cc2c3c(c1)-n1c4ccccc4c4ccccc4c4ccccc4c4cc(-c5cc(C(C)(C)C)cc(C(C)(C)C)c5)cc(c41)B3c1ccc(-c3cccc(C(C)(C)C)c3)cc1O2] 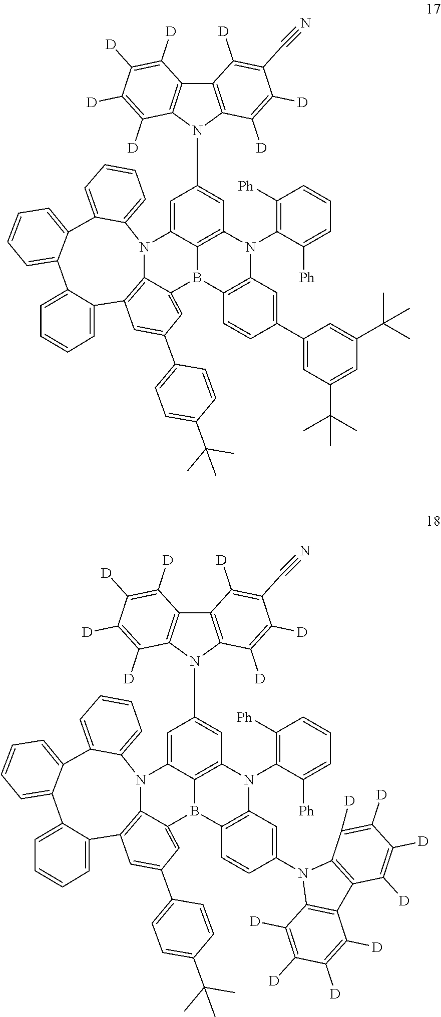 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cc(C(C)(C)C)cc(C(C)(C)C)c3)cc1N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(C#N)c([2H])c([2H])c43)cc3c1B2c1cc(-c2ccc(C(C)(C)C)cc2)cc2c4ccccc4c4ccccc4c4ccccc4n-3c12] 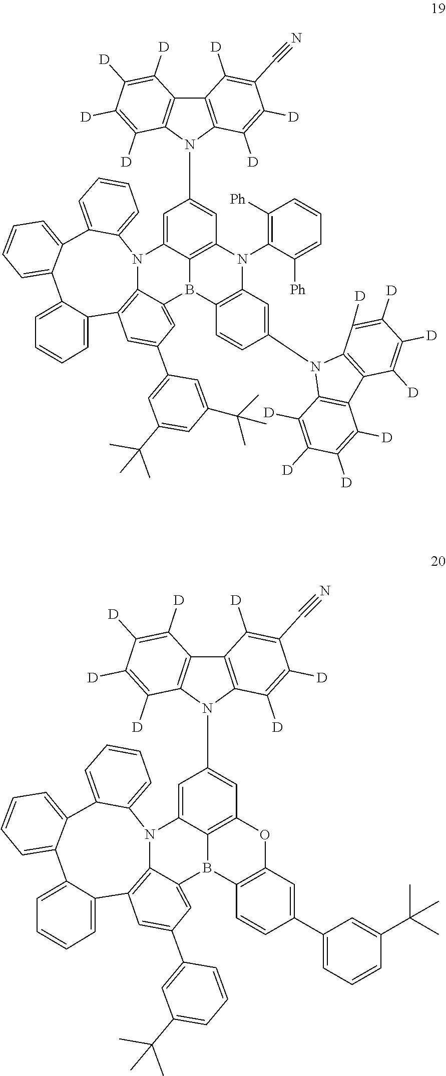 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2] 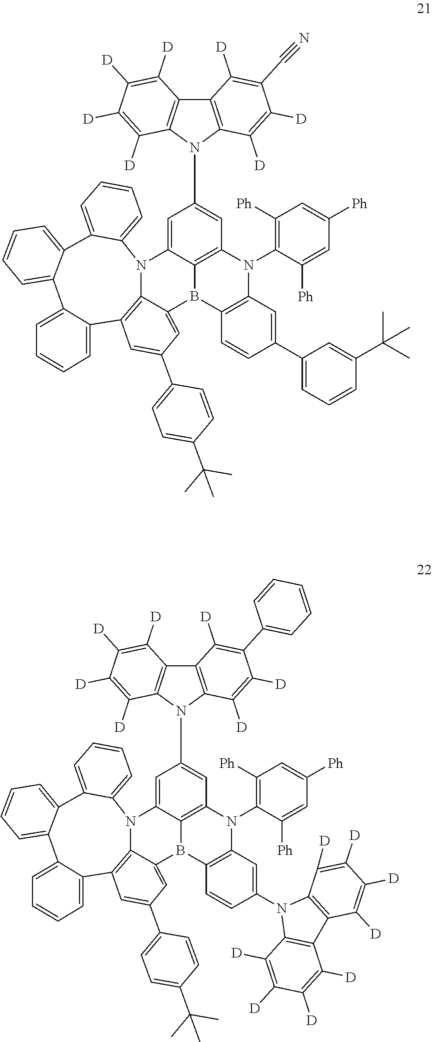 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cccc(C(C)(C)C)c3)cc1N2c1c(-c2ccccc2)cc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-n3c4c([2H])c([2H])c([2H])c([2H])c4c4c([2H])c(-c5ccccc5)c([2H])c([2H])c43)cc3c1B2c1cc(-c2ccc(C(C)(C)C)cc2)cc2c4ccccc4c4ccccc4c4ccccc4n-3c12] 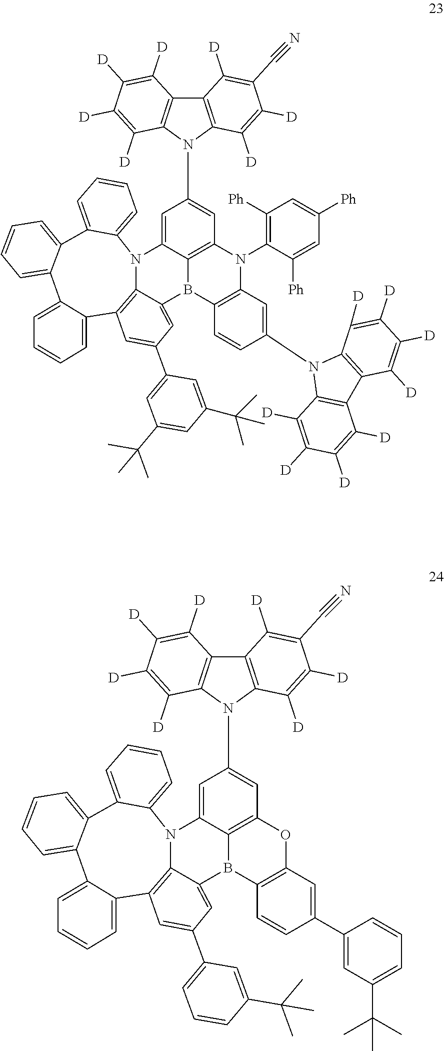 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2] 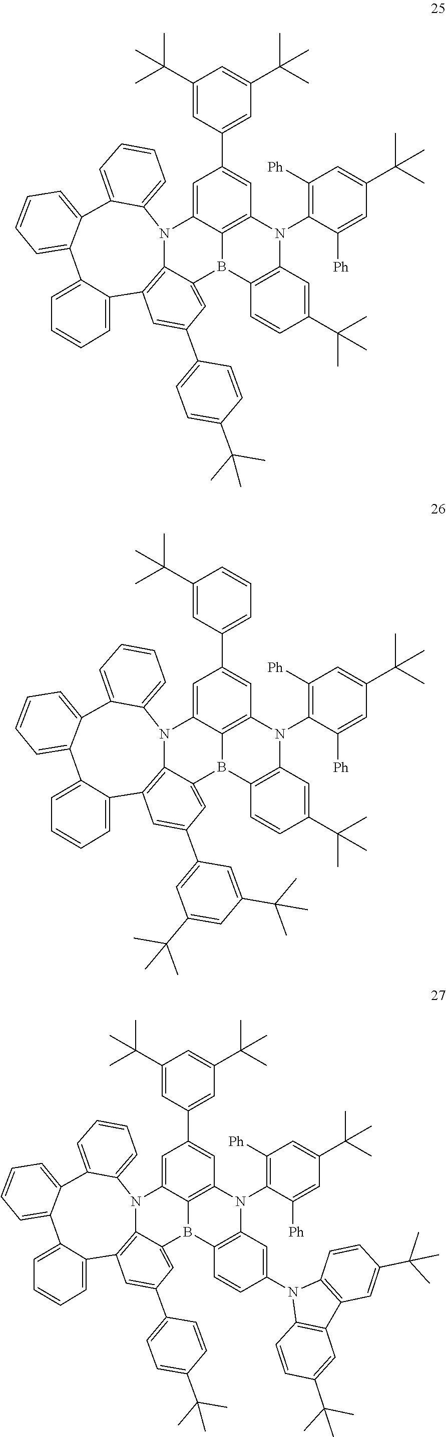 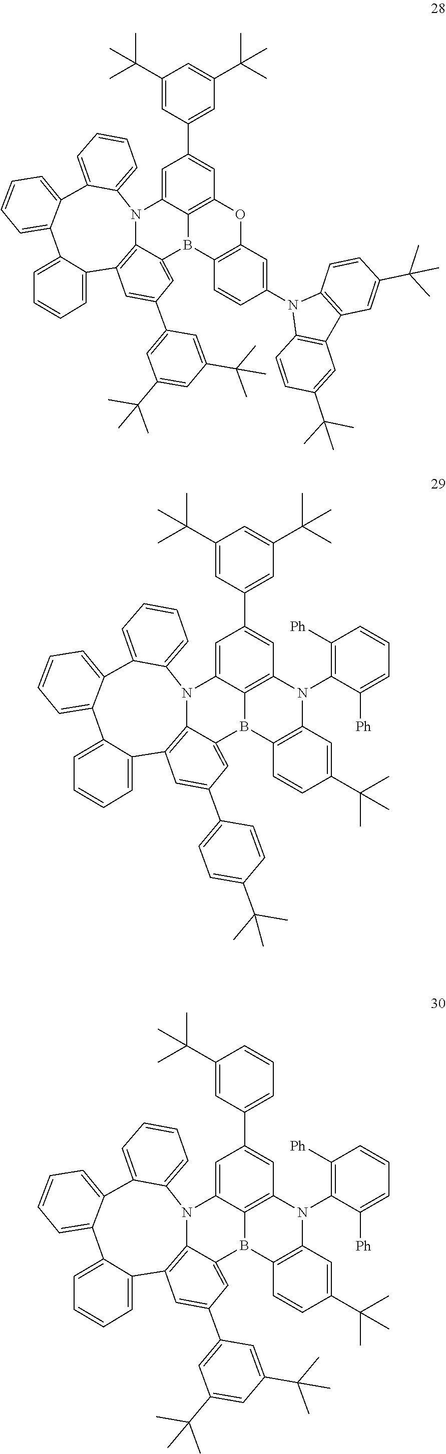 [SMILES: CC(C)(C)c1cc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc(C(C)(C)C)c1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cccc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(C(C)(C)C)cc2N3c2c(-c3ccccc3)cccc2-c2ccccc2)c1] 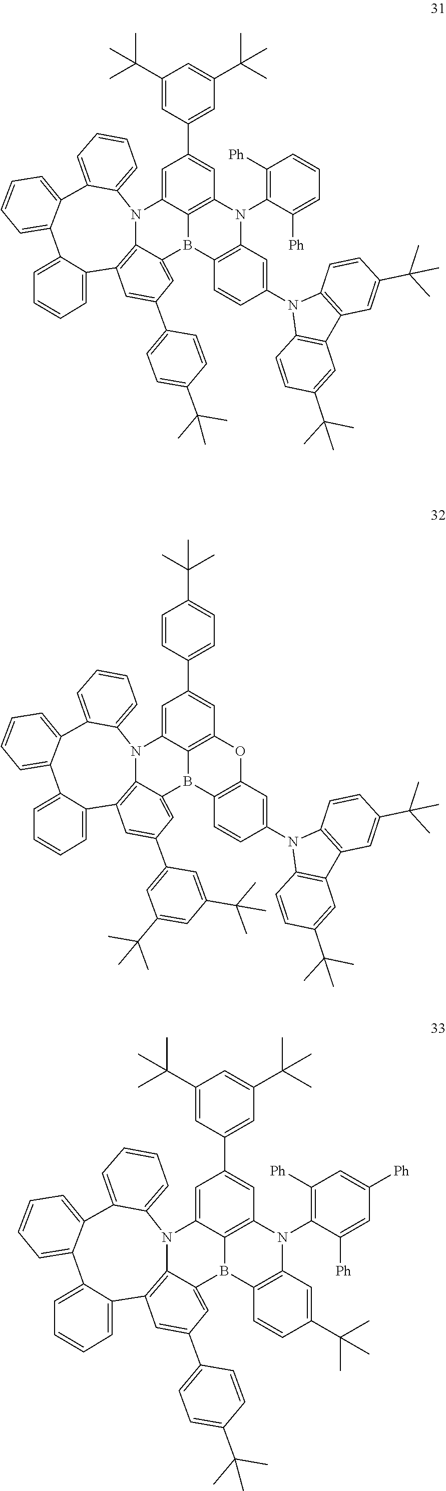 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1ccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cc(-c3ccccc3)cc2-c2ccccc2)cc1] 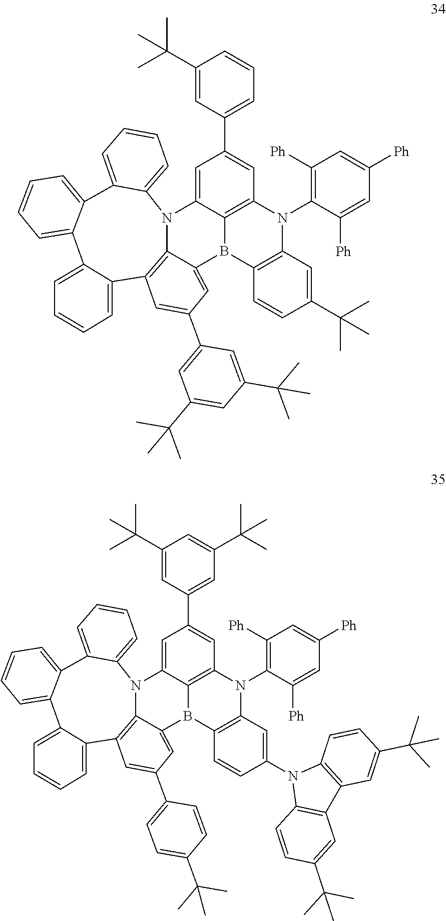 [SMILES: CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(C(C)(C)C)cc2N3c2c(-c3ccccc3)cc(-c3ccccc3)cc2-c2ccccc2)c1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc1] 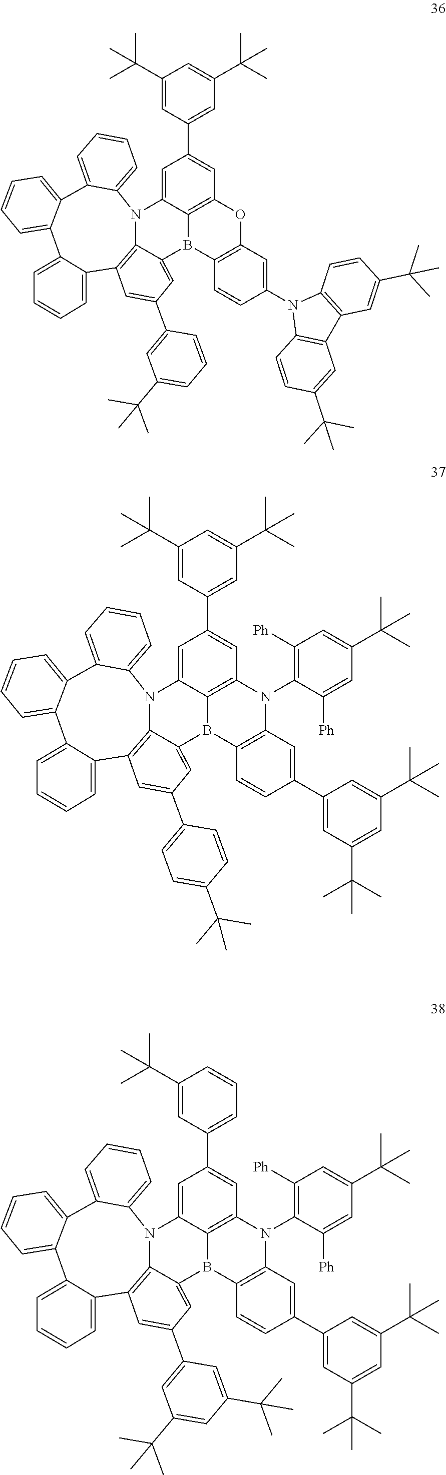 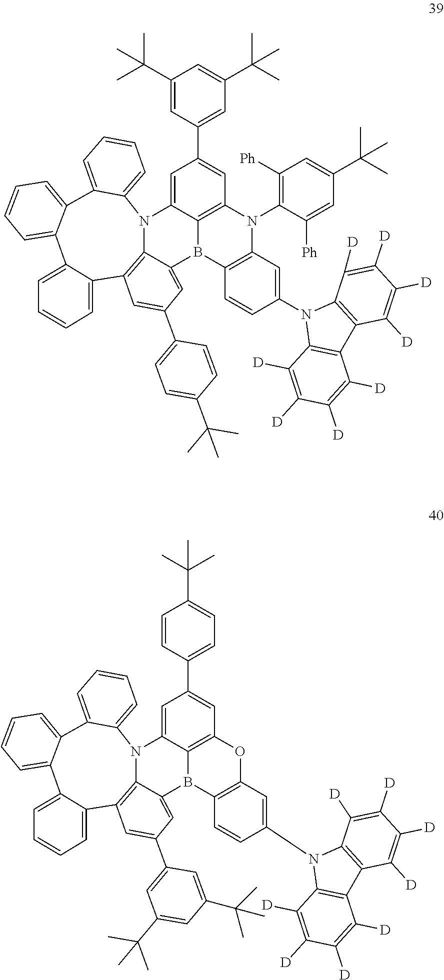 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-c3cc(C(C)(C)C)cc(C(C)(C)C)c3)cc3c1B2c1cc(-c2ccc(C(C)(C)C)cc2)cc2c4ccccc4c4ccccc4c4ccccc4n-3c12 ; [2H]c1c([2H])c([2H])c2c(c1[2H])c1c([2H])c([2H])c([2H])c([2H])c1n2-c1ccc2c(c1)Oc1cc(-c3ccc(C(C)(C)C)cc3)cc3c1B2c1cc(-c2cc(C(C)(C)C)cc(C(C)(C)C)c2)cc2c4ccccc4c4ccccc4c4ccccc4n-3c12] 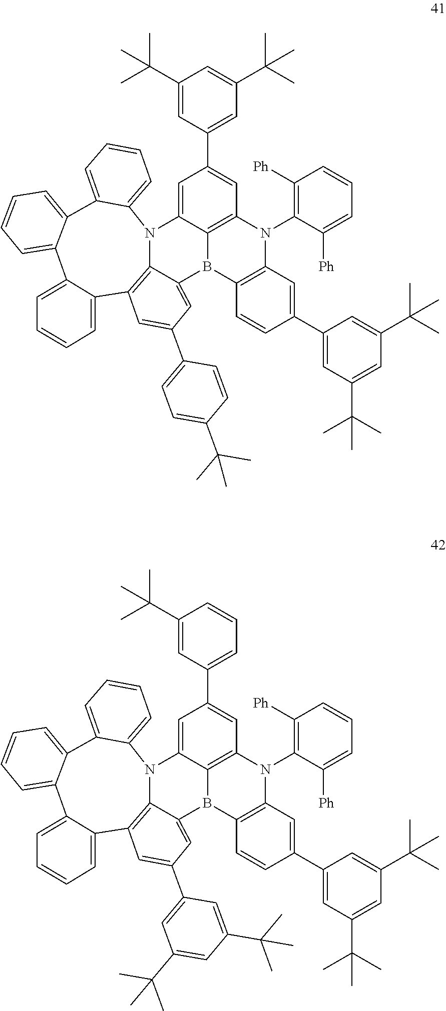 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cccc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-c4cc(C(C)(C)C)cc(C(C)(C)C)c4)cc2N3c2c(-c3ccccc3)cccc2-c2ccccc2)c1] 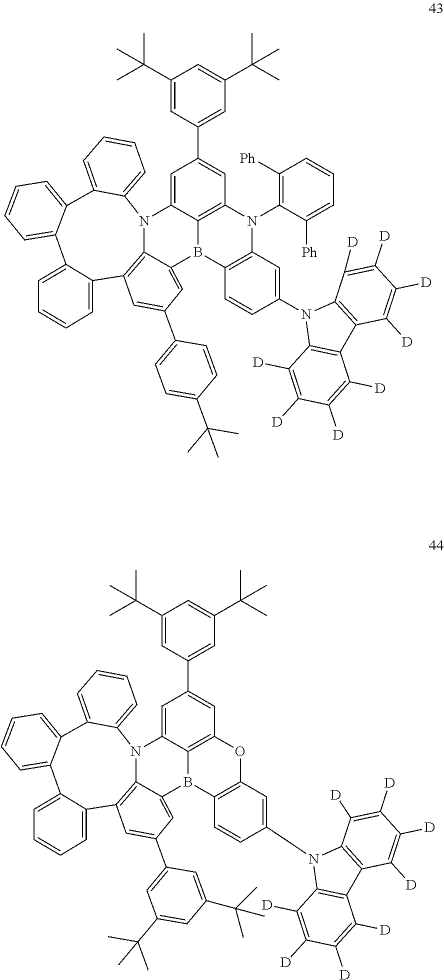 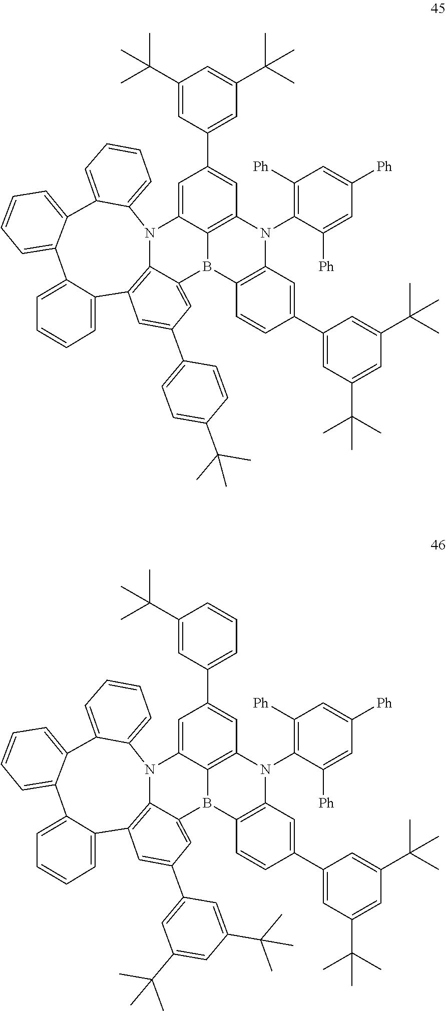 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(-c3ccccc3)cc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-c4cc(C(C)(C)C)cc(C(C)(C)C)c4)cc2N3c2c(-c3ccccc3)cc(-c3ccccc3)cc2-c2ccccc2)c1] 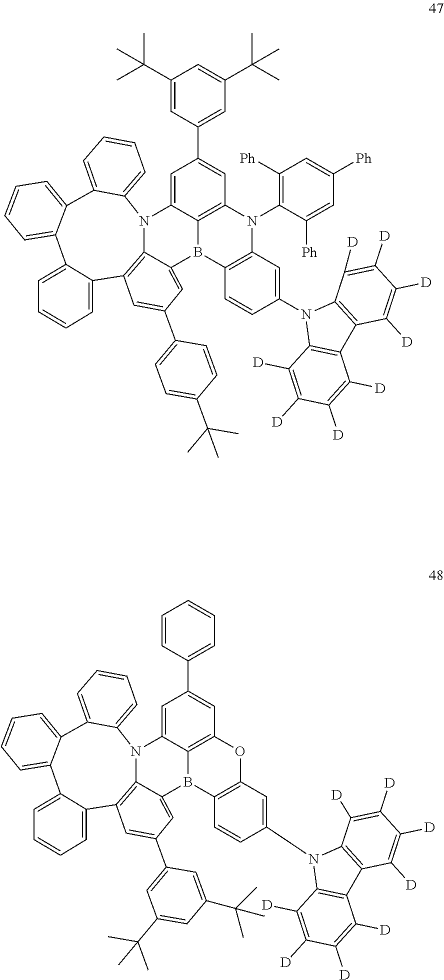 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-c3cc(C(C)(C)C)cc(C(C)(C)C)c3)cc3c1B2c1cc(-c2ccc(C(C)(C)C)cc2)cc2c4ccccc4c4ccccc4c4ccccc4n-3c12 ; [2H]c1c([2H])c([2H])c2c(c1[2H])c1c([2H])c([2H])c([2H])c([2H])c1n2-c1ccc2c(c1)Oc1cc(-c3ccccc3)cc3c1B2c1cc(-c2cc(C(C)(C)C)cc(C(C)(C)C)c2)cc2c4ccccc4c4ccccc4c4ccccc4n-3c12] 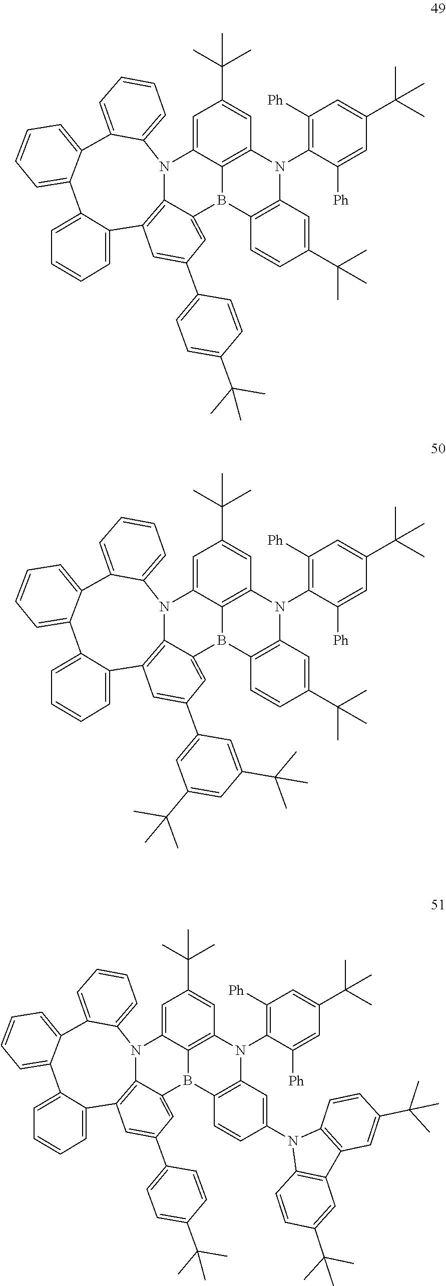 [SMILES: CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc1] 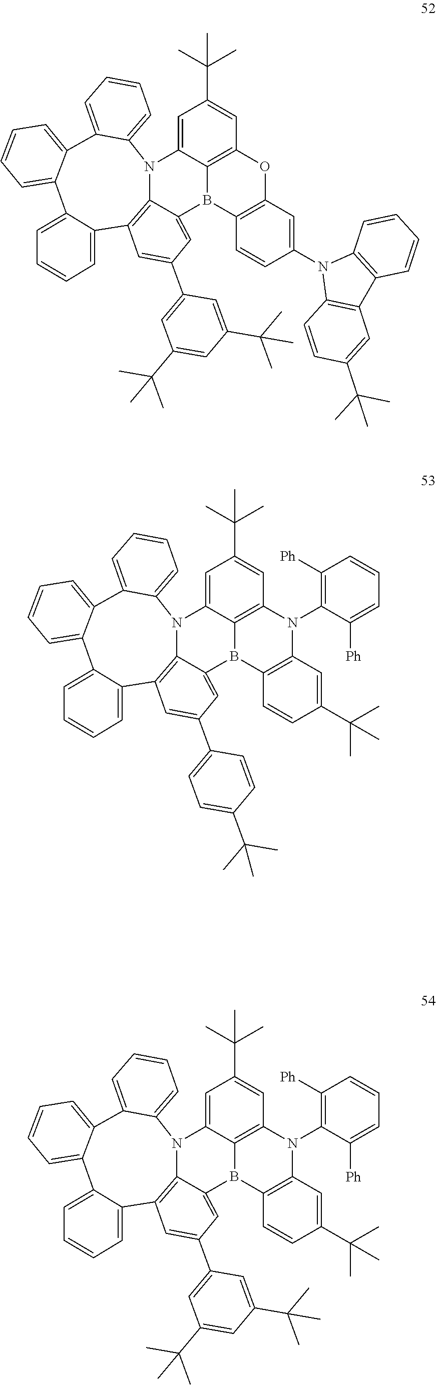 [SMILES: CC(C)(C)c1cc(-c2cc3c4c(c2)c2ccccc2c2ccccc2c2ccccc2n4-c2cc(C(C)(C)C)cc4c2B3c2ccc(-n3c5ccccc5c5cc(C(C)(C)C)ccc53)cc2O4)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc(C(C)(C)C)c1] 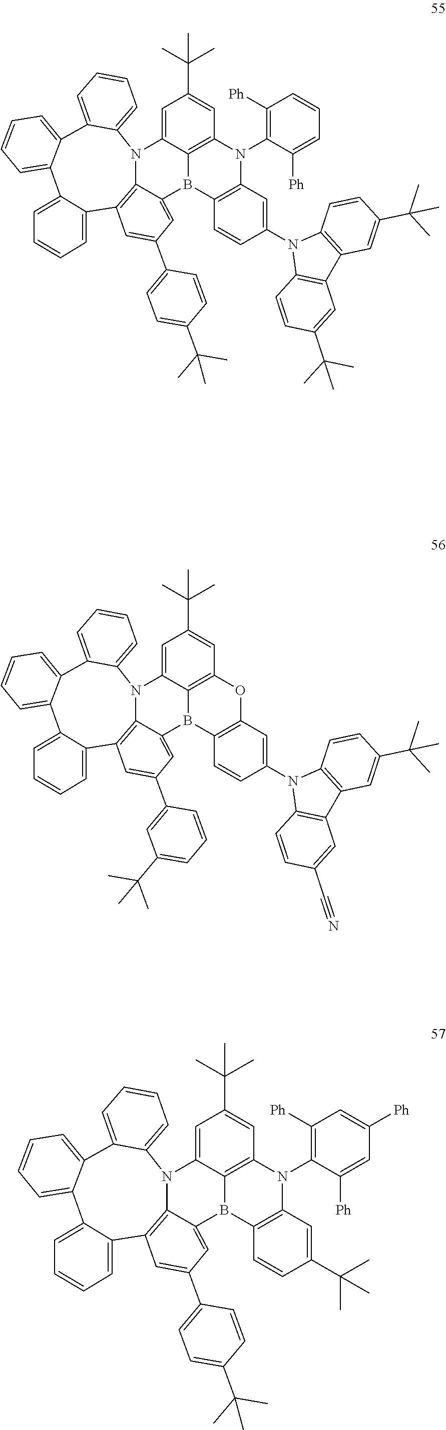 [SMILES: CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1cccc(-c2cc3c4c(c2)c2ccccc2c2ccccc2c2ccccc2n4-c2cc(C(C)(C)C)cc4c2B3c2ccc(-n3c5ccc(C#N)cc5c5cc(C(C)(C)C)ccc53)cc2O4)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc1] 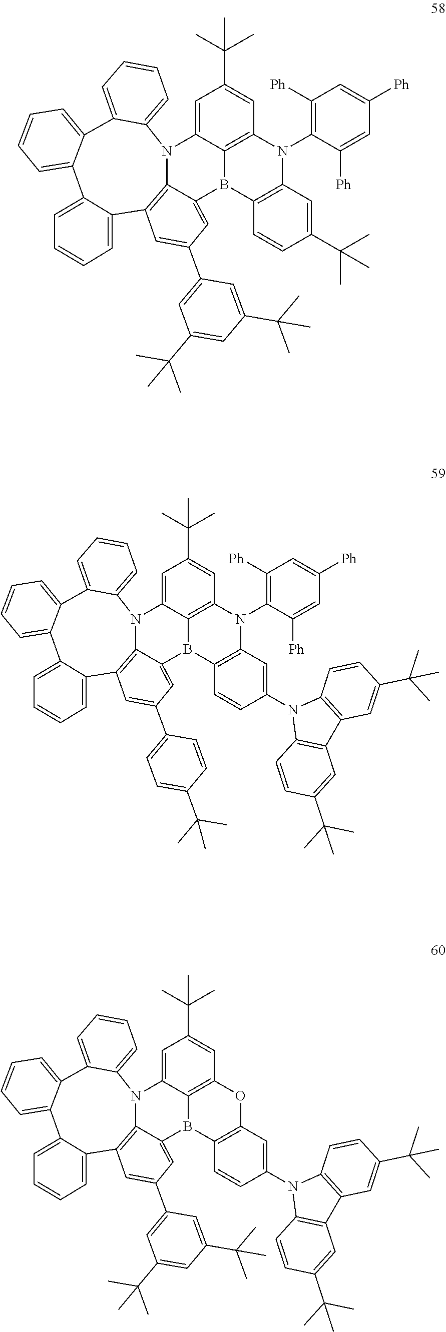 [SMILES: CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2O4)cc(C(C)(C)C)c1] 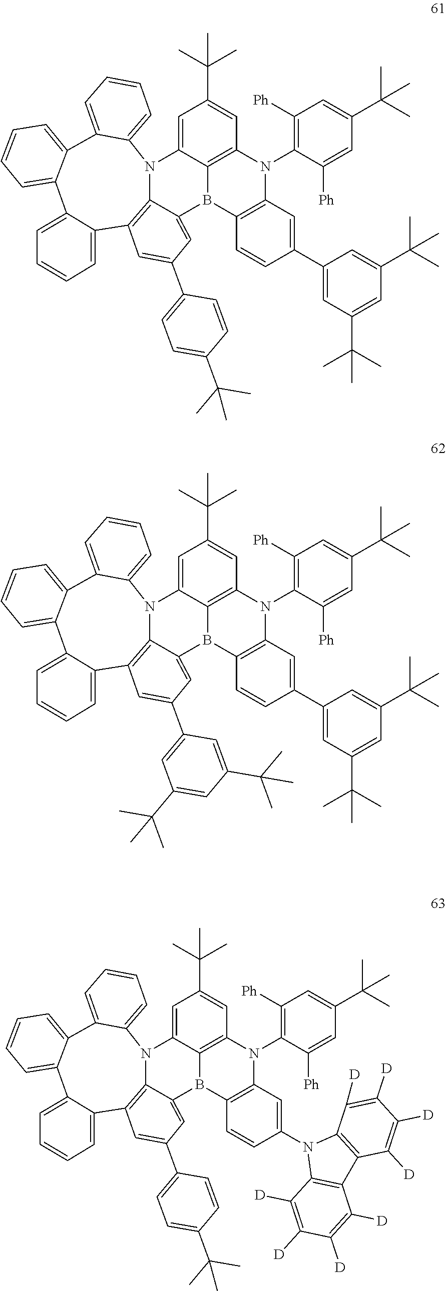 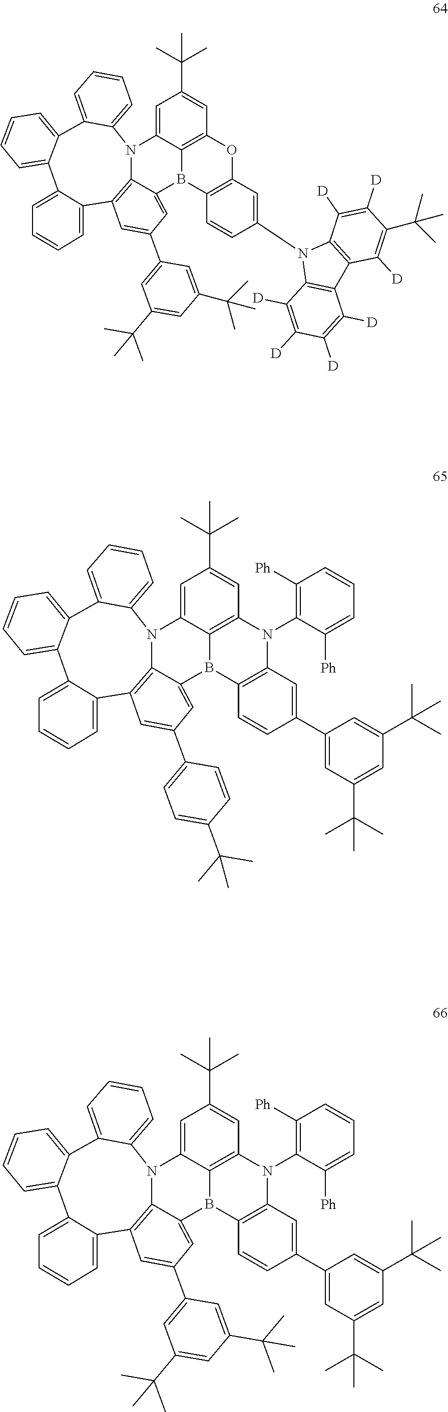 [SMILES: [2H]c1c([2H])c([2H])c2c(c1[2H])c1c([2H])c(C(C)(C)C)c([2H])c([2H])c1n2-c1ccc2c(c1)Oc1cc(C(C)(C)C)cc3c1B2c1cc(-c2cc(C(C)(C)C)cc(C(C)(C)C)c2)cc2c4ccccc4c4ccccc4c4ccccc4n-3c12 ; CC(C)(C)c1ccc(-c2cc3c4c(c2)c2ccccc2c2ccccc2c2ccccc2n4-c2cc(C(C)(C)C)cc4c2B3c2ccc(-c3cc(C(C)(C)C)cc(C(C)(C)C)c3)cc2N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(C(C)(C)C)cc4c2B3c2cc(-c3cc(C(C)(C)C)cc(C(C)(C)C)c3)cc3c5ccccc5c5ccccc5c5ccccc5n-4c23)cc(C(C)(C)C)c1] 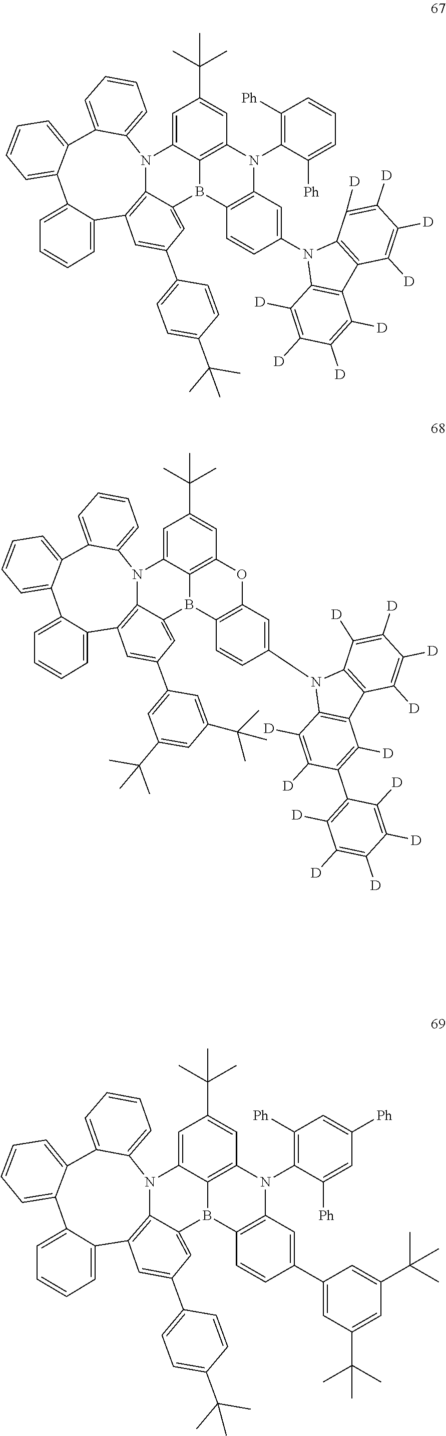 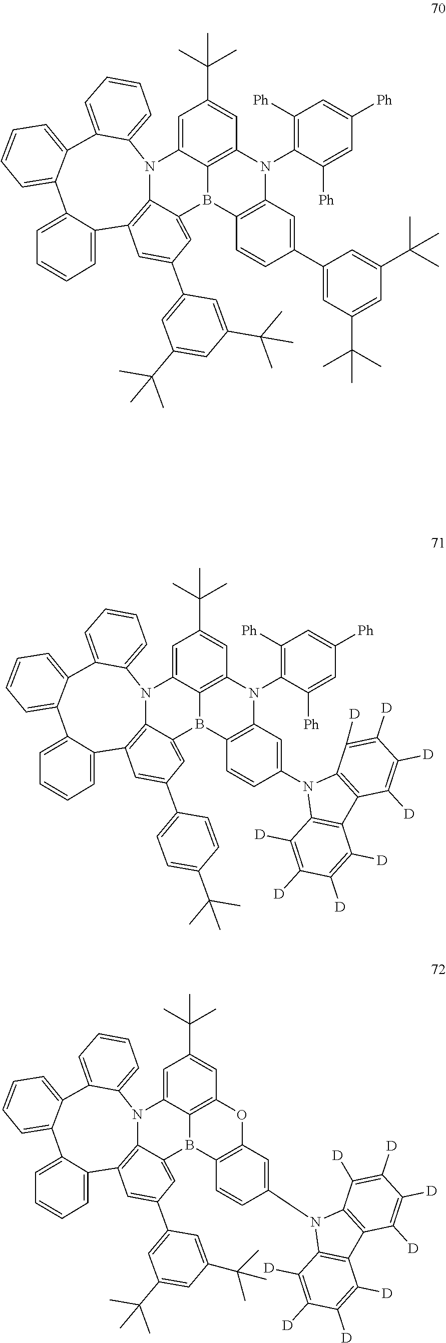 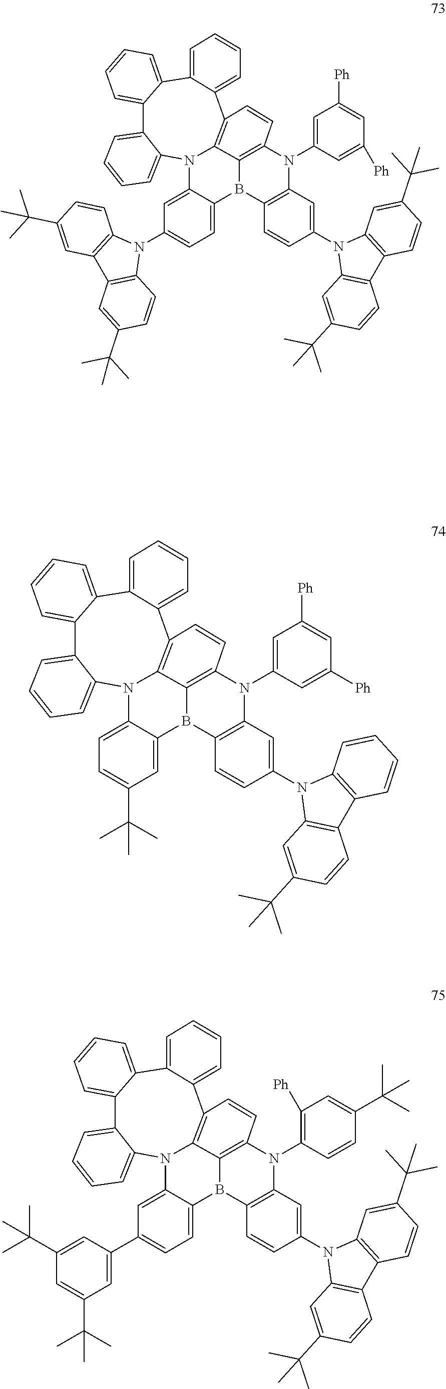 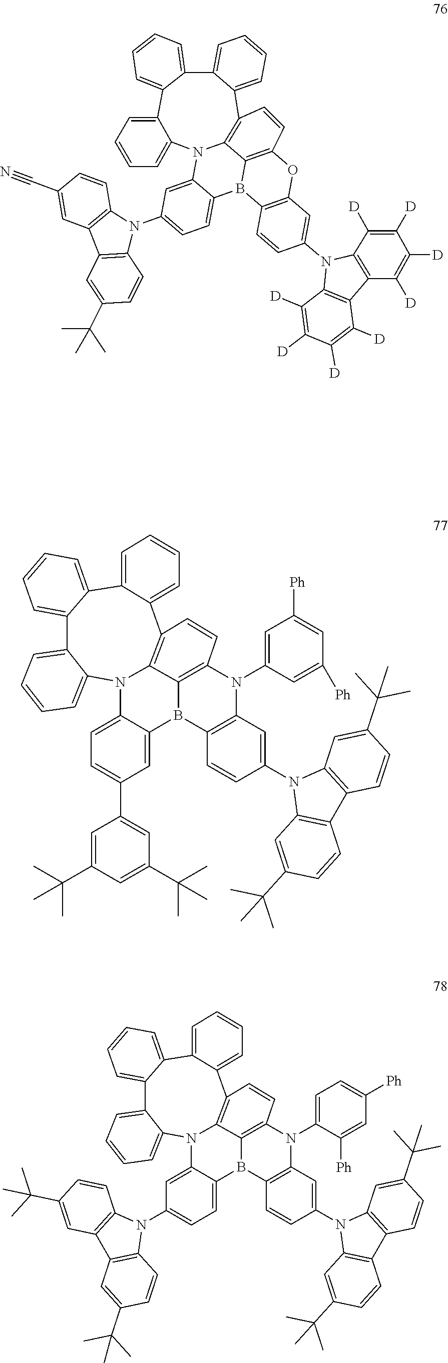 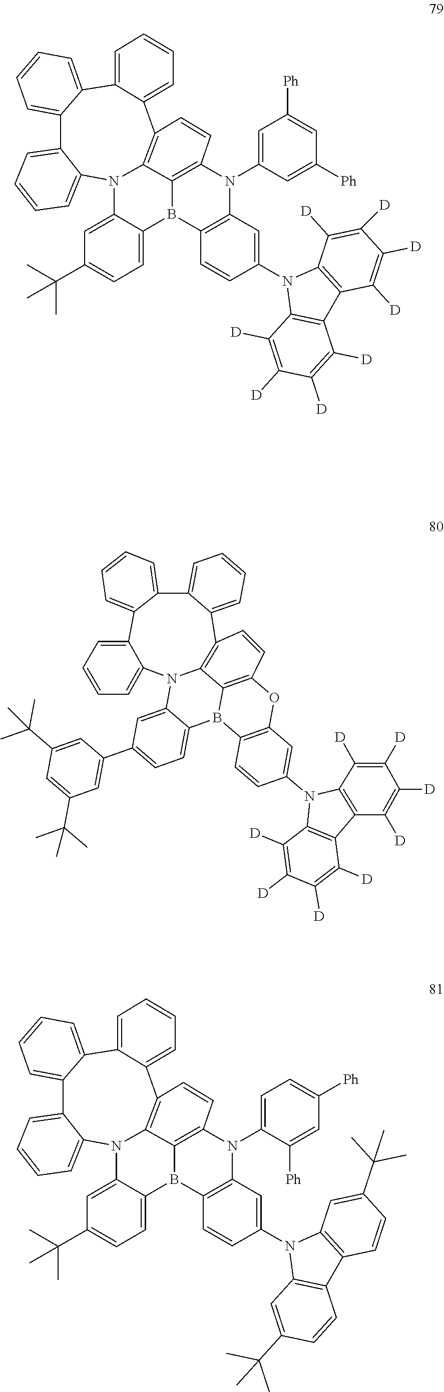 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1ccc(-c2ccccc2)cc1-c1ccccc1] 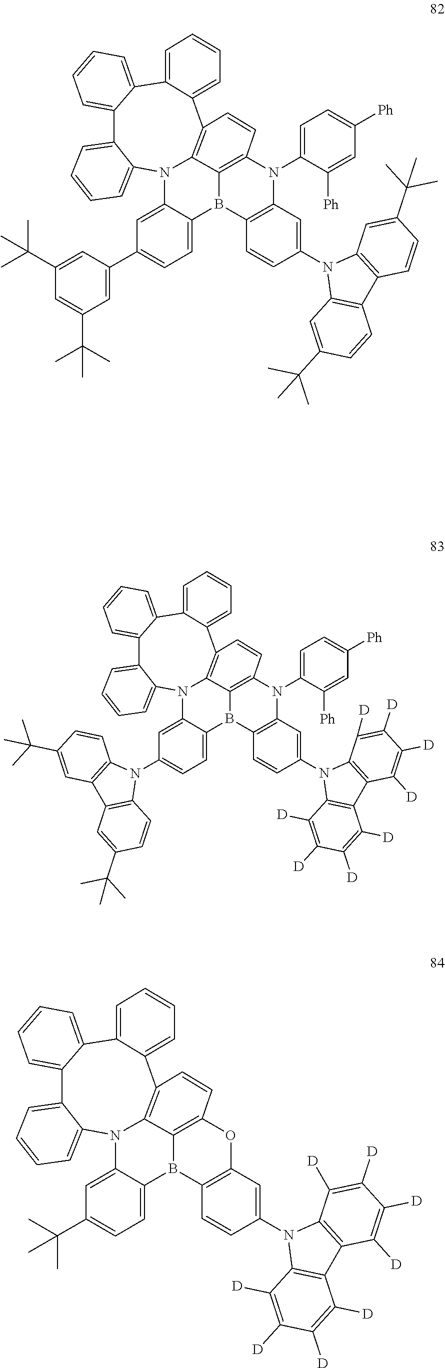 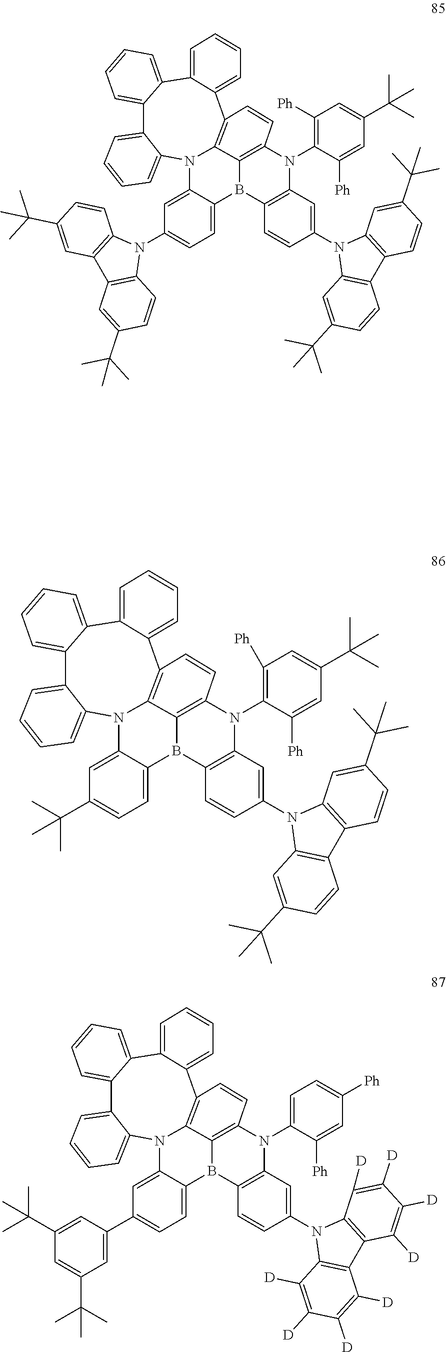 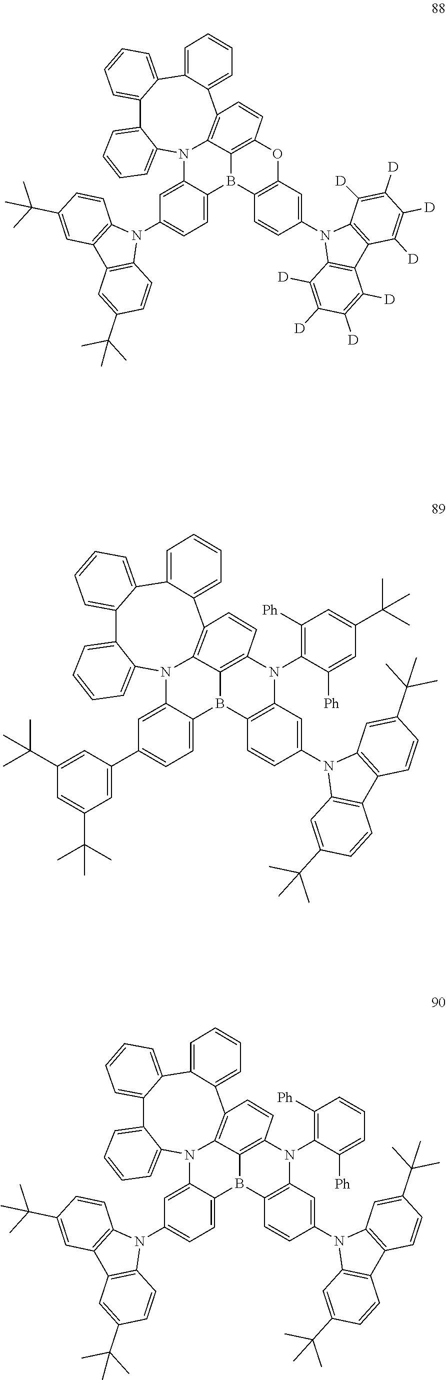 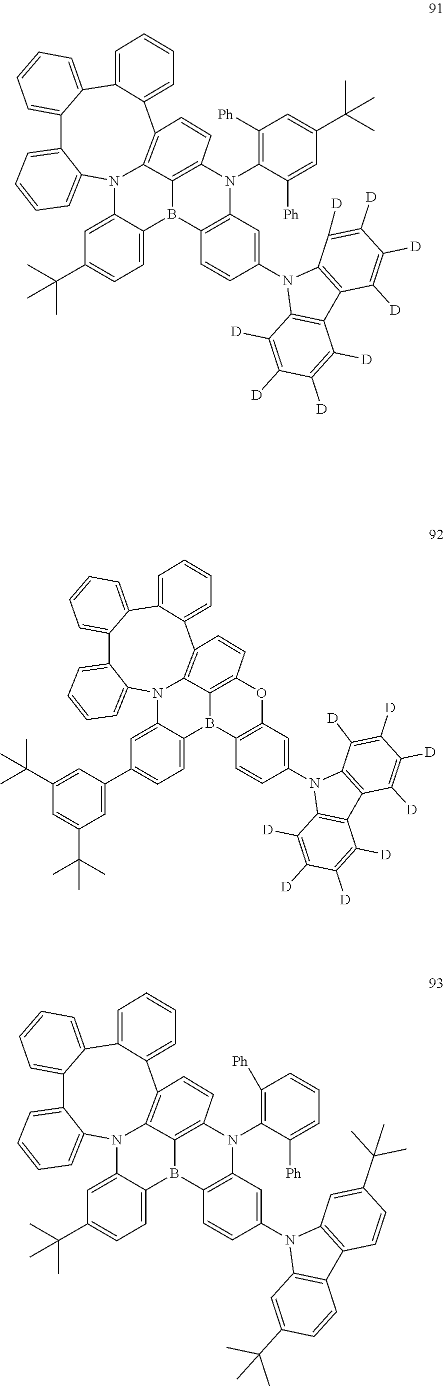 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1c(-c2ccccc2)cccc1-c1ccccc1] 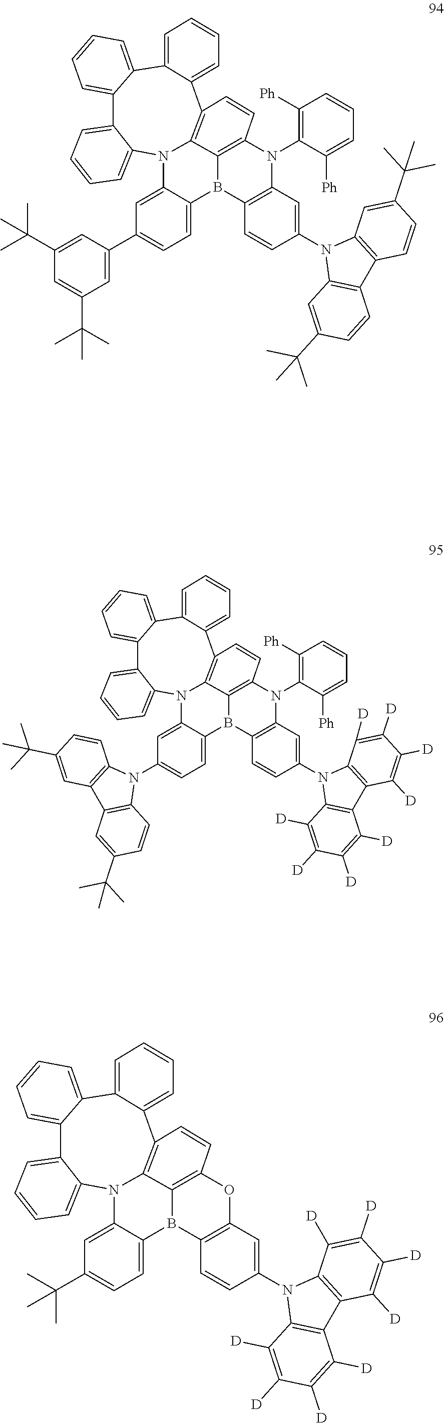 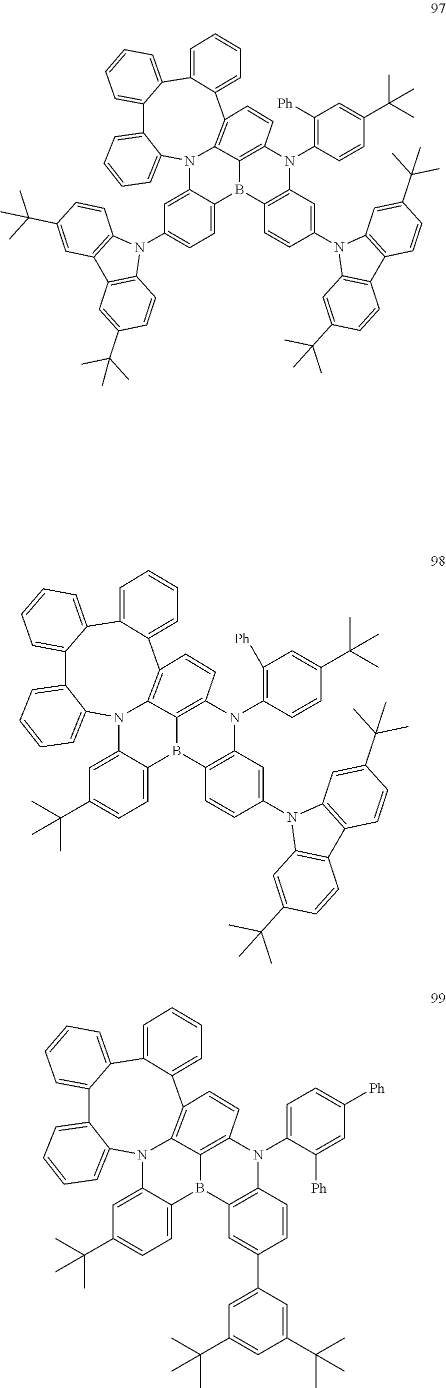 [SMILES: CC(C)(C)c1ccc(N2c3cc(-n4c5cc(C(C)(C)C)ccc5c5ccc(C(C)(C)C)cc54)ccc3B3c4ccc(-n5c6ccc(C(C)(C)C)cc6c6cc(C(C)(C)C)ccc65)cc4-n4c5ccccc5c5ccccc5c5ccccc5c5ccc2c3c54)c(-c2ccccc2)c1 ; CC(C)(C)c1ccc(N2c3cc(-n4c5cc(C(C)(C)C)ccc5c5ccc(C(C)(C)C)cc54)ccc3B3c4ccc(C(C)(C)C)cc4-n4c5ccccc5c5ccccc5c5ccccc5c5ccc2c3c54)c(-c2ccccc2)c1 ; CC(C)(C)c1cc(-c2ccc3c(c2)B2c4ccc(C(C)(C)C)cc4-n4c5ccccc5c5ccccc5c5ccccc5c5ccc(c2c54)N3c2ccc(-c3ccccc3)cc2-c2ccccc2)cc(C(C)(C)C)c1] 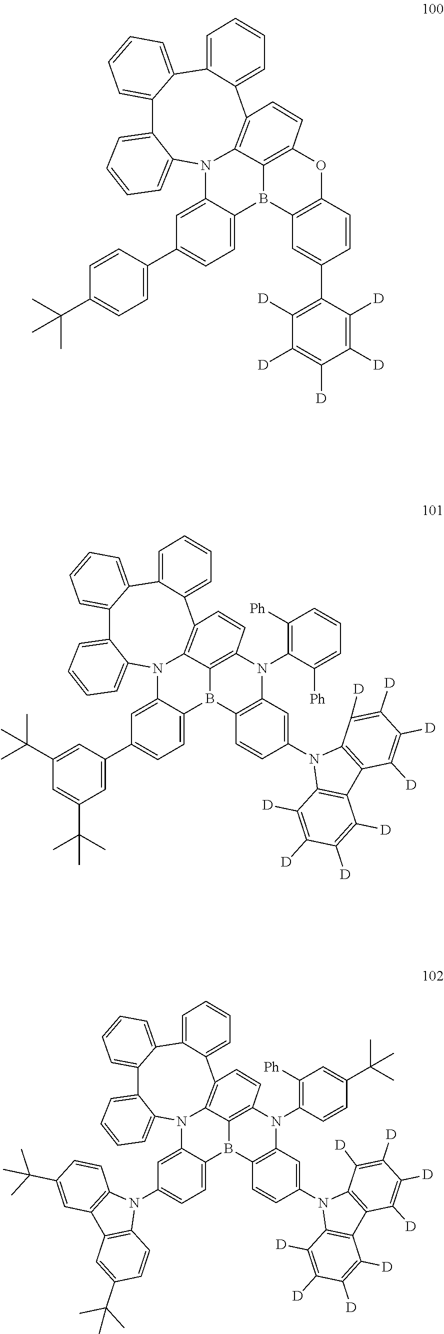 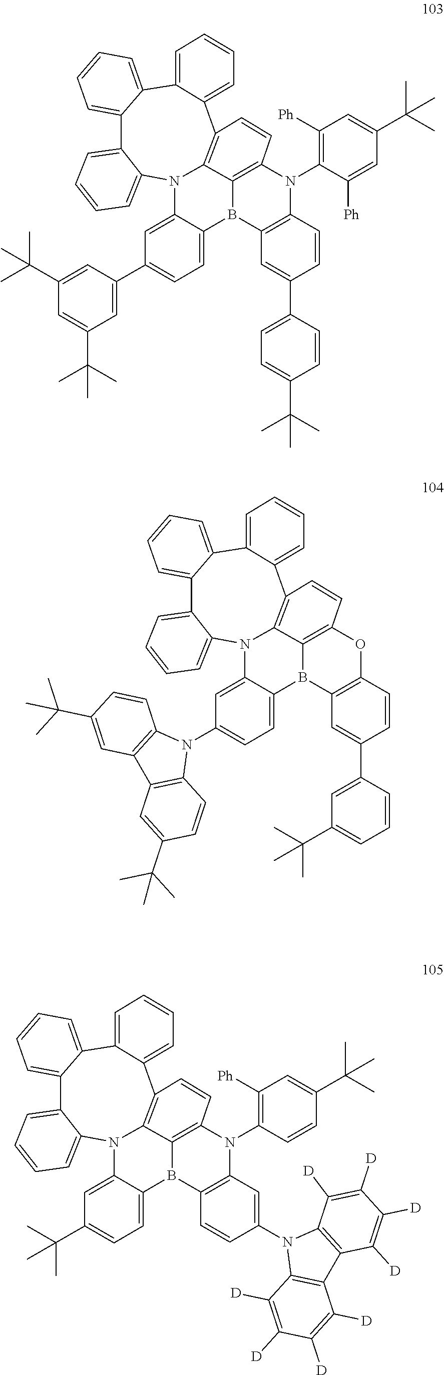 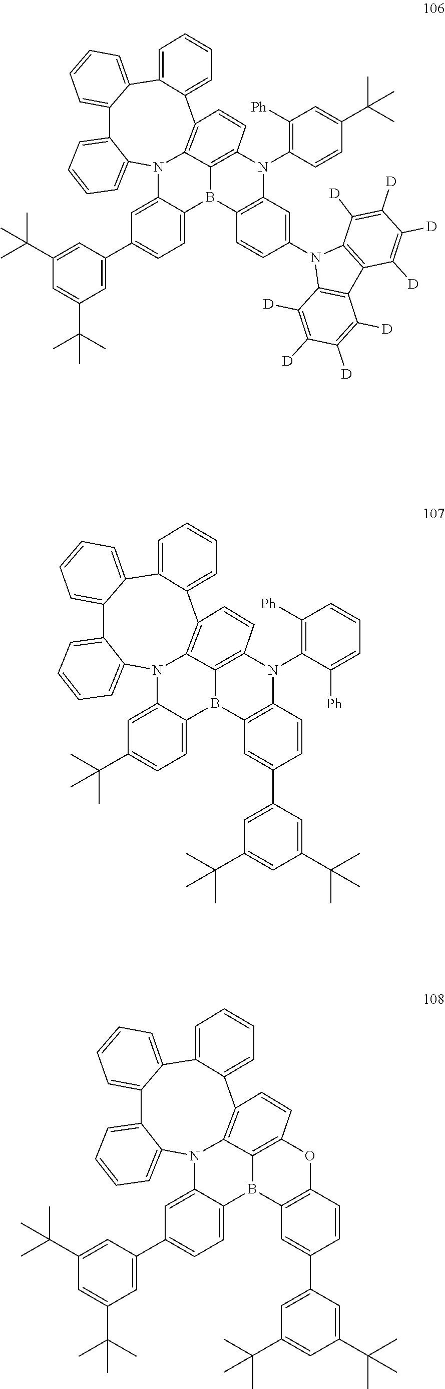 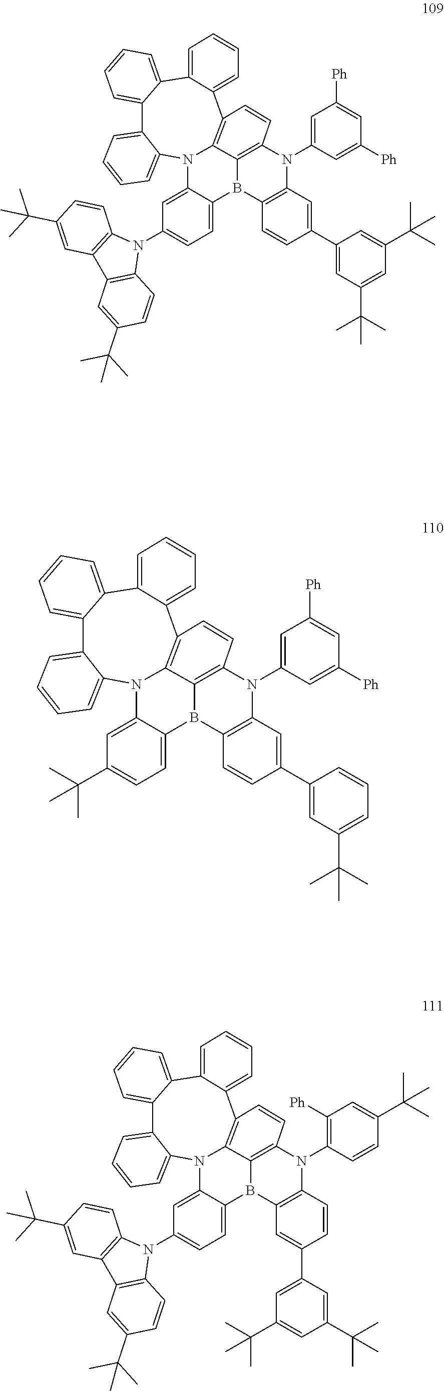 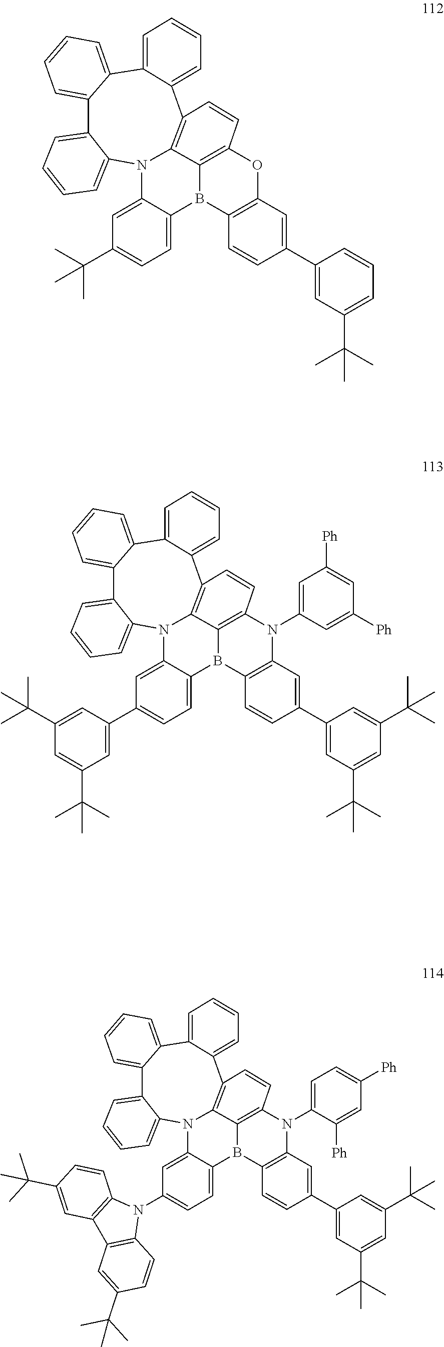 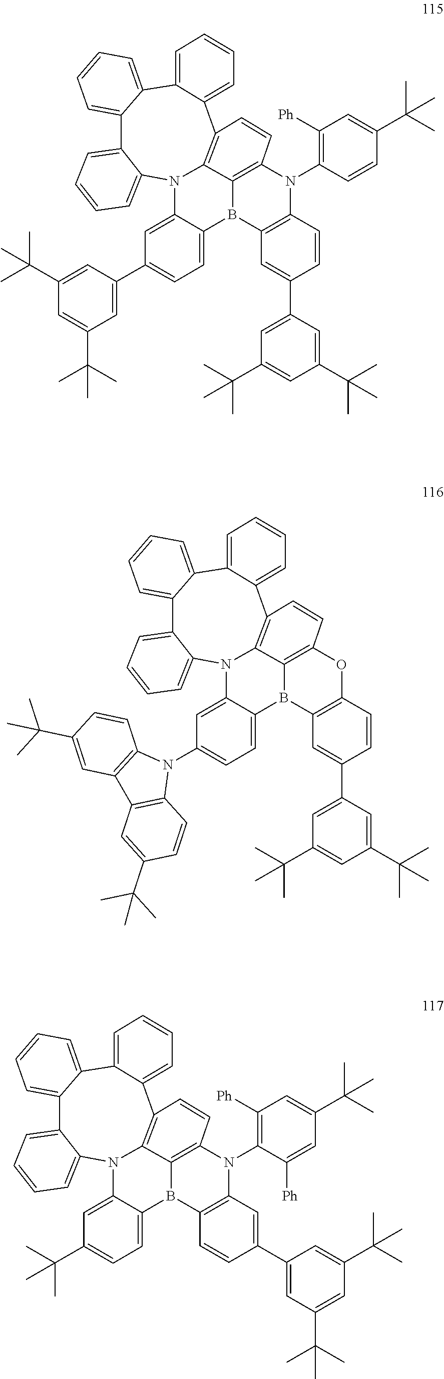 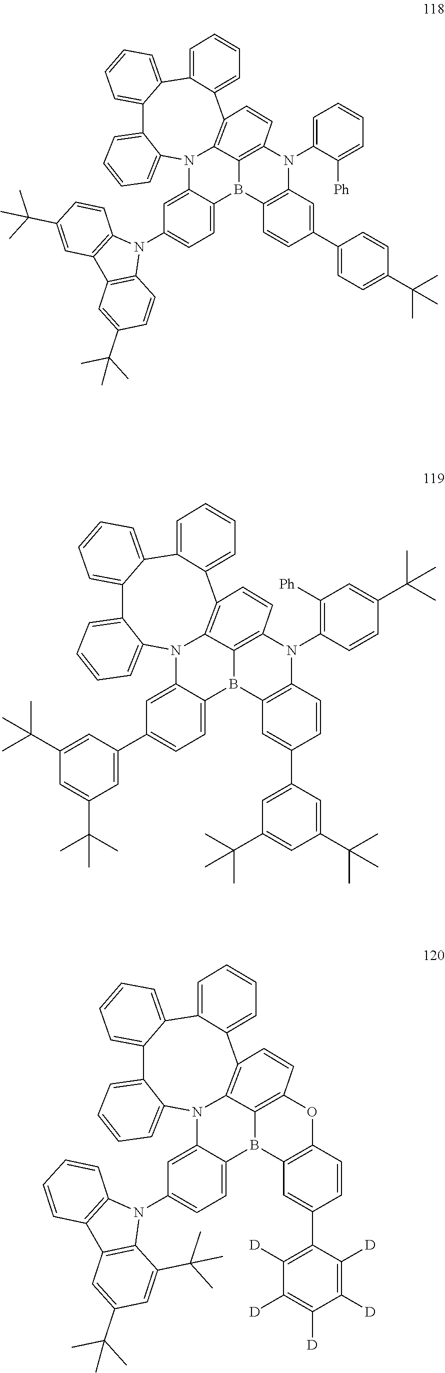
wherein in Compound Group 1, D is a deuterium atom, and Ph is a phenyl group.

13. A fused polycyclic compound represented by Formula 1: 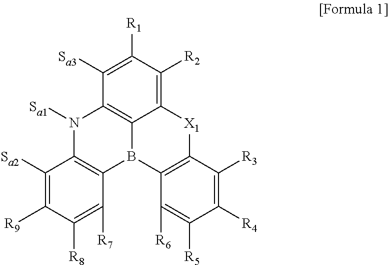
wherein in Formula 1,
X₁ is NR₁₀ or O,
R₁ to R₁₀ are each independently a hydrogen atom, a deuterium atom, a halogen atom, a cyano group, a substituted or unsubstituted amine group, a substituted or unsubstituted silyl group, a substituted or unsubstituted alkyl group having 1 to 30 carbon atoms, a substituted or unsubstituted aryl group having 6 to 60 ring-forming carbon atoms, or a substituted or unsubstituted heterocyclic group having 2 to 60 ring-forming carbon atoms,
wherein,
a first substituent represented by Formula 2 is bonded to Sₐ₁ and Sₐ₂, and Sₐ₃ is a hydrogen atom, or
the first substituent represented by Formula 2 is bonded to Sₐ₁ and Sₐ₃, and Sₐ₂ is a hydrogen atom: 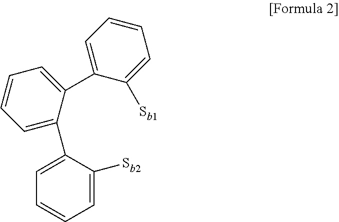
wherein in Formula 2,
S_{b1} and S_{b2} are positions bonded to Formula 1.

14. The fused polycyclic compound of claim 13, wherein Formula 1 is represented by Formula 1-1 or Formula 1-2: 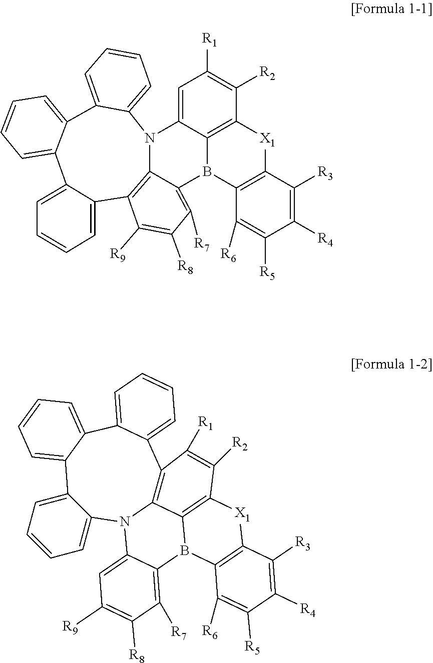
wherein in Formulas 1-1 and 1-2,
R₁ to R₉, and X₁ are the same as defined in Formula 1.

15. The fused polycyclic compound of claim 14, wherein Formula 1-1 is represented by Formula 1-1A: 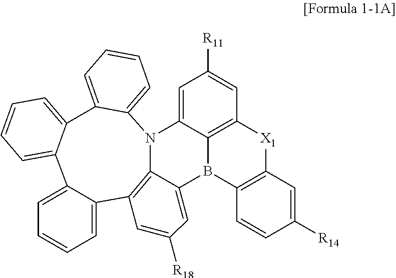
wherein in Formula 1-1A,
R₁₁, R₁₄, and R₁₈ are each independently a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and
X₁ is the same as defined in Formula 1-1.

16. The fused polycyclic compound of claim 14, wherein Formula 1-2 is represented by any one of among Formulas 1-2A to 1-2C: 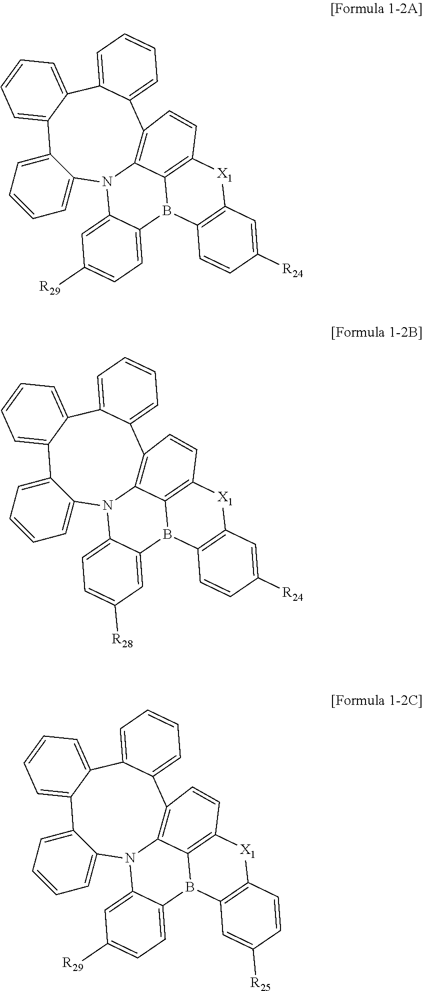
wherein in Formulas 1-2A to 1-2C,
R₂₄, R₂₅, R₂₈, and R₂₉ are each independently a substituted or unsubstituted alkyl group having 1 to 10 carbon atoms, a substituted or unsubstituted aryl group having 6 to 15 ring-forming carbon atoms, or a substituted or unsubstituted heterocyclic group having 2 to 15 ring-forming carbon atoms, and
X₁ is the same as defined in Formula 1-2.

17. The fused polycyclic compound of claim 13, wherein in Formula 1, X₁ is NR₁₀, and R₁₀ is represented by any one of among R10-1 to R10-4:

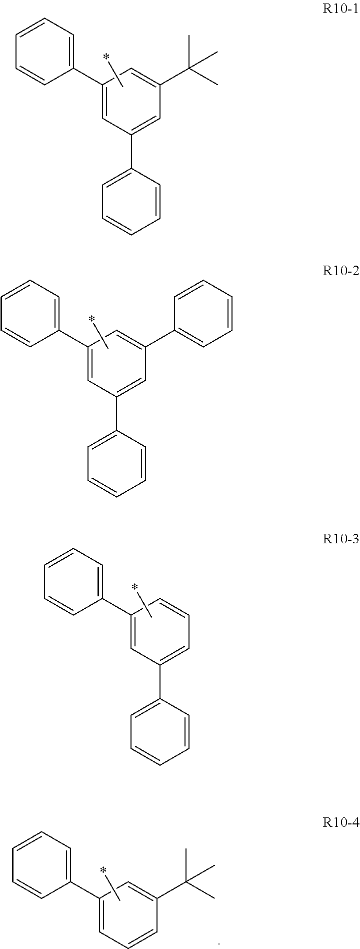

18. The fused polycyclic compound of claim 13, wherein in Formula 1, R₁ to R₉ are each independently a hydrogen atom or represented by any one of among R-1 to R-19: 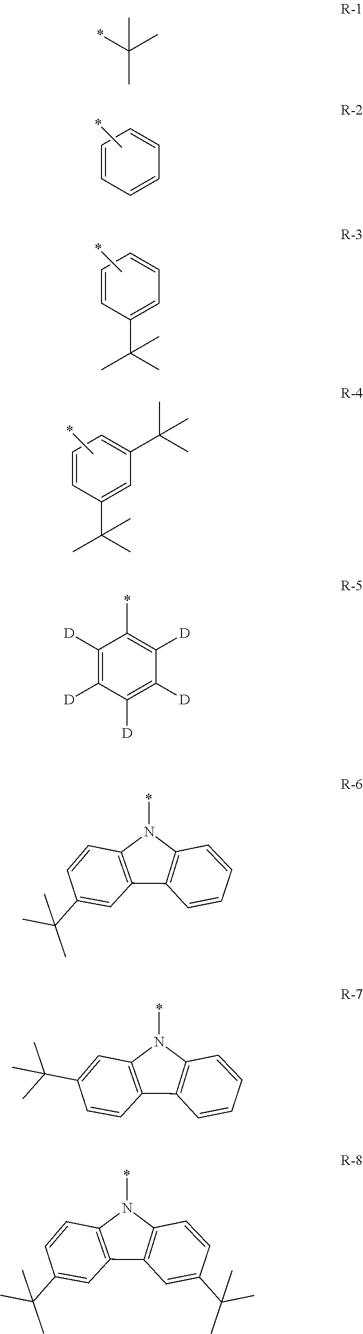 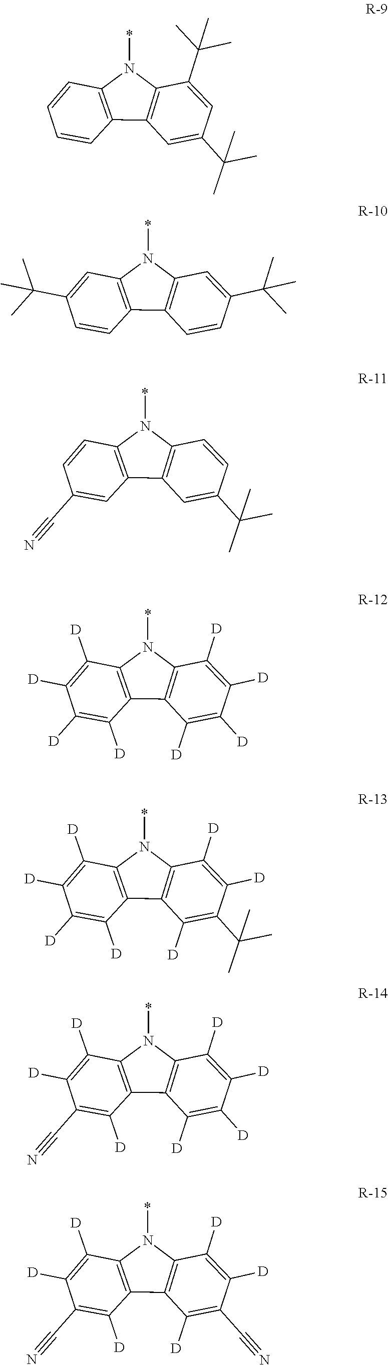 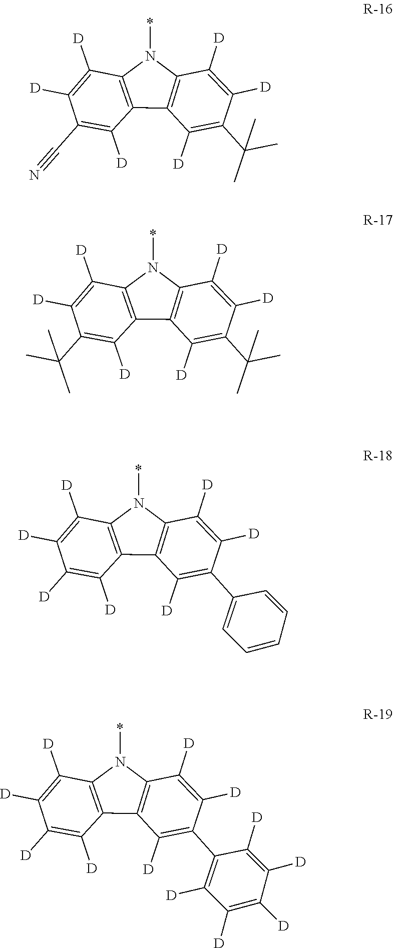
wherein in R-12 and R-19, D is a deuterium atom.

19. The fused polycyclic compound of claim 18, wherein in Formula 1, at least one of R₁ to R₉ is represented by any one of among R-6 to R-19.

20. The fused polycyclic compound of claim 13, wherein in Formula 1, at least one of R₁ to R₉ is a carbazole group substituted with at least one of a deuterium atom, a cyano group, an unsubstituted t-butyl group, an unsubstituted phenyl group, or a substituted phenyl group, or an unsubstituted carbazole group.

21. The fused polycyclic compound of claim 13, wherein in Formula 1, at least one of R₁ to R₉ is a deuterium atom or comprises a substituent containing a deuterium atom.

22. The fused polycyclic compound of claim 13, wherein Formula 1 is represented by any one of among compounds of Compound Group 1: 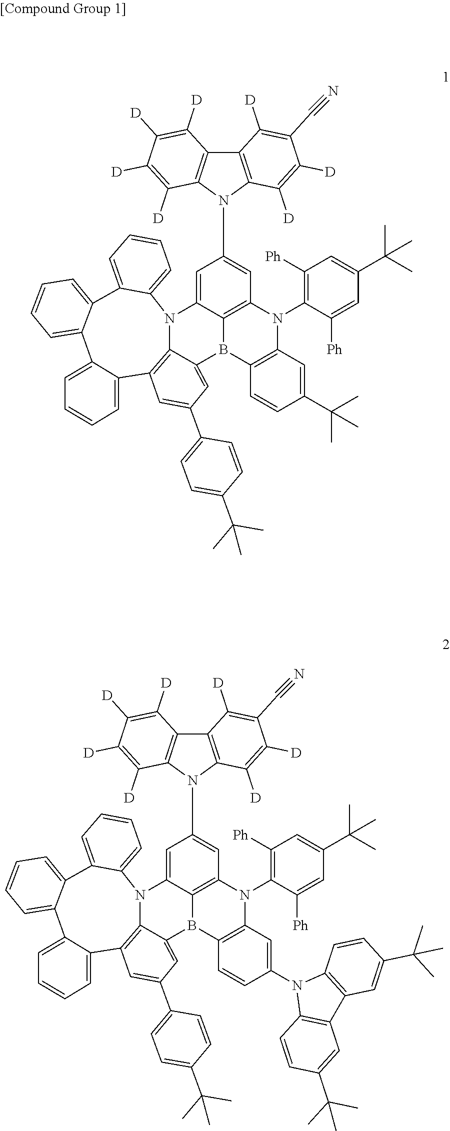 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(C(C)(C)C)cc1N2c1c(-c2ccccc2)cc(C(C)(C)C)cc1-c1ccccc1 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-n3c4ccc(C(C)(C)C)cc4c4cc(C(C)(C)C)ccc43)cc1N2c1c(-c2ccccc2)cc(C(C)(C)C)cc1-c1ccccc1] 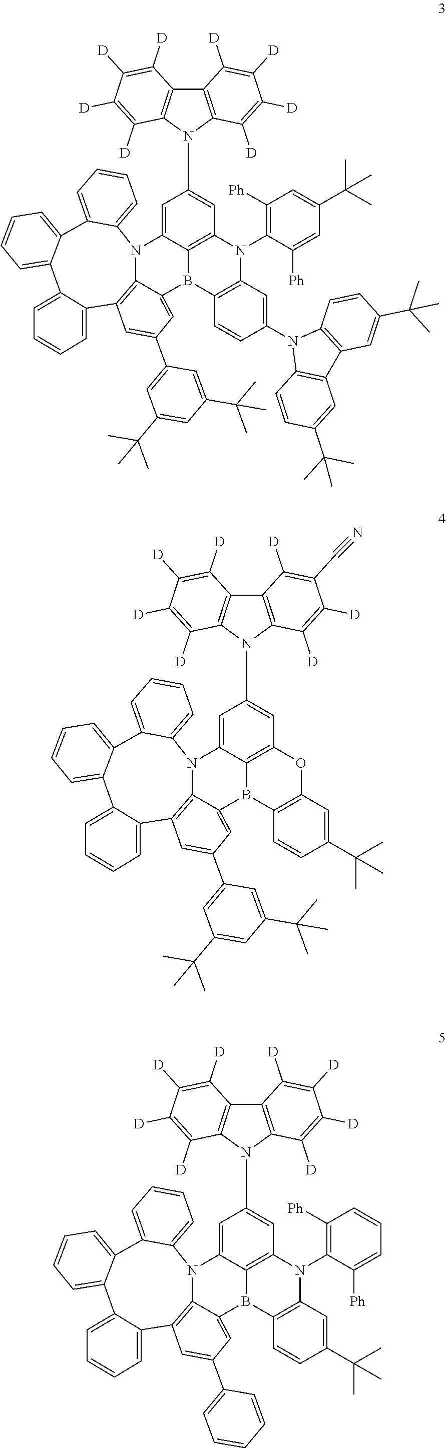 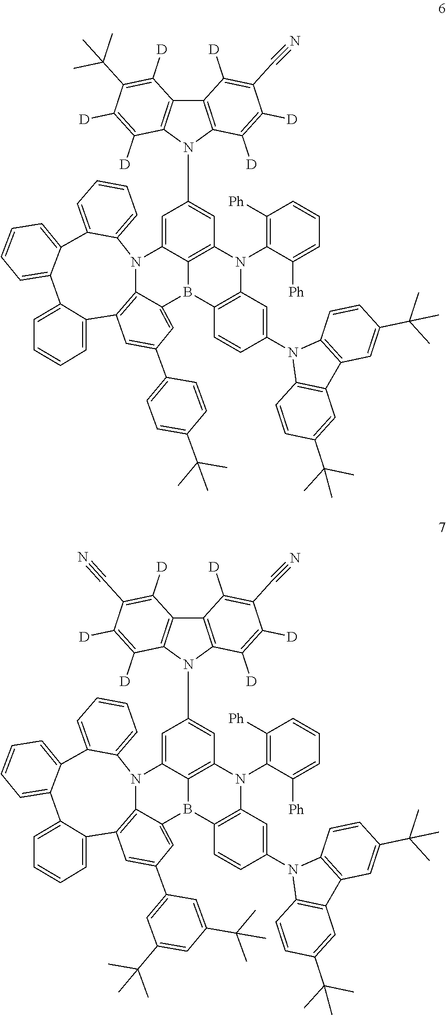 [SMILES: [2H]c1c(C#N)c([2H])c2c3c([2H])c(C(C)(C)C)c([2H])c([2H])c3n(-c3cc4c5c(c3)-n3c6ccccc6c6ccccc6c6ccccc6c6cc(-c7ccc(C(C)(C)C)cc7)cc(c63)B5c3ccc(-n5c6ccc(C(C)(C)C)cc6c6cc(C(C)(C)C)ccc65)cc3N4c3c(-c4ccccc4)cccc3-c3ccccc3)c2c1[2H] ; [2H]c1c(C#N)c([2H])c2c3c([2H])c(C#N)c([2H])c([2H])c3n(-c3cc4c5c(c3)-n3c6ccccc6c6ccccc6c6ccccc6c6cc(-c7cc(C(C)(C)C)cc(C(C)(C)C)c7)cc(c63)B5c3ccc(-n5c6ccc(C(C)(C)C)cc6c6cc(C(C)(C)C)ccc65)cc3N4c3c(-c4ccccc4)cccc3-c3ccccc3)c2c1[2H]] 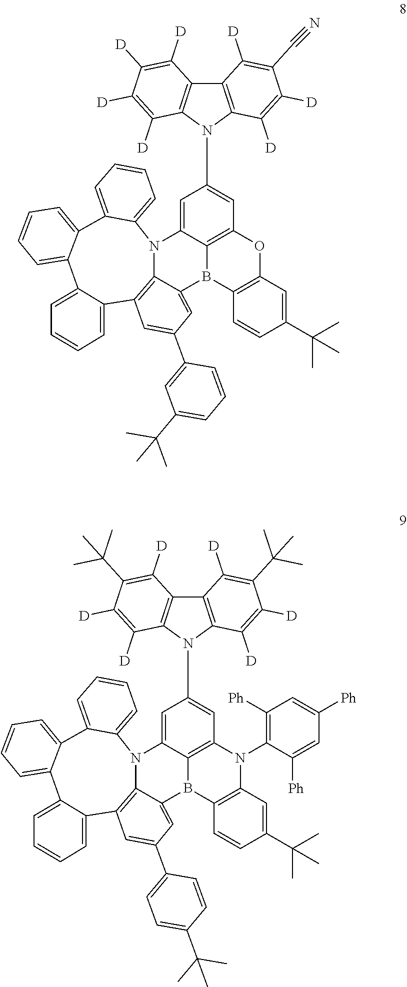 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(C(C)(C)C)cc1O2 ; [2H]c1c(C(C)(C)C)c([2H])c2c3c([2H])c(C(C)(C)C)c([2H])c([2H])c3n(-c3cc4c5c(c3)-n3c6ccccc6c6ccccc6c6ccccc6c6cc(-c7ccc(C(C)(C)C)cc7)cc(c63)B5c3ccc(C(C)(C)C)cc3N4c3c(-c4ccccc4)cc(-c4ccccc4)cc3-c3ccccc3)c2c1[2H]] 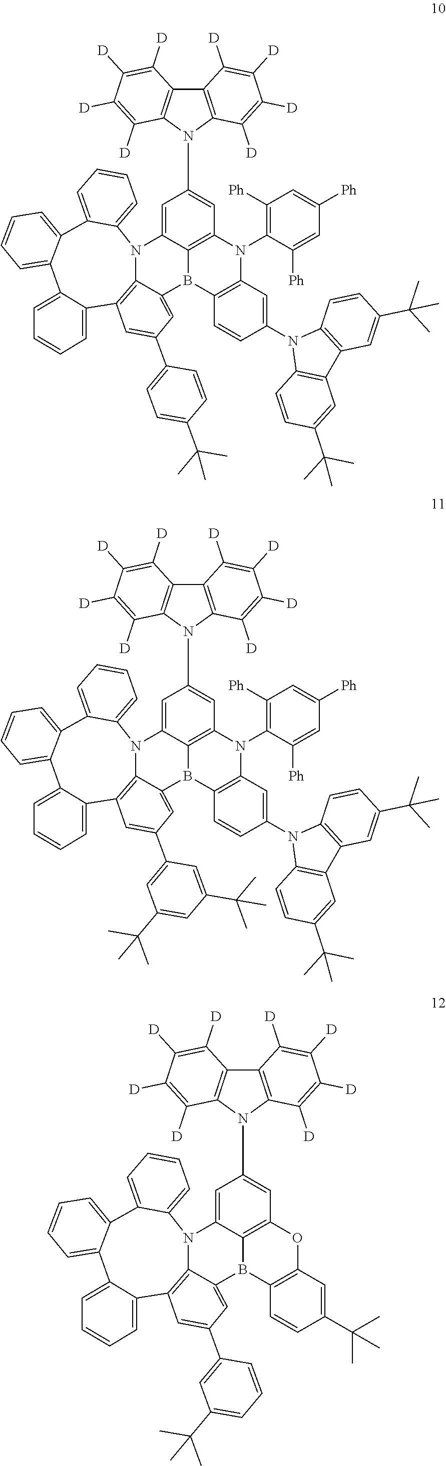 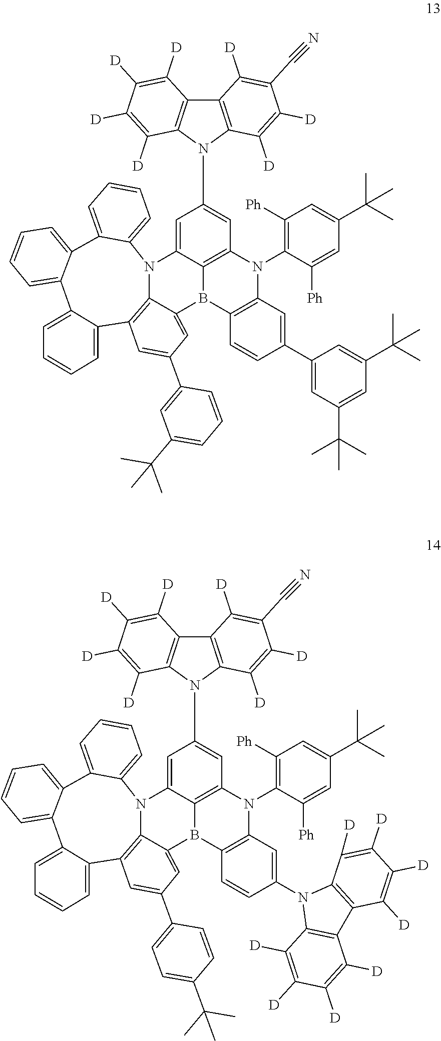 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cc(C(C)(C)C)cc(C(C)(C)C)c3)cc1N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2ccc(C(C)(C)C)cc2)cc2c4ccccc4c4ccccc4c4ccccc4n-3c12] 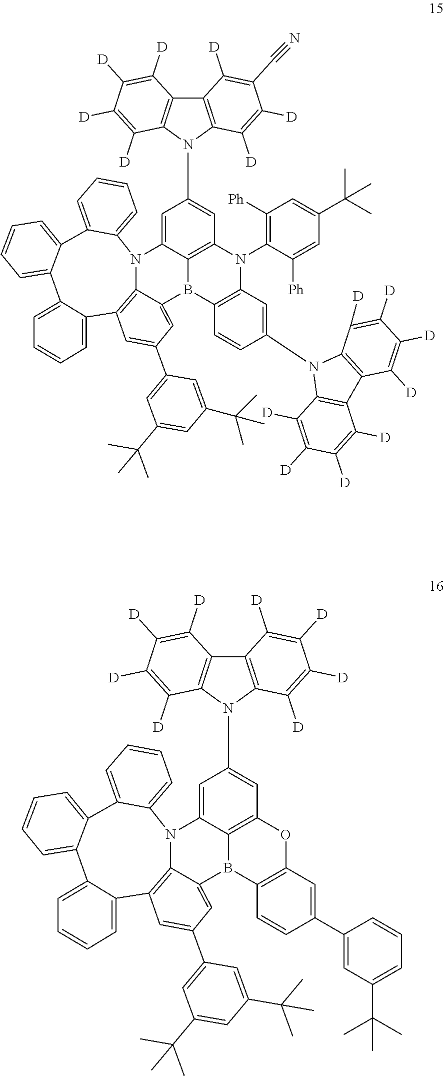 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c([2H])c([2H])c([2H])c1n2-c1cc2c3c(c1)-n1c4ccccc4c4ccccc4c4ccccc4c4cc(-c5cc(C(C)(C)C)cc(C(C)(C)C)c5)cc(c41)B3c1ccc(-c3cccc(C(C)(C)C)c3)cc1O2] 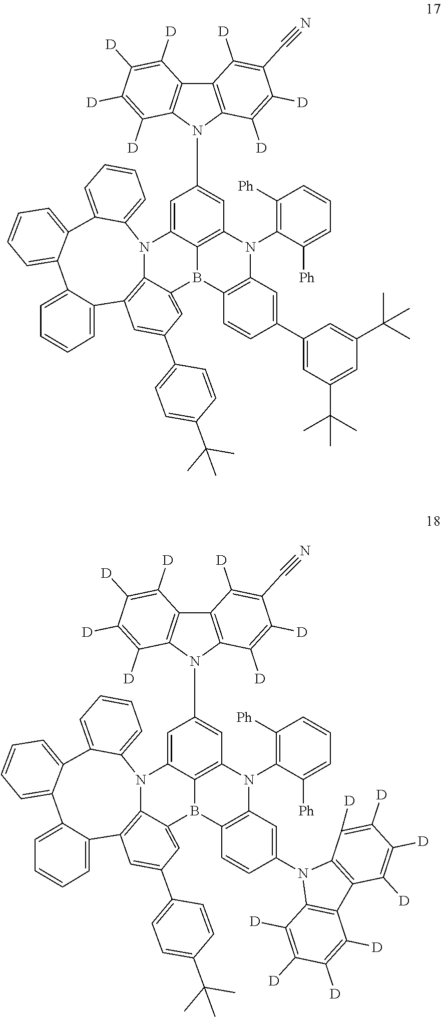 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cc(C(C)(C)C)cc(C(C)(C)C)c3)cc1N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(C#N)c([2H])c([2H])c43)cc3c1B2c1cc(-c2ccc(C(C)(C)C)cc2)cc2c4ccccc4c4ccccc4c4ccccc4n-3c12] 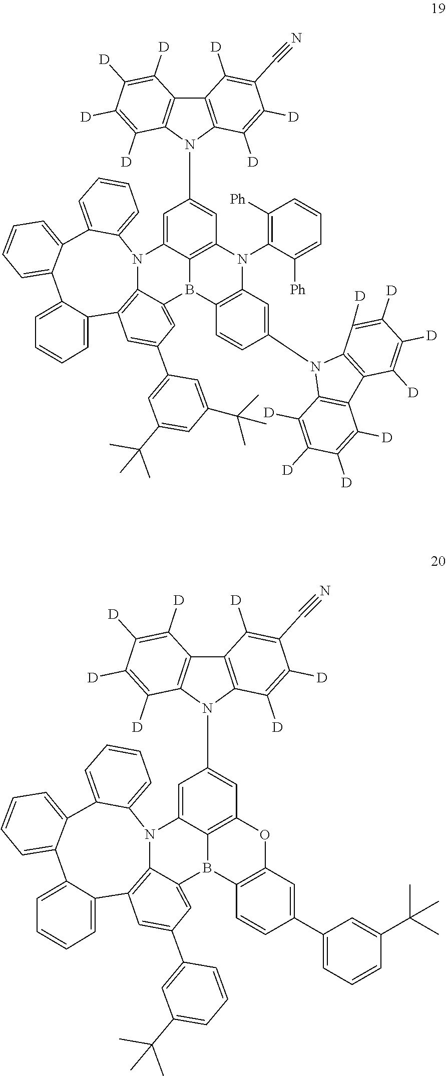 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2] 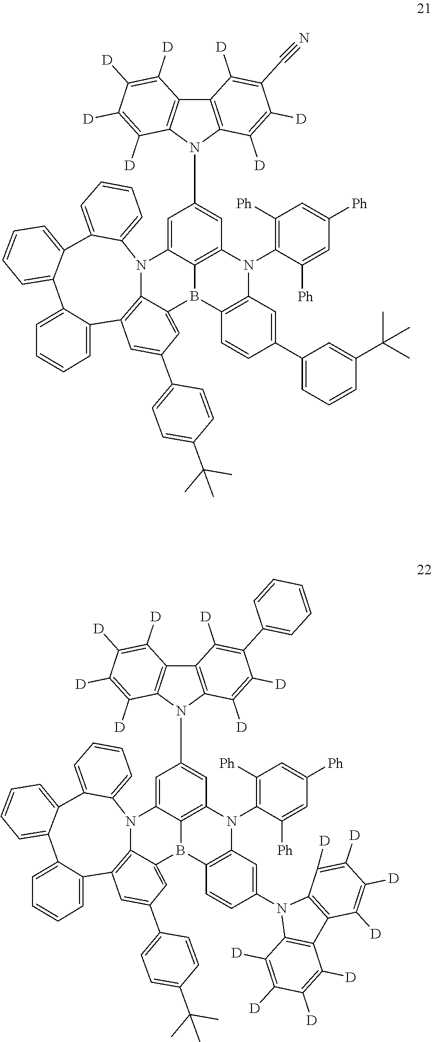 [SMILES: [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5ccc(C(C)(C)C)cc5)cc(c41)B3c1ccc(-c3cccc(C(C)(C)C)c3)cc1N2c1c(-c2ccccc2)cc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-n3c4c([2H])c([2H])c([2H])c([2H])c4c4c([2H])c(-c5ccccc5)c([2H])c([2H])c43)cc3c1B2c1cc(-c2ccc(C(C)(C)C)cc2)cc2c4ccccc4c4ccccc4c4ccccc4n-3c12] 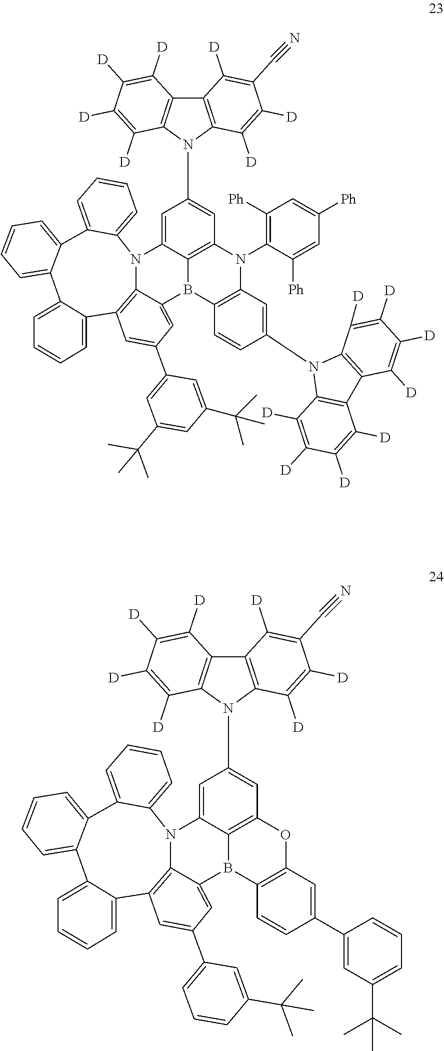 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-n3c4c([2H])c([2H])c([2H])c([2H])c4c4c([2H])c(C#N)c([2H])c([2H])c43)cc3c1B2c1cc(-c2cc(C(C)(C)C)cc(C(C)(C)C)c2)cc2c4ccccc4c4ccccc4c4ccccc4n-3c12 ; [2H]c1c([2H])c([2H])c2c(c1[2H])c1c([2H])c(C#N)c([2H])c([2H])c1n2-c1cc2c3c(c1)-n1c4ccccc4c4ccccc4c4ccccc4c4cc(-c5cccc(C(C)(C)C)c5)cc(c41)B3c1ccc(-c3cccc(C(C)(C)C)c3)cc1O2] 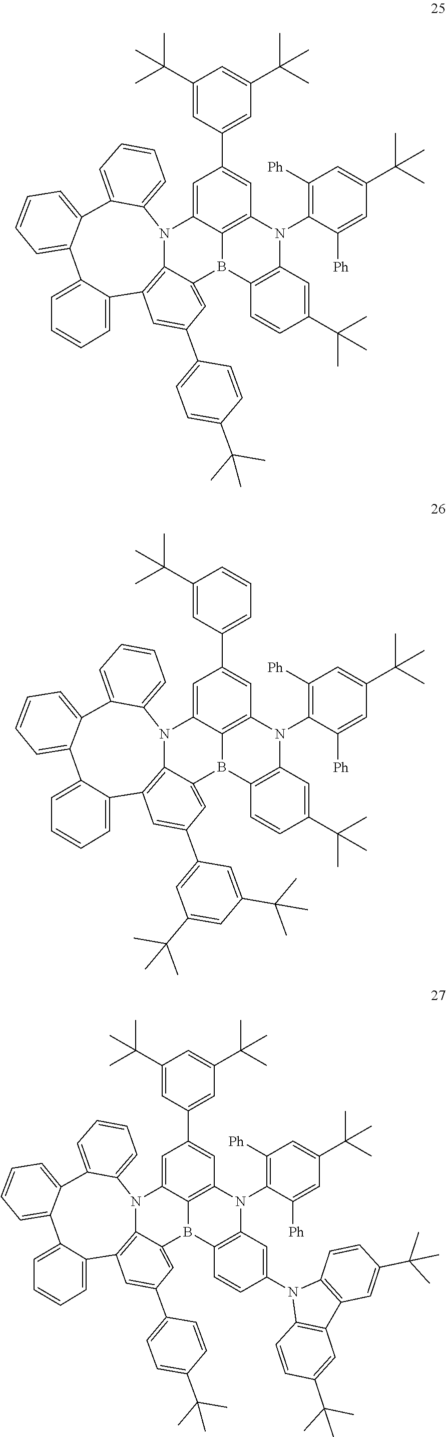 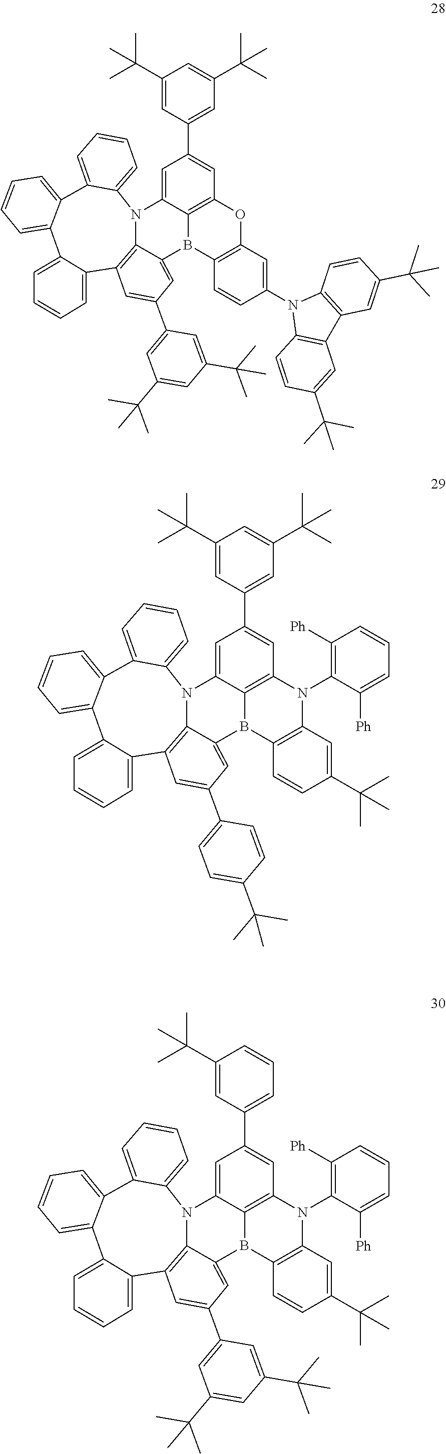 [SMILES: CC(C)(C)c1cc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc(C(C)(C)C)c1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cccc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(C(C)(C)C)cc2N3c2c(-c3ccccc3)cccc2-c2ccccc2)c1] 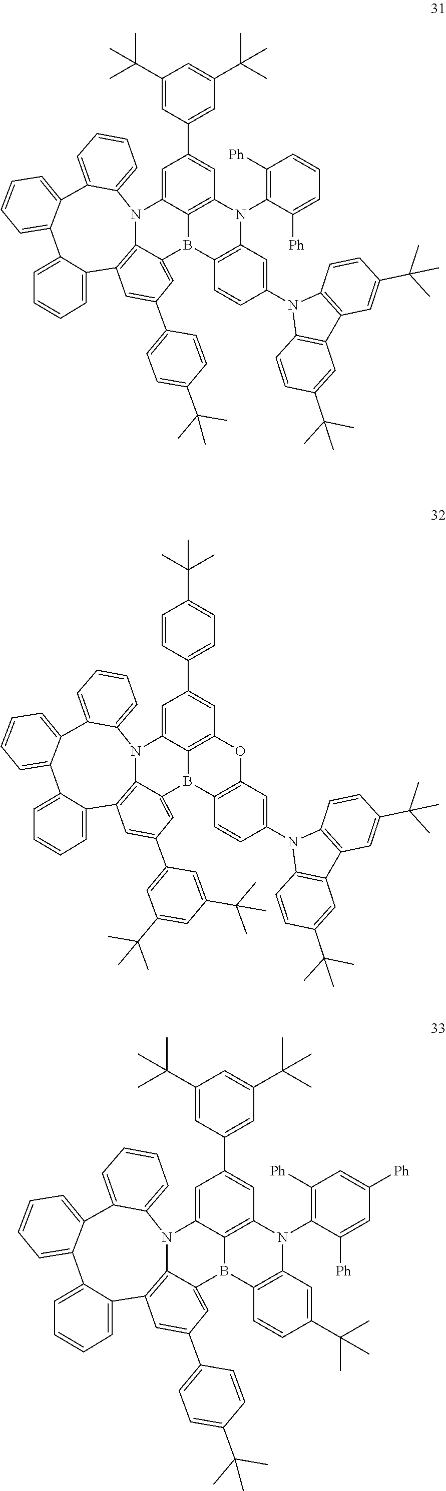 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1ccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-n4c5ccc(C(C)(C)C)cc5c5cc(C(C)(C)C)ccc54)cc2O3)cc1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(C(C)(C)C)cc2N4c2c(-c3ccccc3)cc(-c3ccccc3)cc2-c2ccccc2)cc1] 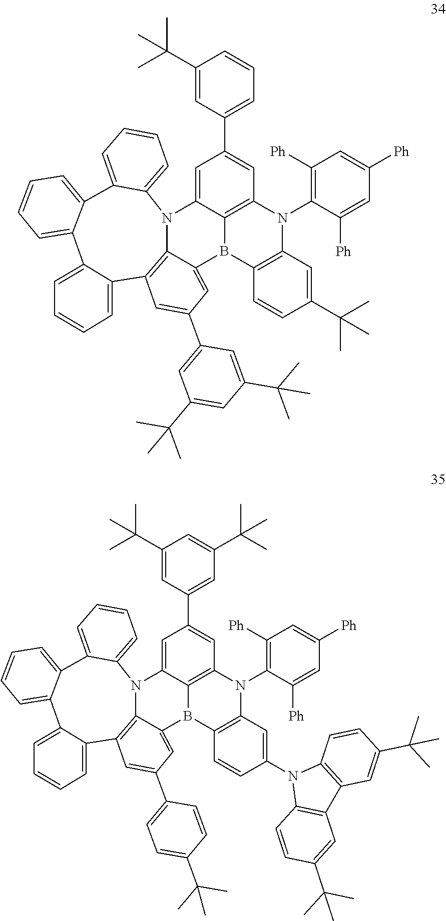 [SMILES: CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(C(C)(C)C)cc2N3c2c(-c3ccccc3)cc(-c3ccccc3)cc2-c2ccccc2)c1 ; CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc1] 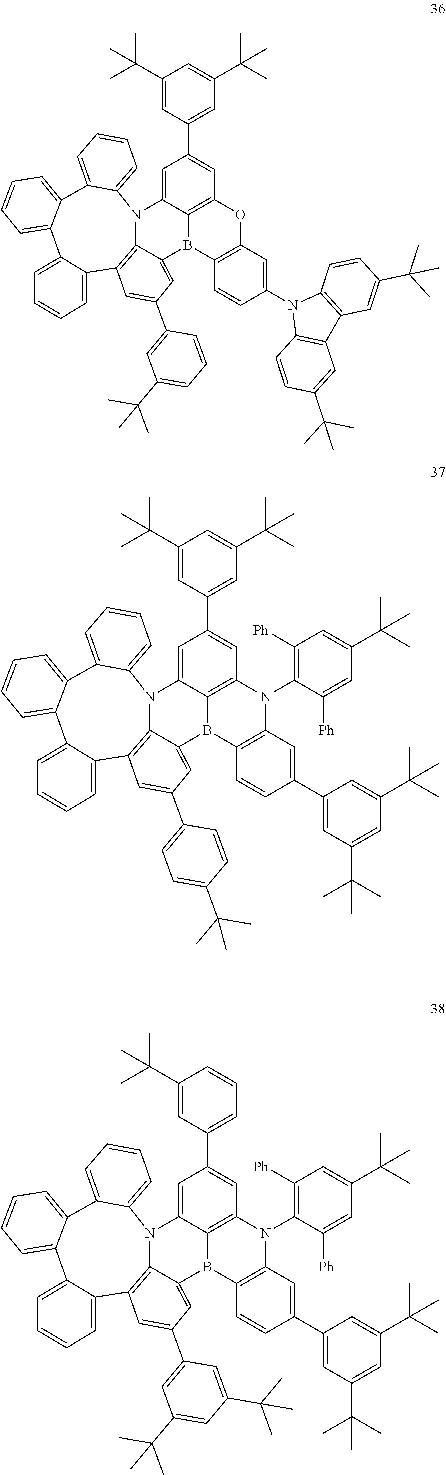 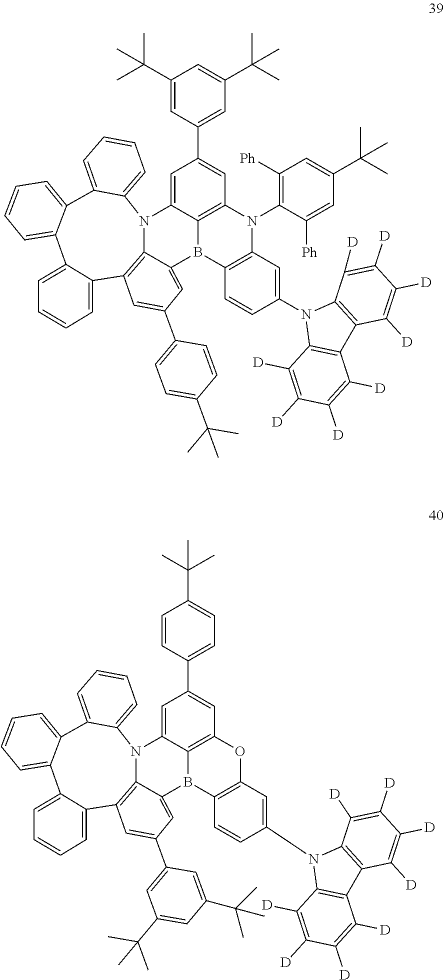 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-c3cc(C(C)(C)C)cc(C(C)(C)C)c3)cc3c1B2c1cc(-c2ccc(C(C)(C)C)cc2)cc2c4ccccc4c4ccccc4c4ccccc4n-3c12 ; [2H]c1c([2H])c([2H])c2c(c1[2H])c1c([2H])c([2H])c([2H])c([2H])c1n2-c1ccc2c(c1)Oc1cc(-c3ccc(C(C)(C)C)cc3)cc3c1B2c1cc(-c2cc(C(C)(C)C)cc(C(C)(C)C)c2)cc2c4ccccc4c4ccccc4c4ccccc4n-3c12] 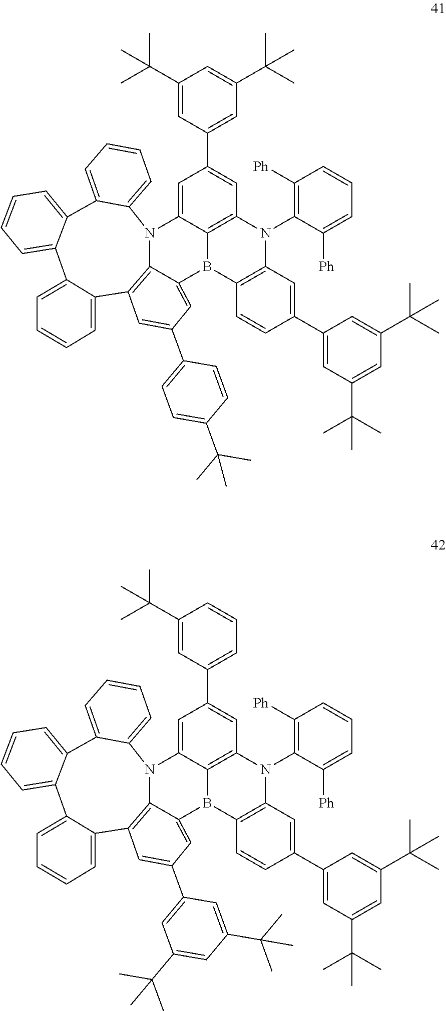 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cccc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-c4cc(C(C)(C)C)cc(C(C)(C)C)c4)cc2N3c2c(-c3ccccc3)cccc2-c2ccccc2)c1] 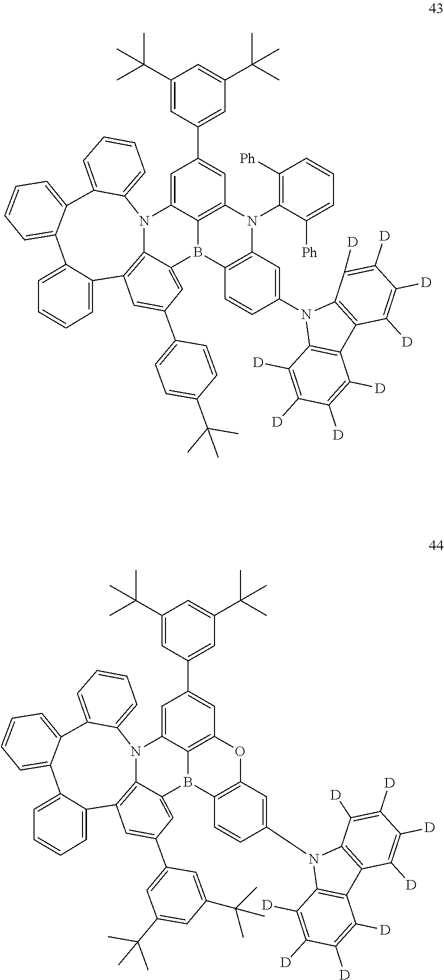 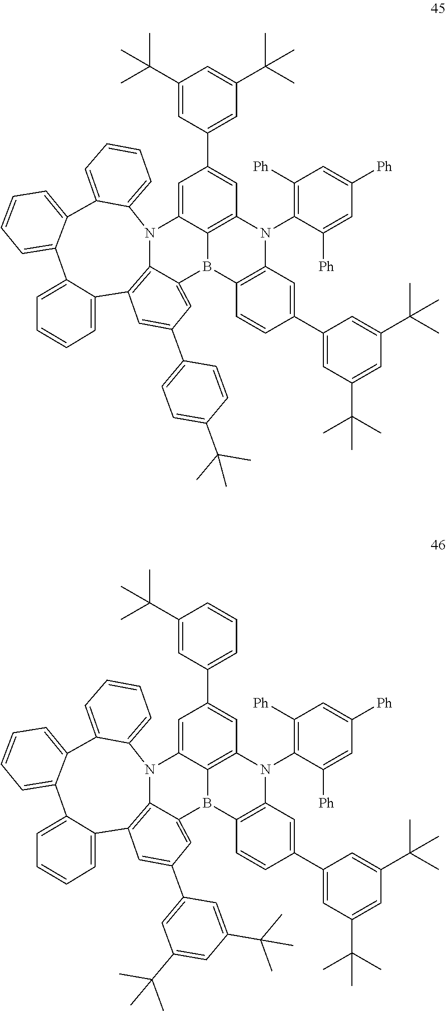 [SMILES: CC(C)(C)c1ccc(-c2cc3c4c(c2)c2ccccc2c2ccccc2c2ccccc2n4-c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(-c3ccccc3)cc2-c2ccccc2)cc1 ; CC(C)(C)c1cccc(-c2cc3c4c(c2)-n2c5ccccc5c5ccccc5c5ccccc5c5cc(-c6cc(C(C)(C)C)cc(C(C)(C)C)c6)cc(c52)B4c2ccc(-c4cc(C(C)(C)C)cc(C(C)(C)C)c4)cc2N3c2c(-c3ccccc3)cc(-c3ccccc3)cc2-c2ccccc2)c1] 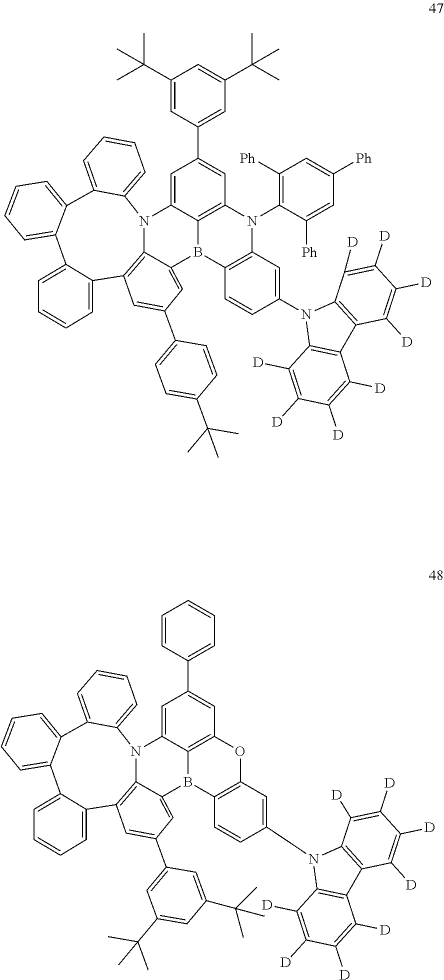 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(-c3cc(C(C)(C)C)cc(C(C)(C)C)c3)cc3c1B2c1cc(-c2ccc(C(C)(C)C)cc2)cc2c4ccccc4c4ccccc4c4ccccc4n-3c12 ; [2H]c1c([2H])c([2H])c2c(c1[2H])c1c([2H])c([2H])c([2H])c([2H])c1n2-c1ccc2c(c1)Oc1cc(-c3ccccc3)cc3c1B2c1cc(-c2cc(C(C)(C)C)cc(C(C)(C)C)c2)cc2c4ccccc4c4ccccc4c4ccccc4n-3c12] 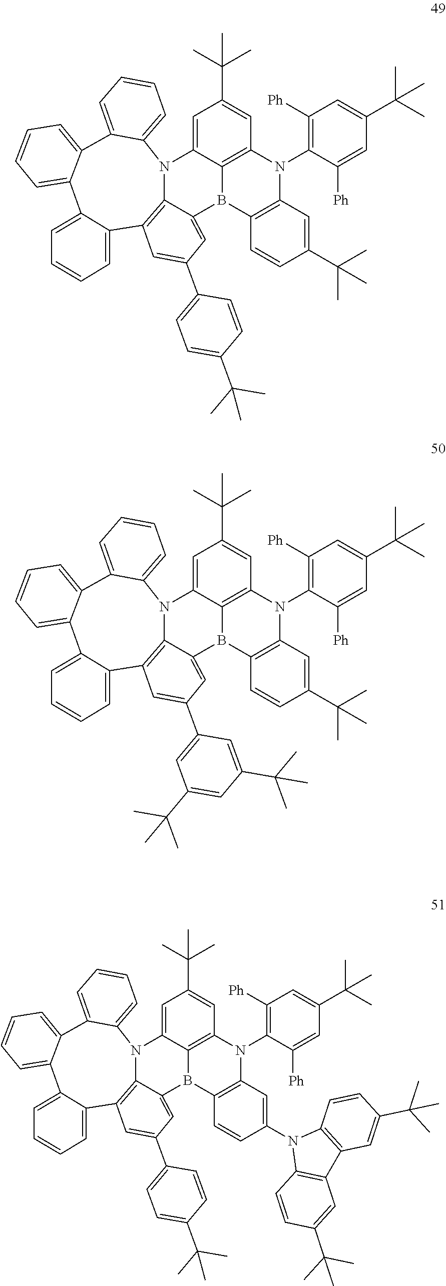 [SMILES: CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(C(C)(C)C)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc1] 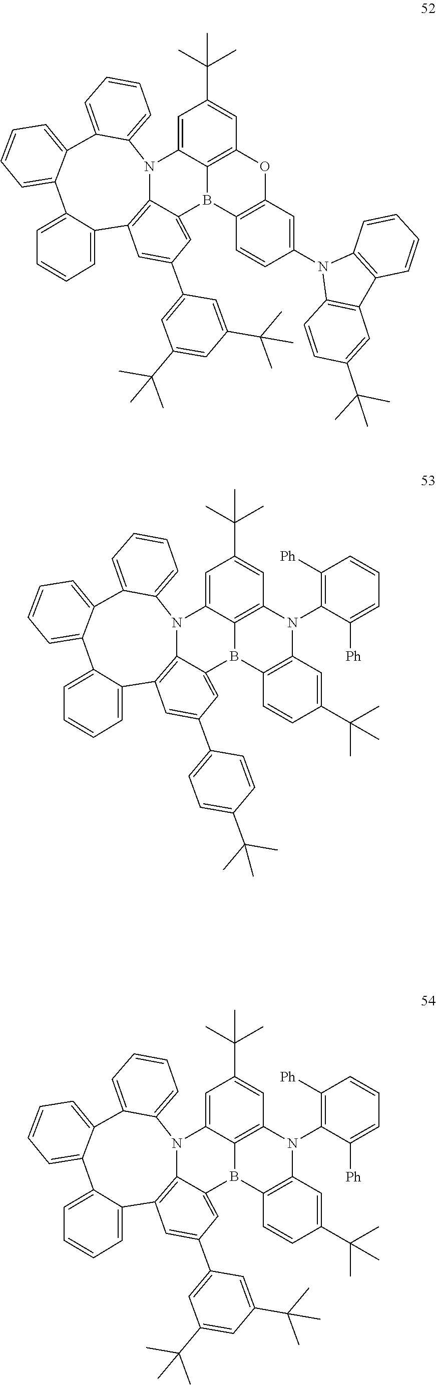 [SMILES: CC(C)(C)c1cc(-c2cc3c4c(c2)c2ccccc2c2ccccc2c2ccccc2n4-c2cc(C(C)(C)C)cc4c2B3c2ccc(-n3c5ccccc5c5cc(C(C)(C)C)ccc53)cc2O4)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cccc2-c2ccccc2)cc(C(C)(C)C)c1] 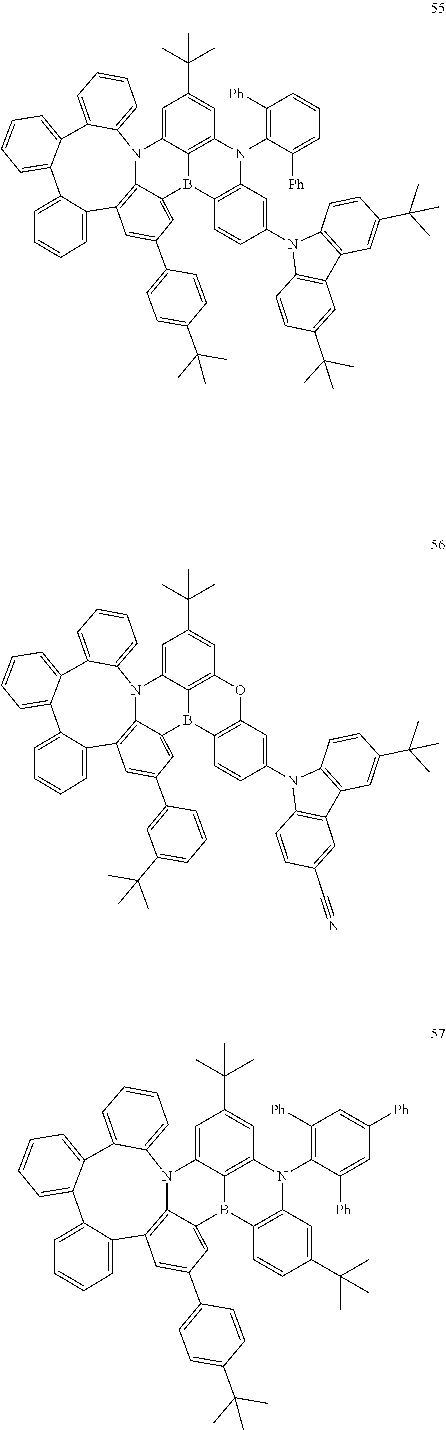 [SMILES: CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cccc2-c2ccccc2)cc1 ; CC(C)(C)c1cccc(-c2cc3c4c(c2)c2ccccc2c2ccccc2c2ccccc2n4-c2cc(C(C)(C)C)cc4c2B3c2ccc(-n3c5ccc(C#N)cc5c5cc(C(C)(C)C)ccc53)cc2O4)c1 ; CC(C)(C)c1ccc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc1] 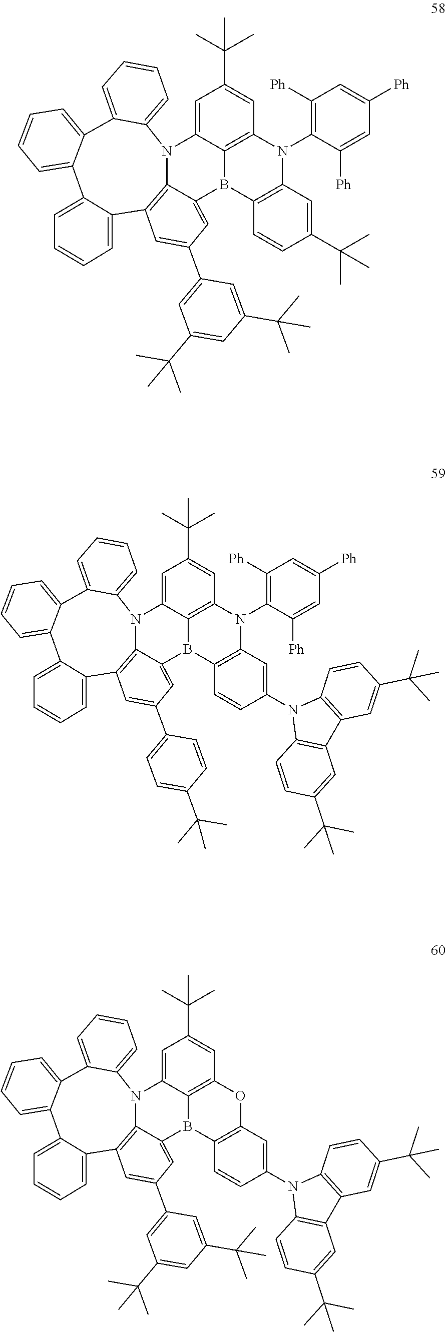 [SMILES: CC(C)(C)c1cc(-c2cc3c4c(c2)c2ccccc2c2ccccc2c2ccccc2n4-c2cc(C(C)(C)C)cc4c2B3c2ccc(C(C)(C)C)cc2N4c2c(-c3ccccc3)cc(-c3ccccc3)cc2-c2ccccc2)cc(C(C)(C)C)c1 ; CC(C)(C)c1ccc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc1 ; CC(C)(C)c1cc(-c2cc3c4c(c2)c2ccccc2c2ccccc2c2ccccc2n4-c2cc(C(C)(C)C)cc4c2B3c2ccc(-n3c5ccc(C(C)(C)C)cc5c5cc(C(C)(C)C)ccc53)cc2O4)cc(C(C)(C)C)c1] 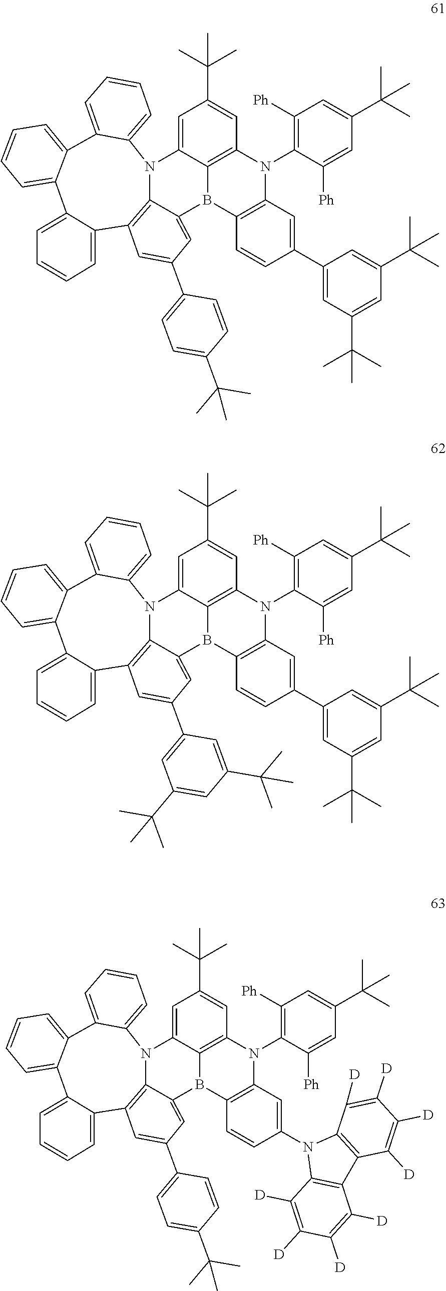 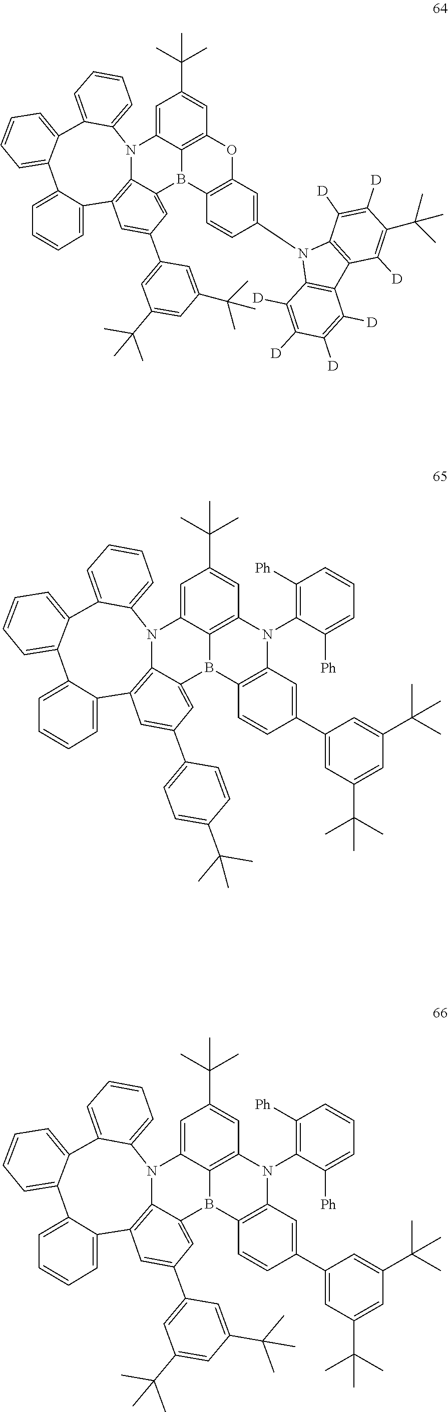 [SMILES: [2H]c1c([2H])c([2H])c2c(c1[2H])c1c([2H])c(C(C)(C)C)c([2H])c([2H])c1n2-c1ccc2c(c1)Oc1cc(C(C)(C)C)cc3c1B2c1cc(-c2cc(C(C)(C)C)cc(C(C)(C)C)c2)cc2c4ccccc4c4ccccc4c4ccccc4n-3c12 ; CC(C)(C)c1ccc(-c2cc3c4c(c2)c2ccccc2c2ccccc2c2ccccc2n4-c2cc(C(C)(C)C)cc4c2B3c2ccc(-c3cc(C(C)(C)C)cc(C(C)(C)C)c3)cc2N4c2c(-c3ccccc3)cccc2-c2ccccc2)cc1 ; CC(C)(C)c1cc(-c2ccc3c(c2)N(c2c(-c4ccccc4)cccc2-c2ccccc2)c2cc(C(C)(C)C)cc4c2B3c2cc(-c3cc(C(C)(C)C)cc(C(C)(C)C)c3)cc3c5ccccc5c5ccccc5c5ccccc5n-4c23)cc(C(C)(C)C)c1] 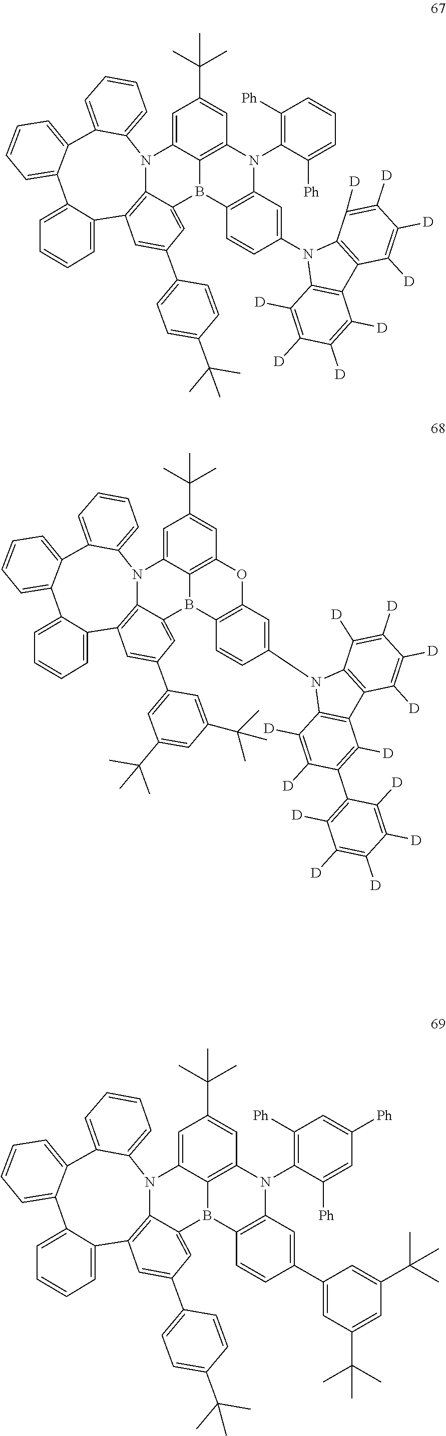 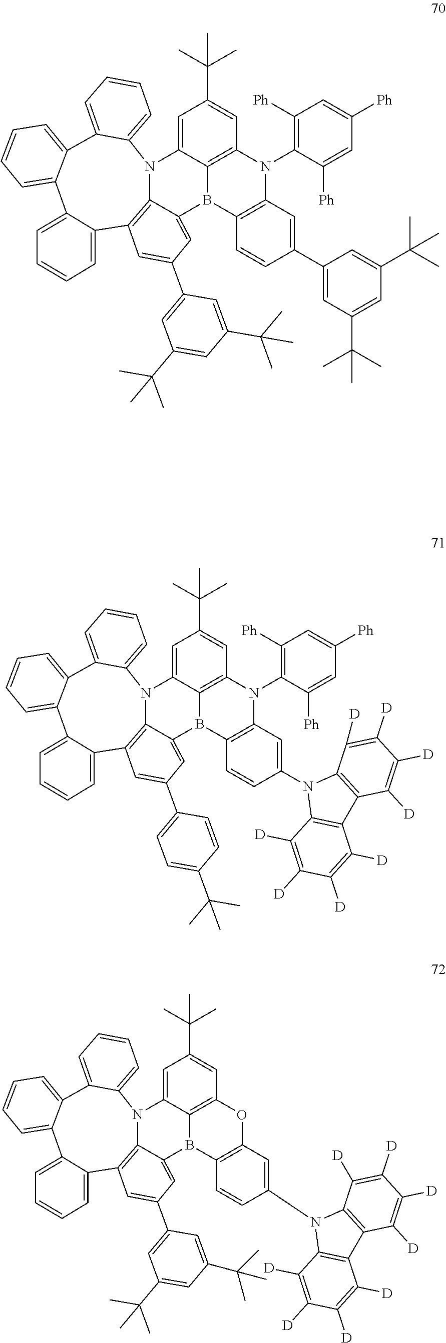 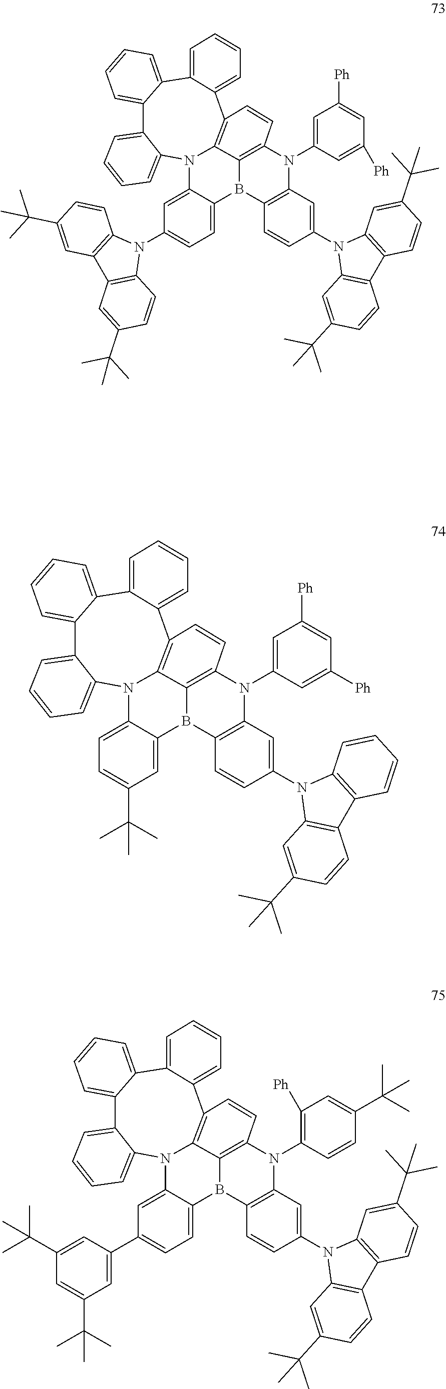 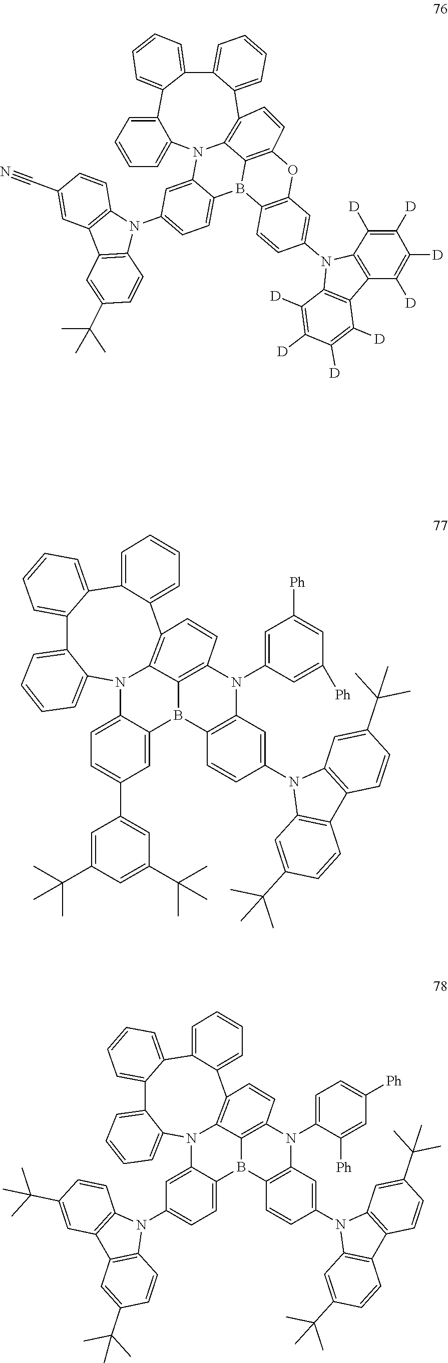 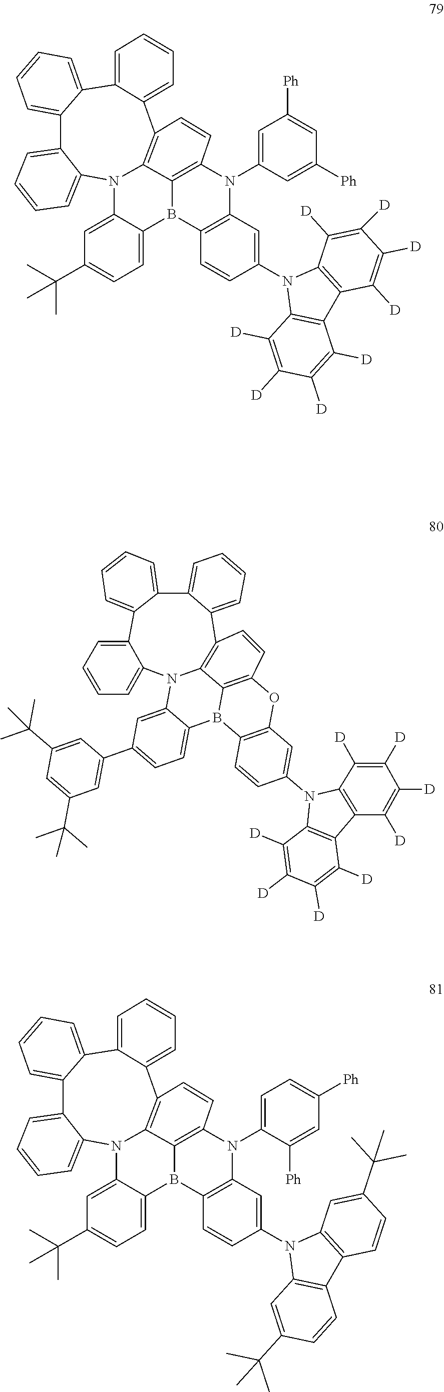 [SMILES: [2H]c1c([2H])c([2H])c2c(c1[2H])c1c([2H])c([2H])c([2H])c([2H])c1n2-c1ccc2c(c1)N(c1cc(-c3ccccc3)cc(-c3ccccc3)c1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1ccc(-c2ccccc2)cc1-c1ccccc1] 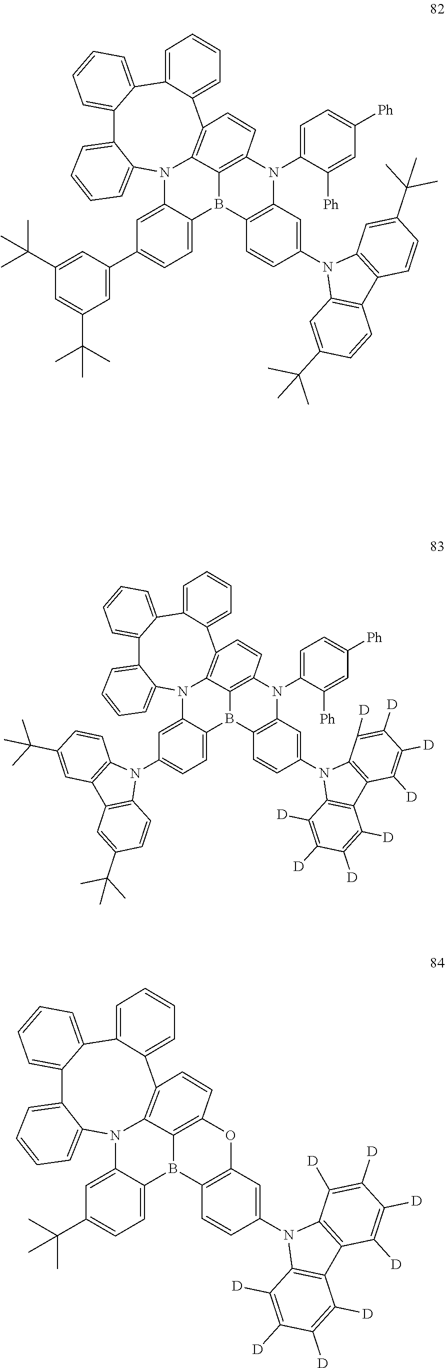 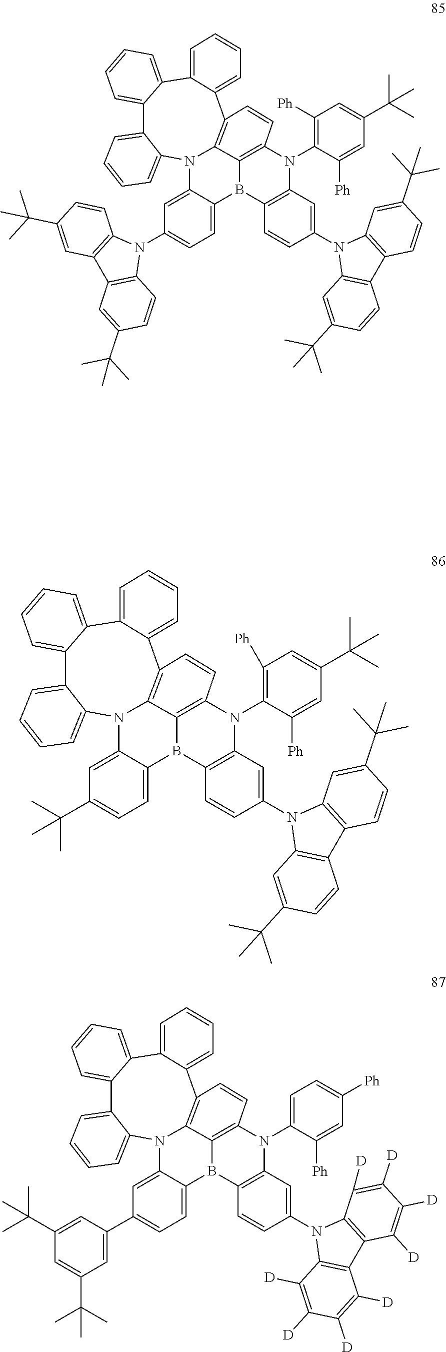 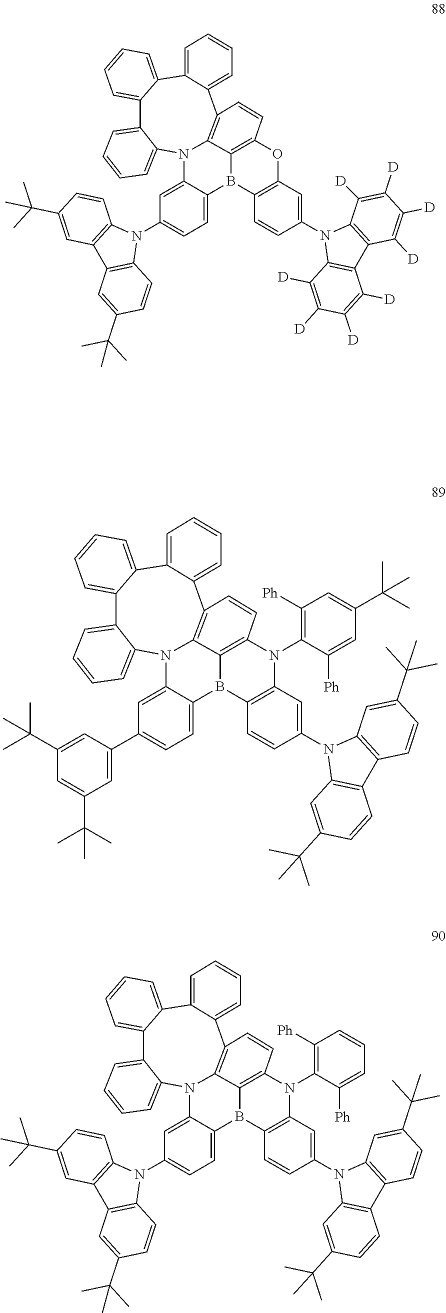 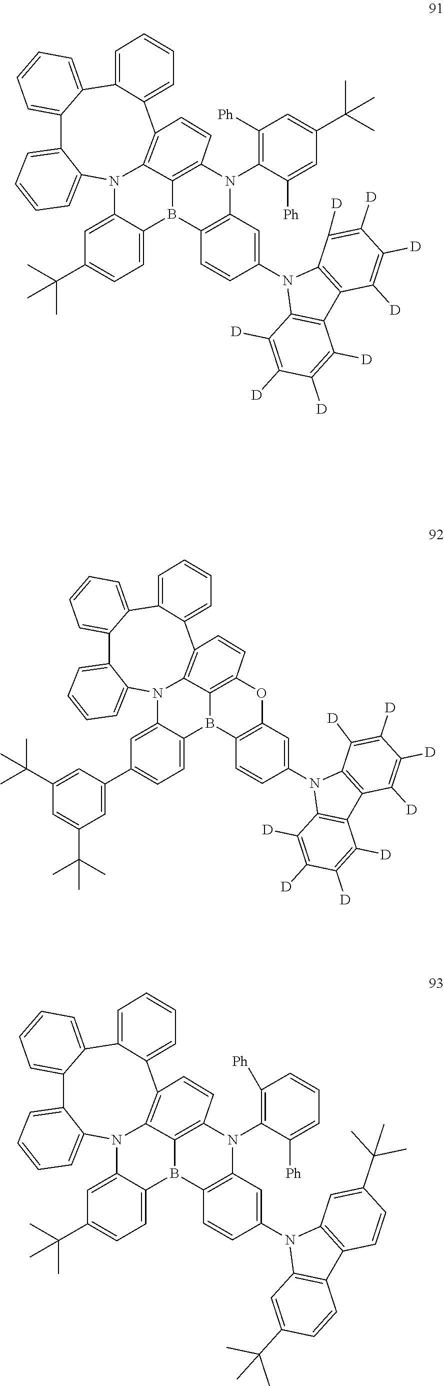 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1ccc3c4ccccc4c4ccccc4c4ccccc4n4c3c1B2c1ccc(C(C)(C)C)cc1-4 ; [2H]c1c([2H])c([2H])c2c(c1[2H])c1c([2H])c([2H])c([2H])c([2H])c1n2-c1ccc2c(c1)Oc1ccc3c4ccccc4c4ccccc4c4ccccc4n4c3c1B2c1ccc(-c2cc(C(C)(C)C)cc(C(C)(C)C)c2)cc1-4 ; CC(C)(C)c1ccc2c(c1)-n1c3ccccc3c3ccccc3c3ccccc3c3ccc4c(c31)B2c1ccc(-n2c3cc(C(C)(C)C)ccc3c3ccc(C(C)(C)C)cc32)cc1N4c1c(-c2ccccc2)cccc1-c1ccccc1] 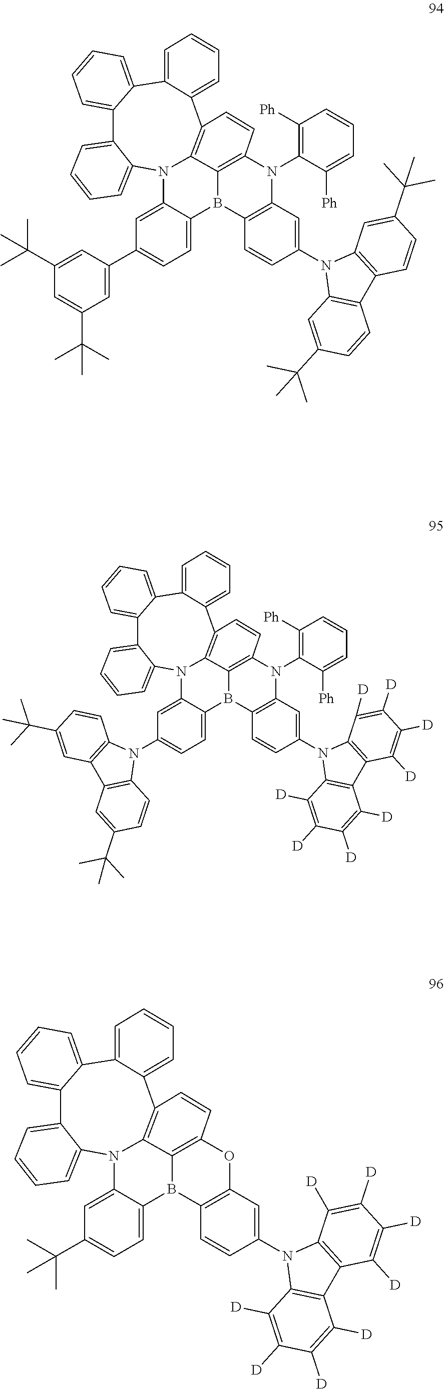 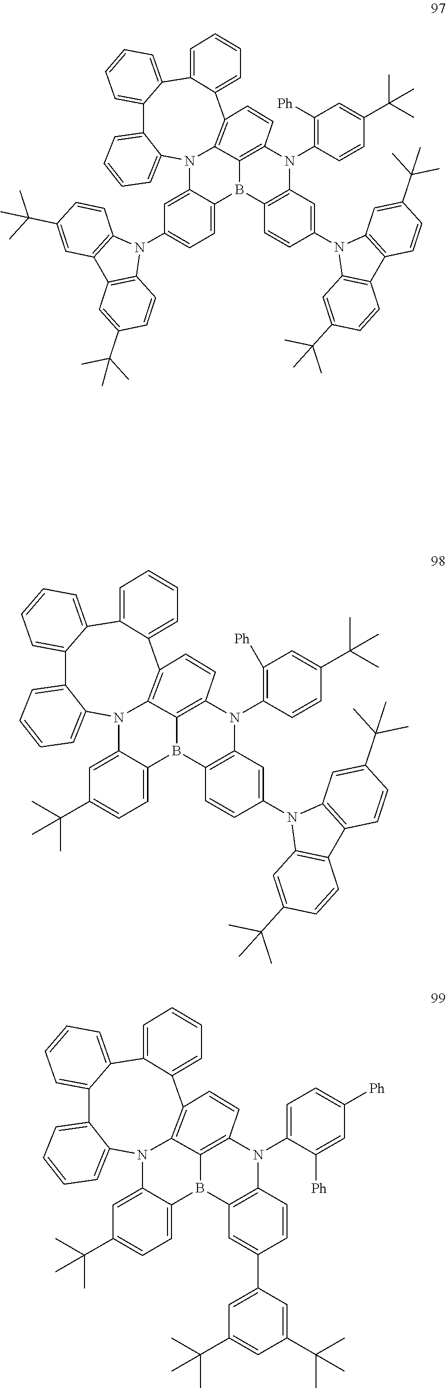 [SMILES: CC(C)(C)c1ccc(N2c3cc(-n4c5cc(C(C)(C)C)ccc5c5ccc(C(C)(C)C)cc54)ccc3B3c4ccc(-n5c6ccc(C(C)(C)C)cc6c6cc(C(C)(C)C)ccc65)cc4-n4c5ccccc5c5ccccc5c5ccccc5c5ccc2c3c54)c(-c2ccccc2)c1 ; CC(C)(C)c1ccc(N2c3cc(-n4c5cc(C(C)(C)C)ccc5c5ccc(C(C)(C)C)cc54)ccc3B3c4ccc(C(C)(C)C)cc4-n4c5ccccc5c5ccccc5c5ccccc5c5ccc2c3c54)c(-c2ccccc2)c1 ; CC(C)(C)c1cc(-c2ccc3c(c2)B2c4ccc(C(C)(C)C)cc4-n4c5ccccc5c5ccccc5c5ccccc5c5ccc(c2c54)N3c2ccc(-c3ccccc3)cc2-c2ccccc2)cc(C(C)(C)C)c1] 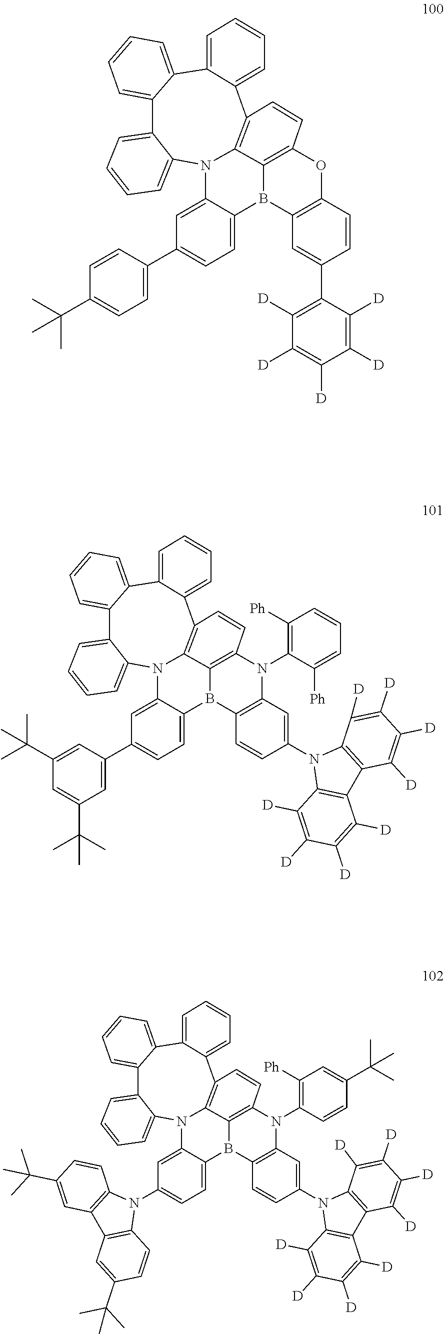 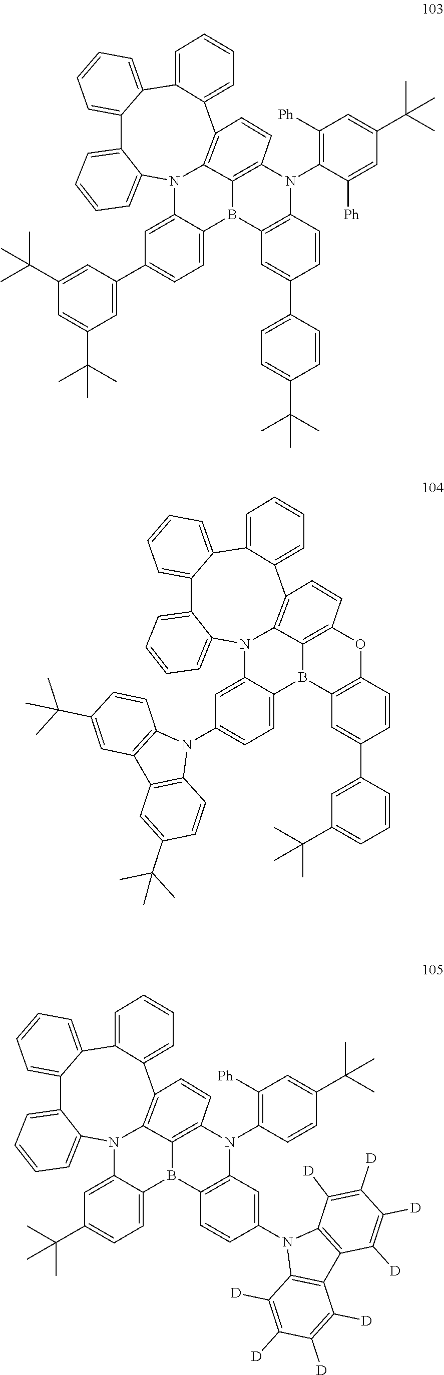 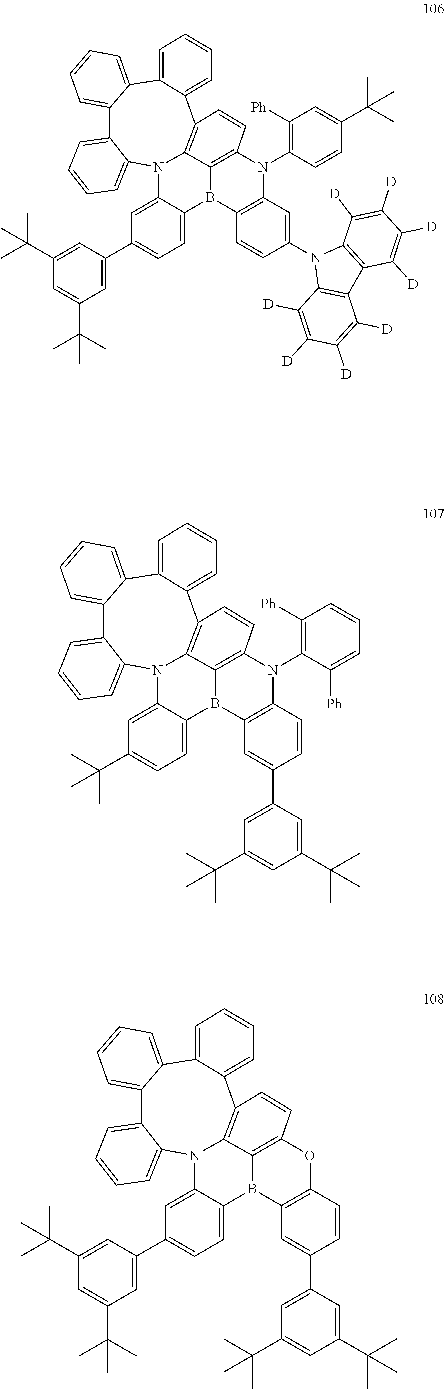 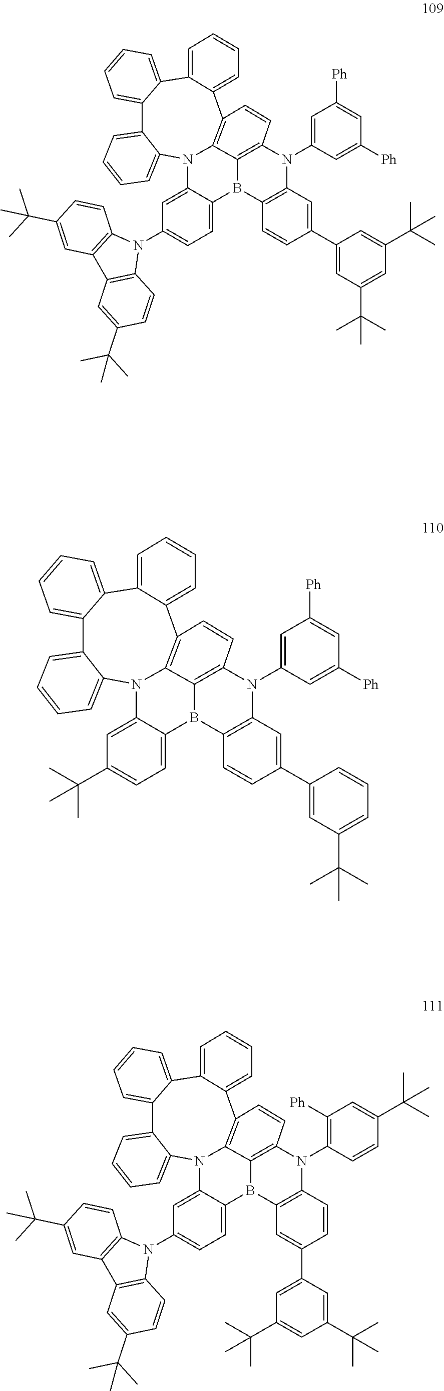 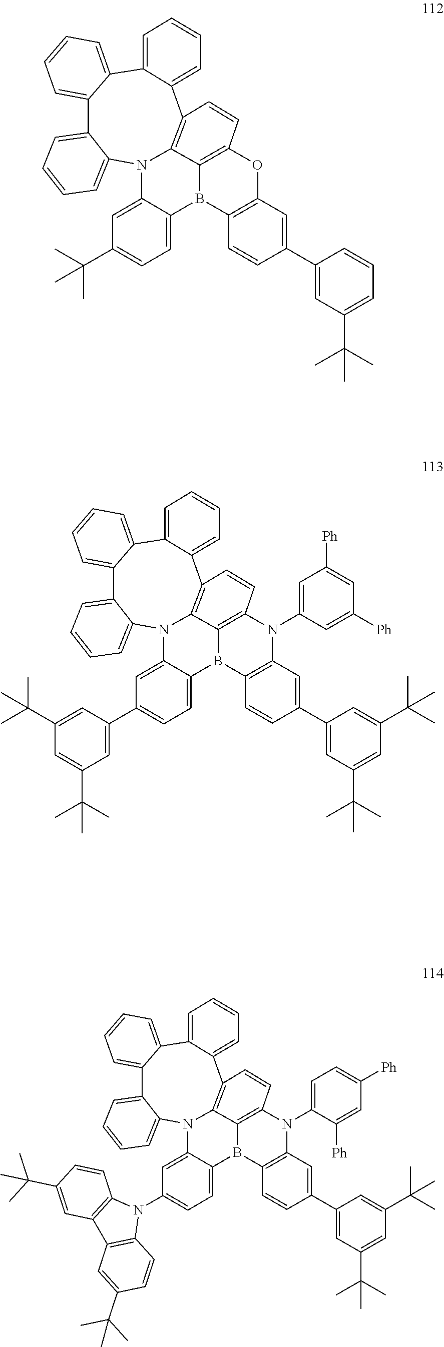 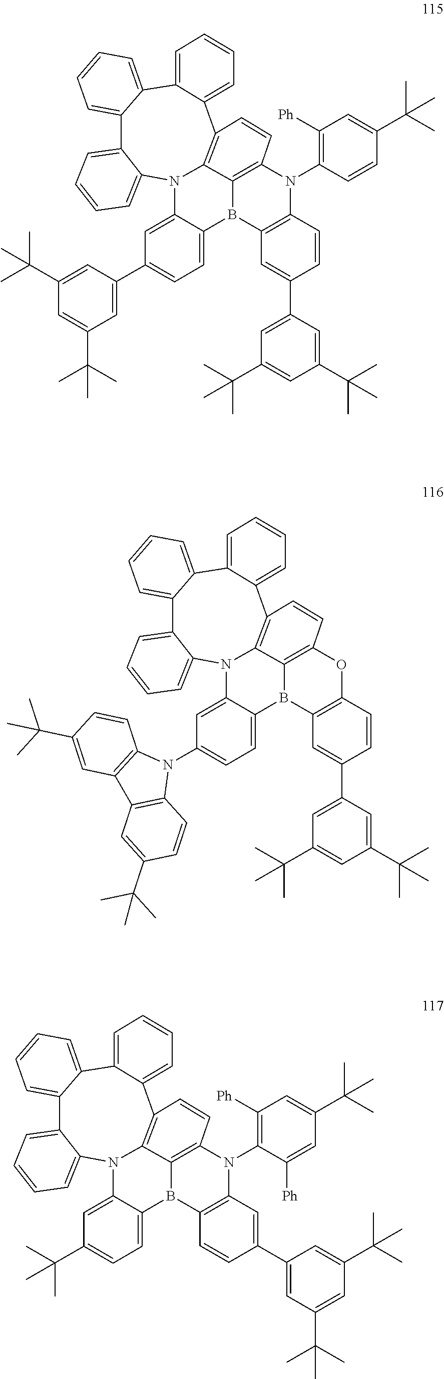 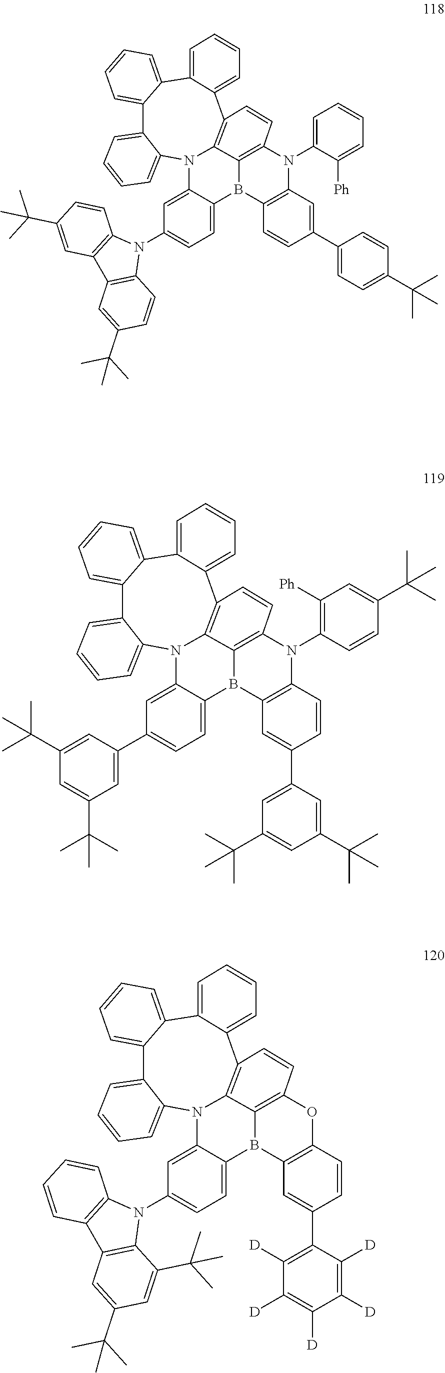
wherein in Compound Group 1, D is a deuterium atom, and Ph is a phenyl group.
